(19) United States
(12) Patent Application Publication
(10) Pub. No.: US 2020/0227644 A1
(43) Pub. Date: Jul. 16, 2020

(54) ORGANIC LIGHT-EMITTING DIODE OPERABLE AT LOW VOLTAGE WITH HIGH EFFICIENCY AND LONG LIFETIME

(71) Applicant: SFC CO., LTD., Cheongju-si (KR)

(72) Inventors: Se-Jin LEE, Cheongju-si (KR); Seok-Bae PARK, Cheongju-si (KR); Bong-Hyang LEE, Cheongju-si (KR); Taejung YU, Cheongju-si (KR); Yeong-Tae CHOI, Cheongju-si (KR); Dajung LEE, Cheongju-si (KR); Seongeun WOO, Cheongju-si (KR)

(21) Appl. No.: 16/629,072

(22) PCT Filed: Jul. 23, 2018
(86) PCT No.: PCT/KR2018/008302

§ 371 Date: Jan. 7, 2020

(30) Foreign Application Priority Data
Jul. 27, 2017 (KR) 10-2017-0095481

(51) Int. Cl. H01L 51/00

(52) U.S. Cl. CPC H01L 51/0061; H01L 51/5012; H01L 51/006

(57) ABSTRACT

Disclosed herein is an organic light-emitting diode comprising: a first electrode; a second electrode facing the first electrode; a light-emitting layer interposed between the first electrode and the second electrode, wherein the light-emitting layer contains at least one of fused ring compounds represented by Chemical Formula A and at least one of hetero ring compounds represented by Chemical Formula D, the Chemical formulas A and B being as defined in the description of the invention.

### TECHNICAL FIELD

The present disclosure pertains to an organic light-emitting diode that can operate at a low voltage with high emission efficiency and long lifetime and, more particularly, to an organic light-emitting diode employing a host material of a specific structure in a light-emitting layer thereof.

### BACKGROUND ART

Organic light-emitting diodes (OLEDs), based on self-luminescence, are used to create digital displays with the advantage of having a wide viewing angle and being able to be made thinner and lighter than liquid crystal displays. In addition, an OLED display exhibits a very fast response time. Accordingly, OLEDs find applications in the full color display field or the illumination field.

In general, the term “organic light-emitting phenomenon” refers to a phenomenon in which electrical energy is converted to light energy by means of an organic material. An organic light-emitting diode using the organic light-emitting phenomenon has a structure usually including an anode, a cathode, and an organic layer interposed therebetween.

In this regard, the organic layer may have, for the most part, a multilayer structure consisting of different materials, for example, a hole injection layer, a hole transport layer, a light-emitting layer, an electron transport layer, and an electron injection layer in order to enhance the efficiency and stability of the organic light-emitting diode. In the organic light-emitting diode having such a structure, application of a voltage between the two electrodes injects a hole from the anode and an electron from the cathode to the organic layer. In the luminescent zone, the hole and the electron recombine to produce an exciton. When the exciton returns to the ground state from the excited state, the molecule of the organic layer emits light. Such an organic light-emitting diode is known to have characteristics such as self-luminescence, high luminance, high efficiency, low driving voltage, a wide viewing angle, high contrast, and high-speed response.

The light-emitting mechanism forms the basis of classification of luminescent materials as fluorescent and phosphorescent materials, which use excitons in singlet and triplet states, respectively.

Meanwhile, when a single material is employed as the luminescent material, intermolecular actions cause the maximum luminescence wavelength to shift toward a longer wavelength, resulting in a reduction in color purity and light emission efficiency due to light attenuation. In this regard, a host-dopant system may be used as a luminescent material so as to increase the color purity and the light emission efficiency through energy transfer.

This is based on the principle whereby, when a dopant which is smaller in energy band gap than a host forming a light-emitting layer is added in a small amount to the light-emitting layer, excitons are generated from the light-emitting layer and transported to the dopant, emitting light at high efficiency. Here, light with desired wavelengths can be obtained depending on the kind of the dopant because the wavelength of the host moves to the wavelength range of the dopant.

With regard to related arts pertaining to host compounds for use in such a light-emitting layer, reference may be made to Korean Patent No. 10-2011-0013220 A (Feb. 9, 2011), which discloses an organic compound having a 6-membered aromatic or heteroaromatic ring frame grafted with an aromatic heterocyclic ring, and Japanese Patent No. 2010-166070 A (Jul. 29, 2010), which discloses an organic compound having a substituted or unsubstituted pyrimidine or quinazoline frame grafted with an aryl or heteroaryl ring.

In spite of enormous effort for fabricating organic light-emitting diodes as in conventional technologies including the cited documents, however, there is still continued need to develop novel organic light-emitting diodes having more improved emission efficacy and long lifetime.

### DETAILED DESCRIPTION OF THE INVENTION

### Technical Problem

Therefore, the purpose of the present disclosure is to provide a novel organic light-emitting diode (OLED) with high efficiency and long lifetime, wherein a host having a specific structure is contained in a light-emitting layer.

### Technical Solution

The present disclosure provides an organic light-emitting diode, comprising: a first electrode; a second electrode facing the first electrode; a light-emitting layer interposed between the first electrode and the second electrode, wherein the light-emitting layer contains at least one of fused ring compounds represented by the following Chemical Formula A and at least one of hetero ring compounds represented by the following Chemical Formula D:

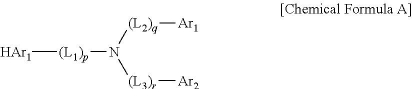

wherein,

Ar₁ and Ar₂, which may be the same or different, are each independently any one selected from a hydrogen atom, a deuterium atom, a halogen, a cyano, a substituted or unsubstituted alkyl of 1 to 20 carbon atoms, a substituted or unsubstituted cycloalkyl of 3 to 20 carbon atoms, a substituted or unsubstituted alkoxy of 1 to 20 carbon atoms, a substituted or unsubstituted aryloxy of 6 to 30 carbon atoms, a substituted or unsubstituted alkylthio of 1 to 20 carbon atoms, a substituted or unsubstituted arylthio of 6 to 30 carbon atoms, a substituted or unsubstituted alkylsilyl of 3 to 50 carbon atoms, a substituted or unsubstituted arylsilyl of 6 to 50 carbon atoms, a substituted or unsubstituted aromatic hydrocarbon of 6 to 30 carbon atoms, and a substituted or unsubstituted hetero ring of 5 to 30 carbon atoms and may each bond to an adjacent radical to form an aliphatic, aromatic, heteroaliphatic, or heteroaromatic fused ring,

linkers L₁ to L₃, which may be the same or different, are each independently a single bond or selected from a substituted or unsubstituted arylene of 6 to 60 carbon atoms and a substituted or unsubstituted heteroarylene of 2 to 60 carbon atoms,

p, q, and r are each an integer of 0 to 3 wherein any of p, q, and r is 2 or greater, the corresponding linkers L₁'s to L₃'s may be the same or different,

HAr₁ is represented by the following [Structural Formula 1]:

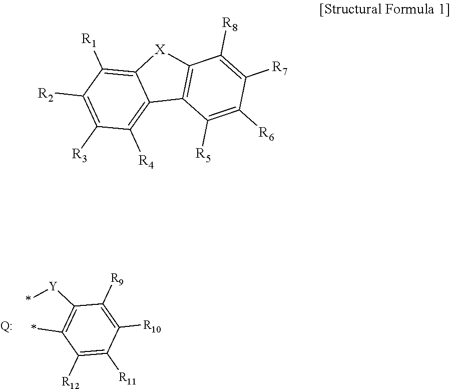

wherein,

X and Y, which may be the same or different, are each independently any one selected from O, S, and CR₁₃R₁₄,

R₁ to R₁₄, which may be the same or different, are each independently any one selected from a hydrogen atom, a deuterium atom, a halogen, a cyano, a substituted or unsubstituted alkyl of 1 to 20 carbon atoms, a substituted or unsubstituted cycloalkyl of 3 to 20 carbon atoms, a substituted or unsubstituted alkoxy of 1 to 20 carbon atoms, a substituted or unsubstituted aryloxy of 6 to 30 carbon atoms, a substituted or unsubstituted alkylthio of 1 to 20 carbon atoms, a substituted or unsubstituted arylthio of 6 to 30 carbon atoms, a substituted or unsubstituted alkylsilyl of 3 to 50 carbon atoms, a substituted or unsubstituted arylsilyl of 6 to 50 carbon atoms, a substituted or unsubstituted aromatic hydrocarbon of 6 to 30 carbon atoms, and a substituted or unsubstituted hetero ring of 5 to 30 carbon atoms as ring members and may each bond to an adjacent radical to form an aliphatic, aromatic, heteroaliphatic, or heteroaromatic fused ring,

two adjacent radicals of R₅ to R₈ are each a single bond connected to * in the Structural Formula Q

any one of R₁ to R₁₂ in Structural Formula 1 representing HAr₁ is a single bond connected to the linker L₁ in Chemical Formula A;

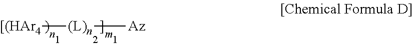

wherein,

HAr₄ is a substituted or unsubstituted aryl of 6 to 30 carbon atoms, or a substituted or unsubstituted heteroaryl of 3 to 30 carbon atoms,

L is a single bond, or any one selected from a substituted or unsubstituted arylene of 6 to 60 carbon atoms and a substituted or unsubstituted heteroarylene of 2 to 60 carbon atoms,

n₁ and n₂ are each an integer of 0 to 3 wherein when any of n₁ and n₂ is two or greater, the corresponding multiple HAr₄ or L are the same or different,

m₁ is an integer of 1 to 4 wherein when m₁ is 2 or greater, the corresponding HAr₄- and L-bearing moieties within the parentheses

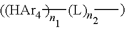

may be the same or different,

Az is represented by any one of the following [Structural Formula 2] to [Structural Formula 8]:

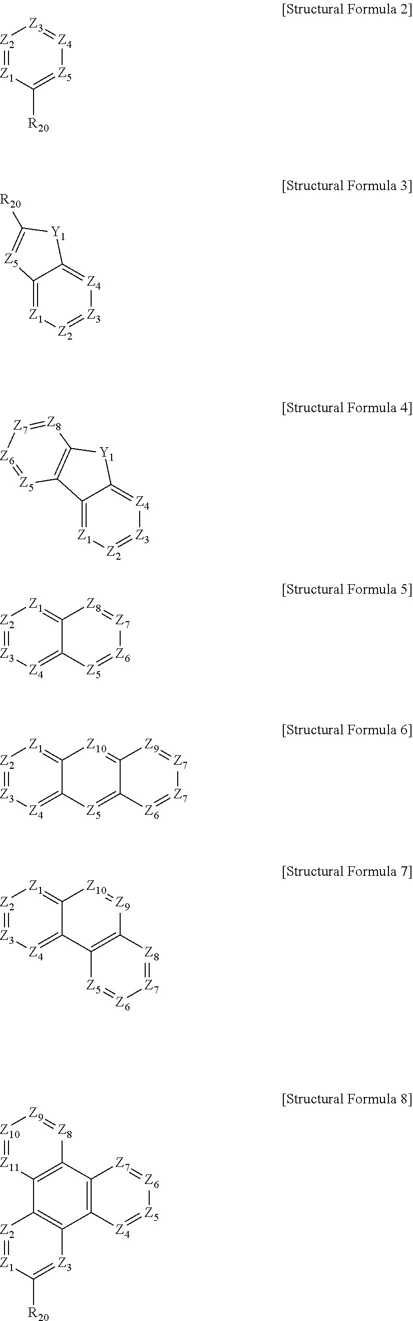

wherein,

Z₁ is N or CR₂₁,

Z₂ is N or CR₂₂,

Z₃ is N or CR₂₃,

Z₄ is N or CR₂₄,

Z₅ is N or CR₂₅,

Z₆ is N or CR₂₆,

Z₇ is N or CR₂₇,

Z₈ is N or CR₂₈,

Z₉ is N or CR₂₉,

Z₁₀ is N or CR₃₀,

Z₁₁ is N or CR₃₁,

Y₁ is any one of O, S, NR₃₂, and CR₃₃R₃₄,

at least one of Z₁ to Z₅ in Structural Formula 2 is N, and m₁ substituents of the substituents R₂₀ to R₂₅ are each a single bond connected to the linker L so that the aromatic ring moiety of Structural Formula 2 has m₁ single bonds to the linker L,

at least one of Z₁ to Z₅ in Structural Formula 3 is N, and m₁ substituents of the substituents R₂₀ to R₂₅ are each a single bond connected to the linker L so that the aromatic ring moiety of Structural Formula 3 has m₁ single bonds to the linker L,

at least one of Z₁ to Z₈ in Structural Formula 4 is N, and m₁ substituents of the substituents R₂₁ to R₂₈ are each a single bond connected to the linker L so that the aromatic ring moiety of Structural Formula 4 has m₁ single bonds to the linker L,

at least one of Z₁ to Z₈ in Structural Formula 5 is N, and m₁ substituents of the substituents R₂₁ to R₂₈ are each a single bond connected to the linker L so that the aromatic ring moiety of Structural Formula 5 has m₁ single bonds to the linker L,

at least one of Z₁ to Z₁₀ in Structural Formula 6 is N, and m₁ substituents of the substituents R₂₁ to R₃₀ are each a single bond connected to the linker L so that the aromatic ring moiety of Structural Formula 6 has m₁ single bonds to the linker L,

at least one of Z₁ to Z₁₀ in Structural Formula 7 is N, and m₁ substituents of the substituents R₂₁ to R₃₀ are each a single bond connected to the linker L so that the aromatic ring moiety of Structural Formula 7 has m₁ single bonds to the linker L,

at least one of Z₁ to Z₁₁ in Structural Formula 8 is N, and m₁ substituents of the substituents R₂₀ to R₃₁ are each a single bond connected to the linker L so that the aromatic ring moiety of Structural Formula 5 has m₁ single bonds to the linker L,

R₂₀ to R₃₄, which may be the same or different, are each independently any one selected from a hydrogen atom, a deuterium atom, a halogen, a cyano, a substituted or unsubstituted alkyl of 1 to 20 carbon atoms, a substituted or unsubstituted cycloalkyl of 3 to 20 carbon atoms, a substituted or unsubstituted alkoxy of 1 to 20 carbon atoms, a substituted or unsubstituted aryloxy of 6 to 30 carbon atoms, a substituted or unsubstituted alkylthio of 1 to 20 carbon atoms, a substituted or unsubstituted arylthio of 6 to 30 carbon atoms, a substituted or unsubstituted alkylsilyl of 3 to 50 carbon atoms, a substituted or unsubstituted arylsilyl of 6 to 50 carbon atoms, a substituted or unsubstituted aromatic hydrocarbon of 6 to 30 carbon atoms, and a substituted or unsubstituted hetero ring of 5 to 30 carbon atoms and may each bond to an adjacent radical to form an aliphatic, aromatic, hetero aliphatic or heteroaromatic fused ring.

### Advantageous Effect

Employing a combination of hosts having specific structures in the light-emitting layer thereof, the organic light-emitting diode according to the present disclosure can operate at a low voltage and can exhibit more improved emission efficacy and a longer lifetime than conventional organic light-emitting diodes.

### BRIEF DESCRIPTION OF THE DRAWINGS

FIG. 1 is a schematic view of an organic light-emitting diode according to an embodiment of the present disclosure.

### BEST MODE FOR INVENTION

Hereinafter, exemplary embodiments which can be easily implemented by those skilled in the art will be described with reference to the accompanying drawings. In each drawing of the present disclosure, sizes or scales of components may be enlarged or reduced than their actual sizes or scales for better illustration, and known components are not depicted therein to clearly show features of the present disclosure. Therefore, the present disclosure is not limited to the drawings.

When describing the principle of the embodiments of the present disclosure in detail, details of well-known functions and features may be omitted to avoid unnecessarily obscuring the presented embodiments.

Provided is an organic light-emitting diode comprising: a first electrode; a second electrode facing the first electrode; a light-emitting layer interposed between the first electrode and the second electrode, wherein the light-emitting layer contains at least one of fused ring compounds represented by the following Chemical Formula A and at least one of hetero ring compounds represented by the following Chemical Formula D:

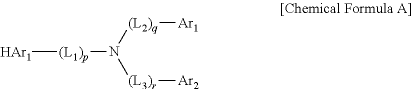

wherein,

Ar₁ and Ar₂, which may be the same or different, are each independently any one selected from a hydrogen atom, a deuterium atom, a halogen, a cyano, a substituted or unsubstituted alkyl of 1 to 20 carbon atoms, a substituted or unsubstituted cycloalkyl of 3 to 20 carbon atoms, a substituted or unsubstituted alkoxy of 1 to 20 carbon atoms, a substituted or unsubstituted aryloxy of 6 to 30 carbon atoms, a substituted or unsubstituted alkylthio of 1 to 20 carbon atoms, a substituted or unsubstituted arylthio of 6 to 30 carbon atoms, a substituted or unsubstituted alkylsilyl of 3 to 50 carbon atoms, a substituted or unsubstituted arylsilyl of 6 to 50 carbon atoms, a substituted or unsubstituted aromatic hydrocarbon of 6 to 30 carbon atoms, and a substituted or unsubstituted hetero ring of 5 to 30 carbon atoms and may each bond to an adjacent radical to form an aliphatic, aromatic, heteroaliphatic, or heteroaromatic fused ring,

linkers L₁ to L₃, which may be the same or different, are each independently a single bond or selected from a substituted or unsubstituted arylene of 6 to 60 carbon atoms and a substituted or unsubstituted heteroarylene of 2 to 60 carbon atoms,

p, q, and r are each an integer of 0 to 3 wherein any of p, q, and r is 2 or greater, the corresponding linkers L₁'s to L₃'s may be the same or different,

HAr₁ is represented by the following [Structural Formula 1]:

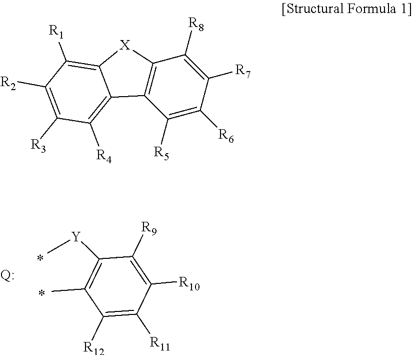

wherein,

X and Y, which may be the same or different, are each independently any one selected from O, S, and CR₁₃R₁₄,

R₁ to R₁₄, which may be the same or different, are each independently any one selected from a hydrogen atom, a deuterium atom, a halogen, a cyano, a substituted or unsubstituted alkyl of 1 to 20 carbon atoms, a substituted or unsubstituted cycloalkyl of 3 to 20 carbon atoms, a substituted or unsubstituted alkoxy of 1 to 20 carbon atoms, a substituted or unsubstituted aryloxy of 6 to 30 carbon atoms, a substituted or unsubstituted alkylthio of 1 to 20 carbon atoms, a substituted or unsubstituted arylthio of 6 to 30 carbon atoms, a substituted or unsubstituted alkylsilyl of 3 to 50 carbon atoms, a substituted or unsubstituted arylsilyl of 6 to 50 carbon atoms, a substituted or unsubstituted aromatic hydrocarbon of 6 to 30 carbon atoms, and a substituted or unsubstituted hetero ring of 5 to 30 carbon atoms as ring members and may each bond to an adjacent radical to form an aliphatic, aromatic, heteroaliphatic, or heteroaromatic fused ring,

two adjacent radicals of R₅ to R₈ are each a single bond connected to * in the Structural Formula Q

any one of R₁ to R₁₂ in Structural Formula 1 representing HAr₁ is a single bond connected to the linker L₁ in Chemical Formula A;

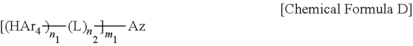

wherein,

HAr₄ is a substituted or unsubstituted aryl of 6 to 30 carbon atoms, or a substituted or unsubstituted heteroaryl of 3 to 30 carbon atoms,

L is a single bond, or any one selected from a substituted or unsubstituted arylene of 6 to 60 carbon atoms and a substituted or unsubstituted heteroarylene of 2 to 60 carbon atoms,

n₁ and n₂ are each an integer of 0 to 3 wherein when any of n₁ and n₂ is two or greater, the corresponding multiple HAr₄ or L are the same or different,

m₁ is an integer of 1 to 4 wherein when m₁ is 2 or greater, the corresponding HAr₄- and L-bearing moieties within the parentheses

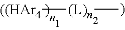

may be the same or different,

Az is represented by any one of the following [Structural Formula 2] to [Structural Formula 8]:

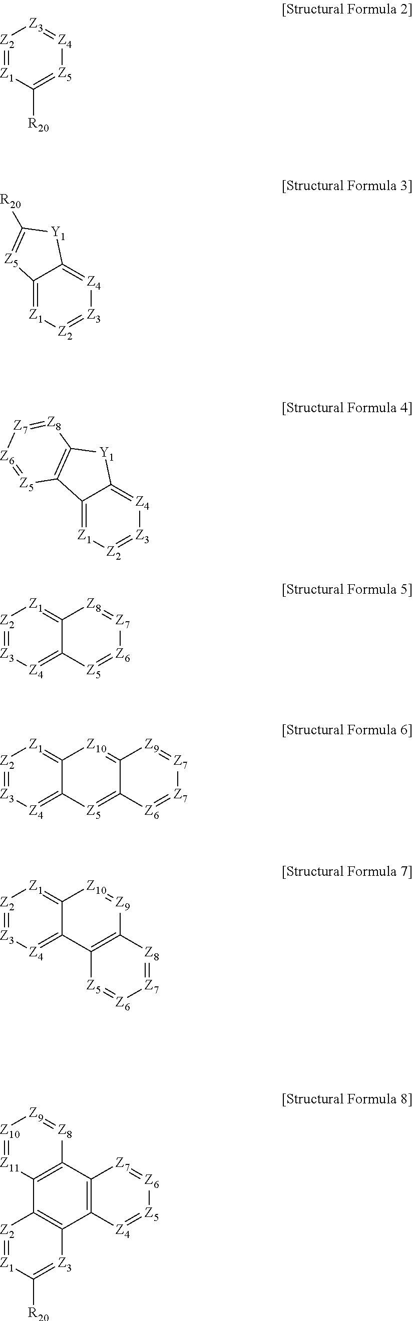

wherein,

Z₁ is N or CR₂₁,

Z₂ is N or CR₂₂,

Z₃ is N or CR₂₃,

Z₄ is N or CR₂₄,

Z₅ is N or CR₂₅,

Z₆ is N or CR₂₆,

Z₇ is N or CR₂₇,

Z₈ is N or CR₂₈,

Z₉ is N or CR₂₉,

Z₁₀ is N or CR₃₀,

Z₁₁ is N or CR₃₁,

Y₁ is any one of O, S, NR₃₂, and CR₃₃R₃₄,

at least one of Z₁ to Z₅ in Structural Formula 2 is N, and m₁ substituents of the substituents R₂₀ to R₂₅ are each a single bond connected to the linker L so that the aromatic ring moiety of Structural Formula 2 has m₁ single bonds to the linker L,

at least one of Z₁ to Z₅ in Structural Formula 3 is N, and m₁ substituents of the substituents R₂₀ to R₂₅ are each a single bond connected to the linker L so that the aromatic ring moiety of Structural Formula 3 has m₁ single bonds to the linker L,

at least one of Z₁ to Z₈ in Structural Formula 4 is N, and m₁ substituents of the substituents R₂₁ to R₂₈ are each a single bond connected to the linker L so that the aromatic ring moiety of Structural Formula 4 has m₁ single bonds to the linker L,

at least one of Z₁ to Z₈ in Structural Formula 5 is N, and m₁ substituents of the substituents R₂₁ to R₂₈ are each a single bond connected to the linker L so that the aromatic ring moiety of Structural Formula 5 has m₁ single bonds to the linker L,

at least one of Z₁ to Z₁₀ in Structural Formula 6 is N, and m₁ substituents of the substituents R₂₁ to R₃₀ are each a single bond connected to the linker L so that the aromatic ring moiety of Structural Formula 6 has m₁ single bonds to the linker L,

at least one of Z₁ to Z₁₀ in Structural Formula 7 is N, and m₁ substituents of the substituents R₂₁ to R₃₀ are each a single bond connected to the linker L so that the aromatic ring moiety of Structural Formula 7 has m₁ single bonds to the linker L,

at least one of Z₁ to Z₁₁ in Structural Formula 8 is N, and m₁ substituents of the substituents R₂₀ to R₃₁ are each a single bond connected to the linker L so that the aromatic ring moiety of Structural Formula 8 has m₁ single bonds to the linker L,

R₂₀ to R₃₄, which may be the same or different, are each independently any one selected from a hydrogen atom, a deuterium atom, a halogen, a cyano, a substituted or unsubstituted alkyl of 1 to 20 carbon atoms, a substituted or unsubstituted cycloalkyl of 3 to 20 carbon atoms, a substituted or unsubstituted alkoxy of 1 to 20 carbon atoms, a substituted or unsubstituted aryloxy of 6 to 30 carbon atoms, a substituted or unsubstituted alkylthio of 1 to 20 carbon atoms, a substituted or unsubstituted arylthio of 6 to 30 carbon atoms, a substituted or unsubstituted alkylsilyl of 3 to 50 carbon atoms, a substituted or unsubstituted arylsilyl of 6 to 50 carbon atoms, a substituted or unsubstituted aromatic hydrocarbon of 6 to 30 carbon atoms, and a substituted or unsubstituted hetero ring of 5 to 30 carbon atoms and may each bond to an adjacent radical to form an aliphatic, aromatic, hetero aliphatic or heteroaromatic fused ring.

wherein the term “substituted” in the expression “substituted or unsubstituted” used for [Chemical Formula A] and [Chemical Formula D] means having at least one substituent selected from the group consisting of a deuterium atom, a cyano, a halogen, a hydroxy, a nitro, an alkyl of 1 to 24 carbon atoms, a halogenated alkyl of 1 to 24 carbon atoms, an alkenyl of 2 to 24 carbon atoms, an alkynyl of 2 to 24 carbon atoms, a heteroalkyl of 1 to 24 carbon atoms, an aryl of 6 to 24 carbon atoms, an arylalkyl of 7 to 24 carbon atoms, a heteroaryl of 2 to 24 carbon atoms or a heteroarylalkyl of 2 to 24 carbon atoms, an alkoxy of 1 to 24 carbon atoms, an alkylamino of 1 to 24 carbon atoms, an arylamino of 6 to 24 carbon atoms, a heteroarylamino of 1 to 24 carbon atoms, an alkylsilyl of 1 to 24 carbon atoms, an arylsilyl of 6 to 24 carbon atoms, and an aryloxy of 6 to 24 carbon atoms.

The expression indicating the number of carbon atoms, such as “a substituted or unsubstituted alkyl of 1 to 24 carbon atoms”, “a substituted or unsubstituted aryl of 6 to 24 carbon atoms”, etc. means the total number of carbon atoms of, for example, the alkyl or aryl radical or moiety alone, exclusive of the number of carbon atoms of substituents attached thereto. For instance, a phenyl group with a butyl at the para position falls within the scope of an aryl of 6 carbon atoms, even though it is substituted with a butyl radical of 4 carbon atoms.

As used herein, the term “aryl” means an organic radical, derived from an aromatic hydrocarbon by removing one hydrogen atom. Further, the aromatic system may include a fused ring that is formed by adjacent substituents on the aryl radical.

Concrete examples of the aryl include phenyl, o-biphenyl, m-biphenyl, p-biphenyl, o-terphenyl, m-terphenyl, p-terphenyl, naphthyl, anthryl, phenanthryl, pyrenyl, indenyl, fluorenyl, tetrahydronaphthyl, perylenyl, chrysenyl, naphthacenyl, and fluoranthenyl at least one hydrogen atom of which may be substituted by a deuterium atom, a halogen atom, a hydroxy, a nitro, a cyano, a silyl, an amino (—NH₂, —NH(R), —N(R′) (R″) wherein R′ and R″ are each independently an alkyl of 1 to 10 carbon atoms, in this case, called “alkylamino”), an amidino, a hydrazine, a hydrazone, a carboxyl, a sulfonic acid, a phosphoric acid, an alkyl of 1 to 24 carbon atoms, a halogenated alkyl of 1 to 24 carbon atoms, an alkenyl of 1 to 24 carbon atoms, an alkynyl of 1 to 24 carbon atoms, a heteroalkyl of 1 to 24 carbon atoms, an aryl of 6 to 24 carbon atoms, an arylalkyl of 6 to 24 carbon atoms, a heteroaryl of 2 to 24 carbon atoms, or a heteroarylalkyl of 2 to 24 carbon atoms.

The substituent heteroaryl used in the compound of the present disclosure refers to a heteroaromatic radical of 2 to 24 carbon atoms bearing one to four heteroatoms selected from among N, O, P, Se, Te, Si, Ge, and S in each ring of the aryl, wherein the rings may be fused. One or more hydrogen atoms on the heteroaryl may be substituted by the same substituents as on the aryl.

As used herein, the term “heteroaromatic ring” refers to an aromatic hydrocarbon ring bearing as a ring member at least one heteroatom selected from among N, O, P, Si, S, Ge, Se, and Te.

Examples of the substituent alkyl useful in the present disclosure include methyl, ethyl, propyl, isobutyl, sec-butyl, tert-butyl, pentyl, iso-amyl, and hexyl. At least one hydrogen atom of the alkyl may be substituted by the same substituent as in the aryl.

Examples of the substituent alkoxy useful in the compound of the present disclosure include methoxy, ethoxy, propoxy, isobutyloxy, sec-butyloxy, pentyloxy, iso-amyloxy, and hexyloxy. At least one hydrogen atom of the alkoxy may be substituted by the same substituent as in the aryl.

Representative among examples of the silyl useful in the compound of the present disclosure are trimethylsilyl, triethylsilyl, triphenylsilyl, trimethoxysilyl, dimethoxyphenylsilyl, diphenylmethylsilyl, diphenylvinylsilyl, methylcyclobutylsilyl, and dimethylfurylsilyl. One or more hydrogen atoms of the silyl may be substituted by the same substituent as in the aryl.

Employing a combination of hosts having specific structures in the light-emitting layer thereof, the organic light-emitting diode according to the present disclosure can operate at a low voltage and can exhibit high emission efficacy and a long lifetime.

Herein, features of the hetero ring compound represented by Chemical Formula A are further explained in detail. The hetero ring compound represented by Chemical Formula A is structurally characterized by the amine compound the nitrogen atom of which is bonded to linkers L₁ to L₃, wherein the linker L₁ is connected to the 6-5-6-5-6-type fused ring in which the Y-bearing, 5-6-type heterobenzo radical (benzofuran, benzothiophene, or indenyl) is fused to the 6-5-6-type heterodibenzo ring, represented by Structural Formula 1, consisting of a X-bearing 5-membered ring with respective aromatic 6-membered benzene rings fused to the opposite sides thereof; and the linkers to which the 6-5-6-5-6-type fused ring represented by Structural Formula 1 is not bonded are linked to Ar₁ and Ar₂, respectively.

In addition, the hetero ring compound represented by Chemical Formula D is structurally characterized in that an aromatic hetero ring bearing at least one nitrogen atom as a ring member are linked to linkers as many as m₁ to each of which a substituted or unsubstituted aryl of 6 to 30 carbon atoms, or a substituted or unsubstituted heteroaryl of 3 to 30 carbon atoms is bonded.

In Chemical Formula A, the linkers L₁ to L₃, which may be the same or different, are each independently a single bond or any one selected from the following [Structural Formula 22] to [Structural Formula 30], and p, q, and r may each be 1 or 2:

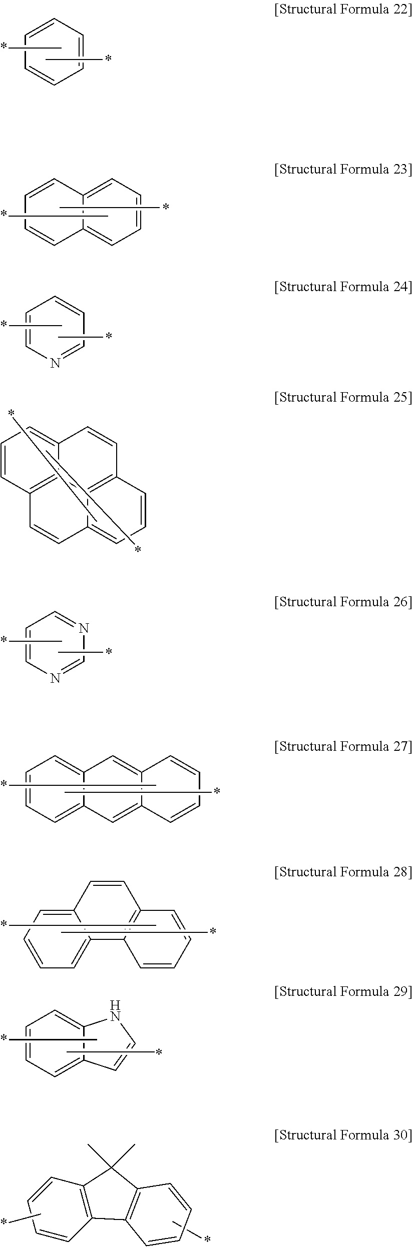

wherein, each of the unsubstituted carbon atoms of the aromatic ring moiety may be bound with a hydrogen atom or a deuterium atom.

In Chemical Formula D, Az represented by [Structural Formula 2] to [Structural Formula 8] may each be any one selected from the following E1 to E24:

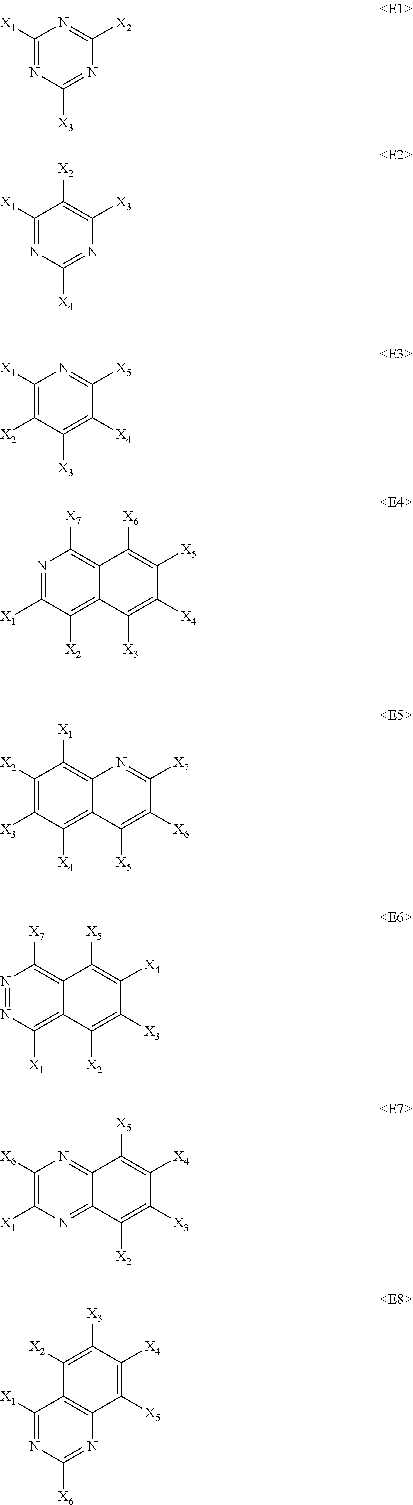

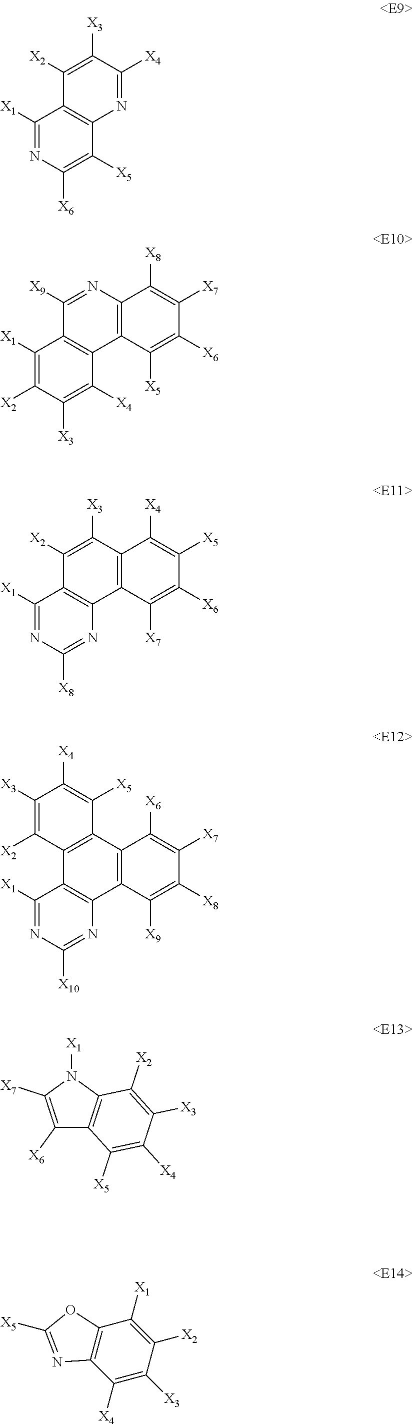

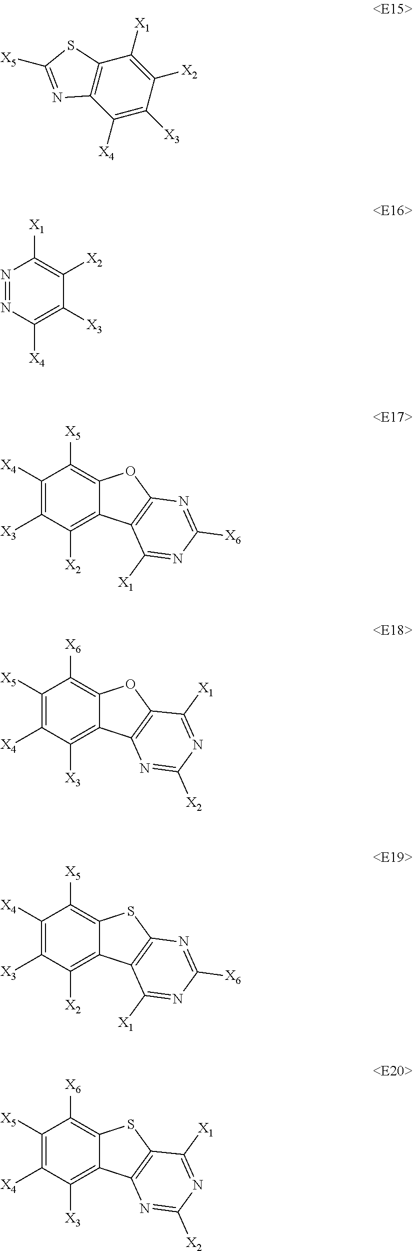

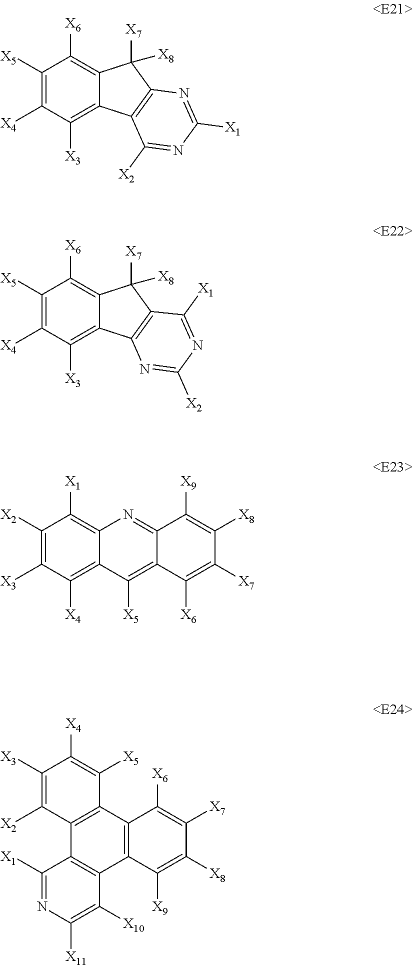

wherein,

X₁ to X₁₁, which may be the same or different, are each independently selected from a hydrogen atom, a deuterium atom, a halogen, a nitrile, a substituted or unsubstituted alkyl of 1 to 30 carbon atoms, a substituted or unsubstituted cycloalkyl of 3 to 30 carbon atoms, a substituted or unsubstituted aryl of 6 to 30 carbon atoms, or a substituted or unsubstituted heteroaryl of 3 to 30 carbon atoms,

m₁ substituents of the substituents X₁ to X₁₁ in E1 to E24 are each a single bond connected to the linker L in Chemical Formula D.

In addition, the linker L in Chemical Formula D may be a single bond or any one selected from the following [Structural Formula 22] to [Structural Formula 30], and n₂ may be 1 or 2:

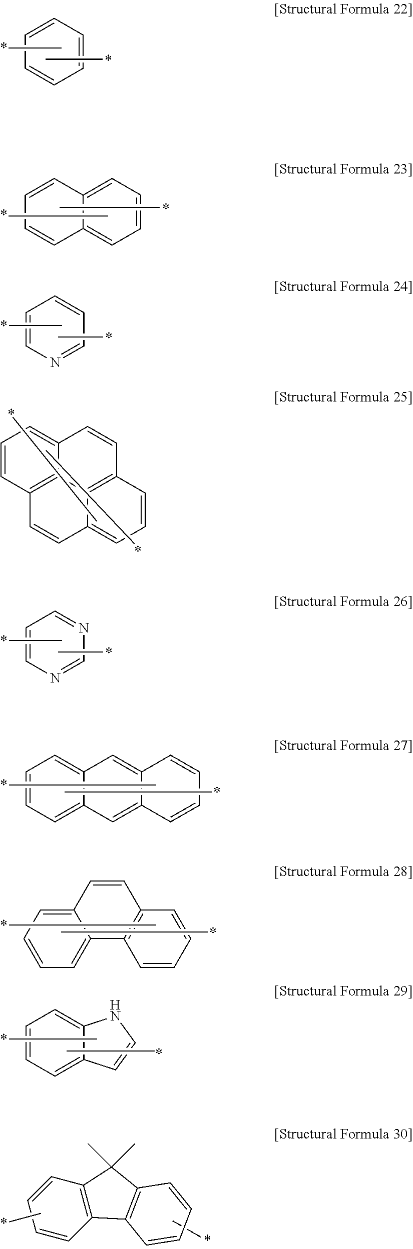

wherein, each of the unsubstituted carbon atoms of the aromatic ring moiety is bound with a hydrogen atom or a deuterium atom.

According to an embodiment, Ar₁ and Ar₂ in Chemical Formula A, which may be the same or different, may each be independently any one selected from a substituted or unsubstituted aryl of 6 to 30 carbon atoms, and a substituted or unsubstituted heteroaryl of 3 to 30 carbon atoms.

According to an embodiment, R₂₀ to R₃₁ in Chemical Formula D, which may be the same or different, may each be independently any one selected from a hydrogen atom, a deuterium atom, a halogen, a cyano, a substituted or unsubstituted alkyl of 1 to 30 carbon atoms, a substituted or unsubstituted cycloalkyl of 3 to 30 carbon atoms, a substituted or unsubstituted aryl of 6 to 30 carbon atoms, and a substituted or unsubstituted heteroaryl of 3 to 30 carbon atoms.

According to an embodiment, at least one of HAr₄ in Chemical Formula D may be a fused ring represented by the following [Structural Formula 9] or [Structural Formula 10]:

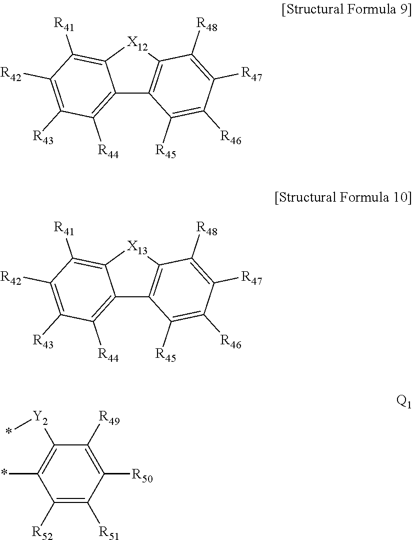

wherein,

X₁₂ is any one selected from O, S, NR₄₉, and CR₅₀R₅₁,

any one of R₄₁ to R₄₈ in Structural Formula 9 is a single bond connected to the linker L in Chemical Formula D,

X₁₃ is any one selected from O, S, NR₅₃, and CR₅₄R₅₅,

Y₂ is any one selected from O, S, NR₅₆, and CR₅₇R₅₈,

any one of R₄₁ to R₅₂ in Structural Formula 10 is a single bond connected to the linker L in Chemical Formula D,

two adjacent substituents of the substituents R₄₅ to R₄₈ are each a single bond connected to respective * in Structural Formula Q1,

R₄₁ to R₅₈, which may be the same or different, are each independently any one selected from a hydrogen atom, a deuterium atom, a halogen, a cyano, a substituted or unsubstituted alkyl of 1 to 20 carbon atoms, a substituted or unsubstituted cycloalkyl of 3 to 20 carbon atoms, a substituted or unsubstituted alkoxy of 1 to 20 carbon atoms, a substituted or unsubstituted aryloxy of 6 to 30 carbon atoms, a substituted or unsubstituted alkylthio of 1 to 20 carbon atoms, a substituted or unsubstituted arylthio of 6 to 30 carbon atoms, a substituted or unsubstituted alkylsilyl of 3 to 50 carbon atoms, a substituted or unsubstituted arylsilyl of 6 to 50 carbon atoms, a substituted or unsubstituted aromatic hydrocarbon of 6 to 30 carbon atoms, and a substituted or unsubstituted hetero ring of 5 to 30 carbon atoms.

According to an embodiment of the present disclosure, Ar₁ or Ar₂ in Chemical Formula A may be a substituent represented by the following Structural Formula 11:

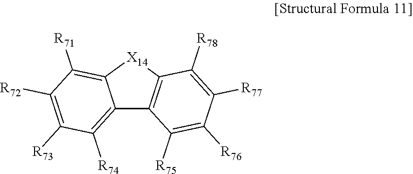

wherein,

X₁₄ is any one selected from 0, S, and CR₇₉R₈₀,

R₇₁ to R₈₀, which may be the same or different, are each independently any one selected from a hydrogen atom, a deuterium atom, a halogen, a cyano, a substituted or unsubstituted alkyl of 1 to 20 carbon atoms, a substituted or unsubstituted cycloalkyl of 3 to 20 carbon atoms, a substituted or unsubstituted alkoxy of 1 to 20 carbon atoms, a substituted or unsubstituted aryloxy of 6 to 30 carbon atoms, a substituted or unsubstituted alkylthio of 1 to 20 carbon atoms, a substituted or unsubstituted arylthio of 6 to 30 carbon atoms, a substituted or unsubstituted alkylsilyl of 3 to 50 carbon atoms, a substituted or unsubstituted arylsilyl of 6 to 50 carbon atoms, a substituted or unsubstituted aromatic hydrocarbon of 6 to 30 carbon atoms, and a substituted or unsubstituted hetero ring of 5 to 30 carbon atoms, and

any one of R₇₁ to R₇₈ is a single bond connected to the linker L₂ or L₃ in Chemical Formula A.

According to an embodiment, any one of R₉ to R₁₂ in [Structural Formula 1] of Chemical Formula A may be a single bond connected to the linker L₁.

In the organic light-emitting diode according to the present disclosure, the fused ring compound represented by Chemical Formula A may be any one selected from the group consisting of the compounds represented by Compounds H1 to H208, but is not limited thereto:

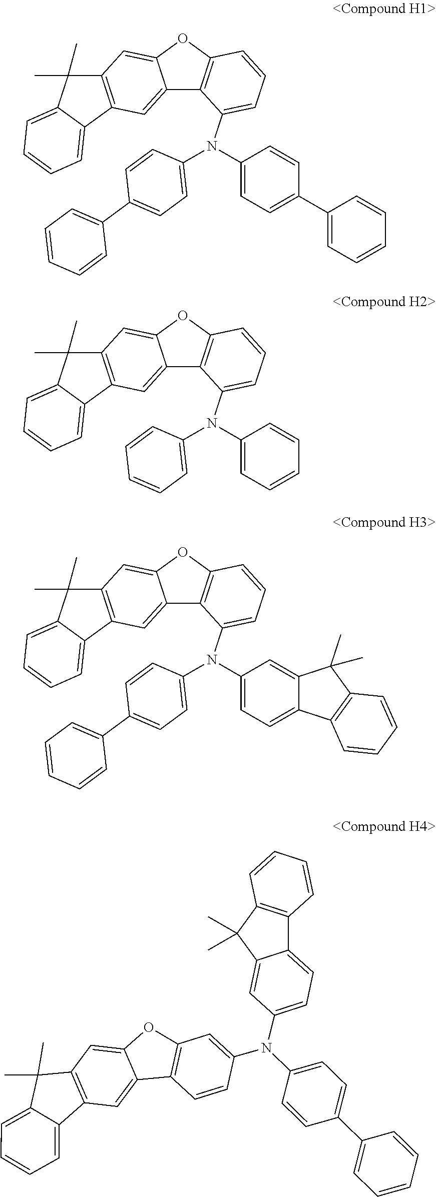

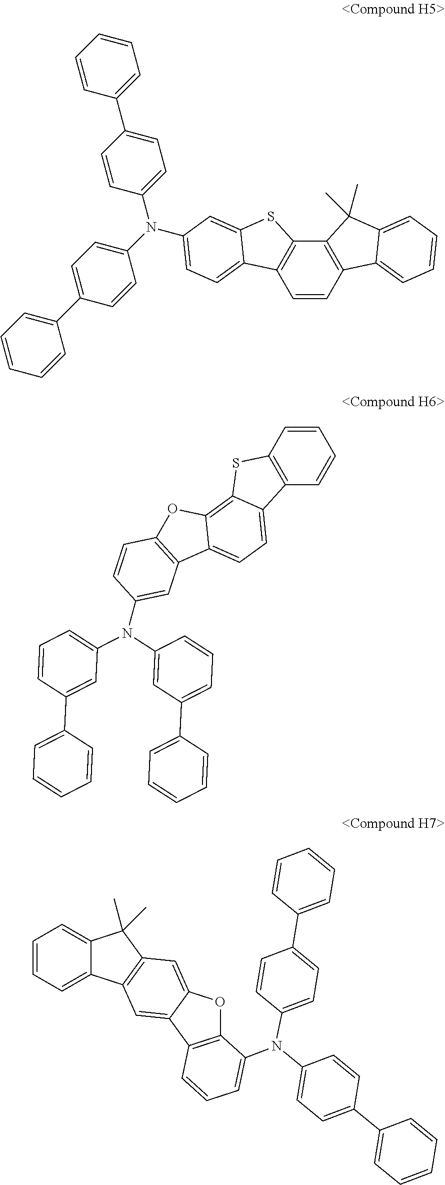 [SMILES: CC1(C)c2ccccc2-c2ccc3c(sc4cc(N(c5ccc(-c6ccccc6)cc5)c5ccc(-c6ccccc6)cc5)ccc43)c21 ; c1ccc(-c2cccc(N(c3cccc(-c4ccccc4)c3)c3ccc4oc5c(ccc6c7ccccc7sc65)c4c3)c2)cc1 ; CC1(C)c2ccccc2-c2cc3c(cc21)oc1c(N(c2ccc(-c4ccccc4)cc2)c2ccc(-c4ccccc4)cc2)cccc13]

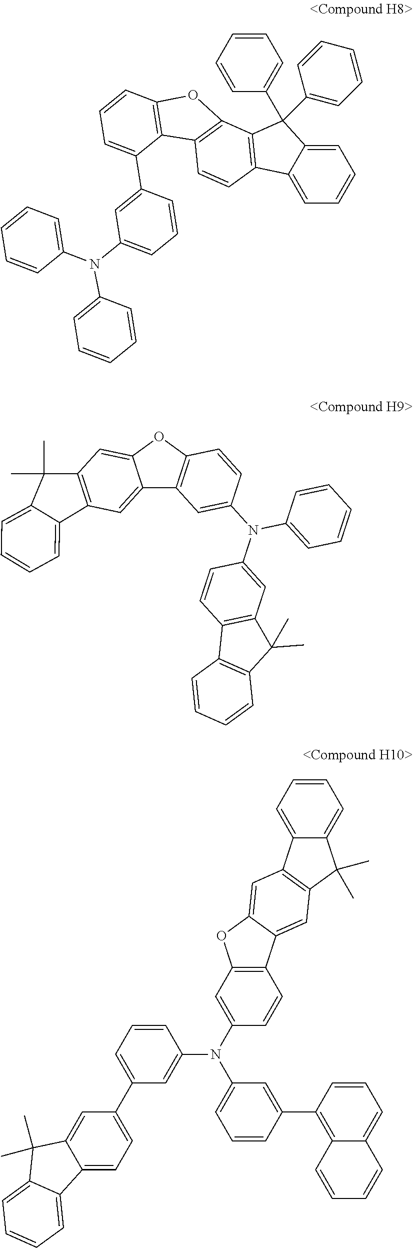 [SMILES: c1ccc(N(c2ccccc2)c2cccc(-c3cccc4oc5c6c(ccc5c34)-c3ccccc3C6(c3ccccc3)c3ccccc3)c2)cc1 ; CC1(C)c2ccccc2-c2ccc(N(c3ccccc3)c3ccc4oc5cc6c(cc5c4c3)-c3ccccc3C6(C)C)cc21 ; CC1(C)c2ccccc2-c2ccc(-c3cccc(N(c4cccc(-c5cccc6ccccc56)c4)c4ccc5c(c4)oc4cc6c(cc45)C(C)(C)c4ccccc4-6)c3)cc21]

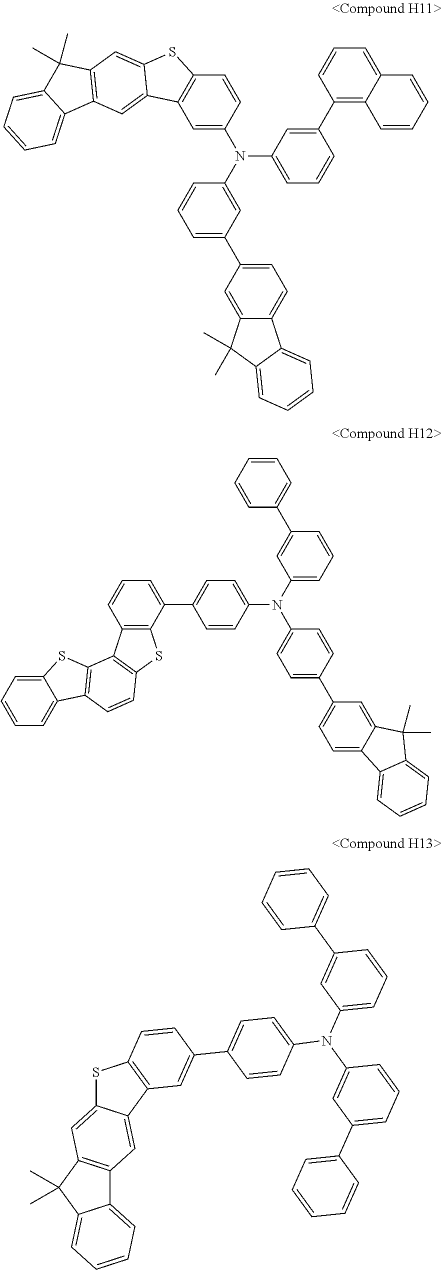

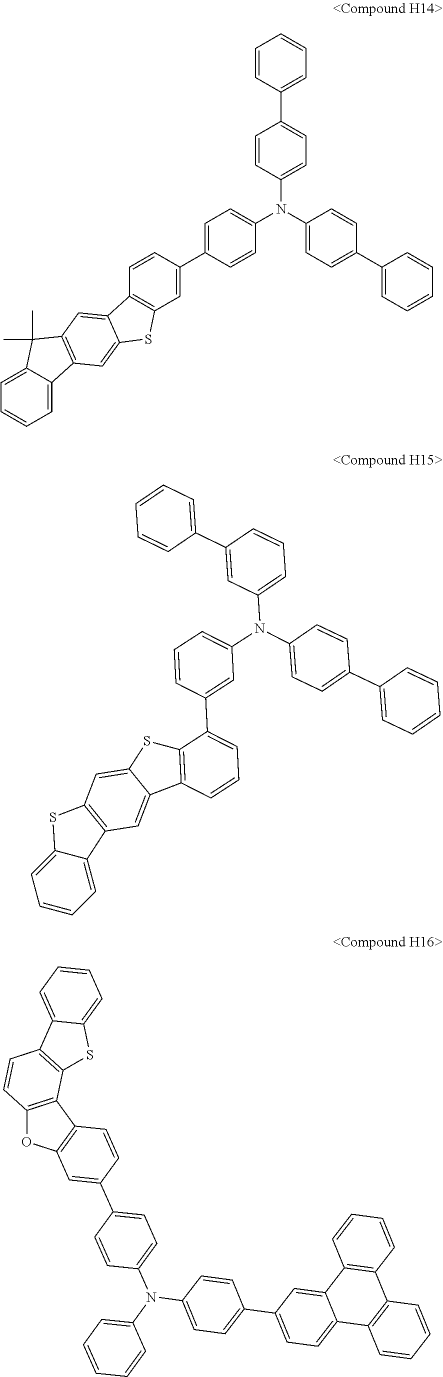 [SMILES: CC1(C)c2ccccc2-c2cc3sc4cc(-c5ccc(N(c6ccc(-c7ccccc7)cc6)c6ccc(-c7ccccc7)cc6)cc5)ccc4c3cc21 ; c1ccc(-c2ccc(N(c3cccc(-c4ccccc4)c3)c3cccc(-c4cccc5c4sc4cc6sc7ccccc7c6cc45)c3)cc2)cc1 ; c1ccc(N(c2ccc(-c3ccc4c(c3)oc3ccc5c6ccccc6sc5c34)cc2)c2ccc(-c3ccc4c5ccccc5c5ccccc5c4c3)cc2)cc1]

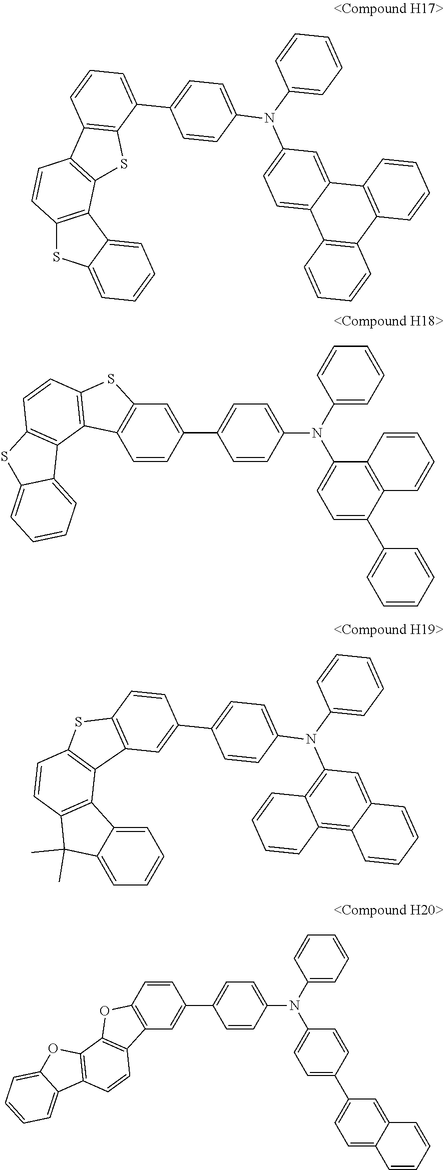 [SMILES: c1ccc(N(c2ccc(-c3cccc4c3sc3c4ccc4sc5ccccc5c43)cc2)c2ccc3c4ccccc4c4ccccc4c3c2)cc1 ; c1ccc(-c2ccc(N(c3ccccc3)c3ccc(-c4ccc5c(c4)sc4ccc6sc7ccccc7c6c45)cc3)c3ccccc23)cc1 ; CC1(C)c2ccccc2-c2c1ccc1sc3ccc(-c4ccc(N(c5ccccc5)c5cc6ccccc6c6ccccc56)cc4)cc3c21 ; c1ccc(N(c2ccc(-c3ccc4ccccc4c3)cc2)c2ccc(-c3ccc4oc5c(ccc6c7ccccc7oc65)c4c3)cc2)cc1]

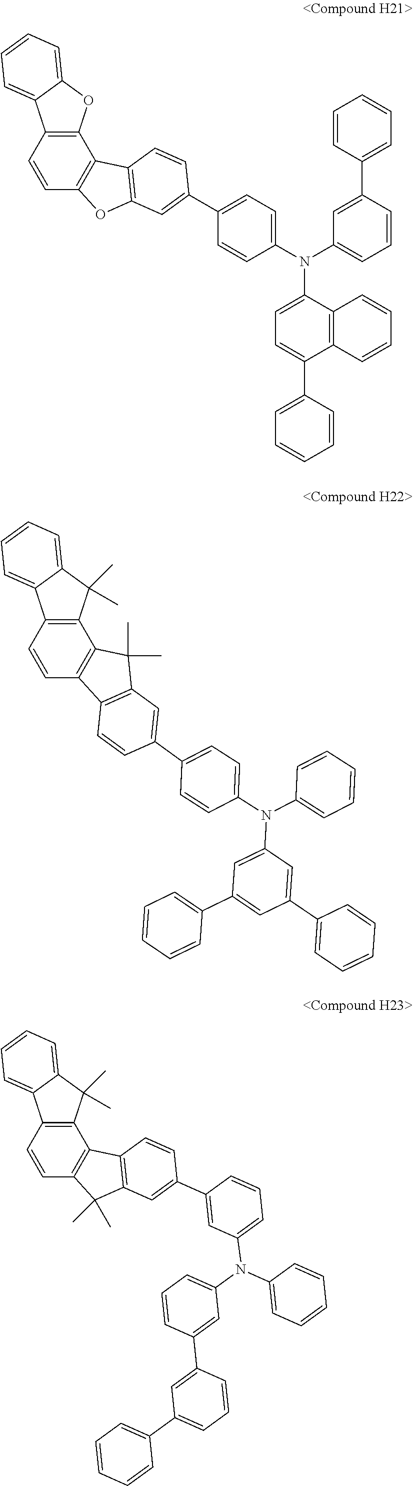 [SMILES: c1ccc(-c2cccc(N(c3ccc(-c4ccc5c(c4)oc4ccc6c7ccccc7oc6c45)cc3)c3ccc(-c4ccccc4)c4ccccc34)c2)cc1 ; CC1(C)c2ccccc2-c2ccc3c(c21)C(C)(C)c1cc(-c2ccc(N(c4ccccc4)c4cc(-c5ccccc5)cc(-c5ccccc5)c4)cc2)ccc1-3 ; CC1(C)c2cc(-c3cccc(N(c4ccccc4)c4cccc(-c5cccc(-c6ccccc6)c5)c4)c3)ccc2-c2c1ccc1c2C(C)(C)c2ccccc2-1]

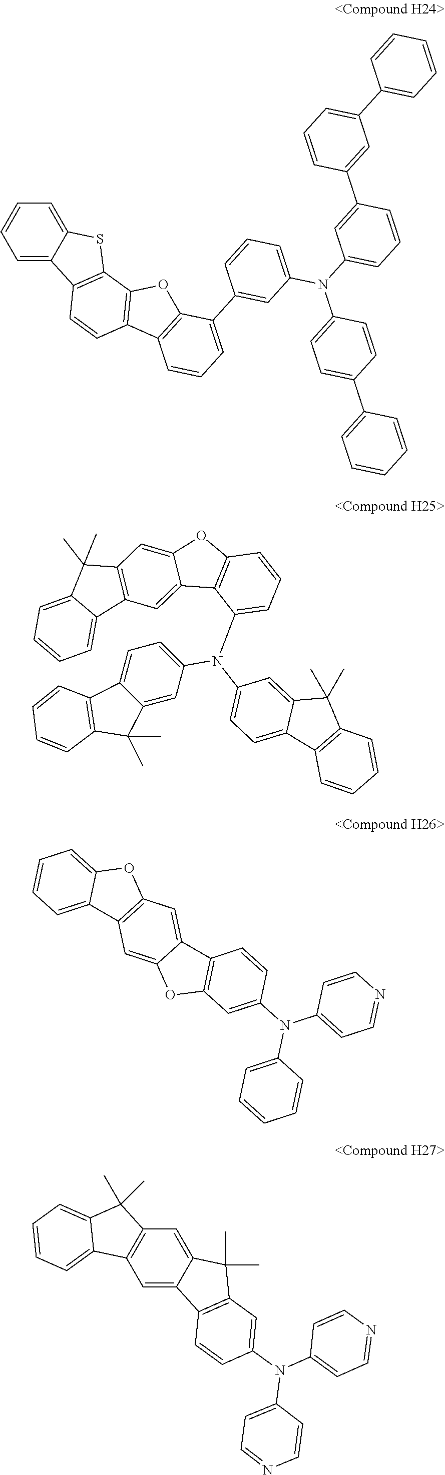 [SMILES: c1ccc(-c2ccc(N(c3cccc(-c4cccc(-c5ccccc5)c4)c3)c3cccc(-c4cccc5c4oc4c5ccc5c6ccccc6sc54)c3)cc2)cc1 ; CC1(C)c2ccccc2-c2ccc(N(c3ccc4c(c3)C(C)(C)c3ccccc3-4)c3cccc4oc5cc6c(cc5c34)-c3ccccc3C6(C)C)cc21 ; c1ccc(N(c2ccncc2)c2ccc3c(c2)oc2cc4c(cc23)oc2ccccc24)cc1 ; CC1(C)c2ccccc2-c2cc3c(cc21)C(C)(C)c1cc(N(c2ccncc2)c2ccncc2)ccc1-3]

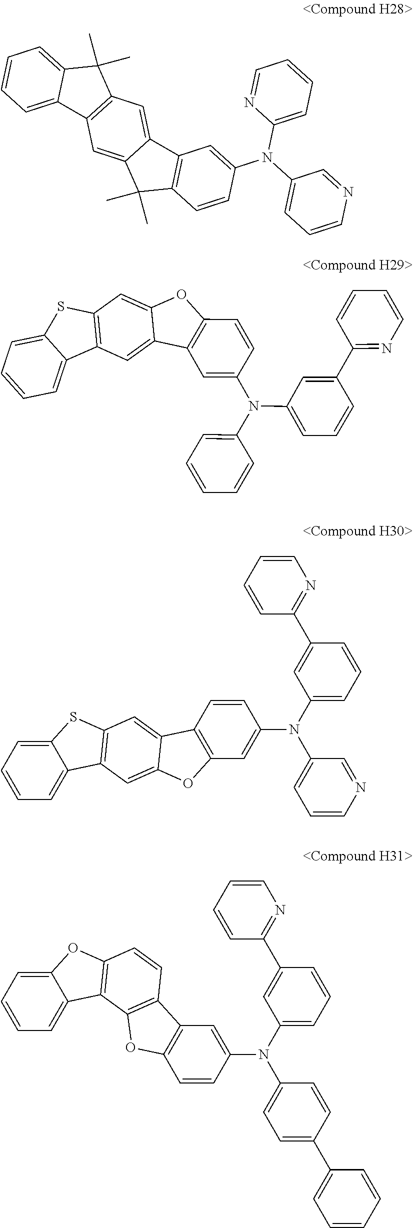 [SMILES: CC1(C)c2ccccc2-c2cc3c(cc21)-c1cc(N(c2cccnc2)c2ccccn2)ccc1C3(C)C ; c1ccc(N(c2cccc(-c3ccccn3)c2)c2ccc3oc4cc5sc6ccccc6c5cc4c3c2)cc1 ; c1ccc(-c2cccc(N(c3cccnc3)c3ccc4c(c3)oc3cc5c(cc34)sc3ccccc35)c2)nc1 ; c1ccc(-c2ccc(N(c3cccc(-c4ccccn4)c3)c3ccc4oc5c(ccc6oc7ccccc7c65)c4c3)cc2)cc1]

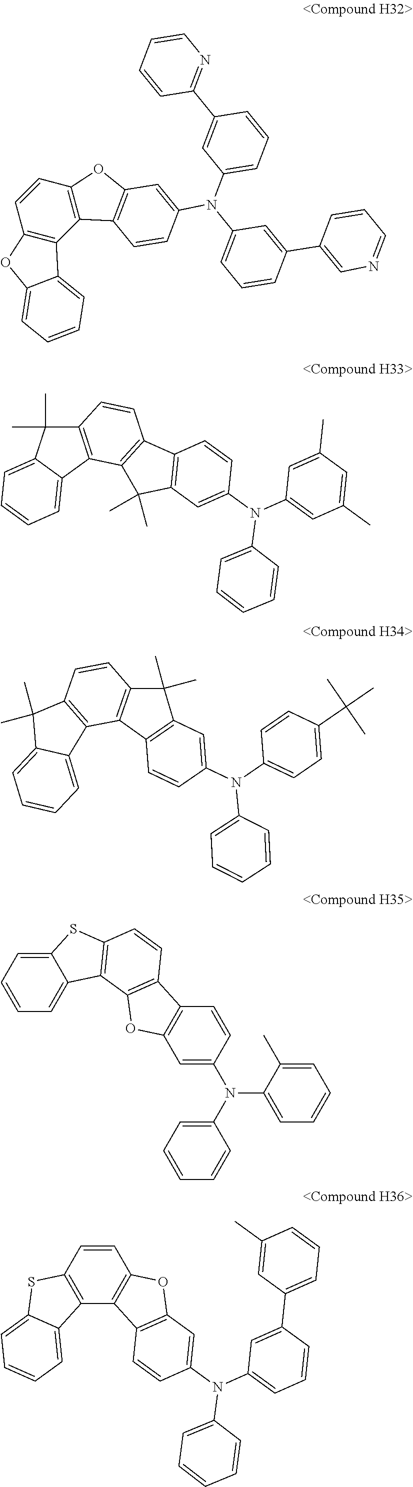

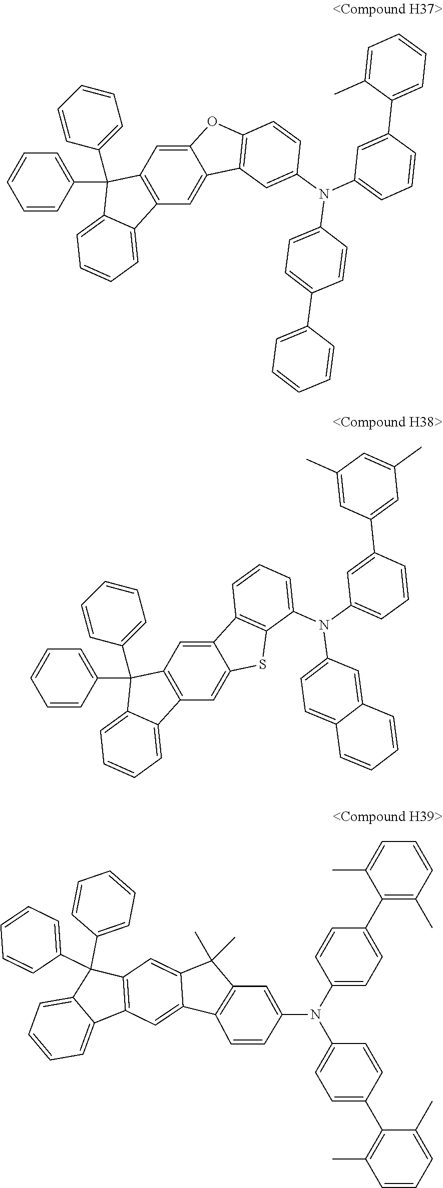 [SMILES: Cc1ccccc1-c1cccc(N(c2ccc(-c3ccccc3)cc2)c2ccc3oc4cc5c(cc4c3c2)-c2ccccc2C5(c2ccccc2)c2ccccc2)c1 ; Cc1cc(C)cc(-c2cccc(N(c3ccc4ccccc4c3)c3cccc4c3sc3cc5c(cc34)C(c3ccccc3)(c3ccccc3)c3ccccc3-5)c2)c1 ; Cc1cccc(C)c1-c1ccc(N(c2ccc(-c3c(C)cccc3C)cc2)c2ccc3c(c2)C(C)(C)c2cc4c(cc2-3)-c2ccccc2C4(c2ccccc2)c2ccccc2)cc1]

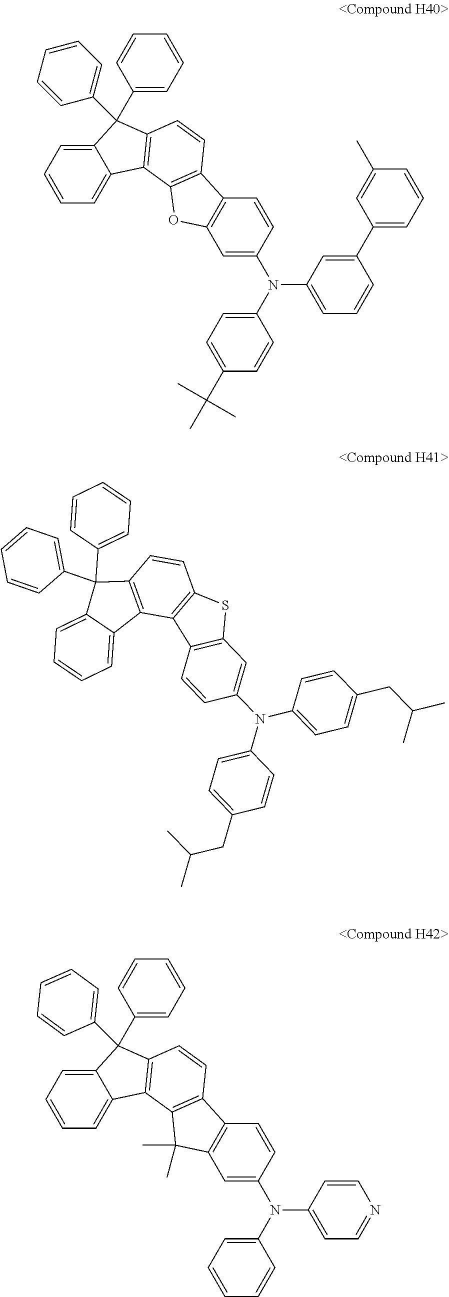 [SMILES: Cc1cccc(-c2cccc(N(c3ccc(C(C)(C)C)cc3)c3ccc4c(c3)oc3c5c(ccc34)C(c3ccccc3)(c3ccccc3)c3ccccc3-5)c2)c1 ; CC(C)Cc1ccc(N(c2ccc(CC(C)C)cc2)c2ccc3c(c2)sc2ccc4c(c23)-c2ccccc2C4(c2ccccc2)c2ccccc2)cc1 ; CC1(C)c2cc(N(c3ccccc3)c3ccncc3)ccc2-c2ccc3c(c21)-c1ccccc1C3(c1ccccc1)c1ccccc1]

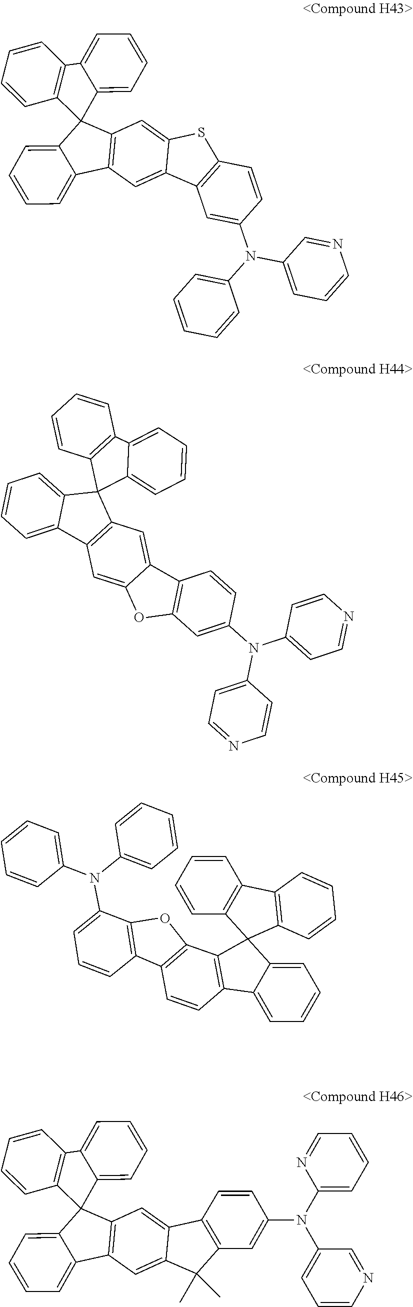 [SMILES: c1ccc(N(c2cccnc2)c2ccc3sc4cc5c(cc4c3c2)-c2ccccc2C52c3ccccc3-c3ccccc32)cc1 ; c1ccc2c(c1)-c1ccccc1C21c2ccccc2-c2cc3oc4cc(N(c5ccncc5)c5ccncc5)ccc4c3cc21 ; c1ccc(N(c2ccccc2)c2cccc3c2oc2c4c(ccc23)-c2ccccc2C42c3ccccc3-c3ccccc32)cc1 ; CC1(C)c2cc(N(c3cccnc3)c3ccccn3)ccc2-c2cc3c(cc21)-c1ccccc1C31c2ccccc2-c2ccccc21]

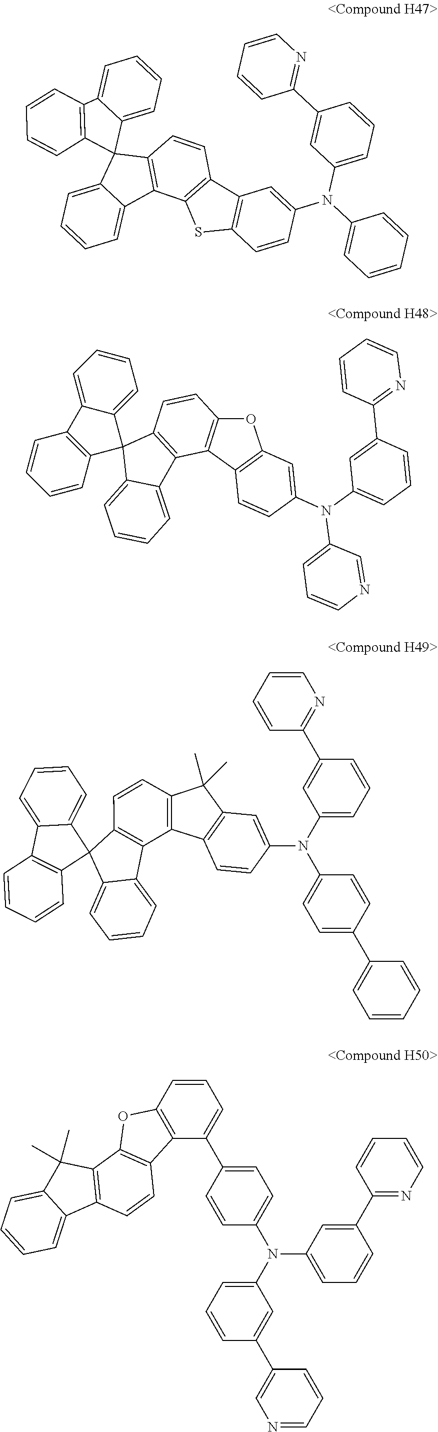 [SMILES: c1ccc(N(c2cccc(-c3ccccn3)c2)c2ccc3sc4c5c(ccc4c3c2)C2(c3ccccc3-c3ccccc32)c2ccccc2-5)cc1 ; c1ccc(-c2cccc(N(c3cccnc3)c3ccc4c(c3)oc3ccc5c(c34)-c3ccccc3C53c4ccccc4-c4ccccc43)c2)nc1 ; CC1(C)c2cc(N(c3ccc(-c4ccccc4)cc3)c3cccc(-c4ccccn4)c3)ccc2-c2c1ccc1c2-c2ccccc2C12c1ccccc1-c1ccccc12 ; CC1(C)c2ccccc2-c2ccc3c(oc4cccc(-c5ccc(N(c6cccc(-c7cccnc7)c6)c6cccc(-c7ccccn7)c6)cc5)c43)c21]

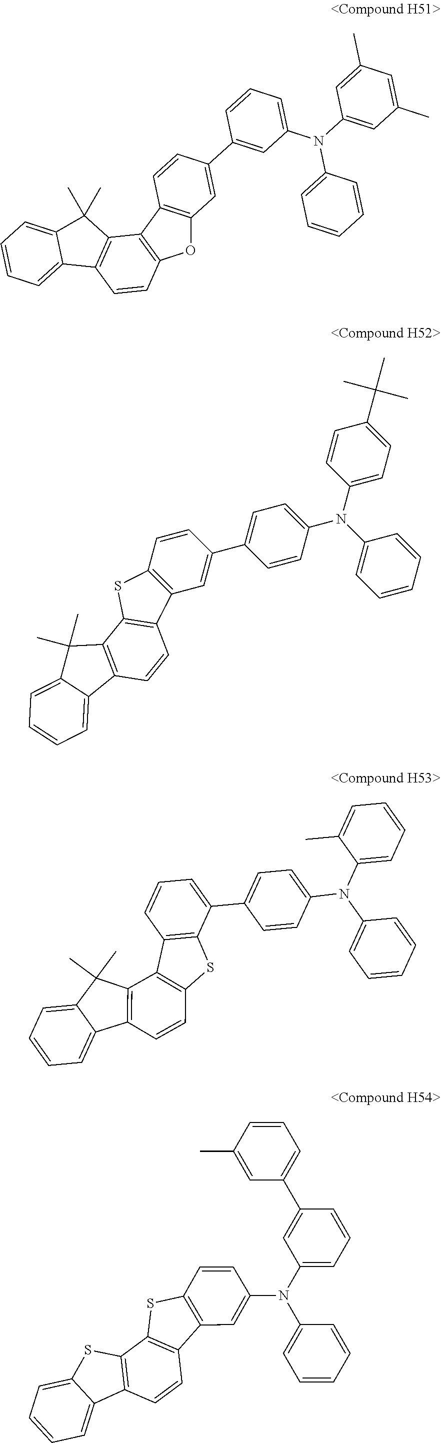 [SMILES: Cc1cc(C)cc(N(c2ccccc2)c2cccc(-c3ccc4c(c3)oc3ccc5c(c34)C(C)(C)c3ccccc3-5)c2)c1 ; CC(C)(C)c1ccc(N(c2ccccc2)c2ccc(-c3ccc4sc5c6c(ccc5c4c3)-c3ccccc3C6(C)C)cc2)cc1 ; Cc1ccccc1N(c1ccccc1)c1ccc(-c2cccc3c2sc2ccc4c(c23)C(C)(C)c2ccccc2-4)cc1 ; Cc1cccc(-c2cccc(N(c3ccccc3)c3ccc4sc5c(ccc6c7ccccc7sc65)c4c3)c2)c1]

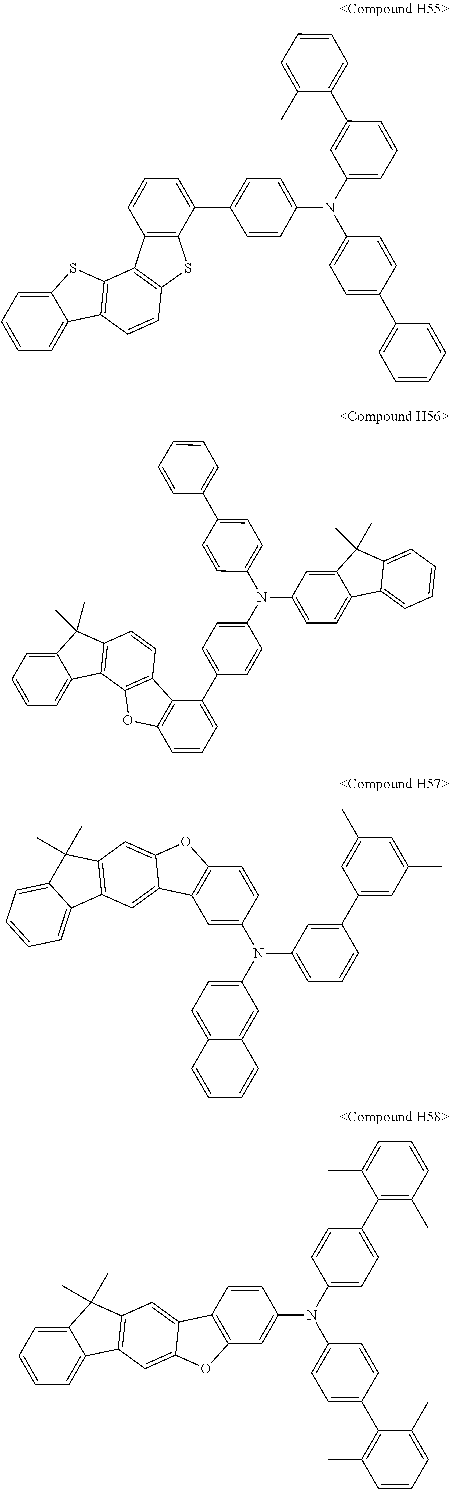 [SMILES: Cc1ccccc1-c1cccc(N(c2ccc(-c3ccccc3)cc2)c2ccc(-c3cccc4c3sc3ccc5c6ccccc6sc5c34)cc2)c1 ; CC1(C)c2ccccc2-c2ccc(N(c3ccc(-c4ccccc4)cc3)c3ccc(-c4cccc5oc6c7c(ccc6c45)C(C)(C)c4ccccc4-7)cc3)cc21 ; Cc1cc(C)cc(-c2cccc(N(c3ccc4ccccc4c3)c3ccc4oc5cc6c(cc5c4c3)-c3ccccc3C6(C)C)c2)c1 ; Cc1cccc(C)c1-c1ccc(N(c2ccc(-c3c(C)cccc3C)cc2)c2ccc3c(c2)oc2cc4c(cc23)C(C)(C)c2ccccc2-4)cc1]

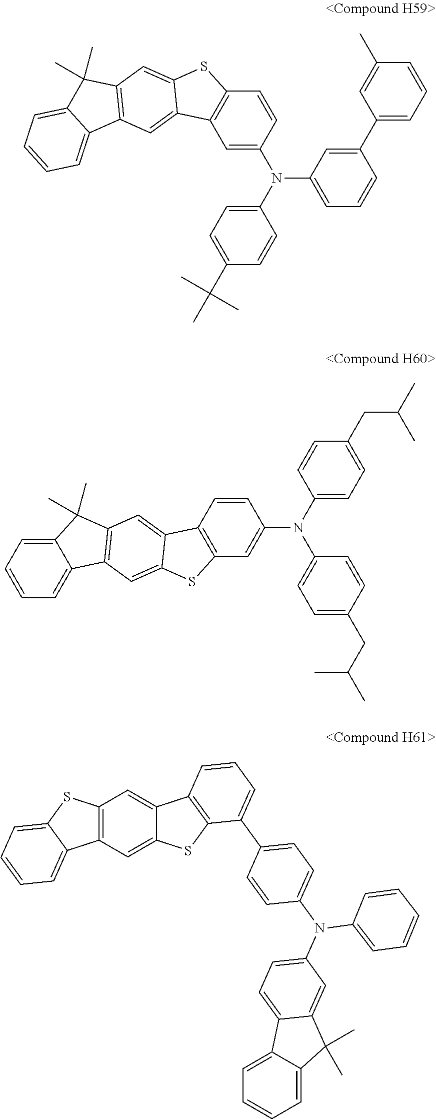 [SMILES: Cc1cccc(-c2cccc(N(c3ccc(C(C)(C)C)cc3)c3ccc4sc5cc6c(cc5c4c3)-c3ccccc3C6(C)C)c2)c1 ; CC(C)Cc1ccc(N(c2ccc(CC(C)C)cc2)c2ccc3c(c2)sc2cc4c(cc23)C(C)(C)c2ccccc2-4)cc1 ; CC1(C)c2ccccc2-c2ccc(N(c3ccccc3)c3ccc(-c4cccc5c4sc4cc6c(cc45)sc4ccccc46)cc3)cc21]

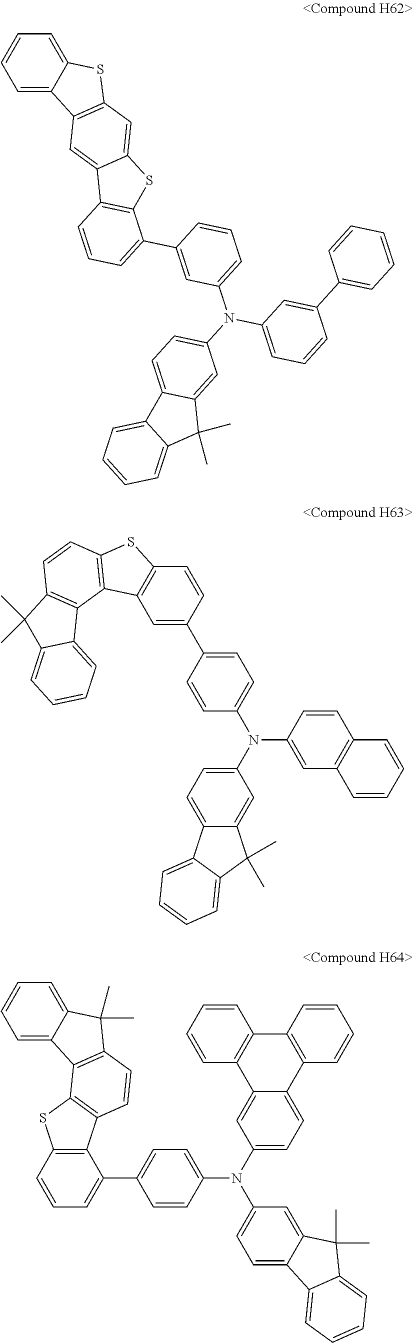 [SMILES: CC1(C)c2ccccc2-c2ccc(N(c3cccc(-c4ccccc4)c3)c3cccc(-c4cccc5c4sc4cc6sc7ccccc7c6cc45)c3)cc21 ; CC1(C)c2ccccc2-c2ccc(N(c3ccc(-c4ccc5sc6ccc7c(c6c5c4)-c4ccccc4C7(C)C)cc3)c3ccc4ccccc4c3)cc21 ; CC1(C)c2ccccc2-c2ccc(N(c3ccc(-c4cccc5sc6c7c(ccc6c45)C(C)(C)c4ccccc4-7)cc3)c3ccc4c5ccccc5c5ccccc5c4c3)cc21]

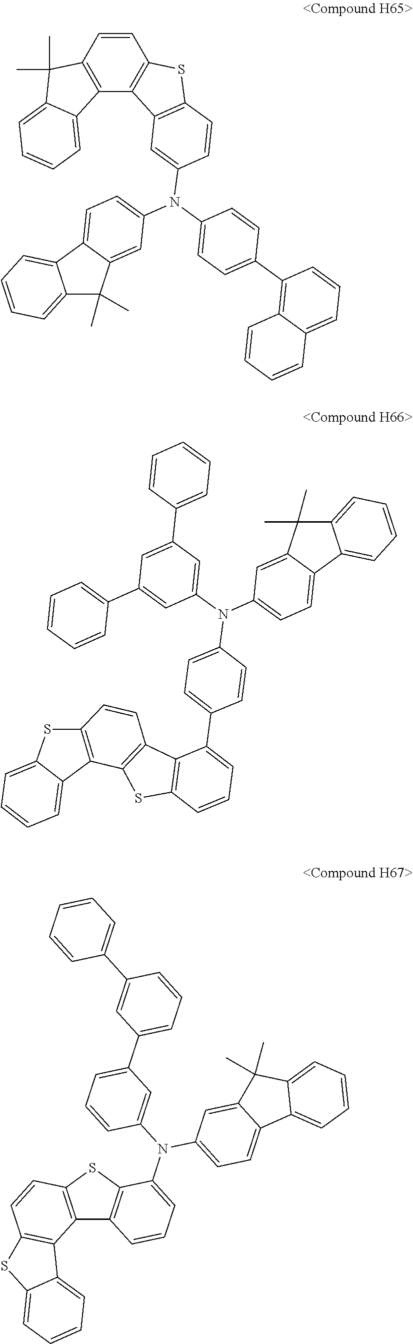 [SMILES: CC1(C)c2ccccc2-c2ccc(N(c3ccc(-c4cccc5ccccc45)cc3)c3ccc4sc5ccc6c(c5c4c3)-c3ccccc3C6(C)C)cc21 ; CC1(C)c2ccccc2-c2ccc(N(c3ccc(-c4cccc5sc6c(ccc7sc8ccccc8c76)c45)cc3)c3cc(-c4ccccc4)cc(-c4ccccc4)c3)cc21 ; CC1(C)c2ccccc2-c2ccc(N(c3cccc(-c4cccc(-c5ccccc5)c4)c3)c3cccc4c3sc3ccc5sc6ccccc6c5c34)cc21]

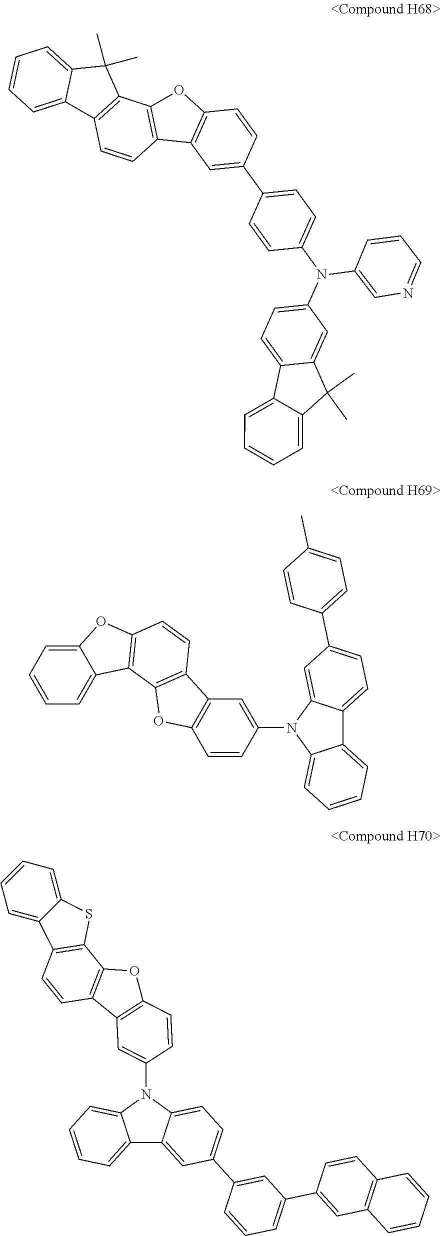 [SMILES: CC1(C)c2ccccc2-c2ccc(N(c3ccc(-c4ccc5oc6c7c(ccc6c5c4)-c4ccccc4C7(C)C)cc3)c3cccnc3)cc21 ; Cc1ccc(-c2ccc3c4ccccc4n(-c4ccc5oc6c(ccc7oc8ccccc8c76)c5c4)c3c2)cc1 ; c1cc(-c2ccc3ccccc3c2)cc(-c2ccc3c(c2)c2ccccc2n3-c2ccc3oc4c(ccc5c6ccccc6sc54)c3c2)c1]

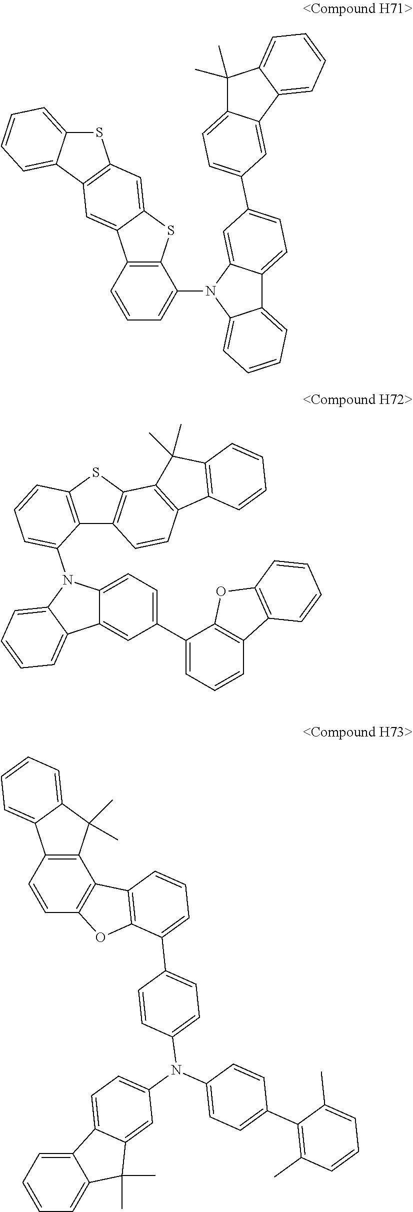 [SMILES: CC1(C)c2ccccc2-c2cc(-c3ccc4c5ccccc5n(-c5cccc6c5sc5cc7sc8ccccc8c7cc56)c4c3)ccc21 ; CC1(C)c2ccccc2-c2ccc3c(sc4cccc(-n5c6ccccc6c6cc(-c7cccc8c7oc7ccccc78)ccc65)c43)c21 ; Cc1cccc(C)c1-c1ccc(N(c2ccc(-c3cccc4c3oc3ccc5c(c34)C(C)(C)c3ccccc3-5)cc2)c2ccc3c(c2)C(C)(C)c2ccccc2-3)cc1]

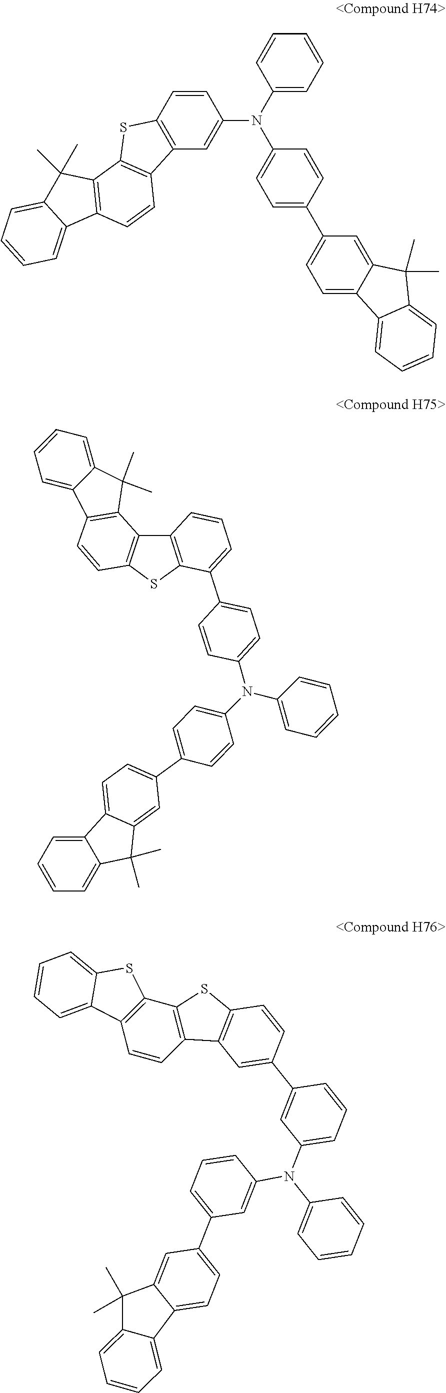 [SMILES: CC1(C)c2ccccc2-c2ccc(-c3ccc(N(c4ccccc4)c4ccc5sc6c7c(ccc6c5c4)-c4ccccc4C7(C)C)cc3)cc21 ; CC1(C)c2ccccc2-c2ccc(-c3ccc(N(c4ccccc4)c4ccc(-c5cccc6c5sc5ccc7c(c56)C(C)(C)c5ccccc5-7)cc4)cc3)cc21 ; CC1(C)c2ccccc2-c2ccc(-c3cccc(N(c4ccccc4)c4cccc(-c5ccc6sc7c(ccc8c9ccccc9sc87)c6c5)c4)c3)cc21]

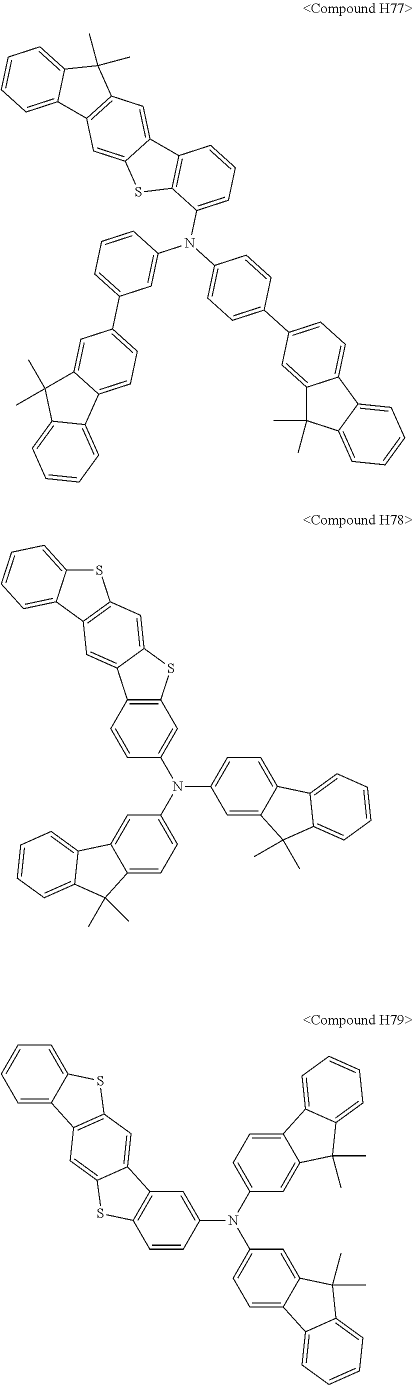 [SMILES: CC1(C)c2ccccc2-c2ccc(-c3ccc(N(c4cccc(-c5ccc6c(c5)C(C)(C)c5ccccc5-6)c4)c4cccc5c4sc4cc6c(cc45)C(C)(C)c4ccccc4-6)cc3)cc21 ; CC1(C)c2ccccc2-c2cc(N(c3ccc4c(c3)C(C)(C)c3ccccc3-4)c3ccc4c(c3)sc3cc5sc6ccccc6c5cc34)ccc21 ; CC1(C)c2ccccc2-c2ccc(N(c3ccc4c(c3)C(C)(C)c3ccccc3-4)c3ccc4sc5cc6c(cc5c4c3)sc3ccccc36)cc21]

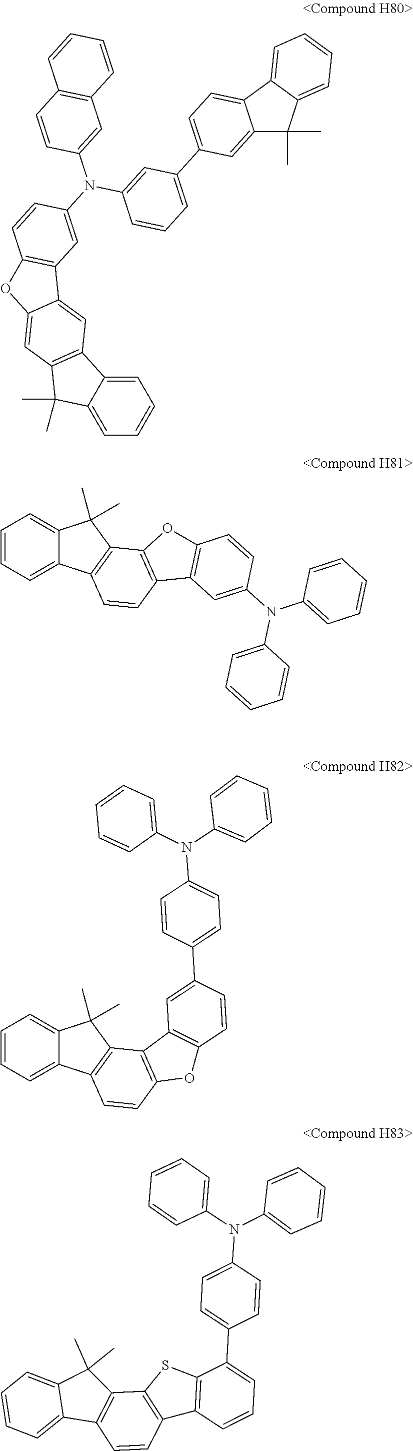 [SMILES: CC1(C)c2ccccc2-c2ccc(-c3cccc(N(c4ccc5ccccc5c4)c4ccc5oc6cc7c(cc6c5c4)-c4ccccc4C7(C)C)c3)cc21 ; CC1(C)c2ccccc2-c2ccc3c(oc4ccc(N(c5ccccc5)c5ccccc5)cc43)c21 ; CC1(C)c2ccccc2-c2ccc3oc4ccc(-c5ccc(N(c6ccccc6)c6ccccc6)cc5)cc4c3c21 ; CC1(C)c2ccccc2-c2ccc3c(sc4c(-c5ccc(N(c6ccccc6)c6ccccc6)cc5)cccc43)c21]

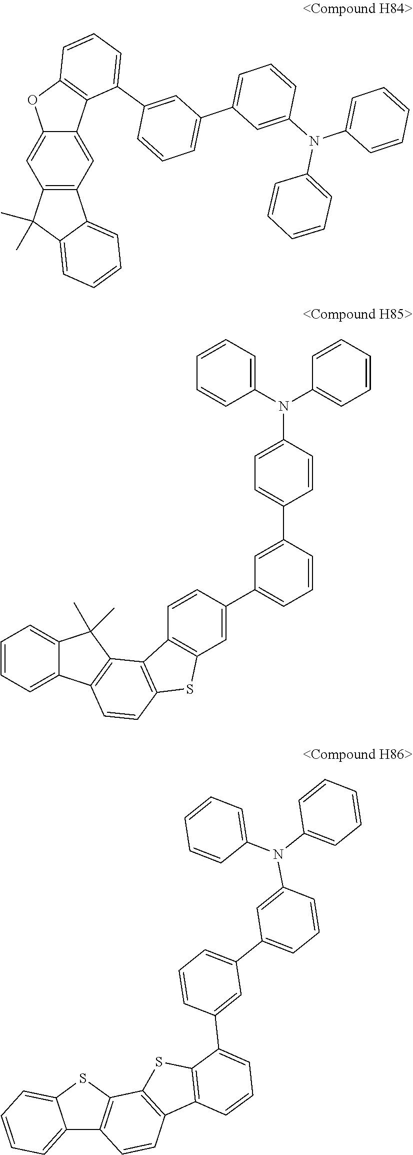 [SMILES: CC1(C)c2ccccc2-c2cc3c(cc21)oc1cccc(-c2cccc(-c4cccc(N(c5ccccc5)c5ccccc5)c4)c2)c13 ; CC1(C)c2ccccc2-c2ccc3sc4cc(-c5cccc(-c6ccc(N(c7ccccc7)c7ccccc7)cc6)c5)ccc4c3c21 ; c1ccc(N(c2ccccc2)c2cccc(-c3cccc(-c4cccc5c4sc4c5ccc5c6ccccc6sc54)c3)c2)cc1]

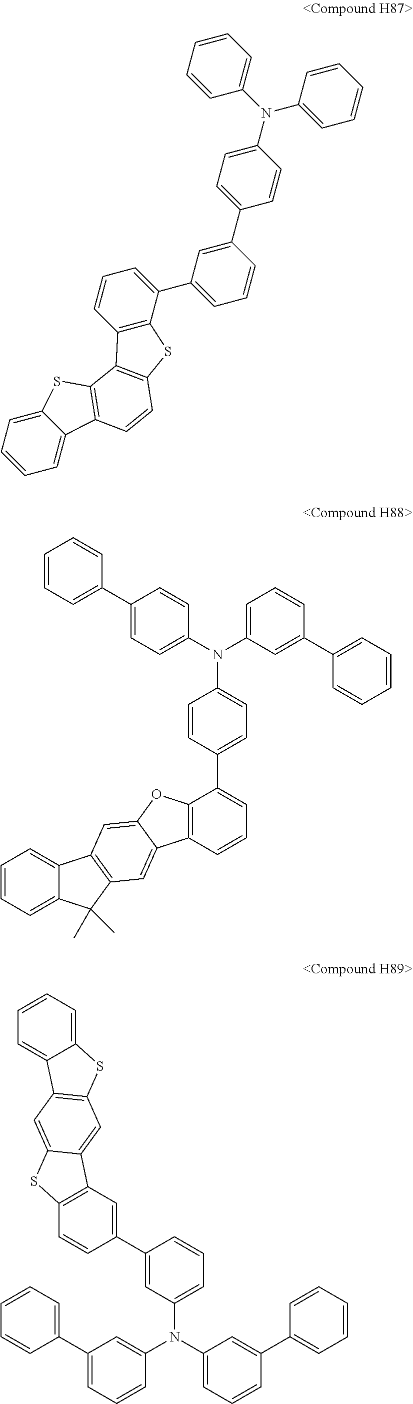 [SMILES: c1ccc(N(c2ccccc2)c2ccc(-c3cccc(-c4cccc5c4sc4ccc6c7ccccc7sc6c45)c3)cc2)cc1 ; CC1(C)c2ccccc2-c2cc3oc4c(-c5ccc(N(c6ccc(-c7ccccc7)cc6)c6cccc(-c7ccccc7)c6)cc5)cccc4c3cc21 ; c1ccc(-c2cccc(N(c3cccc(-c4ccccc4)c3)c3cccc(-c4ccc5sc6cc7c(cc6c5c4)sc4ccccc47)c3)c2)cc1]

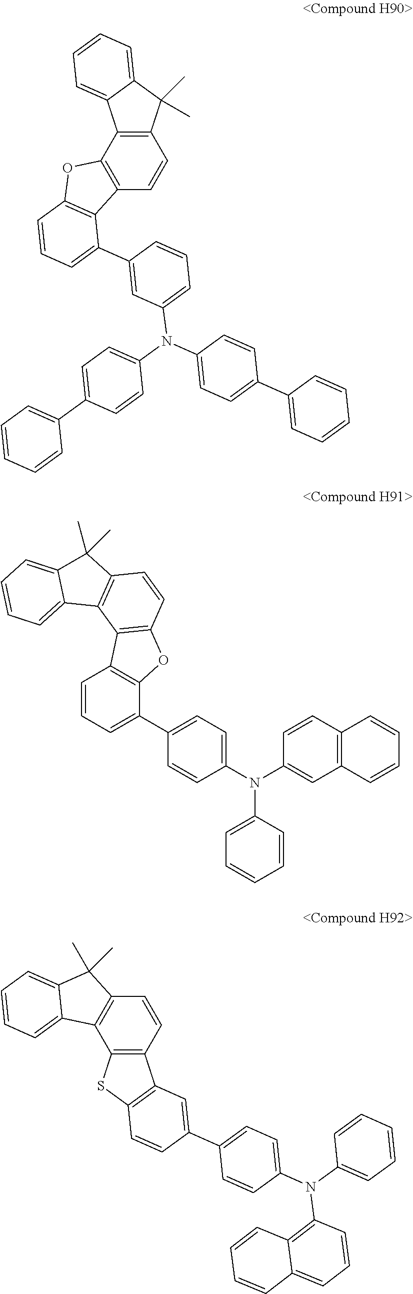 [SMILES: CC1(C)c2ccccc2-c2c1ccc1c2oc2cccc(-c3cccc(N(c4ccc(-c5ccccc5)cc4)c4ccc(-c5ccccc5)cc4)c3)c21 ; CC1(C)c2ccccc2-c2c1ccc1oc3c(-c4ccc(N(c5ccccc5)c5ccc6ccccc6c5)cc4)cccc3c21 ; CC1(C)c2ccccc2-c2c1ccc1c2sc2ccc(-c3ccc(N(c4ccccc4)c4cccc5ccccc45)cc3)cc21]

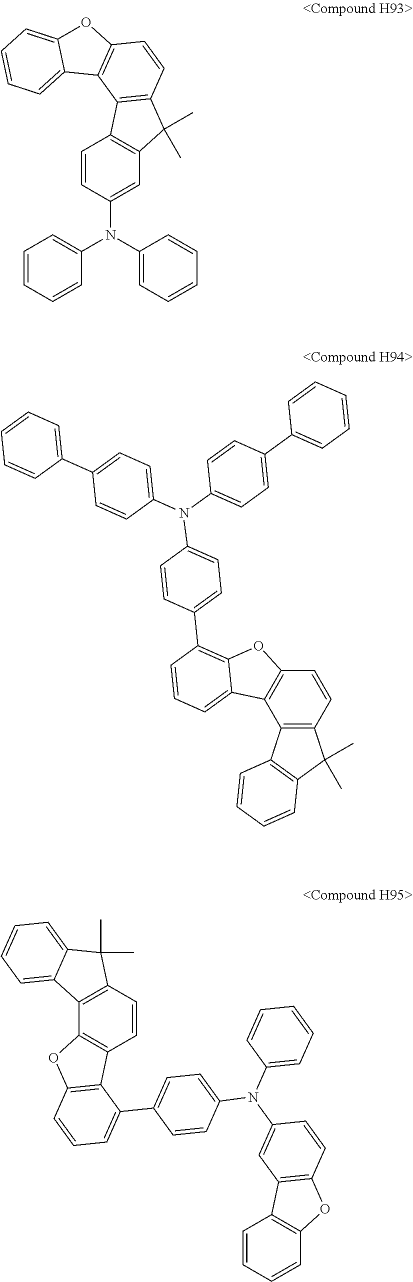 [SMILES: CC1(C)c2cc(N(c3ccccc3)c3ccccc3)ccc2-c2c1ccc1oc3ccccc3c21 ; CC1(C)c2ccccc2-c2c1ccc1oc3c(-c4ccc(N(c5ccc(-c6ccccc6)cc5)c5ccc(-c6ccccc6)cc5)cc4)cccc3c21 ; CC1(C)c2ccccc2-c2c1ccc1c2oc2cccc(-c3ccc(N(c4ccccc4)c4ccc5oc6ccccc6c5c4)cc3)c21]

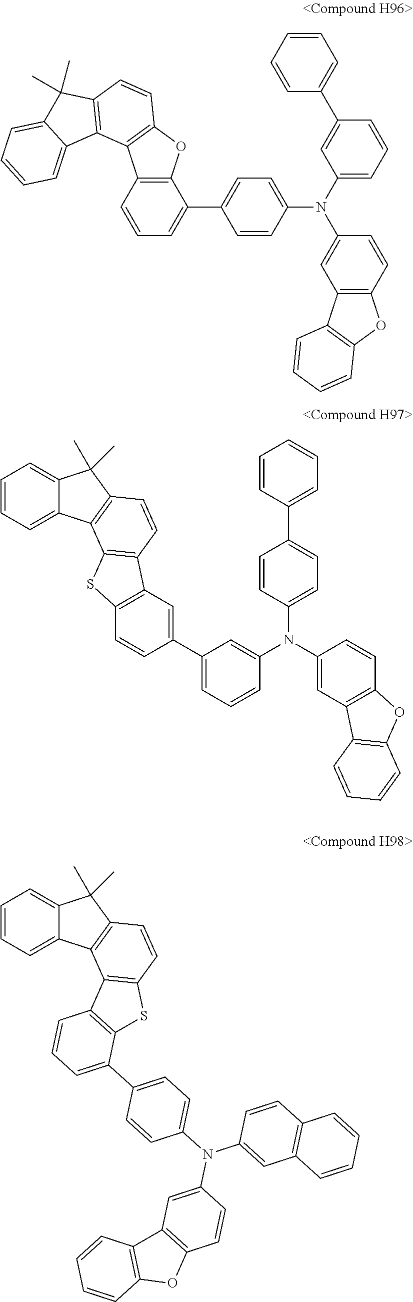 [SMILES: CC1(C)c2ccccc2-c2c1ccc1oc3c(-c4ccc(N(c5cccc(-c6ccccc6)c5)c5ccc6oc7ccccc7c6c5)cc4)cccc3c21 ; CC1(C)c2ccccc2-c2c1ccc1c2sc2ccc(-c3cccc(N(c4ccc(-c5ccccc5)cc4)c4ccc5oc6ccccc6c5c4)c3)cc21 ; CC1(C)c2ccccc2-c2c1ccc1sc3c(-c4ccc(N(c5ccc6ccccc6c5)c5ccc6oc7ccccc7c6c5)cc4)cccc3c21]

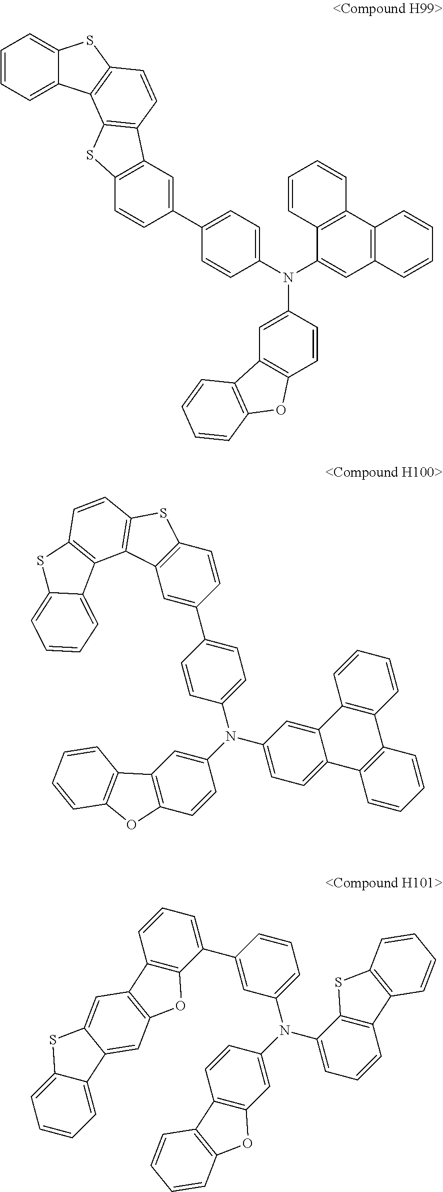 [SMILES: c1ccc2c(c1)cc(N(c1ccc(-c3ccc4sc5c(ccc6sc7ccccc7c65)c4c3)cc1)c1ccc3oc4ccccc4c3c1)c1ccccc12 ; c1ccc2c(c1)oc1ccc(N(c3ccc(-c4ccc5sc6ccc7sc8ccccc8c7c6c5c4)cc3)c3ccc4c5ccccc5c5ccccc5c4c3)cc12 ; c1cc(-c2cccc3c2oc2cc4c(cc23)sc2ccccc24)cc(N(c2ccc3c(c2)oc2ccccc23)c2cccc3c2sc2ccccc23)c1]

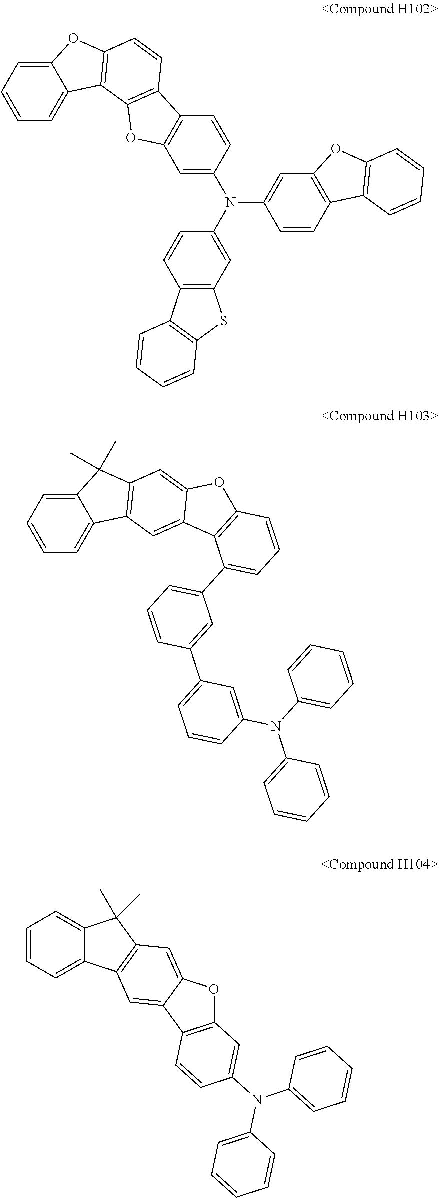 [SMILES: c1ccc2c(c1)oc1cc(N(c3ccc4c(c3)oc3c4ccc4oc5ccccc5c43)c3ccc4c(c3)sc3ccccc34)ccc12 ; CC1(C)c2ccccc2-c2cc3c(cc21)oc1cccc(-c2cccc(-c4cccc(N(c5ccccc5)c5ccccc5)c4)c2)c13 ; CC1(C)c2ccccc2-c2cc3c(cc21)oc1cc(N(c2ccccc2)c2ccccc2)ccc13]

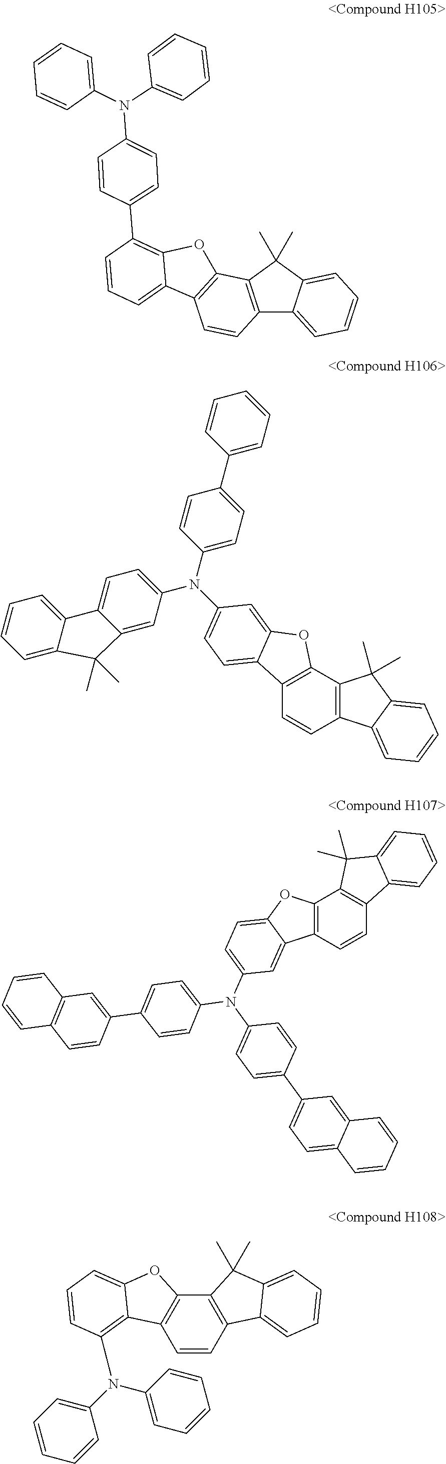 [SMILES: CC1(C)c2ccccc2-c2ccc3c(oc4c(-c5ccc(N(c6ccccc6)c6ccccc6)cc5)cccc43)c21 ; CC1(C)c2ccccc2-c2ccc(N(c3ccc(-c4ccccc4)cc3)c3ccc4c(c3)oc3c5c(ccc34)-c3ccccc3C5(C)C)cc21 ; CC1(C)c2ccccc2-c2ccc3c(oc4ccc(N(c5ccc(-c6ccc7ccccc7c6)cc5)c5ccc(-c6ccc7ccccc7c6)cc5)cc43)c21 ; CC1(C)c2ccccc2-c2ccc3c(oc4cccc(N(c5ccccc5)c5ccccc5)c43)c21]

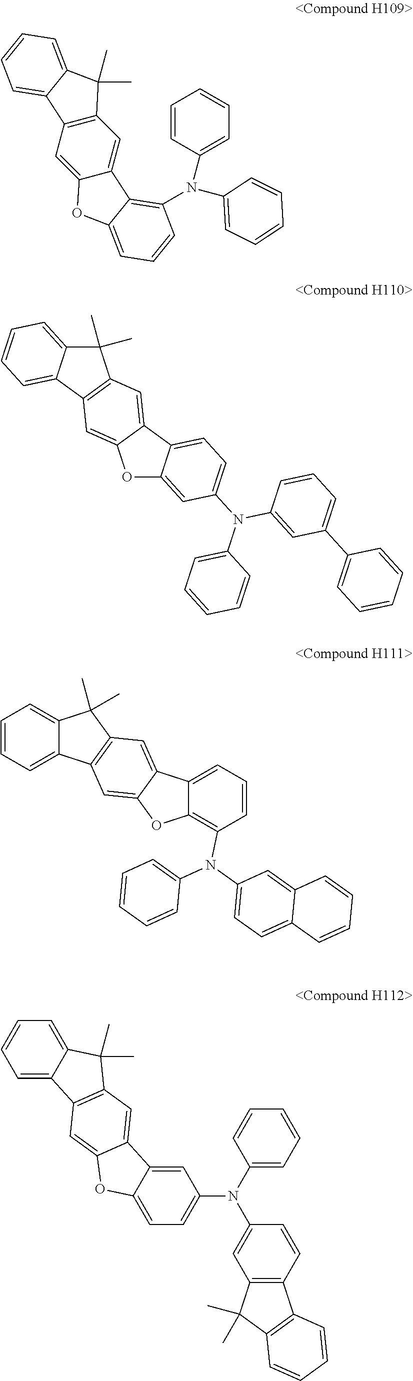 [SMILES: CC1(C)c2ccccc2-c2cc3oc4cccc(N(c5ccccc5)c5ccccc5)c4c3cc21 ; CC1(C)c2ccccc2-c2cc3oc4cc(N(c5ccccc5)c5cccc(-c6ccccc6)c5)ccc4c3cc21 ; CC1(C)c2ccccc2-c2cc3oc4c(N(c5ccccc5)c5ccc6ccccc6c5)cccc4c3cc21 ; CC1(C)c2ccccc2-c2ccc(N(c3ccccc3)c3ccc4oc5cc6c(cc5c4c3)C(C)(C)c3ccccc3-6)cc21]

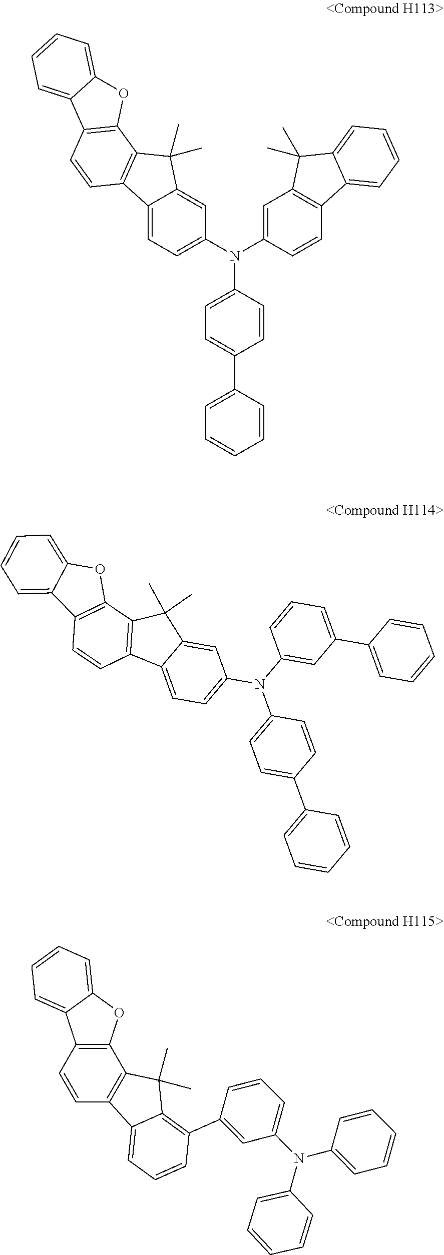 [SMILES: CC1(C)c2ccccc2-c2ccc(N(c3ccc(-c4ccccc4)cc3)c3ccc4c(c3)C(C)(C)c3c-4ccc4c3oc3ccccc34)cc21 ; CC1(C)c2cc(N(c3ccc(-c4ccccc4)cc3)c3cccc(-c4ccccc4)c3)ccc2-c2ccc3c(oc4ccccc43)c21 ; CC1(C)c2c(-c3cccc(N(c4ccccc4)c4ccccc4)c3)cccc2-c2ccc3c(oc4ccccc43)c21]

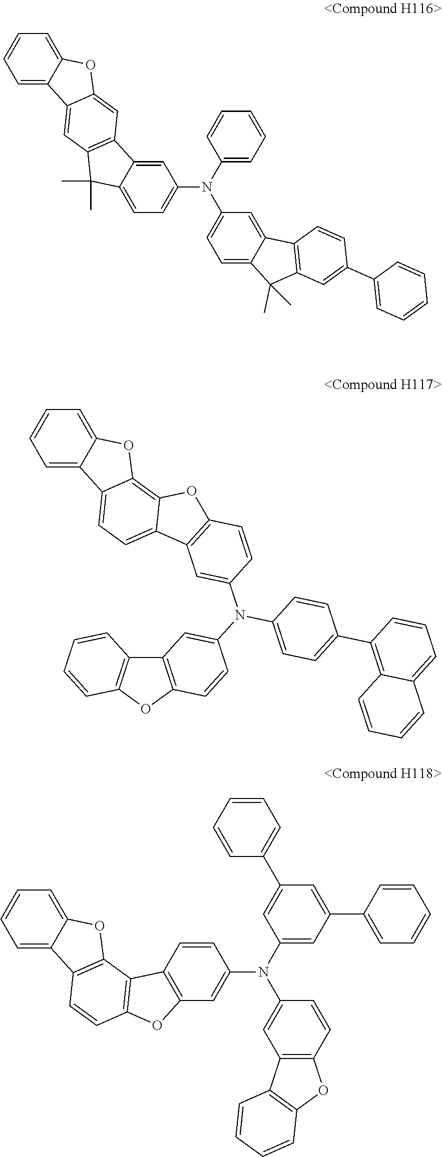 [SMILES: CC1(C)c2ccc(N(c3ccccc3)c3ccc4c(c3)-c3cc5oc6ccccc6c5cc3C4(C)C)cc2-c2ccc(-c3ccccc3)cc21 ; c1ccc2c(-c3ccc(N(c4ccc5oc6ccccc6c5c4)c4ccc5oc6c(ccc7c8ccccc8oc76)c5c4)cc3)cccc2c1 ; c1ccc(-c2cc(-c3ccccc3)cc(N(c3ccc4c(c3)oc3ccc5c6ccccc6oc5c34)c3ccc4oc5ccccc5c4c3)c2)cc1]

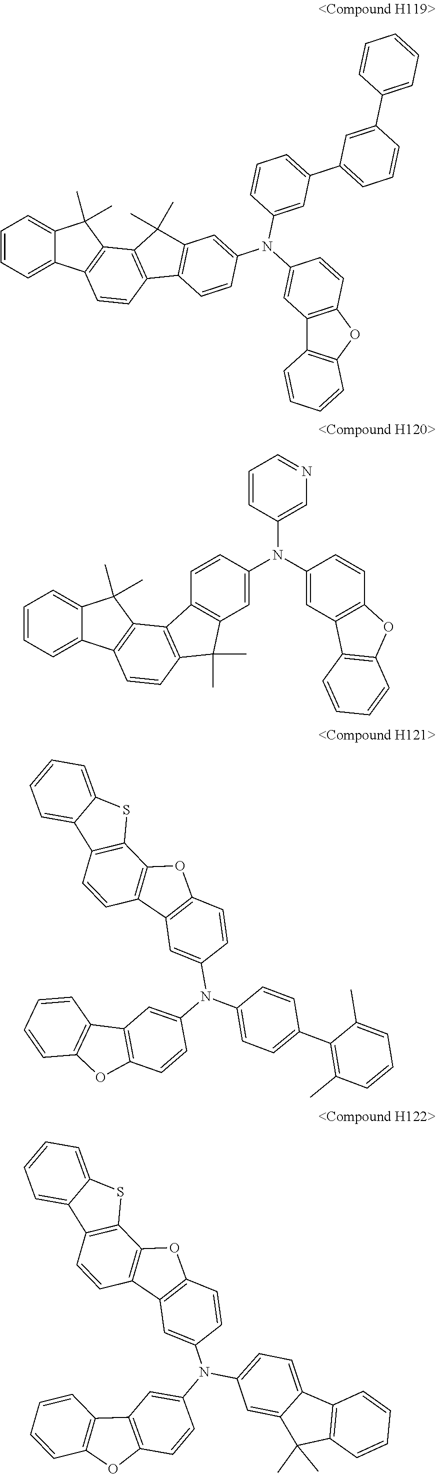 [SMILES: CC1(C)c2ccccc2-c2ccc3c(c21)C(C)(C)c1cc(N(c2cccc(-c4cccc(-c5ccccc5)c4)c2)c2ccc4oc5ccccc5c4c2)ccc1-3 ; CC1(C)c2cc(N(c3cccnc3)c3ccc4oc5ccccc5c4c3)ccc2-c2c1ccc1c2C(C)(C)c2ccccc2-1 ; Cc1cccc(C)c1-c1ccc(N(c2ccc3oc4ccccc4c3c2)c2ccc3oc4c(ccc5c6ccccc6sc54)c3c2)cc1 ; CC1(C)c2ccccc2-c2ccc(N(c3ccc4oc5ccccc5c4c3)c3ccc4oc5c(ccc6c7ccccc7sc65)c4c3)cc21]

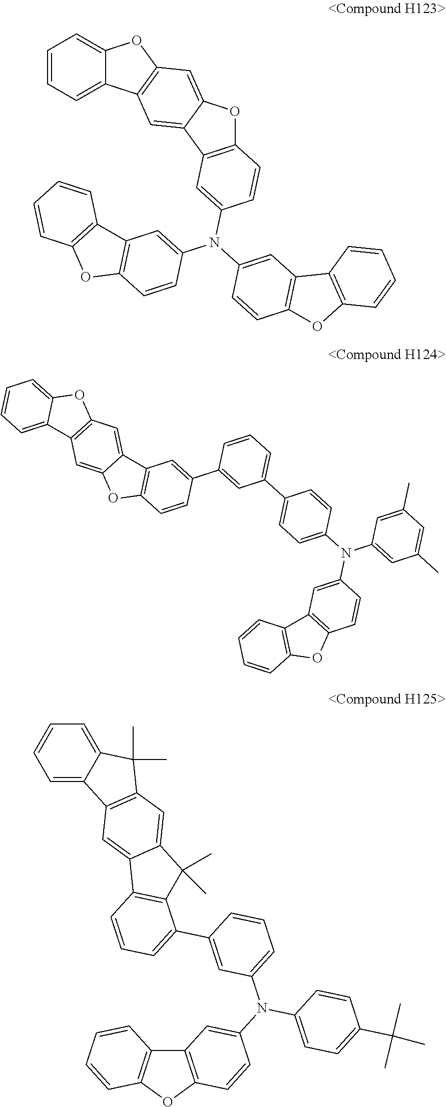 [SMILES: c1ccc2c(c1)oc1ccc(N(c3ccc4oc5ccccc5c4c3)c3ccc4oc5cc6oc7ccccc7c6cc5c4c3)cc12 ; Cc1cc(C)cc(N(c2ccc(-c3cccc(-c4ccc5oc6cc7c(cc6c5c4)oc4ccccc47)c3)cc2)c2ccc3oc4ccccc4c3c2)c1 ; CC(C)(C)c1ccc(N(c2cccc(-c3cccc4c3C(C)(C)c3cc5c(cc3-4)-c3ccccc3C5(C)C)c2)c2ccc3oc4ccccc4c3c2)cc1]

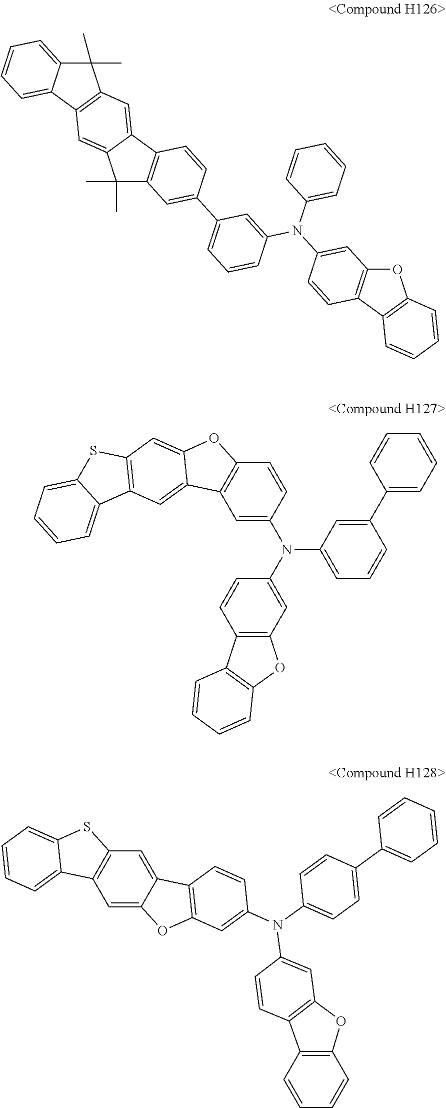 [SMILES: CC1(C)c2ccccc2-c2cc3c(cc21)-c1ccc(-c2cccc(N(c4ccccc4)c4ccc5c(c4)oc4ccccc45)c2)cc1C3(C)C ; c1ccc(-c2cccc(N(c3ccc4c(c3)oc3ccccc34)c3ccc4oc5cc6sc7ccccc7c6cc5c4c3)c2)cc1 ; c1ccc(-c2ccc(N(c3ccc4c(c3)oc3ccccc34)c3ccc4c(c3)oc3cc5c(cc34)sc3ccccc35)cc2)cc1]

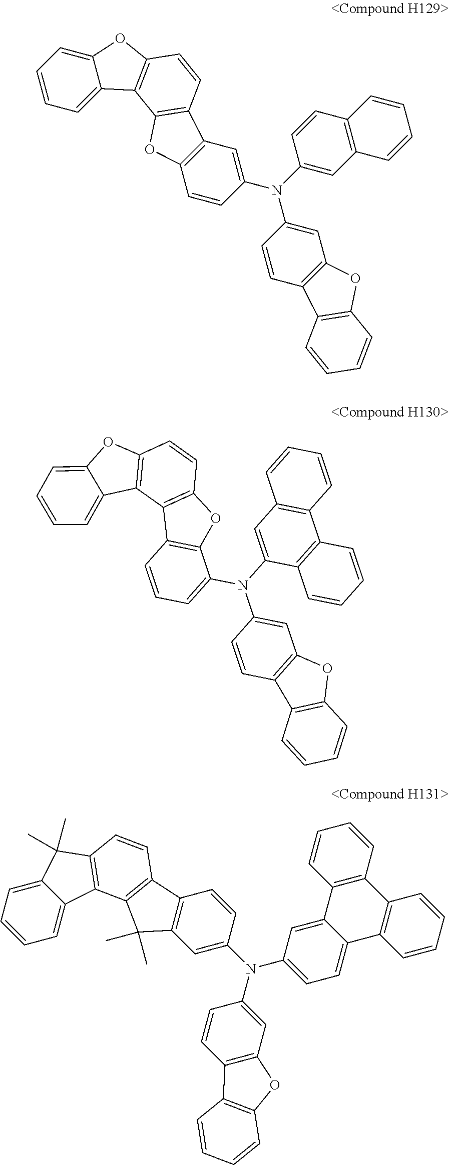 [SMILES: c1ccc2cc(N(c3ccc4c(c3)oc3ccccc34)c3ccc4oc5c(ccc6oc7ccccc7c65)c4c3)ccc2c1 ; c1ccc2c(c1)cc(N(c1ccc3c(c1)oc1ccccc13)c1cccc3c1oc1ccc4oc5ccccc5c4c13)c1ccccc12 ; CC1(C)c2ccccc2-c2c1ccc1c2C(C)(C)c2cc(N(c3ccc4c(c3)oc3ccccc34)c3ccc4c5ccccc5c5ccccc5c4c3)ccc2-1]

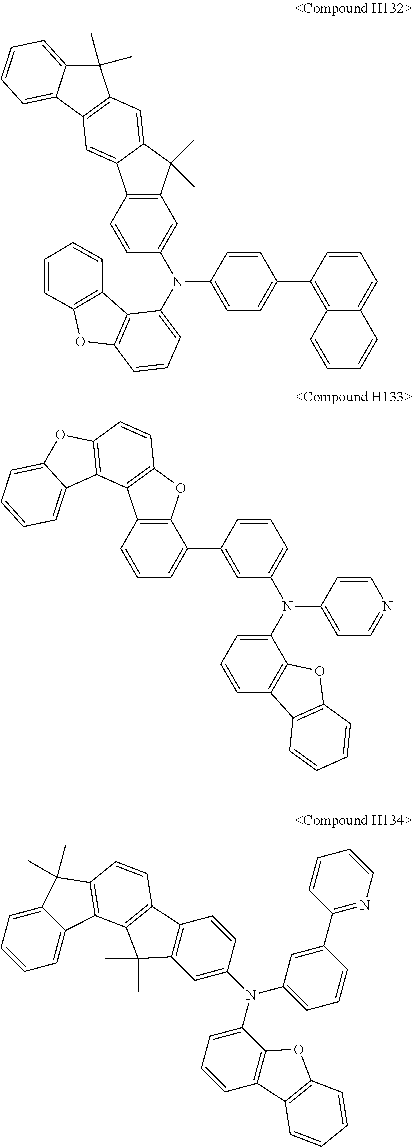 [SMILES: CC1(C)c2ccccc2-c2cc3c(cc21)C(C)(C)c1cc(N(c2ccc(-c4cccc5ccccc45)cc2)c2cccc4oc5ccccc5c24)ccc1-3 ; c1cc(-c2cccc3c2oc2ccc4oc5ccccc5c4c23)cc(N(c2ccncc2)c2cccc3c2oc2ccccc23)c1 ; CC1(C)c2ccccc2-c2c1ccc1c2C(C)(C)c2cc(N(c3cccc(-c4ccccn4)c3)c3cccc4c3oc3ccccc34)ccc2-1]

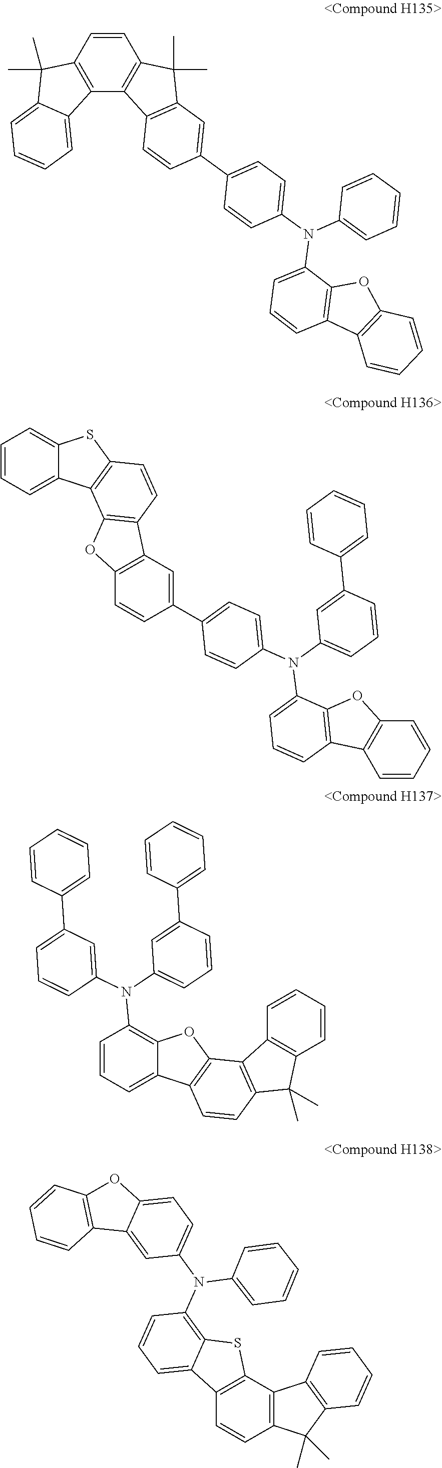 [SMILES: CC1(C)c2ccccc2-c2c1ccc1c2-c2ccc(-c3ccc(N(c4ccccc4)c4cccc5c4oc4ccccc45)cc3)cc2C1(C)C ; c1ccc(-c2cccc(N(c3ccc(-c4ccc5oc6c(ccc7sc8ccccc8c76)c5c4)cc3)c3cccc4c3oc3ccccc34)c2)cc1 ; CC1(C)c2ccccc2-c2c1ccc1c2oc2c(N(c3cccc(-c4ccccc4)c3)c3cccc(-c4ccccc4)c3)cccc21 ; CC1(C)c2ccccc2-c2c1ccc1c2sc2c(N(c3ccccc3)c3ccc4oc5ccccc5c4c3)cccc21]

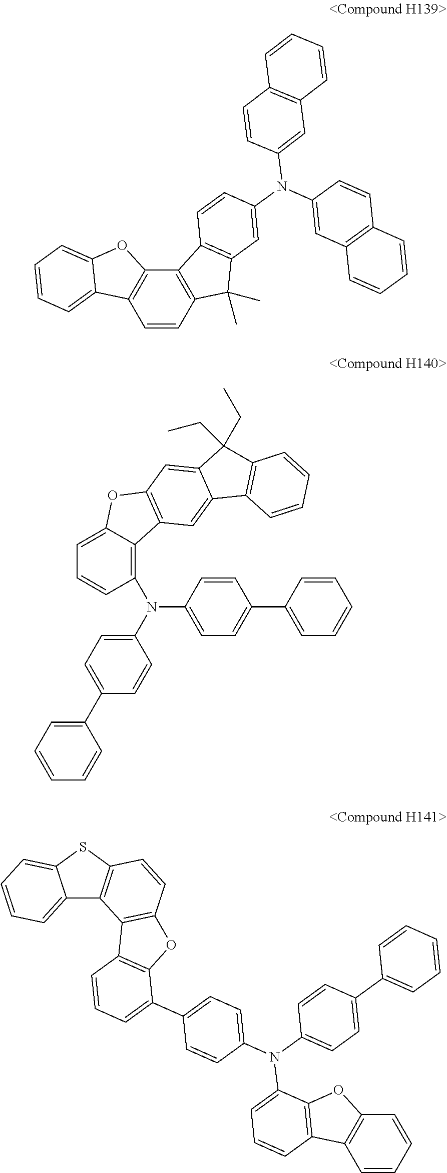 [SMILES: CC1(C)c2cc(N(c3ccc4ccccc4c3)c3ccc4ccccc4c3)ccc2-c2c1ccc1c2oc2ccccc21 ; CCC1(CC)c2ccccc2-c2cc3c(cc21)oc1cccc(N(c2ccc(-c4ccccc4)cc2)c2ccc(-c4ccccc4)cc2)c13 ; c1ccc(-c2ccc(N(c3ccc(-c4cccc5c4oc4ccc6sc7ccccc7c6c45)cc3)c3cccc4c3oc3ccccc34)cc2)cc1]

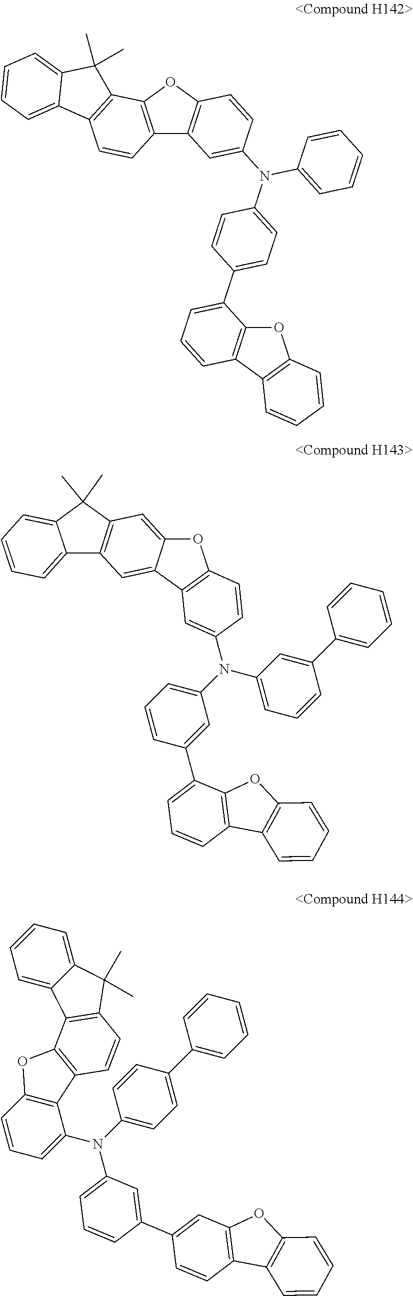 [SMILES: CC1(C)c2ccccc2-c2ccc3c(oc4ccc(N(c5ccccc5)c5ccc(-c6cccc7c6oc6ccccc67)cc5)cc43)c21 ; CC1(C)c2ccccc2-c2cc3c(cc21)oc1ccc(N(c2cccc(-c4ccccc4)c2)c2cccc(-c4cccc5c4oc4ccccc45)c2)cc13 ; CC1(C)c2ccccc2-c2c1ccc1c2oc2cccc(N(c3ccc(-c4ccccc4)cc3)c3cccc(-c4ccc5c(c4)oc4ccccc45)c3)c21]

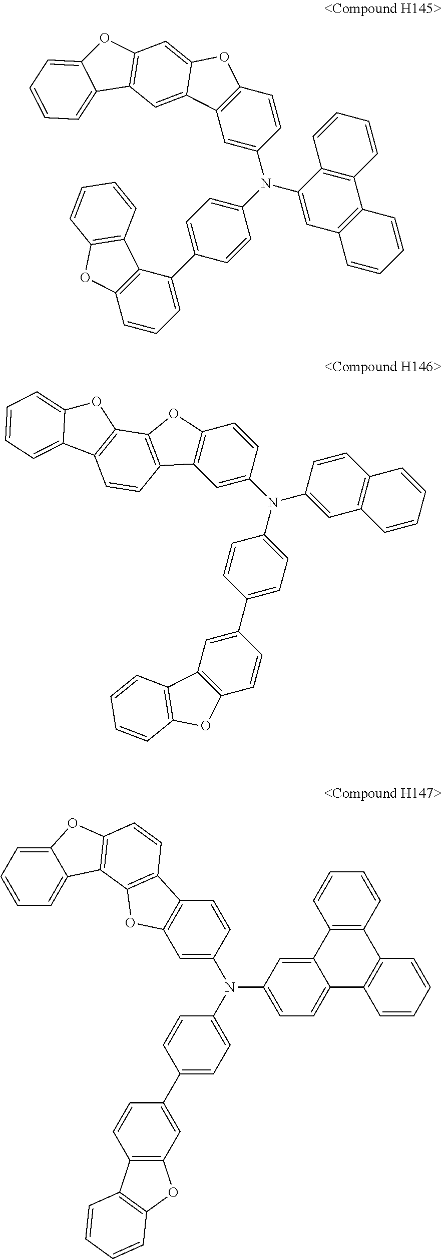 [SMILES: c1ccc2c(c1)cc(N(c1ccc(-c3cccc4oc5ccccc5c34)cc1)c1ccc3oc4cc5oc6ccccc6c5cc4c3c1)c1ccccc12 ; c1ccc2cc(N(c3ccc(-c4ccc5oc6ccccc6c5c4)cc3)c3ccc4oc5c(ccc6c7ccccc7oc65)c4c3)ccc2c1 ; c1ccc2c(c1)oc1cc(-c3ccc(N(c4ccc5c(c4)oc4c5ccc5oc6ccccc6c54)c4ccc5c6ccccc6c6ccccc6c5c4)cc3)ccc12]

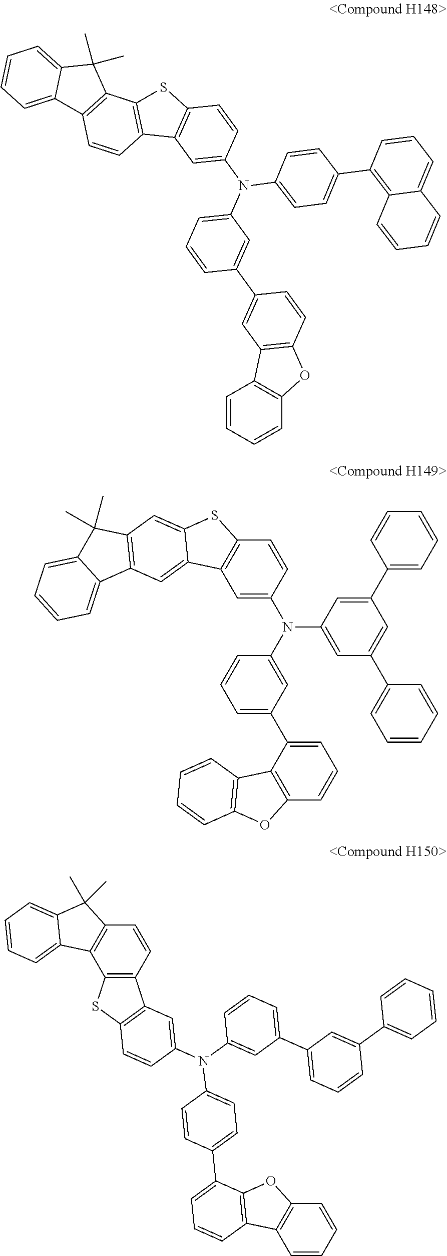 [SMILES: CC1(C)c2ccccc2-c2ccc3c(sc4ccc(N(c5ccc(-c6cccc7ccccc67)cc5)c5cccc(-c6ccc7oc8ccccc8c7c6)c5)cc43)c21 ; CC1(C)c2ccccc2-c2cc3c(cc21)sc1ccc(N(c2cc(-c4ccccc4)cc(-c4ccccc4)c2)c2cccc(-c4cccc5oc6ccccc6c45)c2)cc13 ; CC1(C)c2ccccc2-c2c1ccc1c2sc2ccc(N(c3ccc(-c4cccc5c4oc4ccccc45)cc3)c3cccc(-c4cccc(-c5ccccc5)c4)c3)cc21]

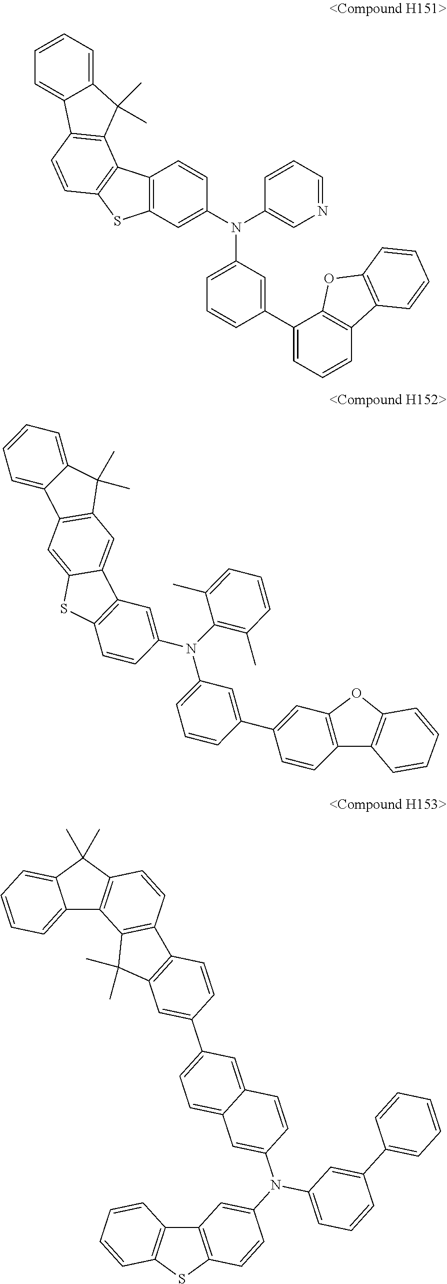 [SMILES: CC1(C)c2ccccc2-c2ccc3sc4cc(N(c5cccnc5)c5cccc(-c6cccc7c6oc6ccccc67)c5)ccc4c3c21 ; Cc1cccc(C)c1N(c1cccc(-c2ccc3c(c2)oc2ccccc23)c1)c1ccc2sc3cc4c(cc3c2c1)C(C)(C)c1ccccc1-4 ; CC1(C)c2ccccc2-c2c1ccc1c2C(C)(C)c2cc(-c3ccc4cc(N(c5cccc(-c6ccccc6)c5)c5ccc6sc7ccccc7c6c5)ccc4c3)ccc2-1]

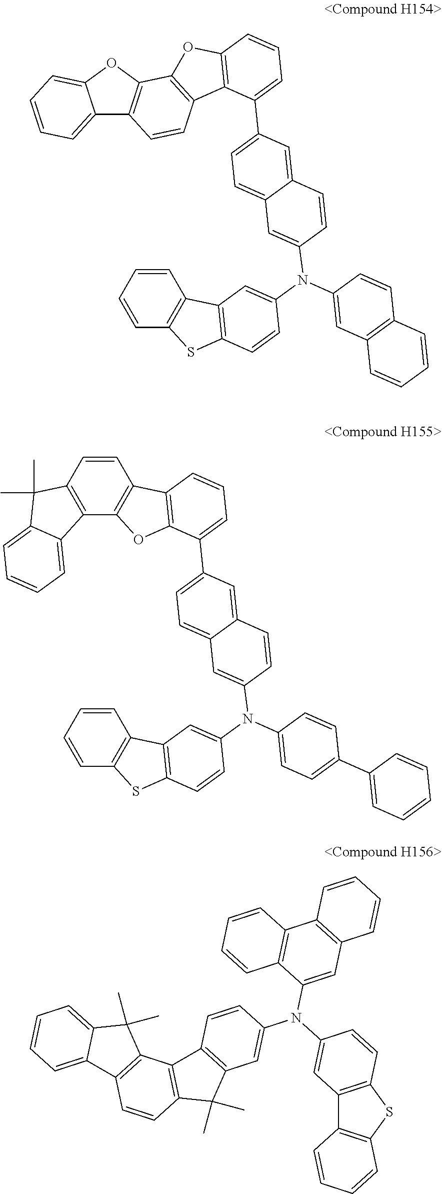 [SMILES: c1ccc2cc(N(c3ccc4cc(-c5cccc6oc7c(ccc8c9ccccc9oc87)c56)ccc4c3)c3ccc4sc5ccccc5c4c3)ccc2c1 ; CC1(C)c2ccccc2-c2c1ccc1c2oc2c(-c3ccc4cc(N(c5ccc(-c6ccccc6)cc5)c5ccc6sc7ccccc7c6c5)ccc4c3)cccc21 ; CC1(C)c2cc(N(c3ccc4sc5ccccc5c4c3)c3cc4ccccc4c4ccccc34)ccc2-c2c1ccc1c2C(C)(C)c2ccccc2-1]

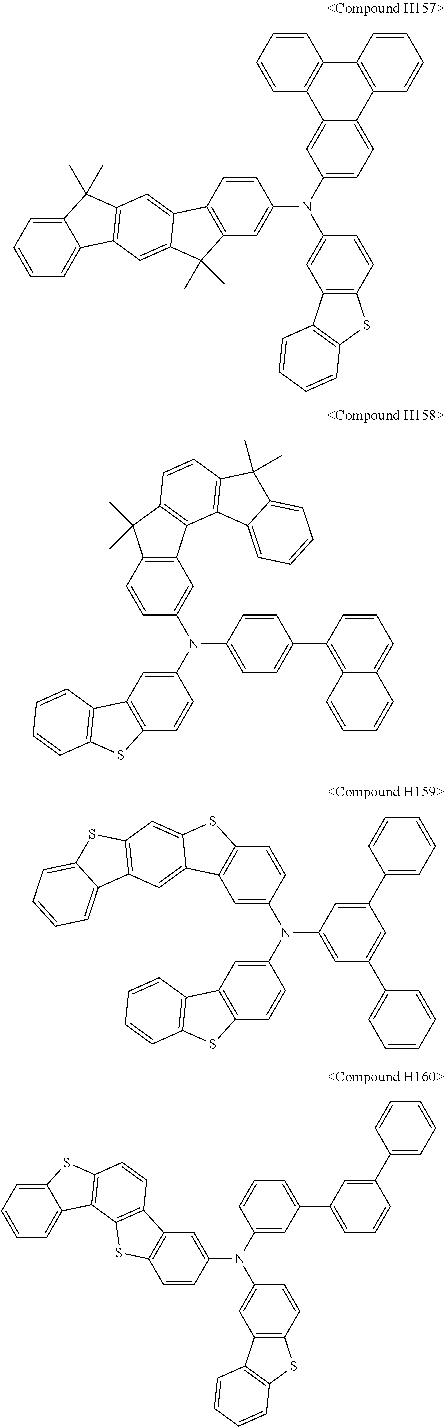 [SMILES: CC1(C)c2ccccc2-c2cc3c(cc21)-c1ccc(N(c2ccc4sc5ccccc5c4c2)c2ccc4c5ccccc5c5ccccc5c4c2)cc1C3(C)C ; CC1(C)c2ccccc2-c2c1ccc1c2-c2cc(N(c3ccc(-c4cccc5ccccc45)cc3)c3ccc4sc5ccccc5c4c3)ccc2C1(C)C ; c1ccc(-c2cc(-c3ccccc3)cc(N(c3ccc4sc5ccccc5c4c3)c3ccc4sc5cc6sc7ccccc7c6cc5c4c3)c2)cc1 ; c1ccc(-c2cccc(-c3cccc(N(c4ccc5sc6ccccc6c5c4)c4ccc5sc6c(ccc7sc8ccccc8c76)c5c4)c3)c2)cc1]

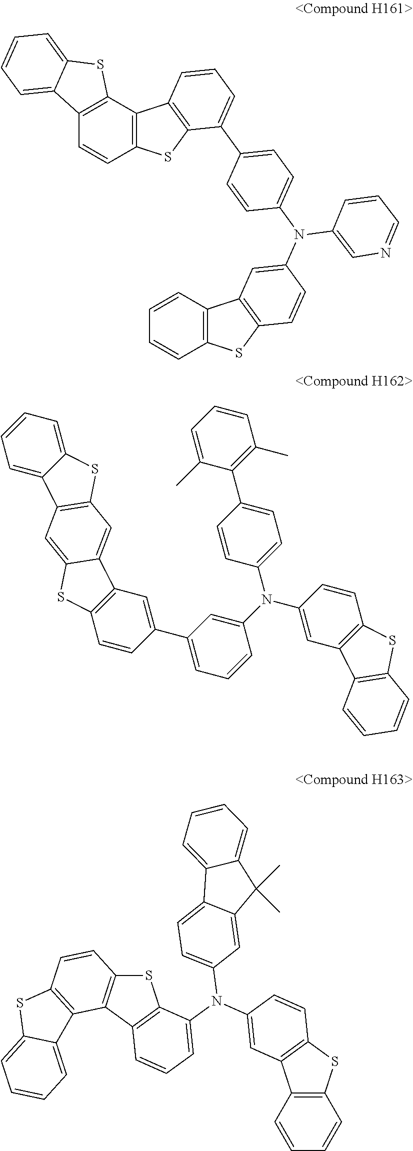 [SMILES: c1cncc(N(c2ccc(-c3cccc4c3sc3ccc5c6ccccc6sc5c34)cc2)c2ccc3sc4ccccc4c3c2)c1 ; Cc1cccc(C)c1-c1ccc(N(c2cccc(-c3ccc4sc5cc6c(cc5c4c3)sc3ccccc36)c2)c2ccc3sc4ccccc4c3c2)cc1 ; CC1(C)c2ccccc2-c2ccc(N(c3ccc4sc5ccccc5c4c3)c3cccc4c3sc3ccc5sc6ccccc6c5c34)cc21]

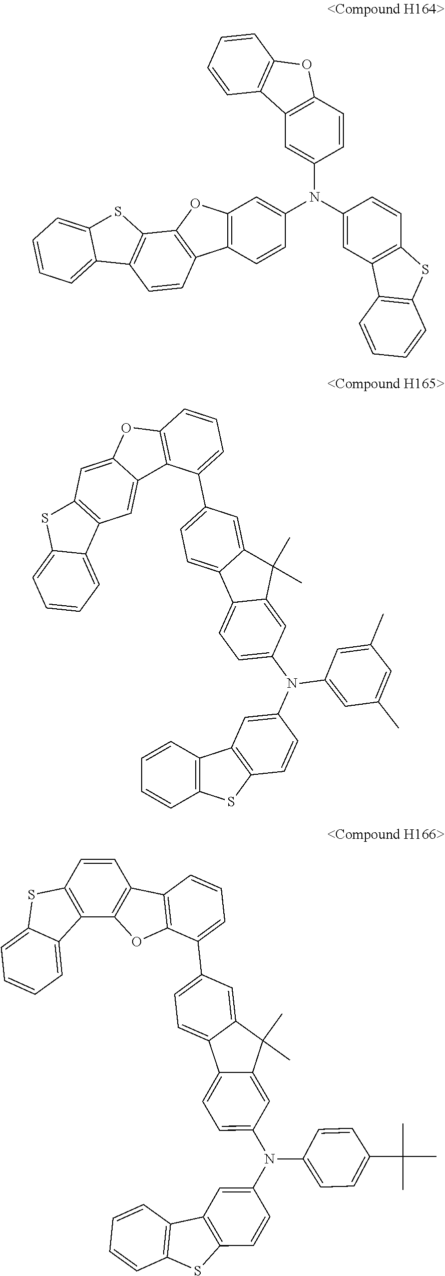 [SMILES: c1ccc2c(c1)oc1ccc(N(c3ccc4c(c3)oc3c4ccc4c5ccccc5sc43)c3ccc4sc5ccccc5c4c3)cc12 ; Cc1cc(C)cc(N(c2ccc3c(c2)C(C)(C)c2cc(-c4cccc5oc6cc7sc8ccccc8c7cc6c45)ccc2-3)c2ccc3sc4ccccc4c3c2)c1 ; CC(C)(C)c1ccc(N(c2ccc3c(c2)C(C)(C)c2cc(-c4cccc5c4oc4c5ccc5sc6ccccc6c54)ccc2-3)c2ccc3sc4ccccc4c3c2)cc1]

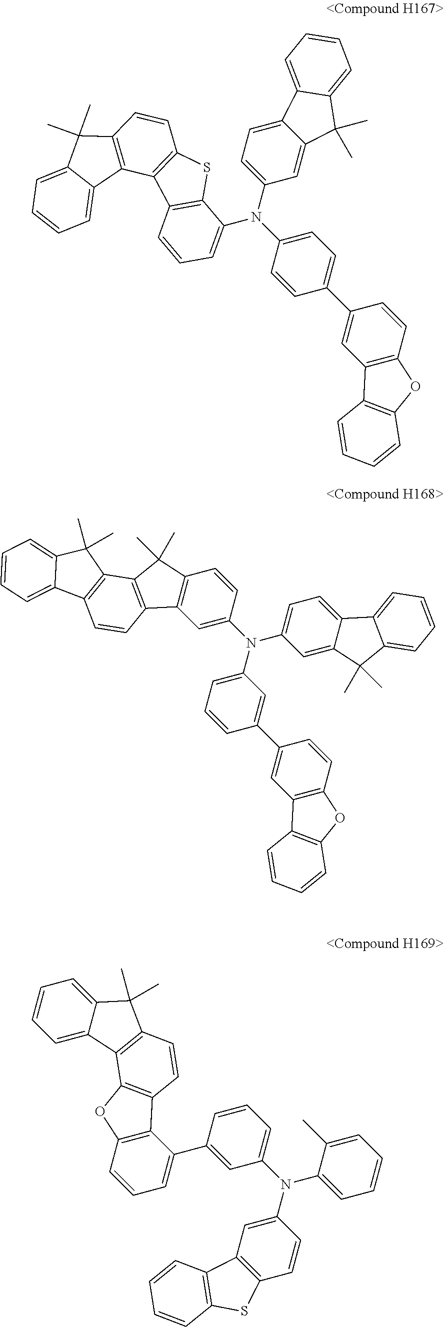 [SMILES: CC1(C)c2ccccc2-c2ccc(N(c3ccc(-c4ccc5oc6ccccc6c5c4)cc3)c3cccc4c3sc3ccc5c(c34)-c3ccccc3C5(C)C)cc21 ; CC1(C)c2ccccc2-c2ccc(N(c3cccc(-c4ccc5oc6ccccc6c5c4)c3)c3ccc4c(c3)-c3ccc5c(c3C4(C)C)C(C)(C)c3ccccc3-5)cc21 ; Cc1ccccc1N(c1cccc(-c2cccc3oc4c5c(ccc4c23)C(C)(C)c2ccccc2-5)c1)c1ccc2sc3ccccc3c2c1]

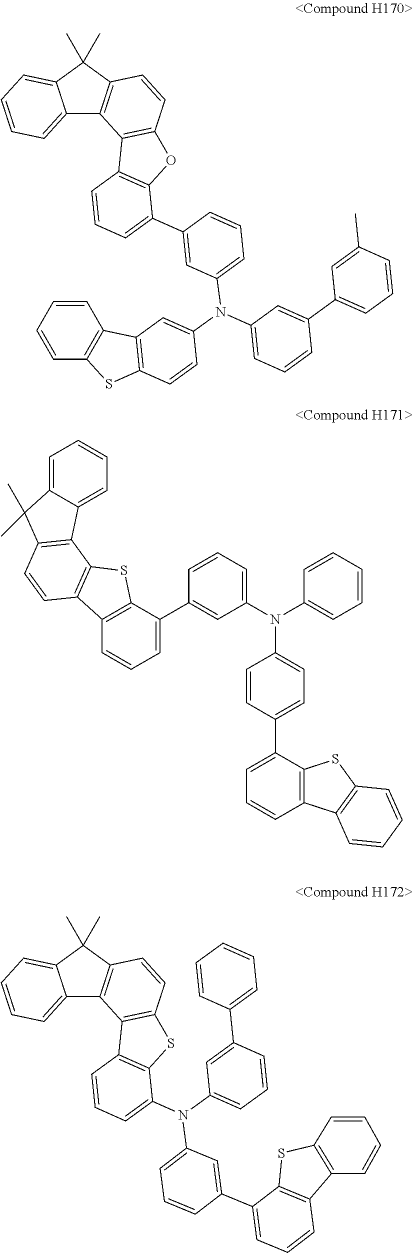 [SMILES: Cc1cccc(-c2cccc(N(c3cccc(-c4cccc5c4oc4ccc6c(c45)-c4ccccc4C6(C)C)c3)c3ccc4sc5ccccc5c4c3)c2)c1 ; CC1(C)c2ccccc2-c2c1ccc1c2sc2c(-c3cccc(N(c4ccccc4)c4ccc(-c5cccc6c5sc5ccccc56)cc4)c3)cccc21 ; CC1(C)c2ccccc2-c2c1ccc1sc3c(N(c4cccc(-c5ccccc5)c4)c4cccc(-c5cccc6c5sc5ccccc56)c4)cccc3c21]

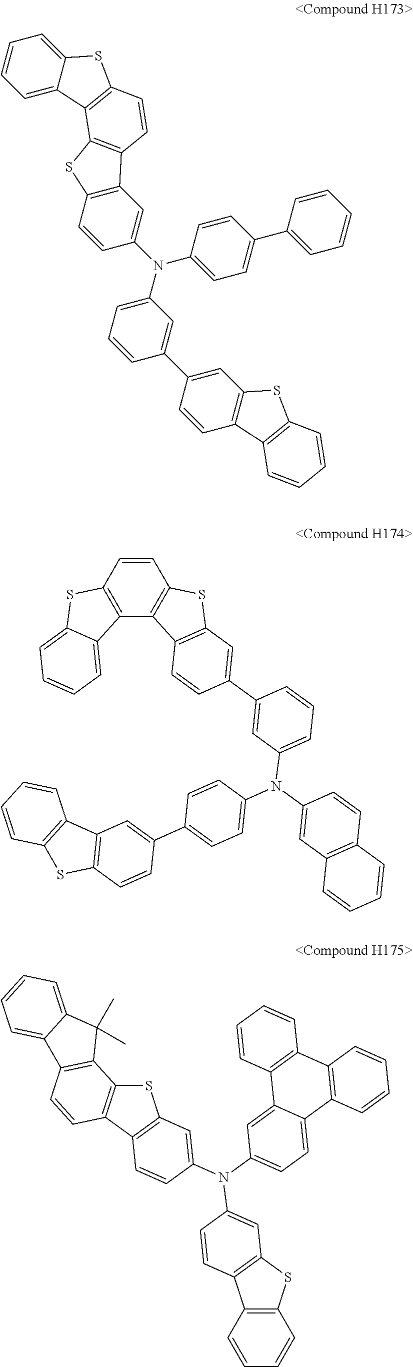 [SMILES: c1ccc(-c2ccc(N(c3cccc(-c4ccc5c(c4)sc4ccccc45)c3)c3ccc4sc5c(ccc6sc7ccccc7c65)c4c3)cc2)cc1 ; c1cc(-c2ccc3c(c2)sc2ccc4sc5ccccc5c4c23)cc(N(c2ccc(-c3ccc4sc5ccccc5c4c3)cc2)c2ccc3ccccc3c2)c1 ; CC1(C)c2ccccc2-c2ccc3c(sc4cc(N(c5ccc6c(c5)sc5ccccc56)c5ccc6c7ccccc7c7ccccc7c6c5)ccc43)c21]

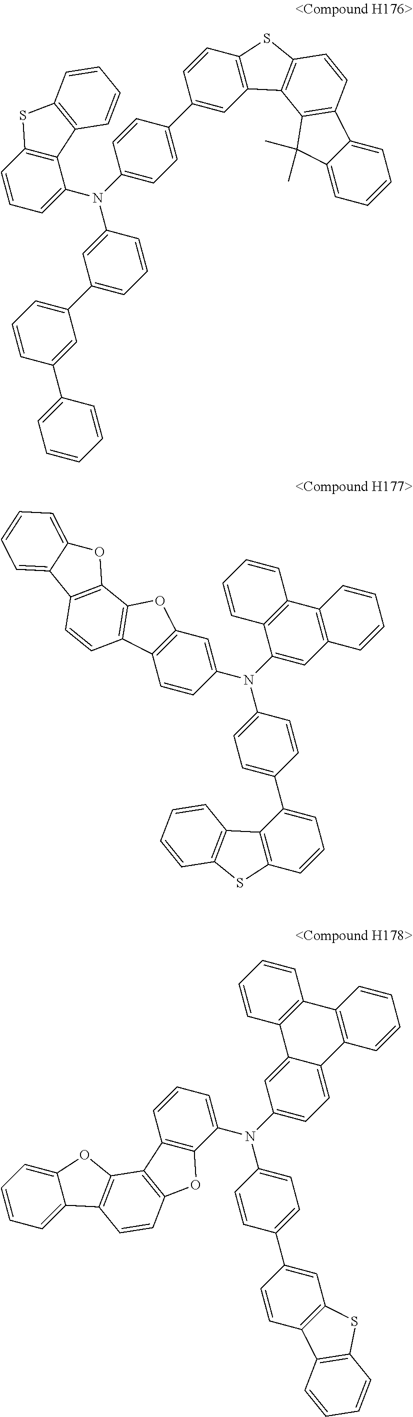 [SMILES: CC1(C)c2ccccc2-c2ccc3sc4ccc(-c5ccc(N(c6cccc(-c7cccc(-c8ccccc8)c7)c6)c6cccc7sc8ccccc8c67)cc5)cc4c3c21 ; c1ccc2c(c1)cc(N(c1ccc(-c3cccc4sc5ccccc5c34)cc1)c1ccc3c(c1)oc1c3ccc3c4ccccc4oc31)c1ccccc12 ; c1ccc2c(c1)oc1c2ccc2oc3c(N(c4ccc(-c5ccc6c(c5)sc5ccccc56)cc4)c4ccc5c6ccccc6c6ccccc6c5c4)cccc3c21]

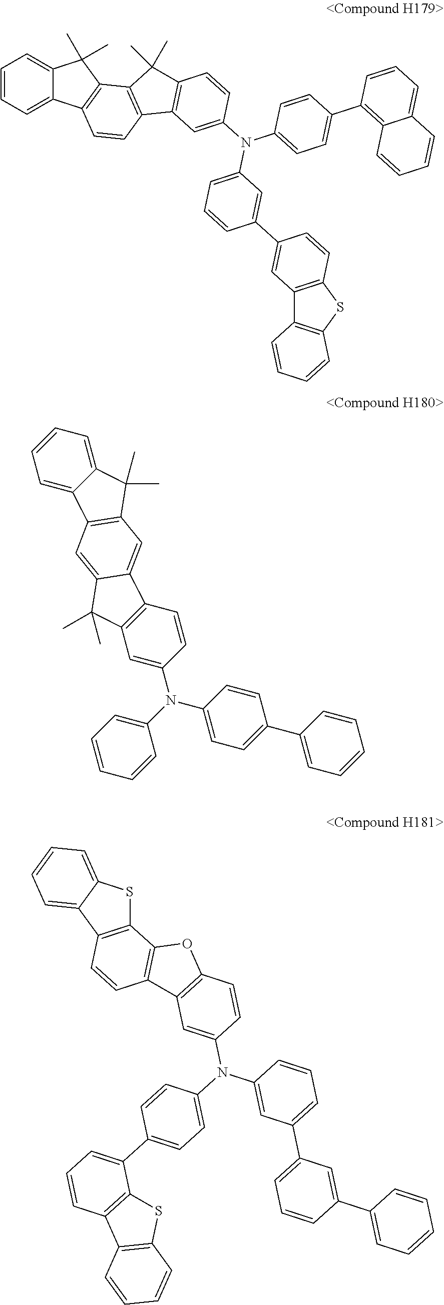 [SMILES: CC1(C)c2ccccc2-c2ccc3c(c21)C(C)(C)c1ccc(N(c2ccc(-c4cccc5ccccc45)cc2)c2cccc(-c4ccc5sc6ccccc6c5c4)c2)cc1-3 ; CC1(C)c2ccccc2-c2cc3c(cc21)-c1ccc(N(c2ccccc2)c2ccc(-c4ccccc4)cc2)cc1C3(C)C ; c1ccc(-c2cccc(-c3cccc(N(c4ccc(-c5cccc6c5sc5ccccc56)cc4)c4ccc5oc6c(ccc7c8ccccc8sc76)c5c4)c3)c2)cc1]

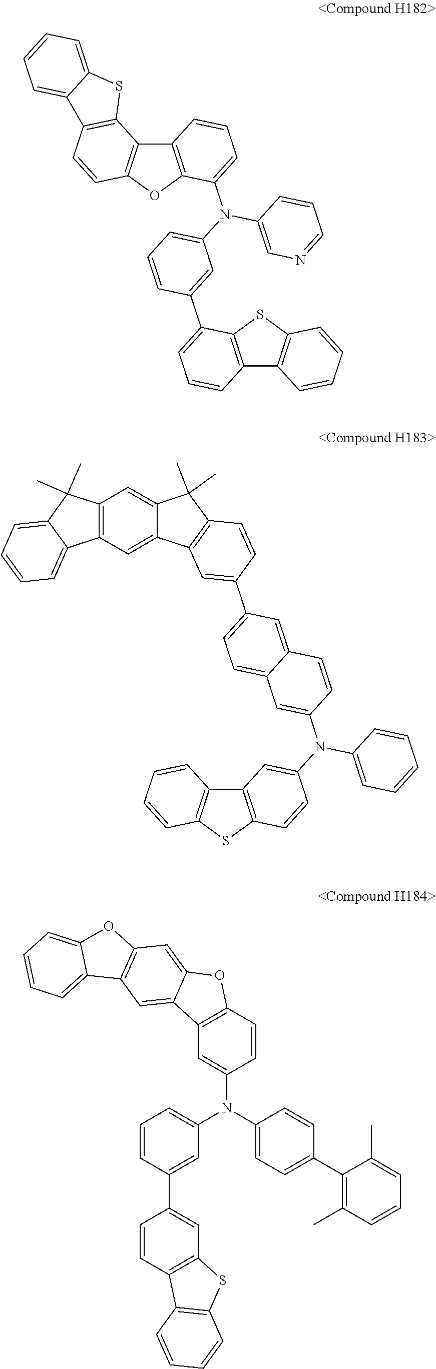 [SMILES: c1cncc(N(c2cccc(-c3cccc4c3sc3ccccc34)c2)c2cccc3c2oc2ccc4c5ccccc5sc4c23)c1 ; CC1(C)c2ccccc2-c2cc3c(cc21)C(C)(C)c1ccc(-c2ccc4cc(N(c5ccccc5)c5ccc6sc7ccccc7c6c5)ccc4c2)cc1-3 ; Cc1cccc(C)c1-c1ccc(N(c2cccc(-c3ccc4c(c3)sc3ccccc34)c2)c2ccc3oc4cc5oc6ccccc6c5cc4c3c2)cc1]

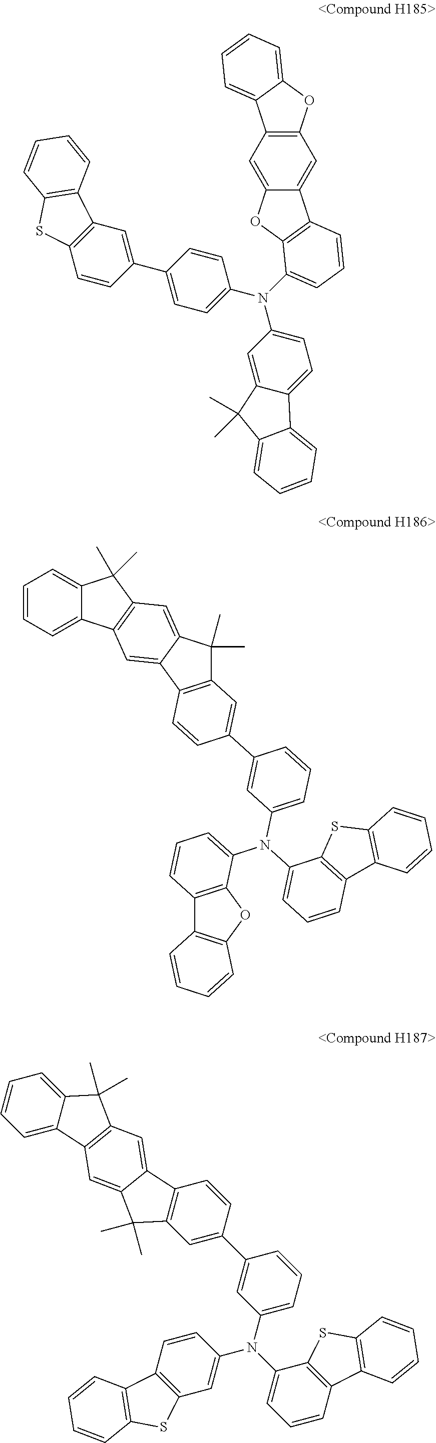 [SMILES: CC1(C)c2ccccc2-c2ccc(N(c3ccc(-c4ccc5sc6ccccc6c5c4)cc3)c3cccc4c3oc3cc5c(cc34)oc3ccccc35)cc21 ; CC1(C)c2ccccc2-c2cc3c(cc21)C(C)(C)c1cc(-c2cccc(N(c4cccc5c4oc4ccccc45)c4cccc5c4sc4ccccc45)c2)ccc1-3 ; CC1(C)c2ccccc2-c2cc3c(cc21)-c1ccc(-c2cccc(N(c4ccc5c(c4)sc4ccccc45)c4cccc5c4sc4ccccc45)c2)cc1C3(C)C]

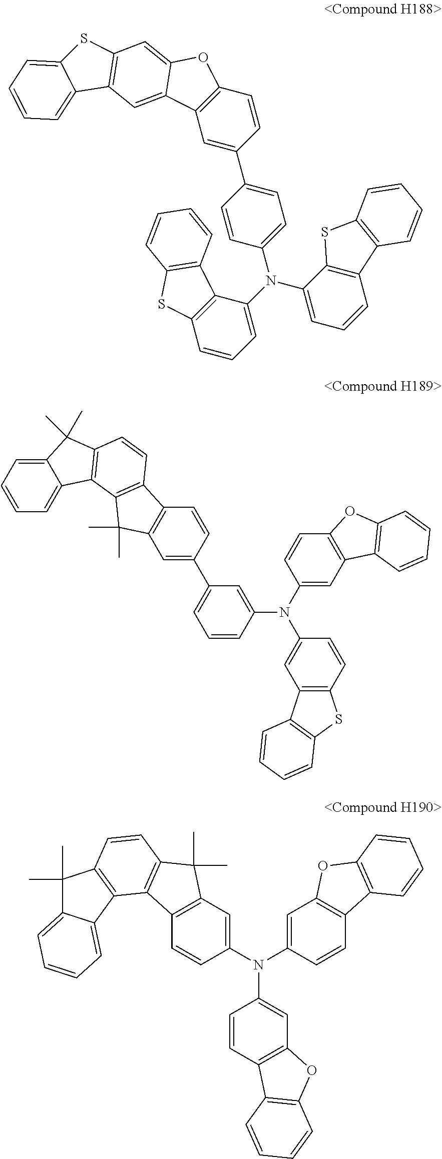 [SMILES: c1ccc2c(c1)sc1cc3oc4ccc(-c5ccc(N(c6cccc7c6sc6ccccc67)c6cccc7sc8ccccc8c67)cc5)cc4c3cc12 ; CC1(C)c2ccccc2-c2c1ccc1c2C(C)(C)c2cc(-c3cccc(N(c4ccc5oc6ccccc6c5c4)c4ccc5sc6ccccc6c5c4)c3)ccc2-1 ; CC1(C)c2ccccc2-c2c1ccc1c2-c2ccc(N(c3ccc4c(c3)oc3ccccc34)c3ccc4c(c3)oc3ccccc34)cc2C1(C)C]

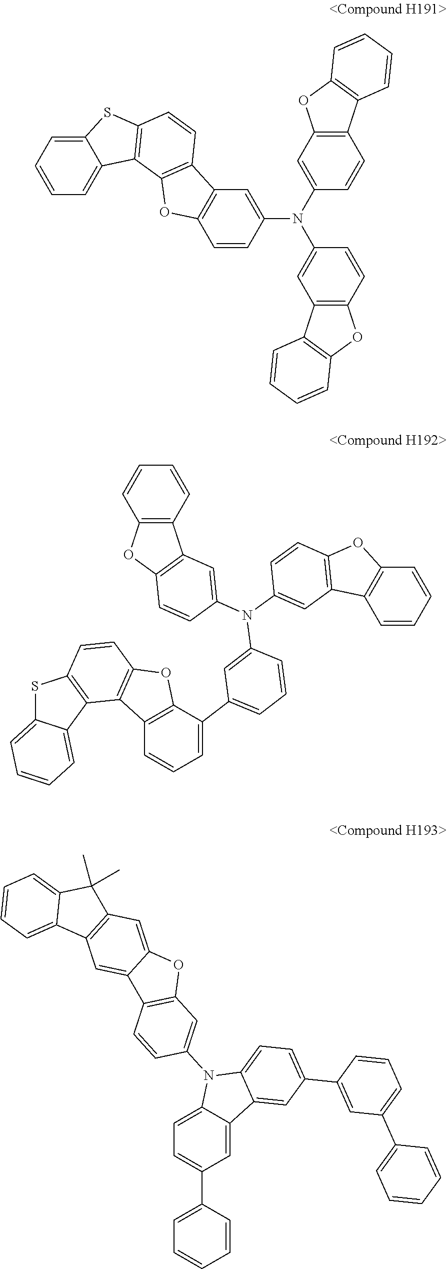 [SMILES: c1ccc2c(c1)oc1cc(N(c3ccc4oc5ccccc5c4c3)c3ccc4oc5c(ccc6sc7ccccc7c65)c4c3)ccc12 ; c1cc(-c2cccc3c2oc2ccc4sc5ccccc5c4c23)cc(N(c2ccc3oc4ccccc4c3c2)c2ccc3oc4ccccc4c3c2)c1 ; CC1(C)c2ccccc2-c2cc3c(cc21)oc1cc(-n2c4ccc(-c5ccccc5)cc4c4cc(-c5cccc(-c6ccccc6)c5)ccc42)ccc13]

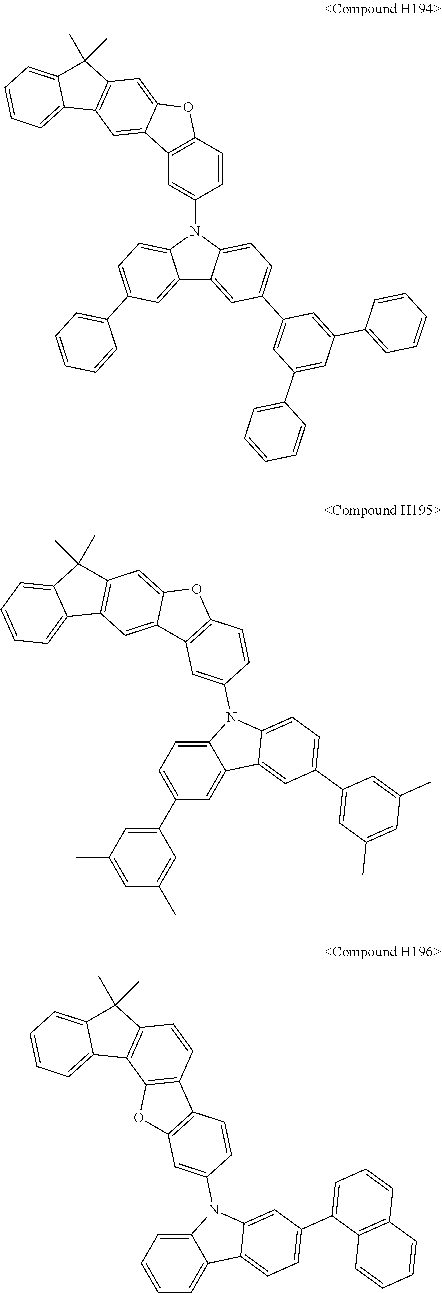 [SMILES: CC1(C)c2ccccc2-c2cc3c(cc21)oc1ccc(-n2c4ccc(-c5ccccc5)cc4c4cc(-c5cc(-c6ccccc6)cc(-c6ccccc6)c5)ccc42)cc13 ; Cc1cc(C)cc(-c2ccc3c(c2)c2cc(-c4cc(C)cc(C)c4)ccc2n3-c2ccc3oc4cc5c(cc4c3c2)-c2ccccc2C5(C)C)c1 ; CC1(C)c2ccccc2-c2c1ccc1c2oc2cc(-n3c4ccccc4c4ccc(-c5cccc6ccccc56)cc43)ccc21]

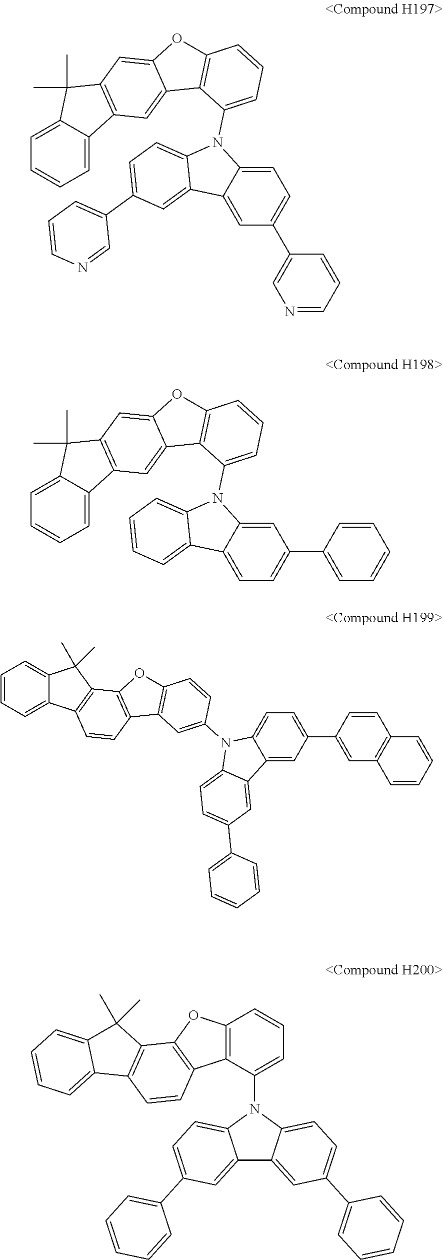 [SMILES: CC1(C)c2ccccc2-c2cc3c(cc21)oc1cccc(-n2c4ccc(-c5cccnc5)cc4c4cc(-c5cccnc5)ccc42)c13 ; CC1(C)c2ccccc2-c2cc3c(cc21)oc1cccc(-n2c4ccccc4c4ccc(-c5ccccc5)cc42)c13 ; CC1(C)c2ccccc2-c2ccc3c(oc4ccc(-n5c6ccc(-c7ccccc7)cc6c6cc(-c7ccc8ccccc8c7)ccc65)cc43)c21 ; CC1(C)c2ccccc2-c2ccc3c(oc4cccc(-n5c6ccc(-c7ccccc7)cc6c6cc(-c7ccccc7)ccc65)c43)c21]

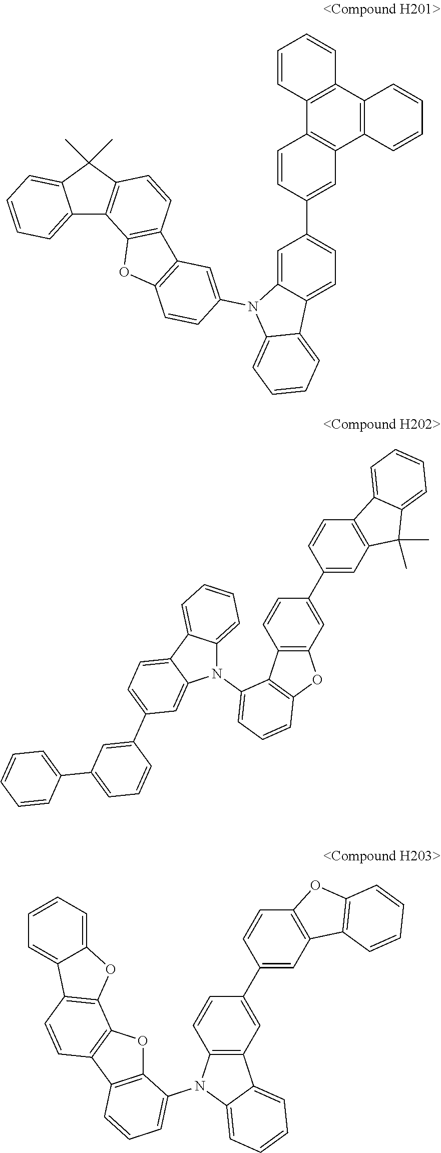 [SMILES: CC1(C)c2ccccc2-c2c1ccc1c2oc2ccc(-n3c4ccccc4c4ccc(-c5ccc6c7ccccc7c7ccccc7c6c5)cc43)cc21 ; CC1(C)c2ccccc2-c2ccc(-c3ccc4c(c3)oc3cccc(-n5c6ccccc6c6ccc(-c7cccc(-c8ccccc8)c7)cc65)c34)cc21 ; c1ccc2c(c1)oc1ccc(-c3ccc4c(c3)c3ccccc3n4-c3cccc4c3oc3c4ccc4c5ccccc5oc43)cc12]

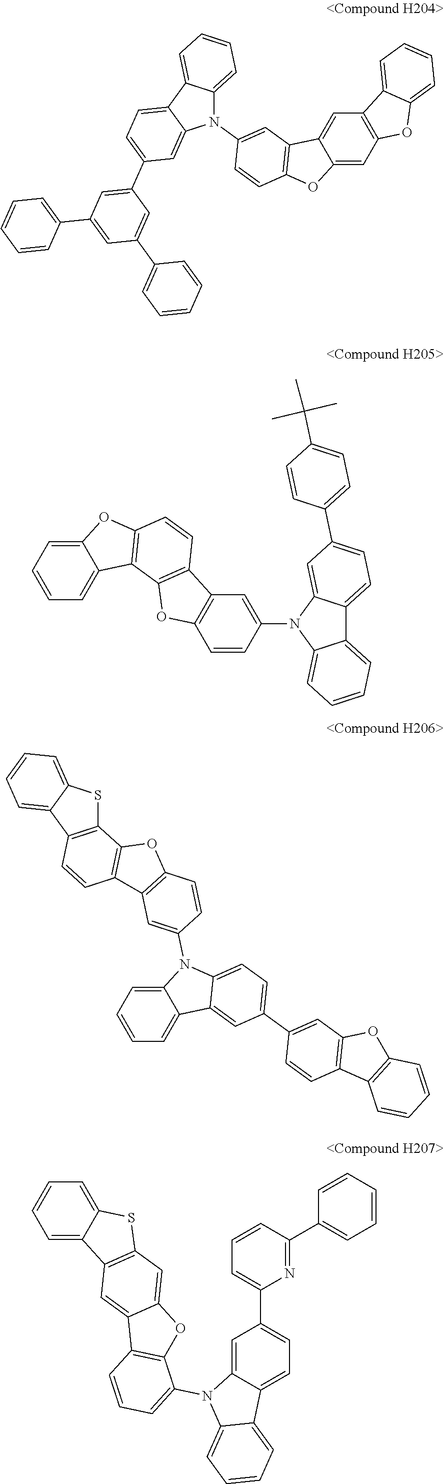 [SMILES: c1ccc(-c2cc(-c3ccccc3)cc(-c3ccc4c5ccccc5n(-c5ccc6oc7cc8oc9ccccc9c8cc7c6c5)c4c3)c2)cc1 ; CC(C)(C)c1ccc(-c2ccc3c4ccccc4n(-c4ccc5oc6c(ccc7oc8ccccc8c76)c5c4)c3c2)cc1 ; c1ccc2c(c1)oc1cc(-c3ccc4c(c3)c3ccccc3n4-c3ccc4oc5c(ccc6c7ccccc7sc65)c4c3)ccc12 ; c1ccc(-c2cccc(-c3ccc4c5ccccc5n(-c5cccc6c5oc5cc7sc8ccccc8c7cc56)c4c3)n2)cc1]

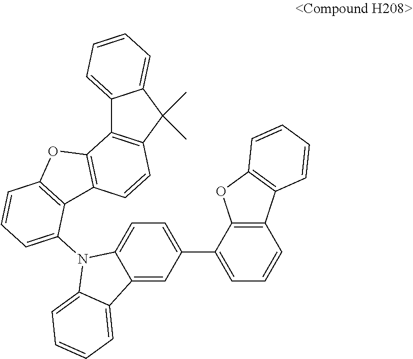 [SMILES: CC1(C)c2ccccc2-c2c1ccc1c2oc2cccc(-n3c4ccccc4c4cc(-c5cccc6c5oc5ccccc56)ccc43)c21]

Furthermore, in the organic light-emitting diode according to the present disclosure, the hetero ring compound represented by Chemical Formula D may be any one selected from the group consisting of compounds represented by the following Chemical Formula s E1 to E144, but is not limited thereto:

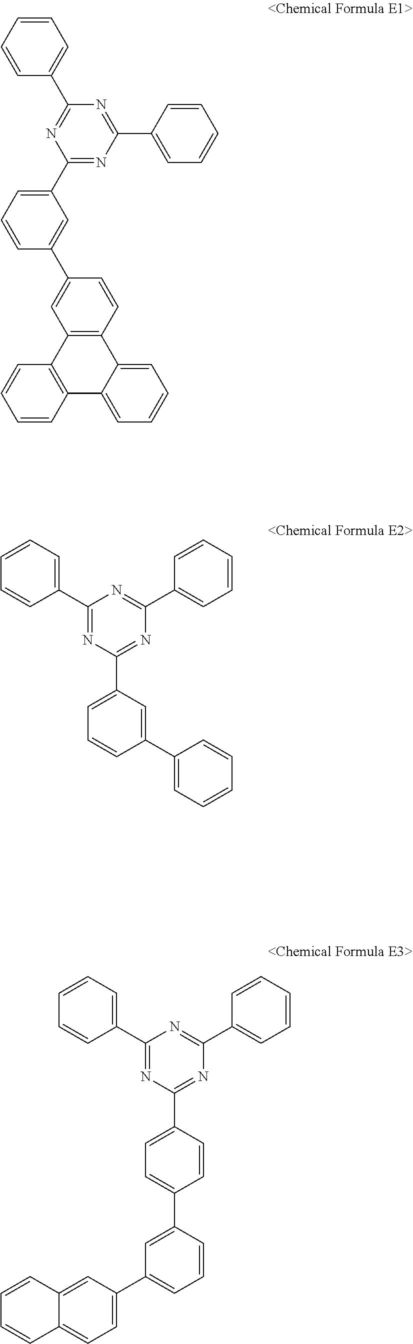 [SMILES: c1ccc(-c2nc(-c3ccccc3)nc(-c3cccc(-c4ccc5c6ccccc6c6ccccc6c5c4)c3)n2)cc1 ; c1ccc(-c2cccc(-c3nc(-c4ccccc4)nc(-c4ccccc4)n3)c2)cc1 ; c1ccc(-c2nc(-c3ccccc3)nc(-c3ccc(-c4cccc(-c5ccc6ccccc6c5)c4)cc3)n2)cc1]

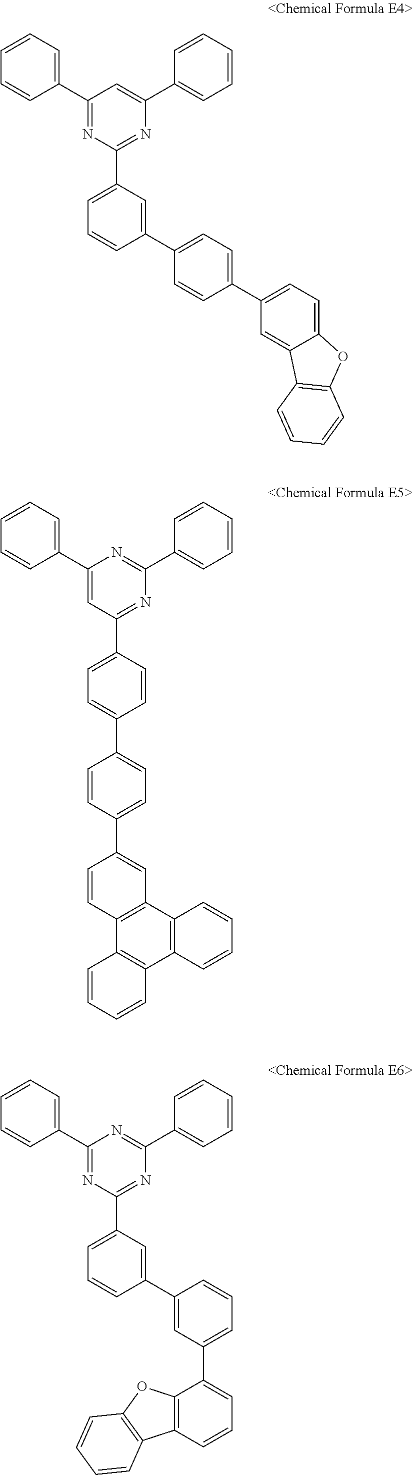 [SMILES: c1ccc(-c2cc(-c3ccccc3)nc(-c3cccc(-c4ccc(-c5ccc6oc7ccccc7c6c5)cc4)c3)n2)cc1 ; c1ccc(-c2cc(-c3ccc(-c4ccc(-c5ccc6c7ccccc7c7ccccc7c6c5)cc4)cc3)nc(-c3ccccc3)n2)cc1 ; c1ccc(-c2nc(-c3ccccc3)nc(-c3cccc(-c4cccc(-c5cccc6c5oc5ccccc56)c4)c3)n2)cc1]

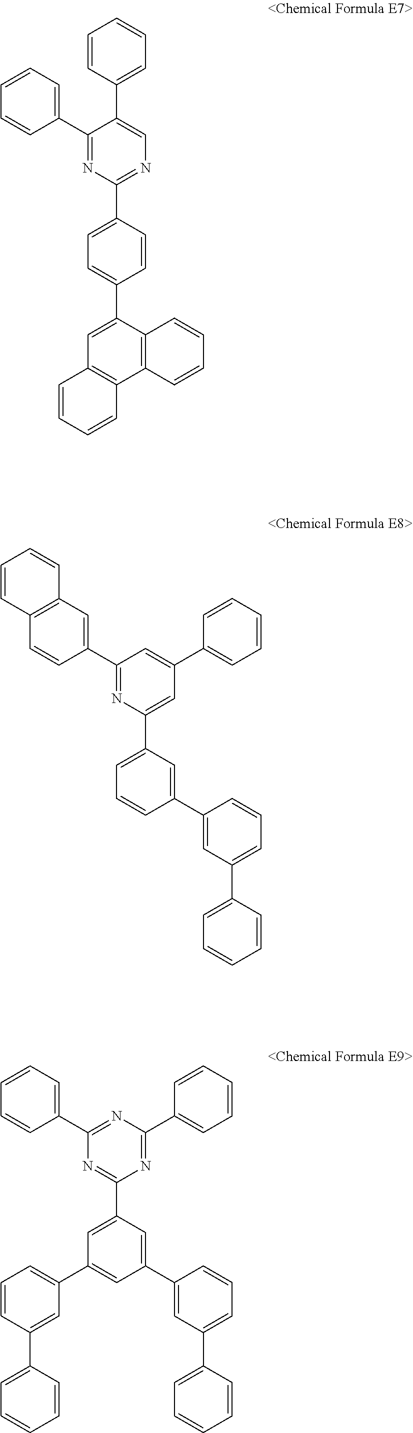 [SMILES: c1ccc(-c2cnc(-c3ccc(-c4cc5ccccc5c5ccccc45)cc3)nc2-c2ccccc2)cc1 ; c1ccc(-c2cccc(-c3cccc(-c4cc(-c5ccccc5)cc(-c5ccc6ccccc6c5)n4)c3)c2)cc1 ; c1ccc(-c2cccc(-c3cc(-c4cccc(-c5ccccc5)c4)cc(-c4nc(-c5ccccc5)nc(-c5ccccc5)n4)c3)c2)cc1]

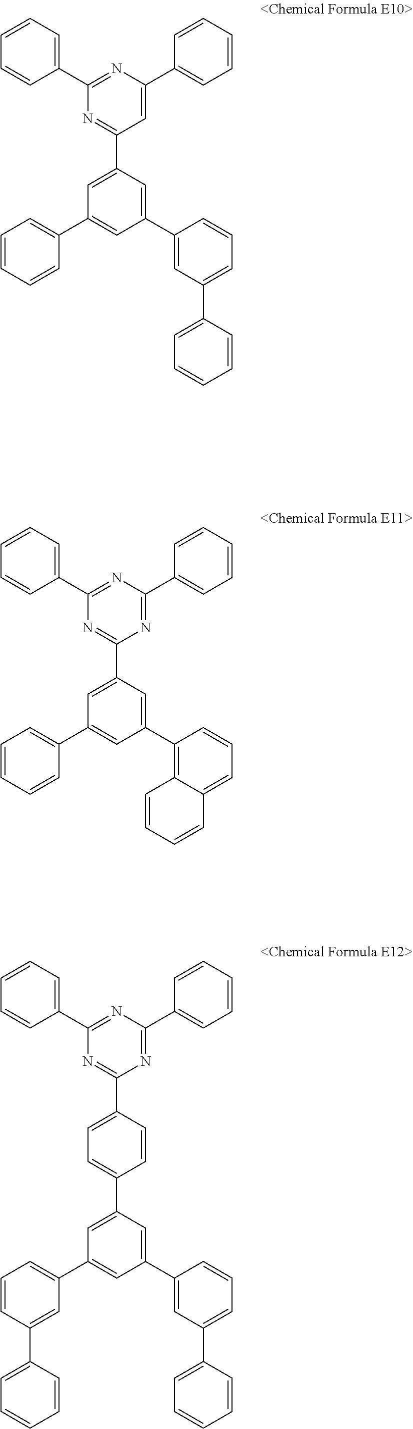 [SMILES: c1ccc(-c2cccc(-c3cc(-c4ccccc4)cc(-c4cc(-c5ccccc5)nc(-c5ccccc5)n4)c3)c2)cc1 ; c1ccc(-c2cc(-c3nc(-c4ccccc4)nc(-c4ccccc4)n3)cc(-c3cccc4ccccc34)c2)cc1 ; c1ccc(-c2cccc(-c3cc(-c4ccc(-c5nc(-c6ccccc6)nc(-c6ccccc6)n5)cc4)cc(-c4cccc(-c5ccccc5)c4)c3)c2)cc1]

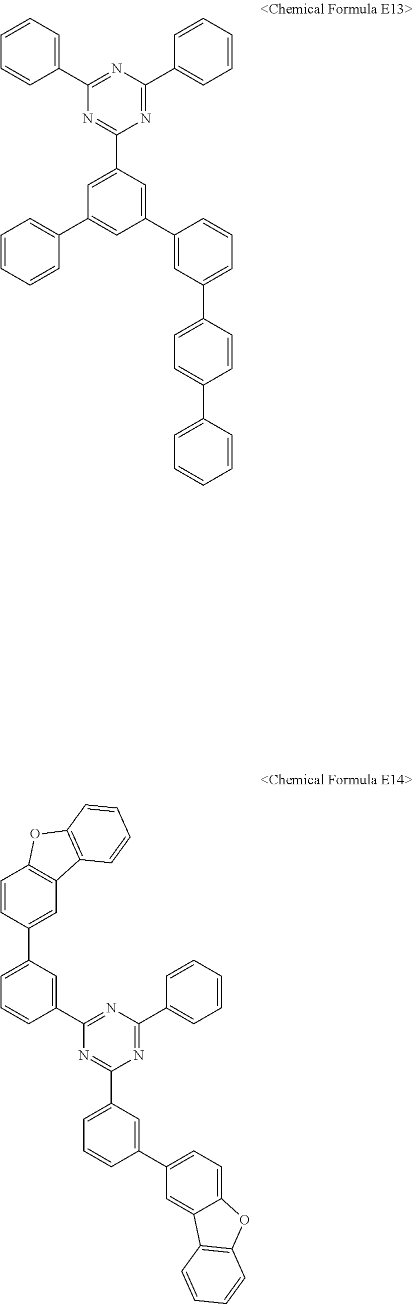 [SMILES: c1ccc(-c2ccc(-c3cccc(-c4cc(-c5ccccc5)cc(-c5nc(-c6ccccc6)nc(-c6ccccc6)n5)c4)c3)cc2)cc1 ; c1ccc(-c2nc(-c3cccc(-c4ccc5oc6ccccc6c5c4)c3)nc(-c3cccc(-c4ccc5oc6ccccc6c5c4)c3)n2)cc1]

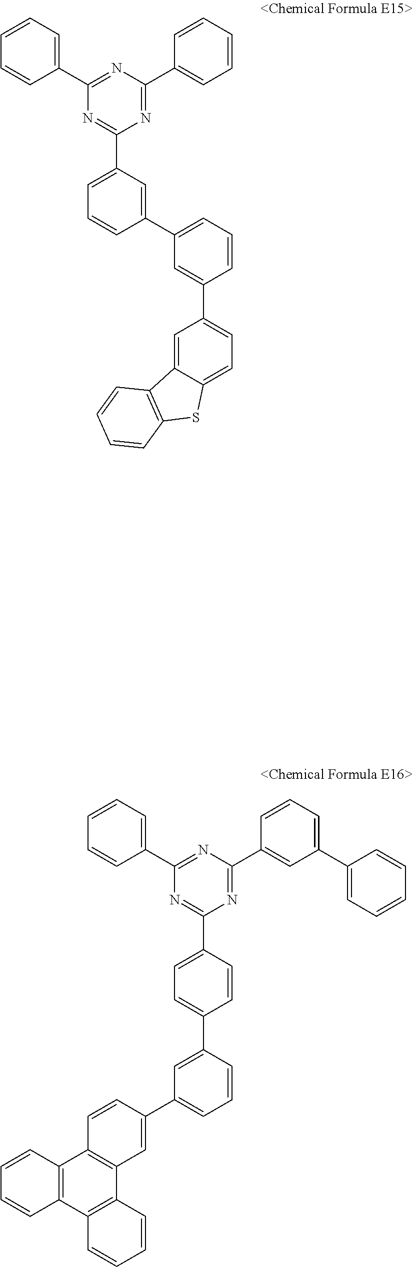 [SMILES: c1ccc(-c2nc(-c3ccccc3)nc(-c3cccc(-c4cccc(-c5ccc6sc7ccccc7c6c5)c4)c3)n2)cc1 ; c1ccc(-c2cccc(-c3nc(-c4ccccc4)nc(-c4ccc(-c5cccc(-c6ccc7c8ccccc8c8ccccc8c7c6)c5)cc4)n3)c2)cc1]

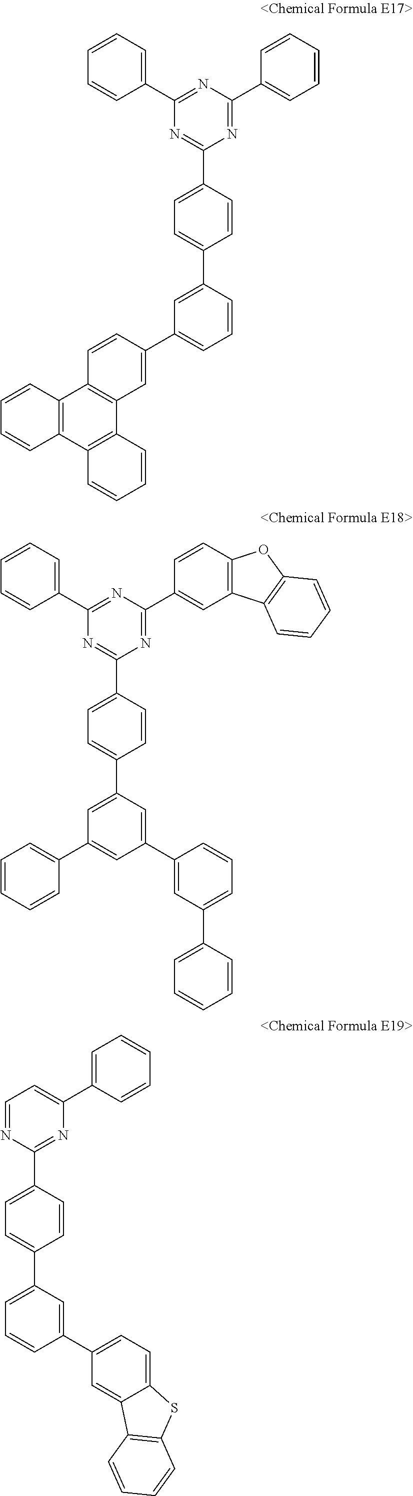 [SMILES: c1ccc(-c2nc(-c3ccccc3)nc(-c3ccc(-c4cccc(-c5ccc6c7ccccc7c7ccccc7c6c5)c4)cc3)n2)cc1 ; c1ccc(-c2cccc(-c3cc(-c4ccccc4)cc(-c4ccc(-c5nc(-c6ccccc6)nc(-c6ccc7oc8ccccc8c7c6)n5)cc4)c3)c2)cc1 ; c1ccc(-c2ccnc(-c3ccc(-c4cccc(-c5ccc6sc7ccccc7c6c5)c4)cc3)n2)cc1]

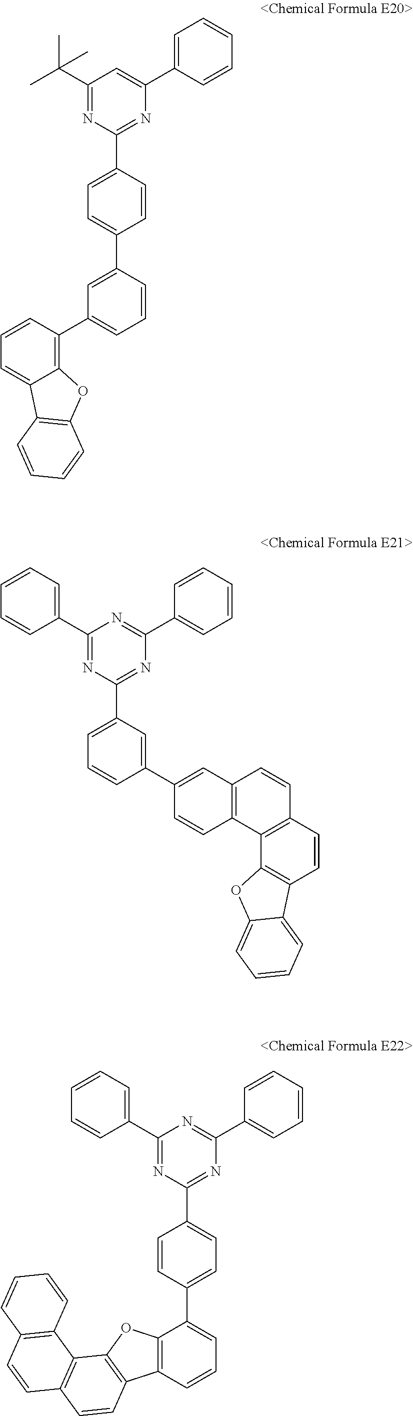 [SMILES: CC(C)(C)c1cc(-c2ccccc2)nc(-c2ccc(-c3cccc(-c4cccc5c4oc4ccccc45)c3)cc2)n1 ; c1ccc(-c2nc(-c3ccccc3)nc(-c3cccc(-c4ccc5c(ccc6ccc7c8ccccc8oc7c65)c4)c3)n2)cc1 ; c1ccc(-c2nc(-c3ccccc3)nc(-c3ccc(-c4cccc5c4oc4c5ccc5ccc6ccccc6c54)cc3)n2)cc1]

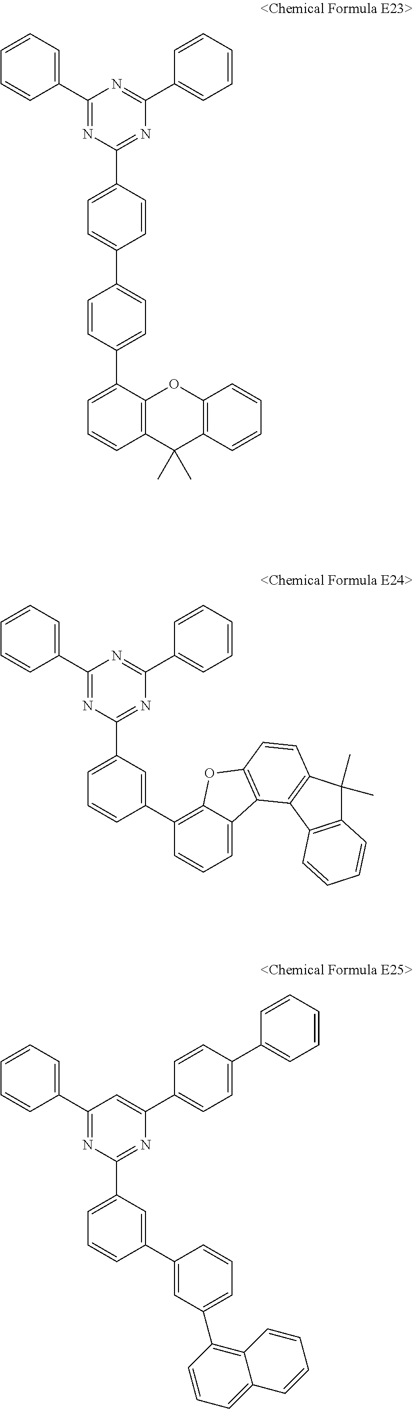 [SMILES: CC1(C)c2ccccc2Oc2c(-c3ccc(-c4ccc(-c5nc(-c6ccccc6)nc(-c6ccccc6)n5)cc4)cc3)cccc21 ; CC1(C)c2ccccc2-c2c1ccc1oc3c(-c4cccc(-c5nc(-c6ccccc6)nc(-c6ccccc6)n5)c4)cccc3c21 ; c1ccc(-c2ccc(-c3cc(-c4ccccc4)nc(-c4cccc(-c5cccc(-c6cccc7ccccc67)c5)c4)n3)cc2)cc1]

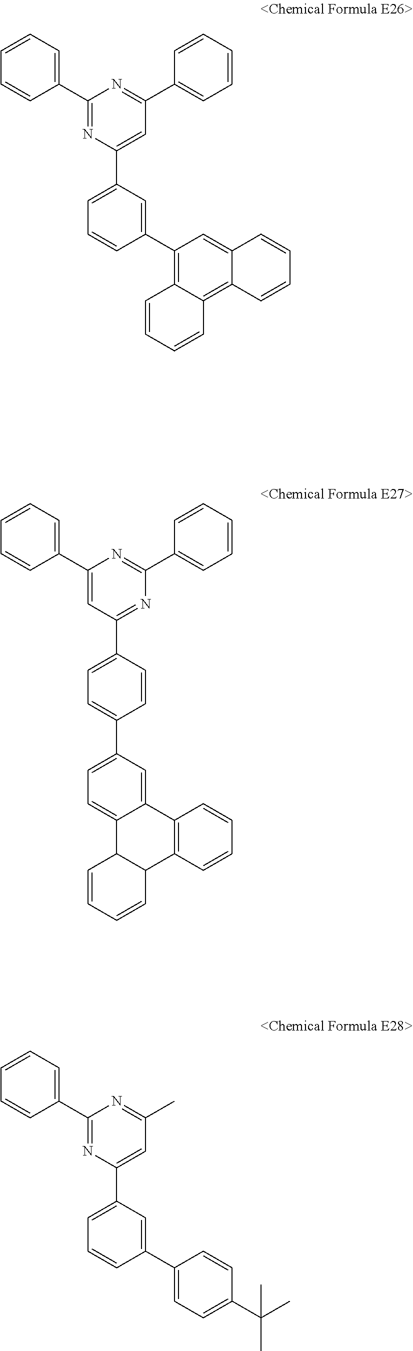 [SMILES: c1ccc(-c2cc(-c3cccc(-c4cc5ccccc5c5ccccc45)c3)nc(-c3ccccc3)n2)cc1 ; C1=CC2c3ccccc3-c3cc(-c4ccc(-c5cc(-c6ccccc6)nc(-c6ccccc6)n5)cc4)ccc3C2C=C1 ; Cc1cc(-c2cccc(-c3ccc(C(C)(C)C)cc3)c2)nc(-c2ccccc2)n1]

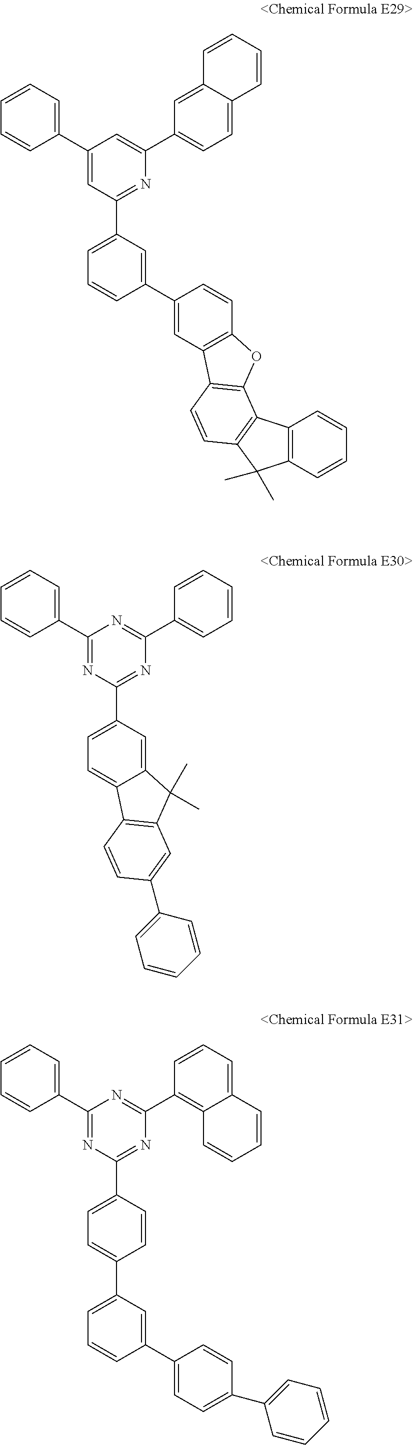 [SMILES: CC1(C)c2ccccc2-c2c1ccc1c2oc2ccc(-c3cccc(-c4cc(-c5ccccc5)cc(-c5ccc6ccccc6c5)n4)c3)cc21 ; CC1(C)c2cc(-c3ccccc3)ccc2-c2ccc(-c3nc(-c4ccccc4)nc(-c4ccccc4)n3)cc21 ; c1ccc(-c2ccc(-c3cccc(-c4ccc(-c5nc(-c6ccccc6)nc(-c6cccc7ccccc67)n5)cc4)c3)cc2)cc1]

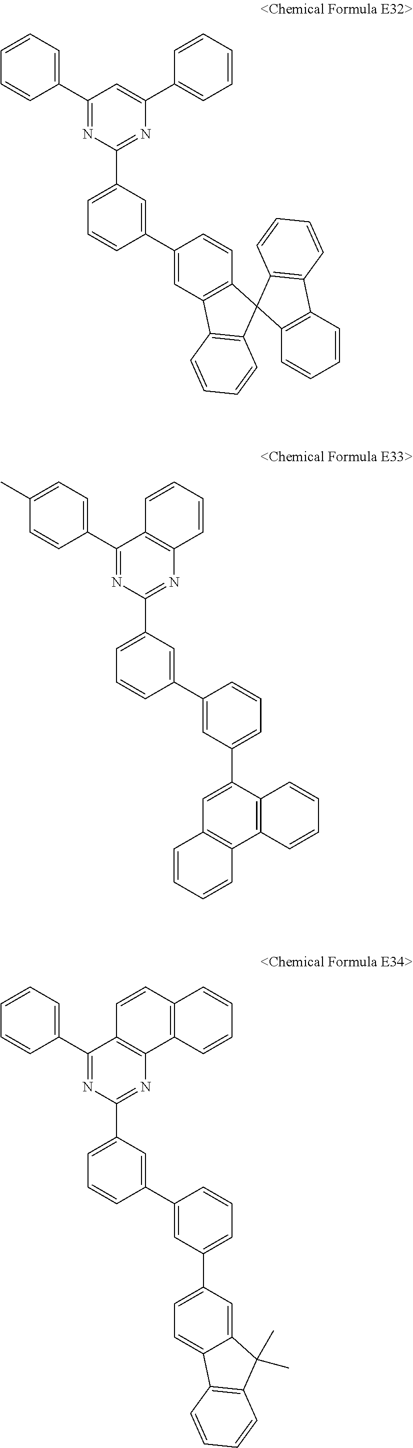 [SMILES: c1ccc(-c2cc(-c3ccccc3)nc(-c3cccc(-c4ccc5c(c4)-c4ccccc4C54c5ccccc5-c5ccccc54)c3)n2)cc1 ; Cc1ccc(-c2nc(-c3cccc(-c4cccc(-c5cc6ccccc6c6ccccc56)c4)c3)nc3ccccc23)cc1 ; CC1(C)c2ccccc2-c2ccc(-c3cccc(-c4cccc(-c5nc(-c6ccccc6)c6ccc7ccccc7c6n5)c4)c3)cc21]

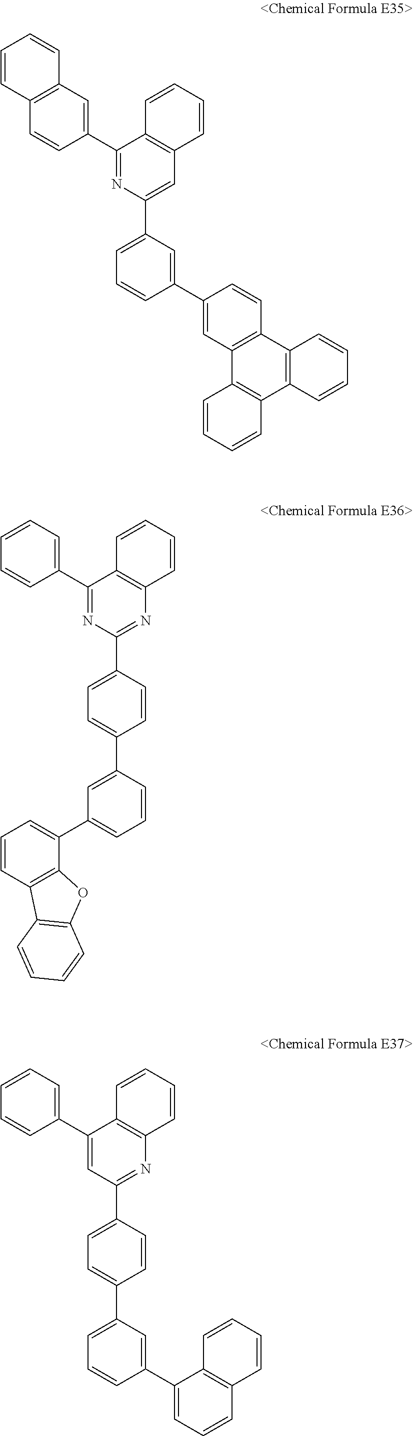 [SMILES: c1cc(-c2ccc3c4ccccc4c4ccccc4c3c2)cc(-c2cc3ccccc3c(-c3ccc4ccccc4c3)n2)c1 ; c1ccc(-c2nc(-c3ccc(-c4cccc(-c5cccc6c5oc5ccccc56)c4)cc3)nc3ccccc23)cc1 ; c1ccc(-c2cc(-c3ccc(-c4cccc(-c5cccc6ccccc56)c4)cc3)nc3ccccc23)cc1]

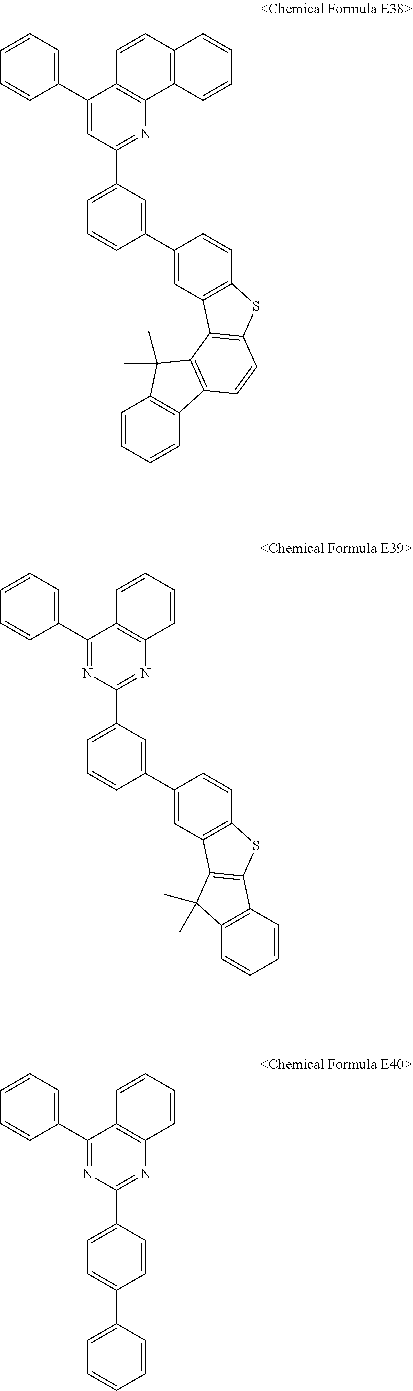 [SMILES: CC1(C)c2ccccc2-c2ccc3sc4ccc(-c5cccc(-c6cc(-c7ccccc7)c7ccc8ccccc8c7n6)c5)cc4c3c21 ; CC1(C)c2ccccc2-c2sc3ccc(-c4cccc(-c5nc(-c6ccccc6)c6ccccc6n5)c4)cc3c21 ; c1ccc(-c2ccc(-c3nc(-c4ccccc4)c4ccccc4n3)cc2)cc1]

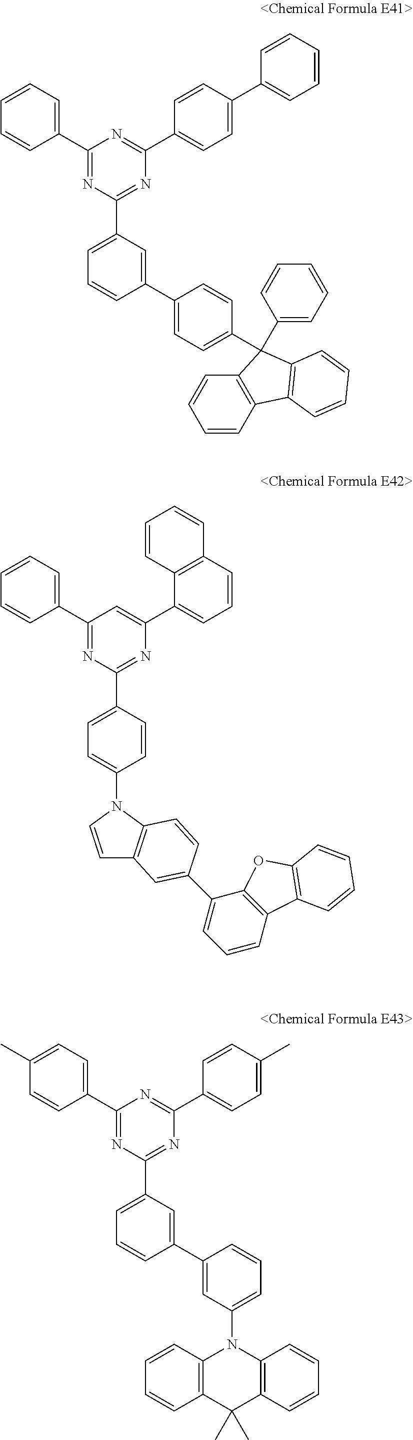 [SMILES: c1ccc(-c2ccc(-c3nc(-c4ccccc4)nc(-c4cccc(-c5ccc(C6(c7ccccc7)c7ccccc7-c7ccccc76)cc5)c4)n3)cc2)cc1 ; c1ccc(-c2cc(-c3cccc4ccccc34)nc(-c3ccc(-n4ccc5cc(-c6cccc7c6oc6ccccc67)ccc54)cc3)n2)cc1 ; Cc1ccc(-c2nc(-c3ccc(C)cc3)nc(-c3cccc(-c4cccc(N5c6ccccc6C(C)(C)c6ccccc65)c4)c3)n2)cc1]

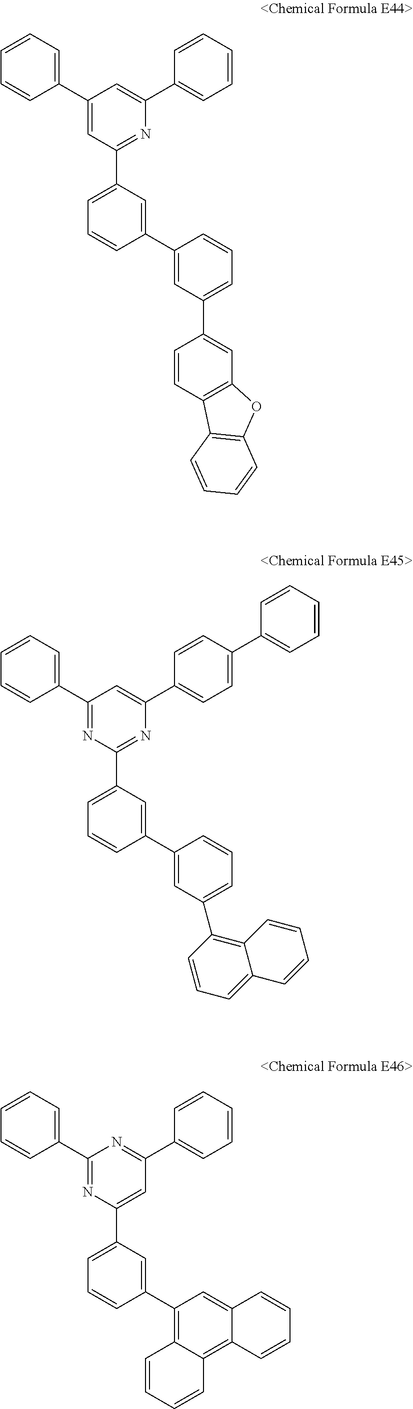 [SMILES: c1ccc(-c2cc(-c3ccccc3)nc(-c3cccc(-c4cccc(-c5ccc6c(c5)oc5ccccc56)c4)c3)c2)cc1 ; c1ccc(-c2ccc(-c3cc(-c4ccccc4)nc(-c4cccc(-c5cccc(-c6cccc7ccccc67)c5)c4)n3)cc2)cc1 ; c1ccc(-c2cc(-c3cccc(-c4cc5ccccc5c5ccccc45)c3)nc(-c3ccccc3)n2)cc1]

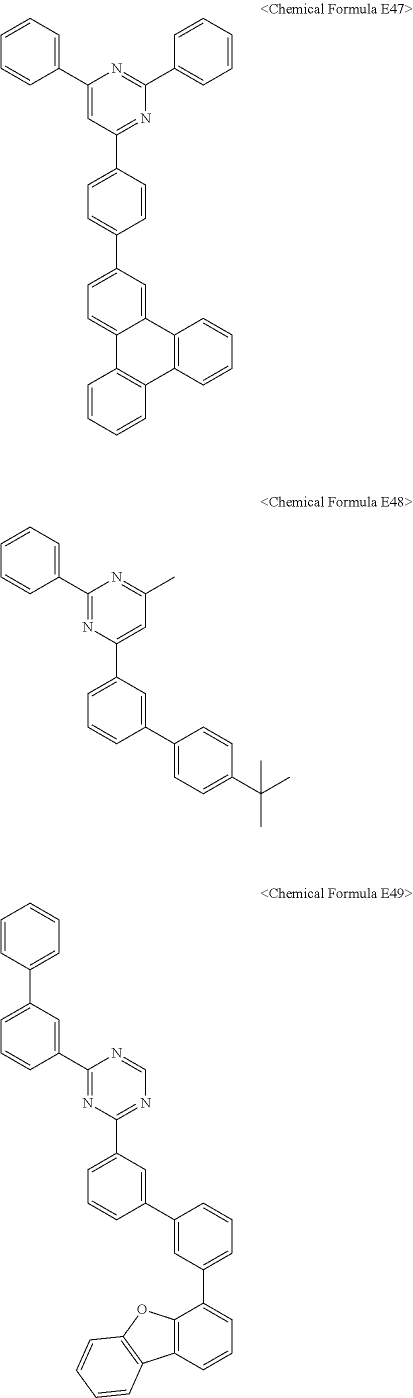 [SMILES: c1ccc(-c2cc(-c3ccc(-c4ccc5c6ccccc6c6ccccc6c5c4)cc3)nc(-c3ccccc3)n2)cc1 ; Cc1cc(-c2cccc(-c3ccc(C(C)(C)C)cc3)c2)nc(-c2ccccc2)n1 ; c1ccc(-c2cccc(-c3ncnc(-c4cccc(-c5cccc(-c6cccc7c6oc6ccccc67)c5)c4)n3)c2)cc1]

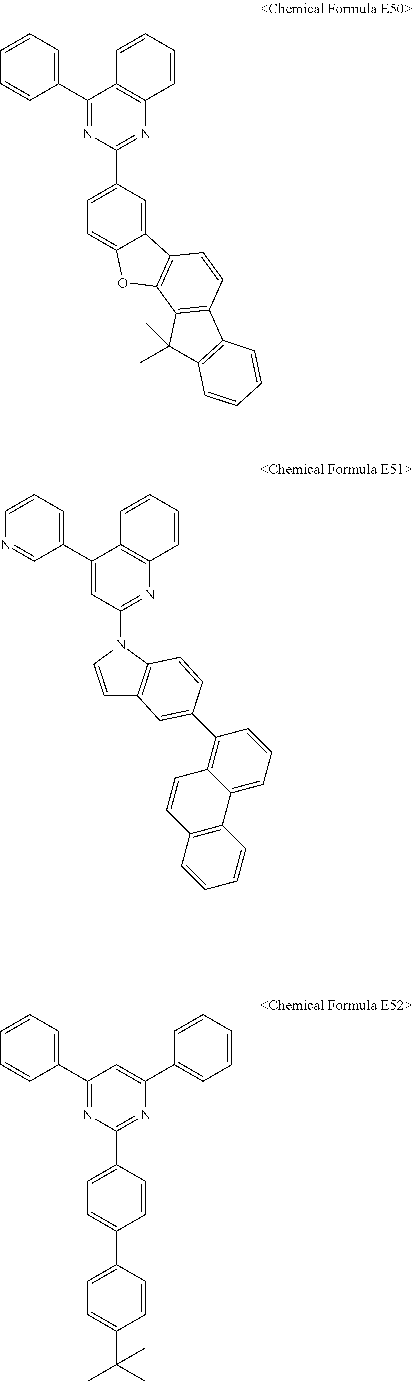 [SMILES: CC1(C)c2ccccc2-c2ccc3c(oc4ccc(-c5nc(-c6ccccc6)c6ccccc6n5)cc43)c21 ; c1cncc(-c2cc(-n3ccc4cc(-c5cccc6c5ccc5ccccc56)ccc43)nc3ccccc23)c1 ; CC(C)(C)c1ccc(-c2ccc(-c3nc(-c4ccccc4)cc(-c4ccccc4)n3)cc2)cc1]

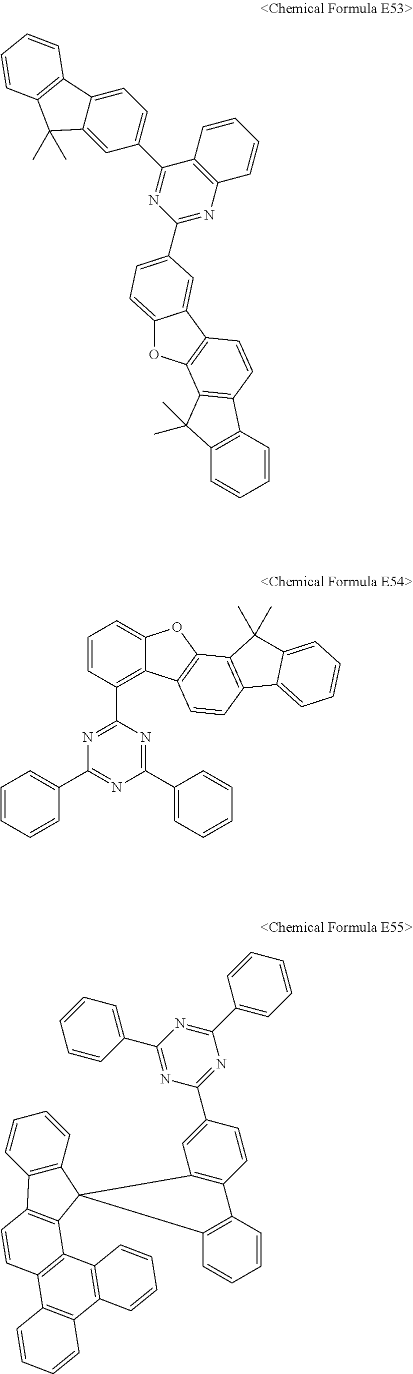 [SMILES: CC1(C)c2ccccc2-c2ccc(-c3nc(-c4ccc5oc6c7c(ccc6c5c4)-c4ccccc4C7(C)C)nc4ccccc34)cc21 ; CC1(C)c2ccccc2-c2ccc3c(oc4cccc(-c5nc(-c6ccccc6)nc(-c6ccccc6)n5)c43)c21 ; c1ccc(-c2nc(-c3ccccc3)nc(-c3ccc4c(c3)C3(c5ccccc5-4)c4ccccc4-c4ccc5c6ccccc6c6ccccc6c5c43)n2)cc1]

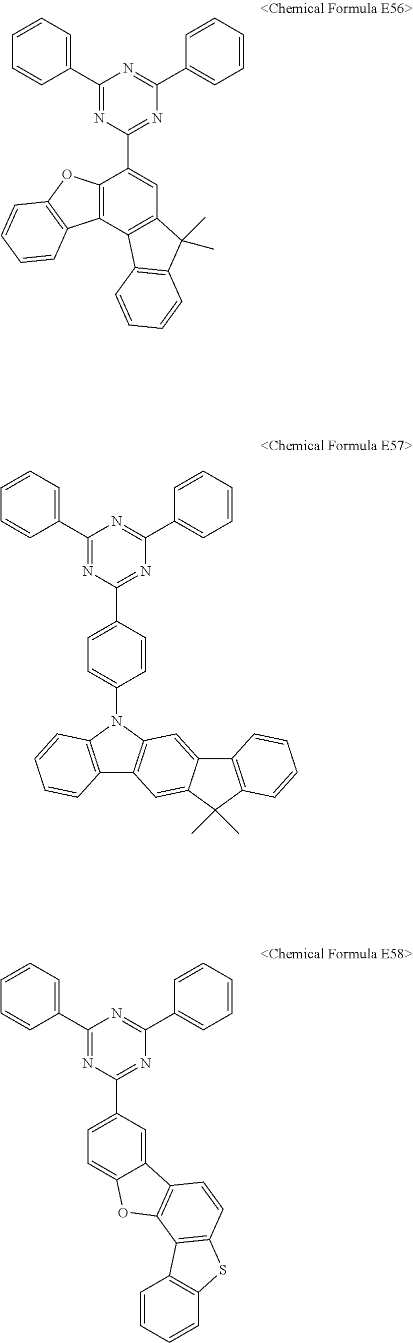 [SMILES: CC1(C)c2ccccc2-c2c1cc(-c1nc(-c3ccccc3)nc(-c3ccccc3)n1)c1oc3ccccc3c21 ; CC1(C)c2ccccc2-c2cc3c(cc21)c1ccccc1n3-c1ccc(-c2nc(-c3ccccc3)nc(-c3ccccc3)n2)cc1 ; c1ccc(-c2nc(-c3ccccc3)nc(-c3ccc4oc5c(ccc6sc7ccccc7c65)c4c3)n2)cc1]

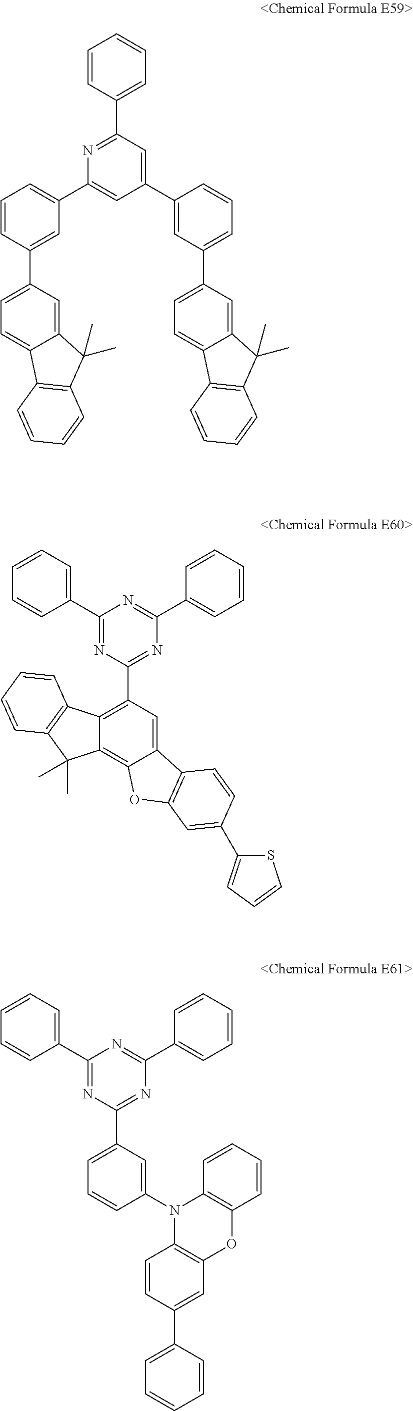 [SMILES: CC1(C)c2ccccc2-c2ccc(-c3cccc(-c4cc(-c5ccccc5)nc(-c5cccc(-c6ccc7c(c6)C(C)(C)c6ccccc6-7)c5)c4)c3)cc21 ; CC1(C)c2ccccc2-c2c(-c3nc(-c4ccccc4)nc(-c4ccccc4)n3)cc3c(oc4cc(-c5cccs5)ccc43)c21 ; c1ccc(-c2ccc3c(c2)Oc2ccccc2N3c2cccc(-c3nc(-c4ccccc4)nc(-c4ccccc4)n3)c2)cc1]

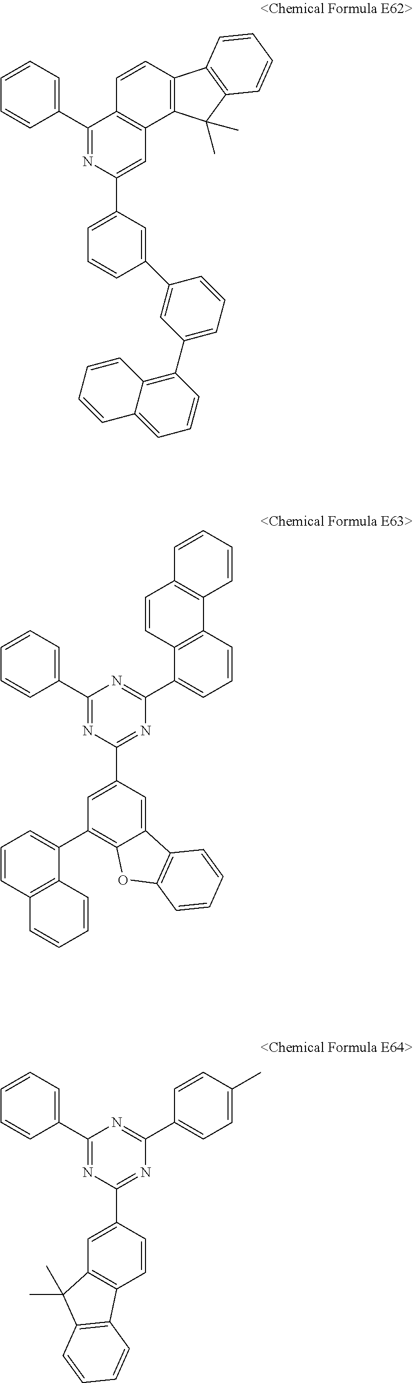 [SMILES: CC1(C)c2ccccc2-c2ccc3c(-c4ccccc4)nc(-c4cccc(-c5cccc(-c6cccc7ccccc67)c5)c4)cc3c21 ; c1ccc(-c2nc(-c3cc(-c4cccc5ccccc45)c4oc5ccccc5c4c3)nc(-c3cccc4c3ccc3ccccc34)n2)cc1 ; Cc1ccc(-c2nc(-c3ccccc3)nc(-c3ccc4c(c3)C(C)(C)c3ccccc3-4)n2)cc1]

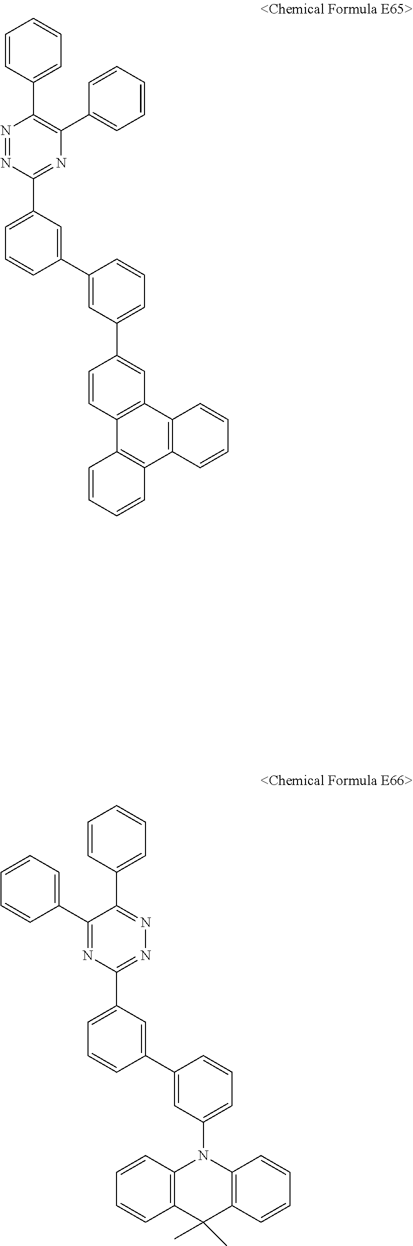 [SMILES: c1ccc(-c2nnc(-c3cccc(-c4cccc(-c5ccc6c7ccccc7c7ccccc7c6c5)c4)c3)nc2-c2ccccc2)cc1 ; CC1(C)c2ccccc2N(c2cccc(-c3cccc(-c4nnc(-c5ccccc5)c(-c5ccccc5)n4)c3)c2)c2ccccc21]

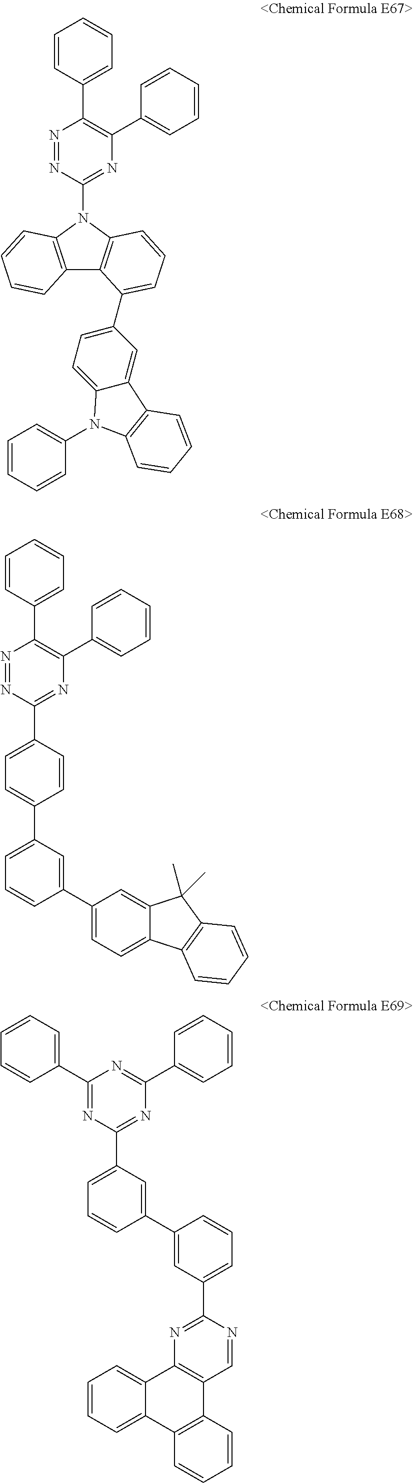

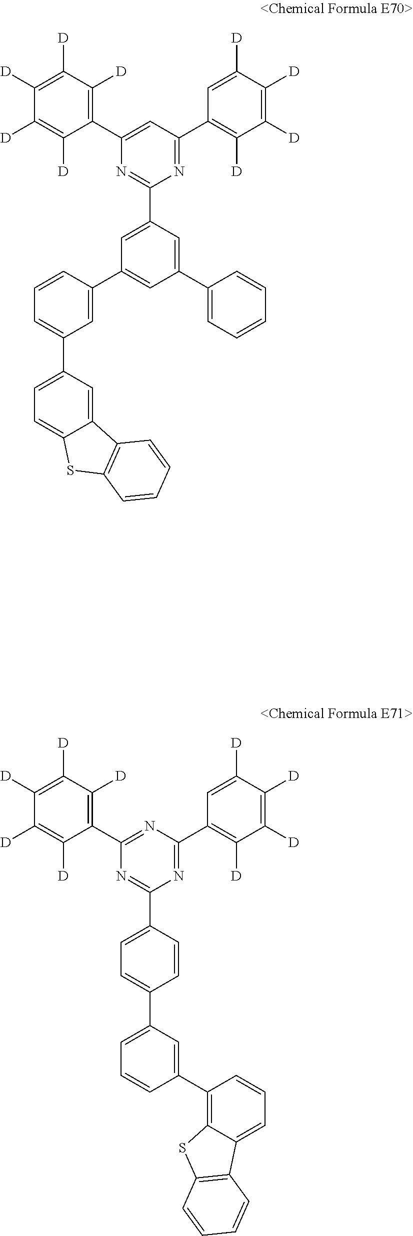 [SMILES: [2H]c1cc(-c2cc(-c3c([2H])c([2H])c([2H])c([2H])c3[2H])nc(-c3cc(-c4ccccc4)cc(-c4cccc(-c5ccc6sc7ccccc7c6c5)c4)c3)n2)c([2H])c([2H])c1[2H] ; [2H]c1cc(-c2nc(-c3ccc(-c4cccc(-c5cccc6c5sc5ccccc56)c4)cc3)nc(-c3c([2H])c([2H])c([2H])c([2H])c3[2H])n2)c([2H])c([2H])c1[2H]]

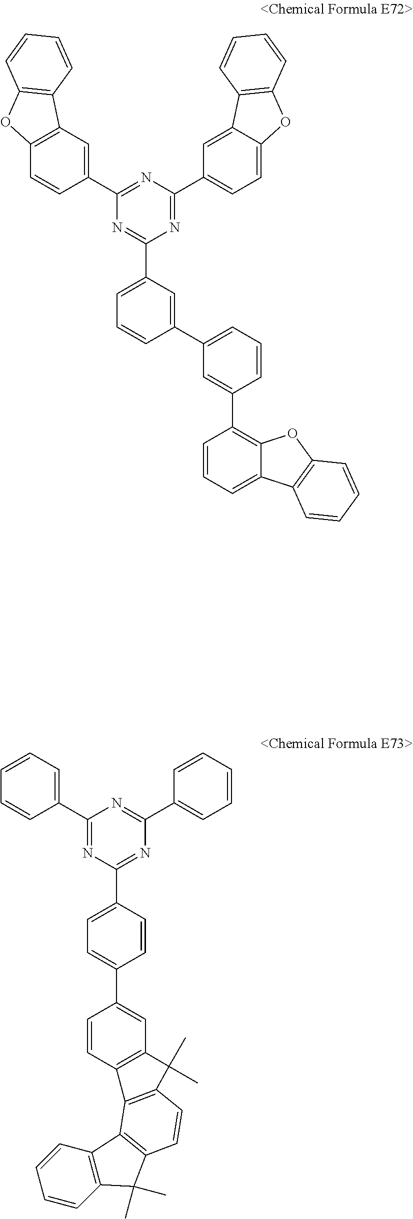 [SMILES: c1cc(-c2cccc(-c3cccc4c3oc3ccccc34)c2)cc(-c2nc(-c3ccc4oc5ccccc5c4c3)nc(-c3ccc4oc5ccccc5c4c3)n2)c1 ; CC1(C)c2ccccc2-c2c1ccc1c2-c2ccc(-c3ccc(-c4nc(-c5ccccc5)nc(-c5ccccc5)n4)cc3)cc2C1(C)C]

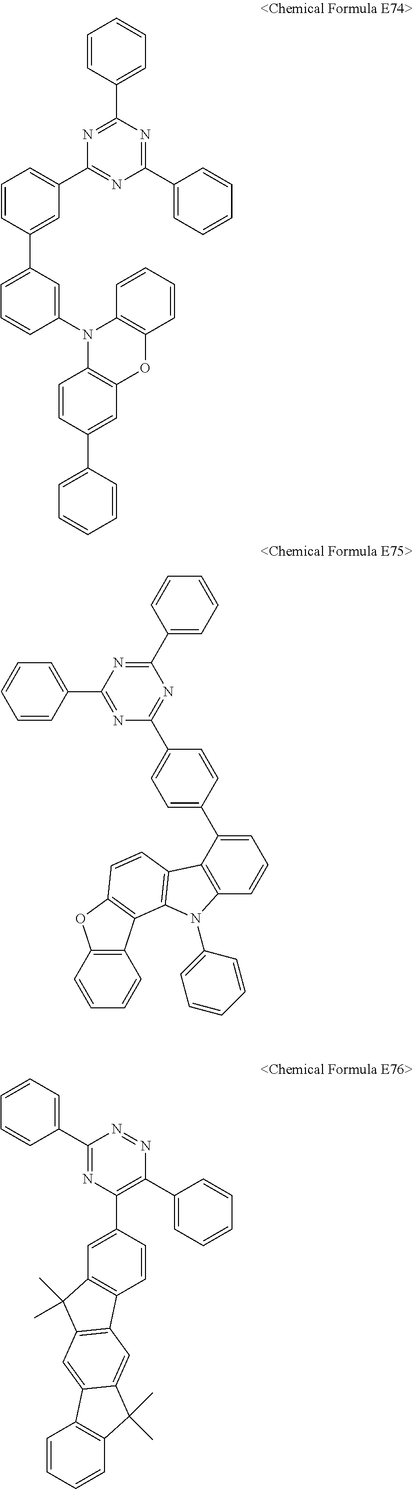 [SMILES: c1ccc(-c2ccc3c(c2)Oc2ccccc2N3c2cccc(-c3cccc(-c4nc(-c5ccccc5)nc(-c5ccccc5)n4)c3)c2)cc1 ; c1ccc(-c2nc(-c3ccccc3)nc(-c3ccc(-c4cccc5c4c4ccc6oc7ccccc7c6c4n5-c4ccccc4)cc3)n2)cc1 ; CC1(C)c2ccccc2-c2cc3c(cc21)-c1ccc(-c2nc(-c4ccccc4)nnc2-c2ccccc2)cc1C3(C)C]

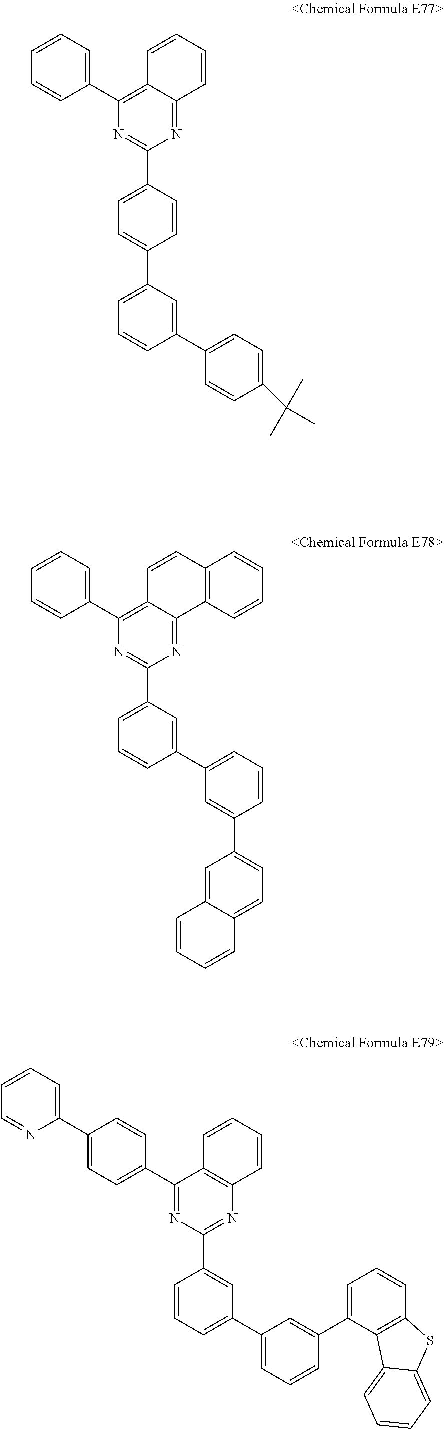 [SMILES: CC(C)(C)c1ccc(-c2cccc(-c3ccc(-c4nc(-c5ccccc5)c5ccccc5n4)cc3)c2)cc1 ; c1ccc(-c2nc(-c3cccc(-c4cccc(-c5ccc6ccccc6c5)c4)c3)nc3c2ccc2ccccc23)cc1 ; c1ccc(-c2ccc(-c3nc(-c4cccc(-c5cccc(-c6cccc7sc8ccccc8c67)c5)c4)nc4ccccc34)cc2)nc1]

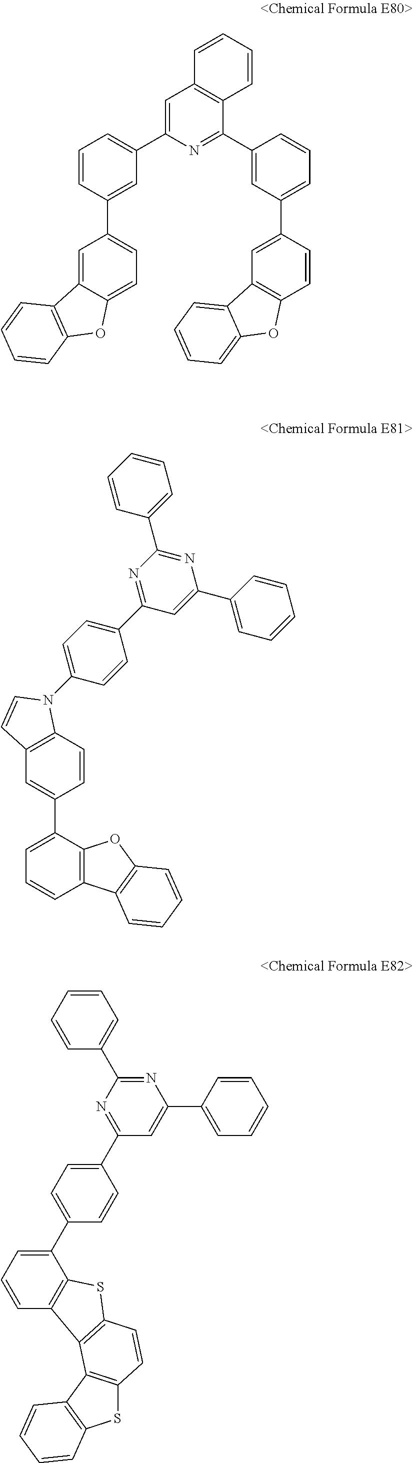 [SMILES: c1cc(-c2ccc3oc4ccccc4c3c2)cc(-c2cc3ccccc3c(-c3cccc(-c4ccc5oc6ccccc6c5c4)c3)n2)c1 ; c1ccc(-c2cc(-c3ccc(-n4ccc5cc(-c6cccc7c6oc6ccccc67)ccc54)cc3)nc(-c3ccccc3)n2)cc1 ; c1ccc(-c2cc(-c3ccc(-c4cccc5c4sc4ccc6sc7ccccc7c6c45)cc3)nc(-c3ccccc3)n2)cc1]

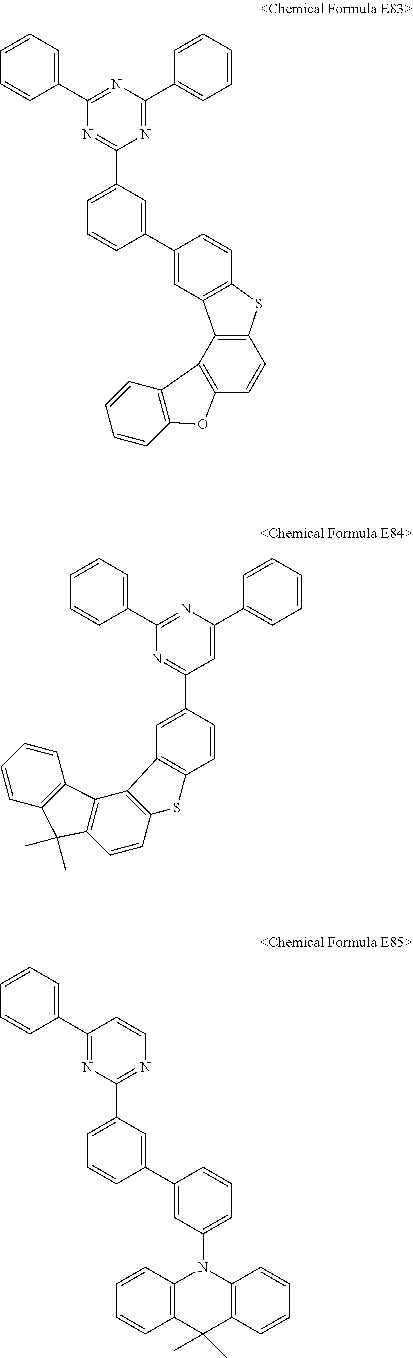 [SMILES: c1ccc(-c2nc(-c3ccccc3)nc(-c3cccc(-c4ccc5sc6ccc7oc8ccccc8c7c6c5c4)c3)n2)cc1 ; CC1(C)c2ccccc2-c2c1ccc1sc3ccc(-c4cc(-c5ccccc5)nc(-c5ccccc5)n4)cc3c21 ; CC1(C)c2ccccc2N(c2cccc(-c3cccc(-c4nccc(-c5ccccc5)n4)c3)c2)c2ccccc21]

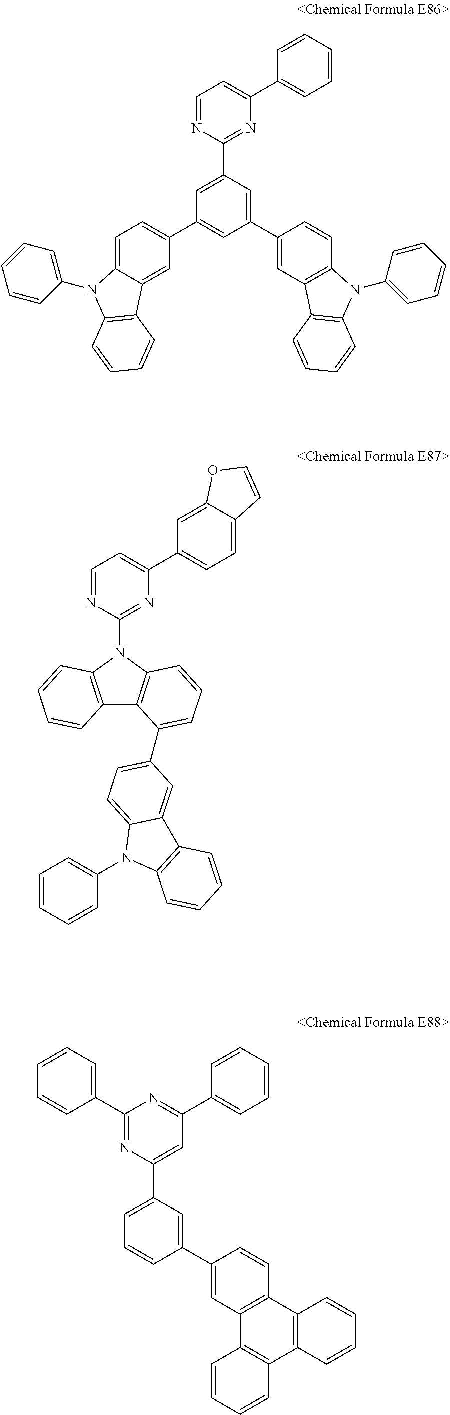 [SMILES: c1ccc(-c2ccnc(-c3cc(-c4ccc5c(c4)c4ccccc4n5-c4ccccc4)cc(-c4ccc5c(c4)c4ccccc4n5-c4ccccc4)c3)n2)cc1 ; c1ccc(-n2c3ccccc3c3cc(-c4cccc5c4c4ccccc4n5-c4nccc(-c5ccc6ccoc6c5)n4)ccc32)cc1 ; c1ccc(-c2cc(-c3cccc(-c4ccc5c6ccccc6c6ccccc6c5c4)c3)nc(-c3ccccc3)n2)cc1]

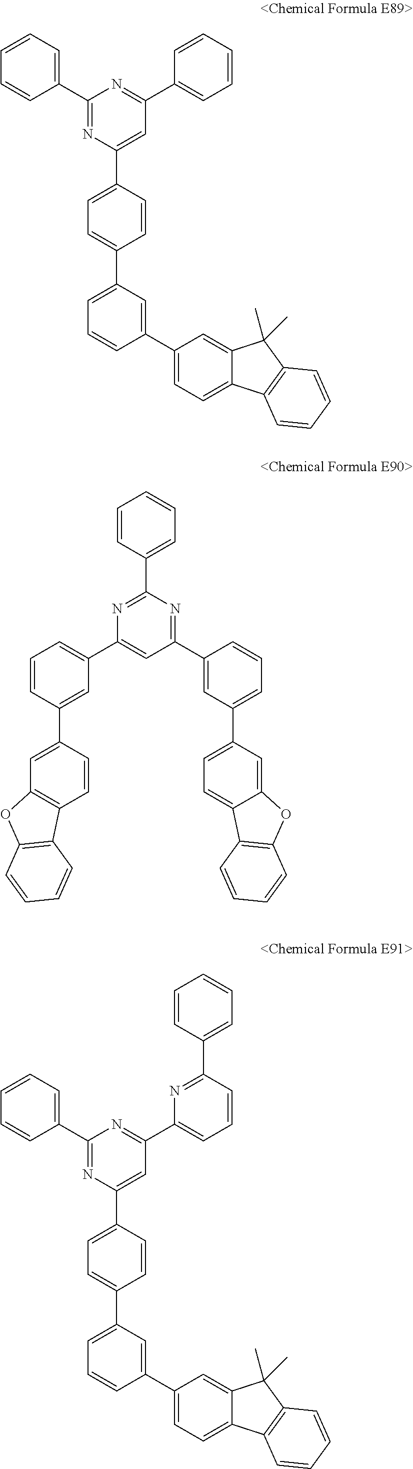 [SMILES: CC1(C)c2ccccc2-c2ccc(-c3cccc(-c4ccc(-c5cc(-c6ccccc6)nc(-c6ccccc6)n5)cc4)c3)cc21 ; c1ccc(-c2nc(-c3cccc(-c4ccc5c(c4)oc4ccccc45)c3)cc(-c3cccc(-c4ccc5c(c4)oc4ccccc45)c3)n2)cc1 ; CC1(C)c2ccccc2-c2ccc(-c3cccc(-c4ccc(-c5cc(-c6cccc(-c7ccccc7)n6)nc(-c6ccccc6)n5)cc4)c3)cc21]

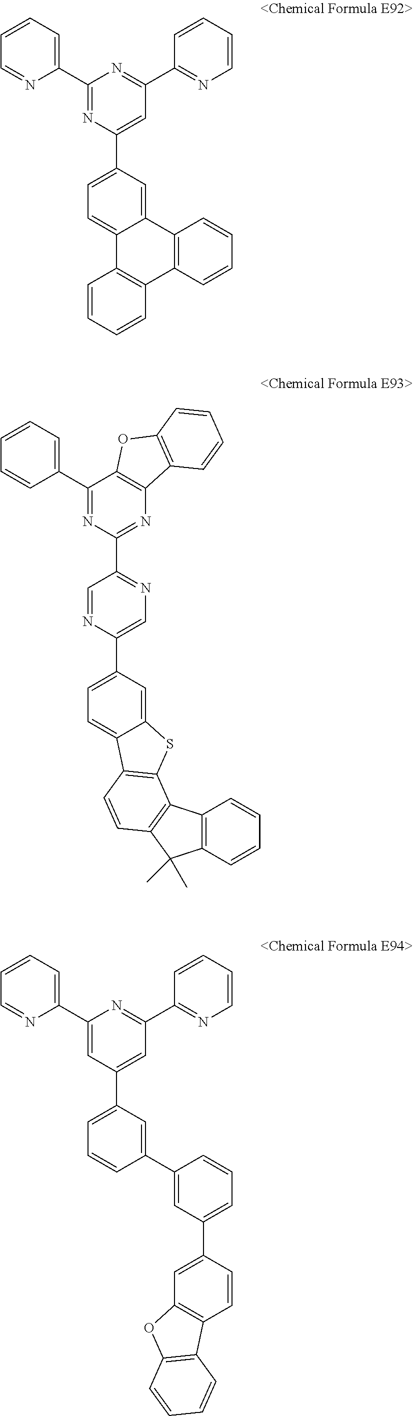 [SMILES: c1ccc(-c2cc(-c3ccc4c5ccccc5c5ccccc5c4c3)nc(-c3ccccn3)n2)nc1 ; CC1(C)c2ccccc2-c2c1ccc1c2sc2cc(-c3cnc(-c4nc(-c5ccccc5)c5oc6ccccc6c5n4)cn3)ccc21 ; c1ccc(-c2cc(-c3cccc(-c4cccc(-c5ccc6c(c5)oc5ccccc56)c4)c3)cc(-c3ccccn3)n2)nc1]

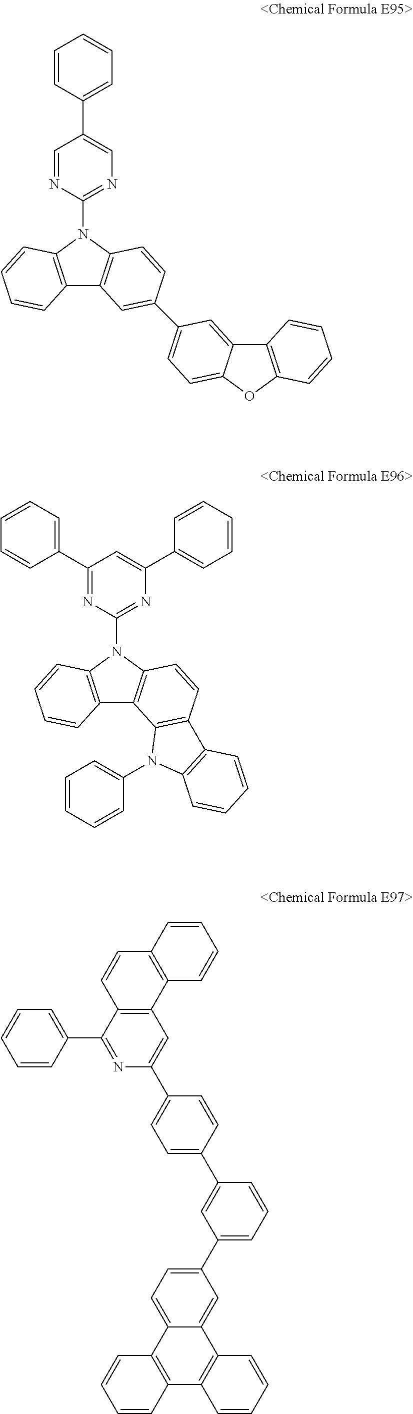 [SMILES: c1ccc(-c2cnc(-n3c4ccccc4c4cc(-c5ccc6oc7ccccc7c6c5)ccc43)nc2)cc1 ; c1ccc(-c2cc(-c3ccccc3)nc(-n3c4ccccc4c4c3ccc3c5ccccc5n(-c5ccccc5)c34)n2)cc1 ; c1ccc(-c2nc(-c3ccc(-c4cccc(-c5ccc6c7ccccc7c7ccccc7c6c5)c4)cc3)cc3c2ccc2ccccc23)cc1]

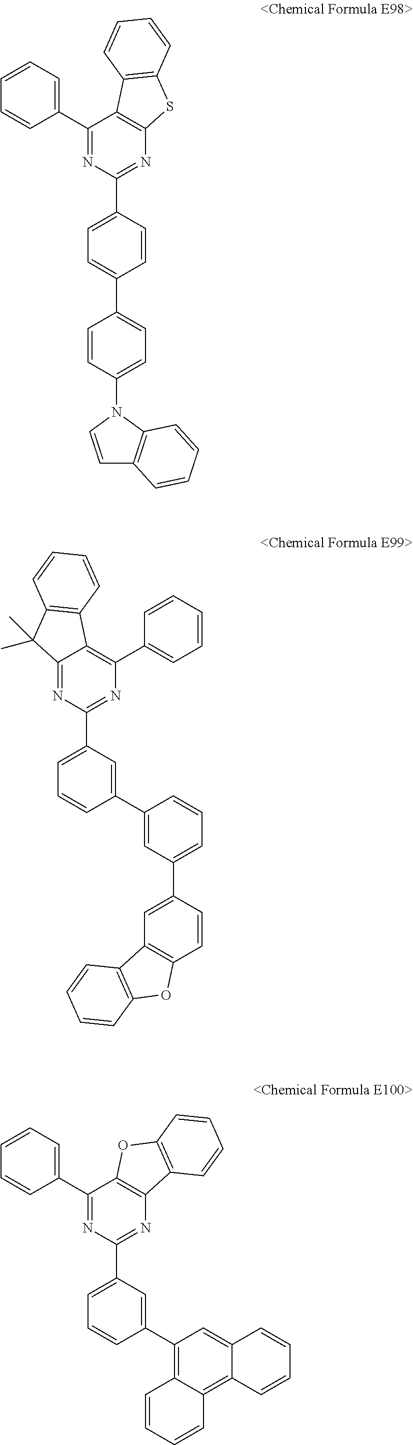 [SMILES: c1ccc(-c2nc(-c3ccc(-c4ccc(-n5ccc6ccccc65)cc4)cc3)nc3sc4ccccc4c23)cc1 ; CC1(C)c2ccccc2-c2c(-c3ccccc3)nc(-c3cccc(-c4cccc(-c5ccc6oc7ccccc7c6c5)c4)c3)nc21 ; c1ccc(-c2nc(-c3cccc(-c4cc5ccccc5c5ccccc45)c3)nc3c2oc2ccccc23)cc1]

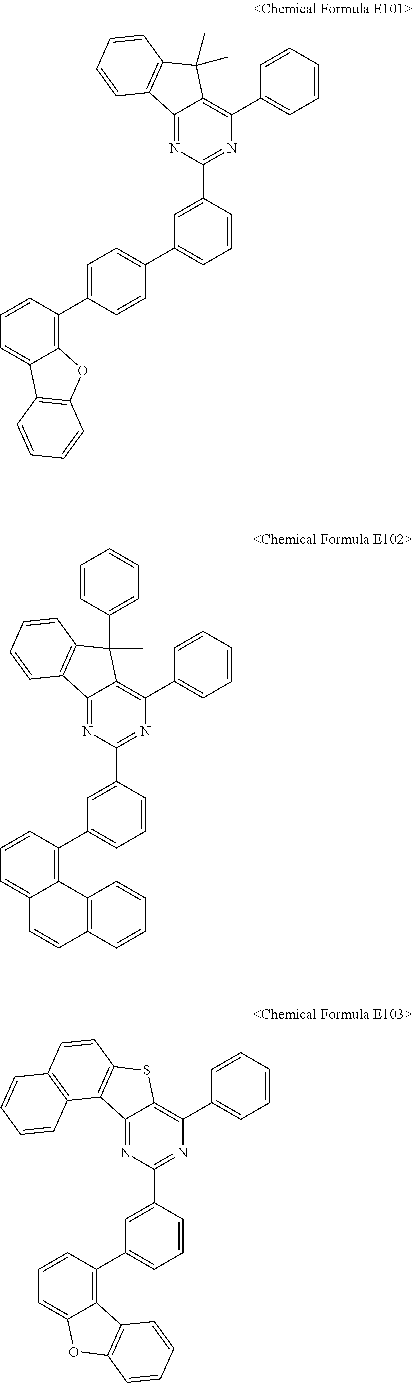 [SMILES: CC1(C)c2ccccc2-c2nc(-c3cccc(-c4ccc(-c5cccc6c5oc5ccccc56)cc4)c3)nc(-c3ccccc3)c21 ; CC1(c2ccccc2)c2ccccc2-c2nc(-c3cccc(-c4cccc5ccc6ccccc6c45)c3)nc(-c3ccccc3)c21 ; c1ccc(-c2nc(-c3cccc(-c4cccc5oc6ccccc6c45)c3)nc3c2sc2ccc4ccccc4c23)cc1]

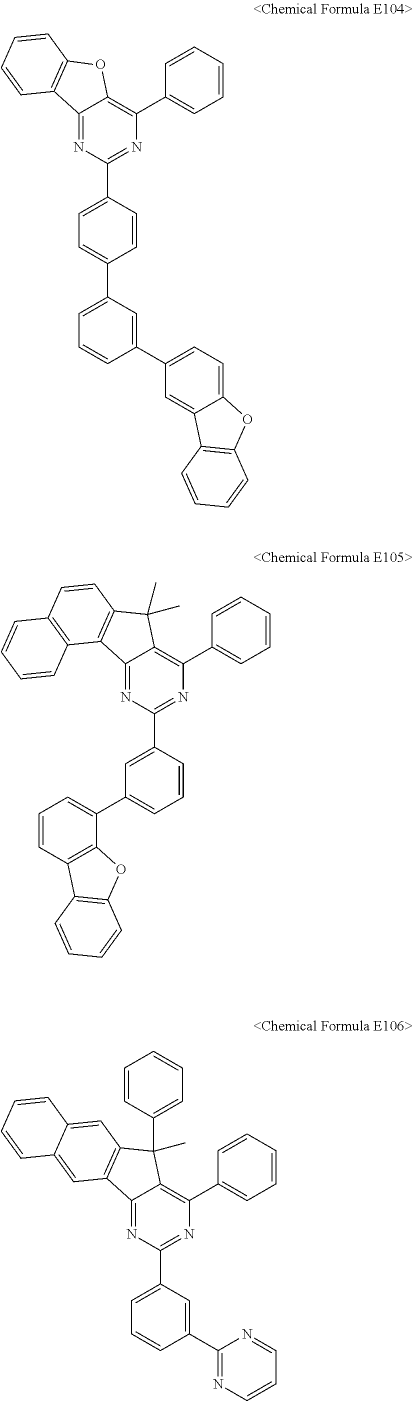 [SMILES: c1ccc(-c2nc(-c3ccc(-c4cccc(-c5ccc6oc7ccccc7c6c5)c4)cc3)nc3c2oc2ccccc23)cc1 ; CC1(C)c2ccc3ccccc3c2-c2nc(-c3cccc(-c4cccc5c4oc4ccccc45)c3)nc(-c3ccccc3)c21 ; CC1(c2ccccc2)c2cc3ccccc3cc2-c2nc(-c3cccc(-c4ncccn4)c3)nc(-c3ccccc3)c21]

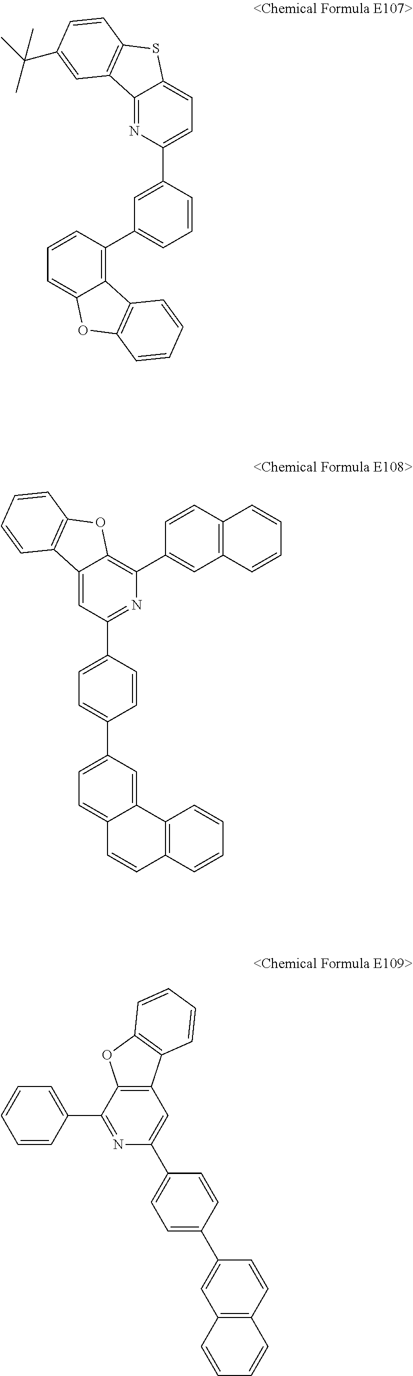 [SMILES: CC(C)(C)c1ccc2sc3ccc(-c4cccc(-c5cccc6oc7ccccc7c56)c4)nc3c2c1 ; c1ccc2cc(-c3nc(-c4ccc(-c5ccc6ccc7ccccc7c6c5)cc4)cc4c3oc3ccccc34)ccc2c1 ; c1ccc(-c2nc(-c3ccc(-c4ccc5ccccc5c4)cc3)cc3c2oc2ccccc23)cc1]

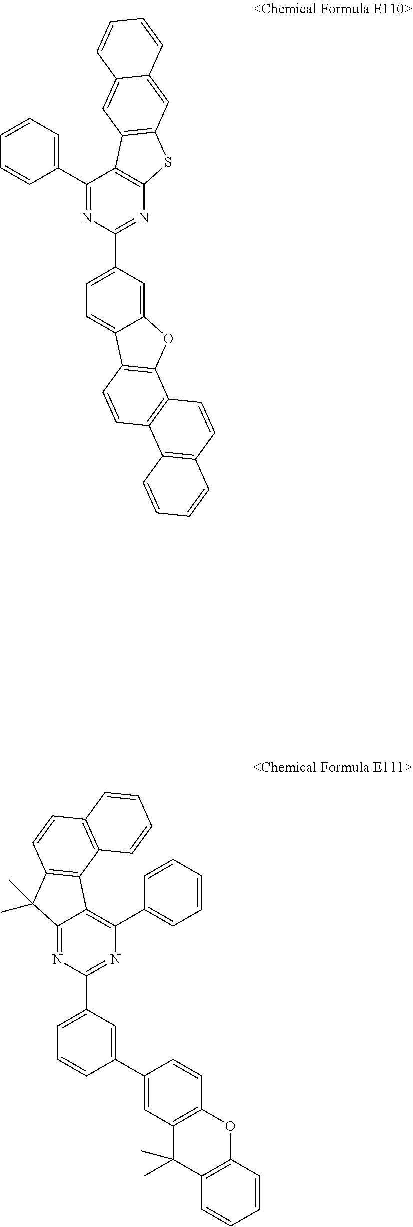 [SMILES: c1ccc(-c2nc(-c3ccc4c(c3)oc3c4ccc4c5ccccc5ccc43)nc3sc4cc5ccccc5cc4c23)cc1 ; CC1(C)c2ccccc2Oc2ccc(-c3cccc(-c4nc(-c5ccccc5)c5c(n4)C(C)(C)c4ccc6ccccc6c4-5)c3)cc21]

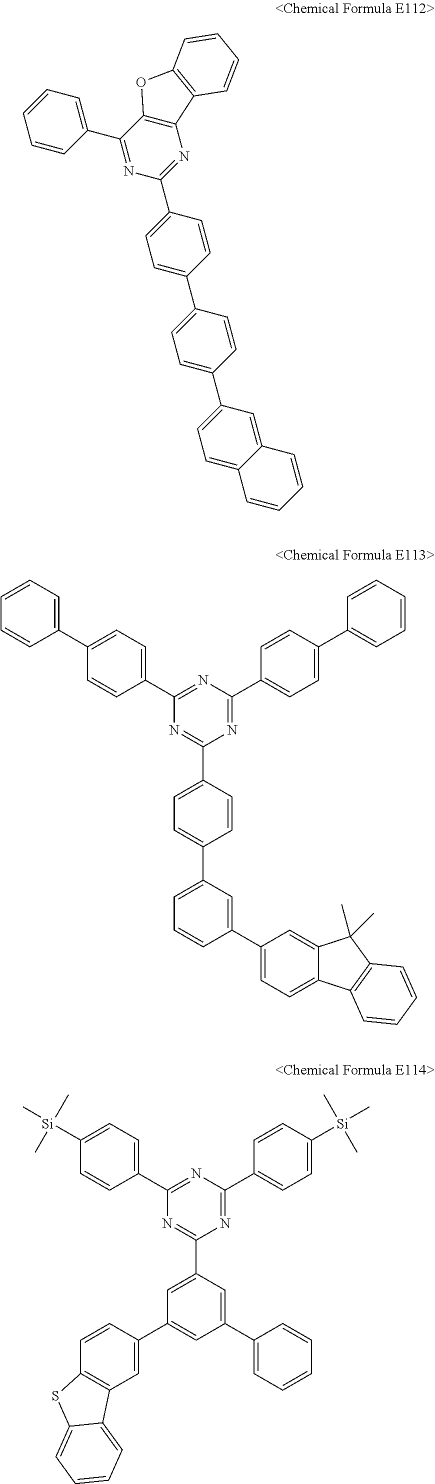

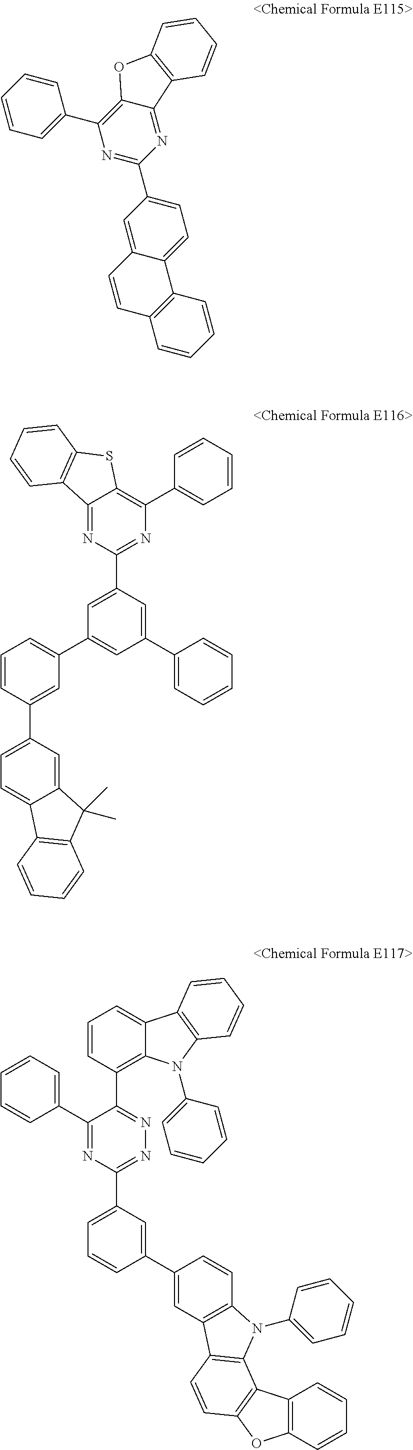 [SMILES: c1ccc(-c2nc(-c3ccc4c(ccc5ccccc54)c3)nc3c2oc2ccccc23)cc1 ; CC1(C)c2ccccc2-c2ccc(-c3cccc(-c4cc(-c5ccccc5)cc(-c5nc(-c6ccccc6)c6sc7ccccc7c6n5)c4)c3)cc21 ; c1ccc(-c2nc(-c3cccc(-c4ccc5c(c4)c4ccc6oc7ccccc7c6c4n5-c4ccccc4)c3)nnc2-c2cccc3c4ccccc4n(-c4ccccc4)c23)cc1]

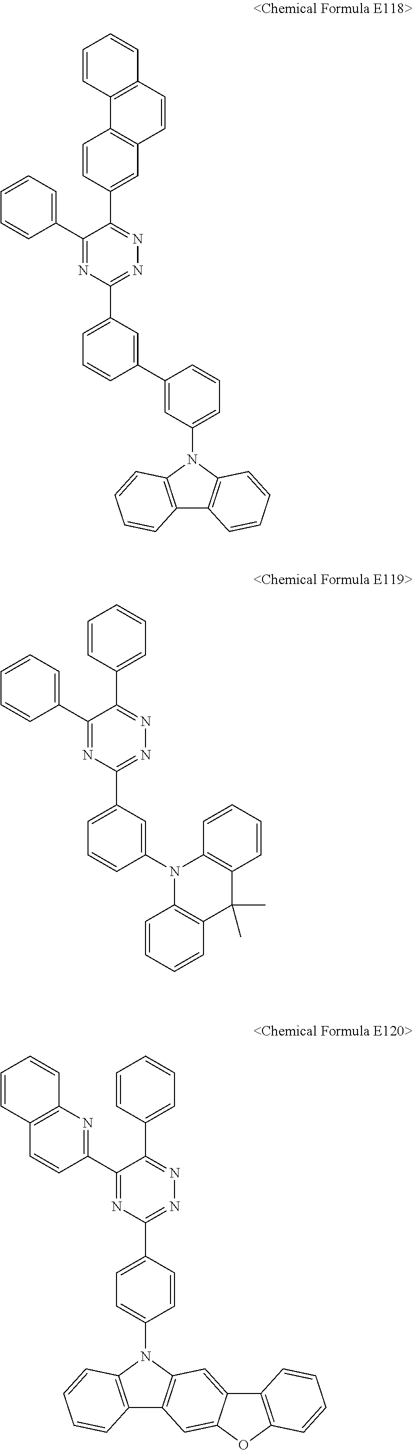 [SMILES: c1ccc(-c2nc(-c3cccc(-c4cccc(-n5c6ccccc6c6ccccc65)c4)c3)nnc2-c2ccc3c(ccc4ccccc43)c2)cc1 ; CC1(C)c2ccccc2N(c2cccc(-c3nnc(-c4ccccc4)c(-c4ccccc4)n3)c2)c2ccccc21 ; c1ccc(-c2nnc(-c3ccc(-n4c5ccccc5c5cc6oc7ccccc7c6cc54)cc3)nc2-c2ccc3ccccc3n2)cc1]

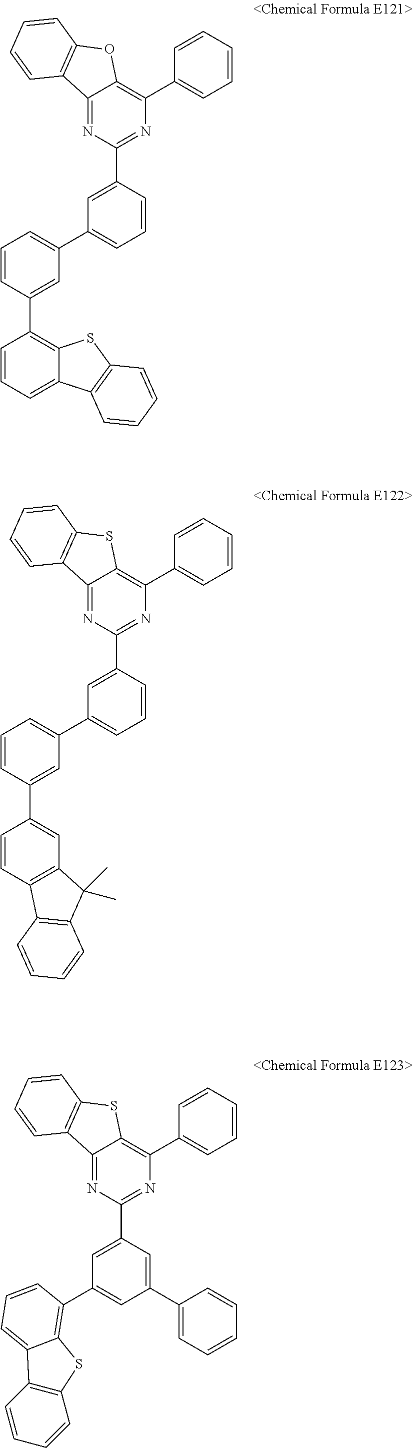 [SMILES: c1ccc(-c2nc(-c3cccc(-c4cccc(-c5cccc6c5sc5ccccc56)c4)c3)nc3c2oc2ccccc23)cc1 ; CC1(C)c2ccccc2-c2ccc(-c3cccc(-c4cccc(-c5nc(-c6ccccc6)c6sc7ccccc7c6n5)c4)c3)cc21 ; c1ccc(-c2cc(-c3nc(-c4ccccc4)c4sc5ccccc5c4n3)cc(-c3cccc4c3sc3ccccc34)c2)cc1]

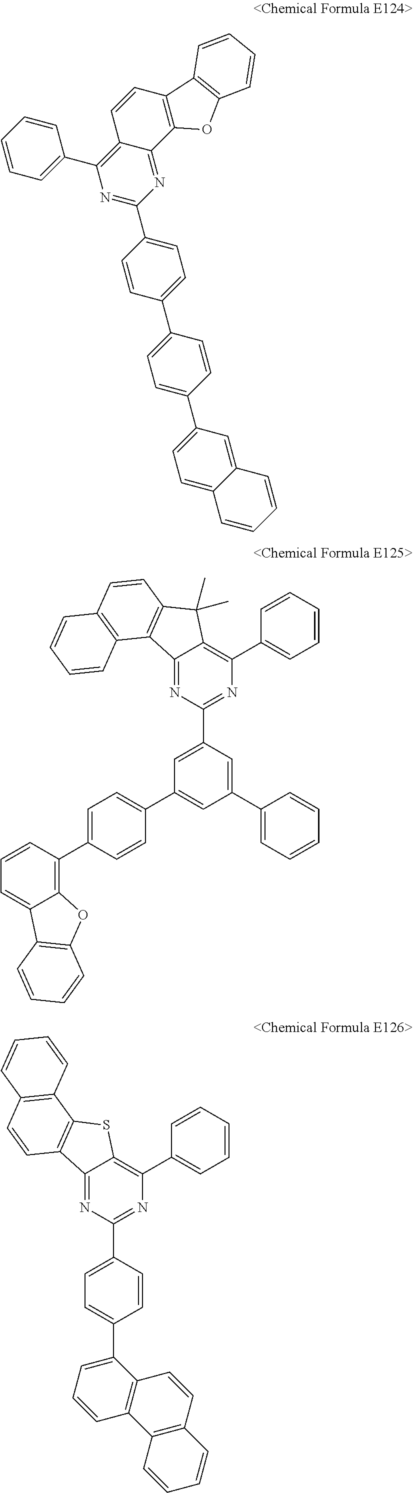

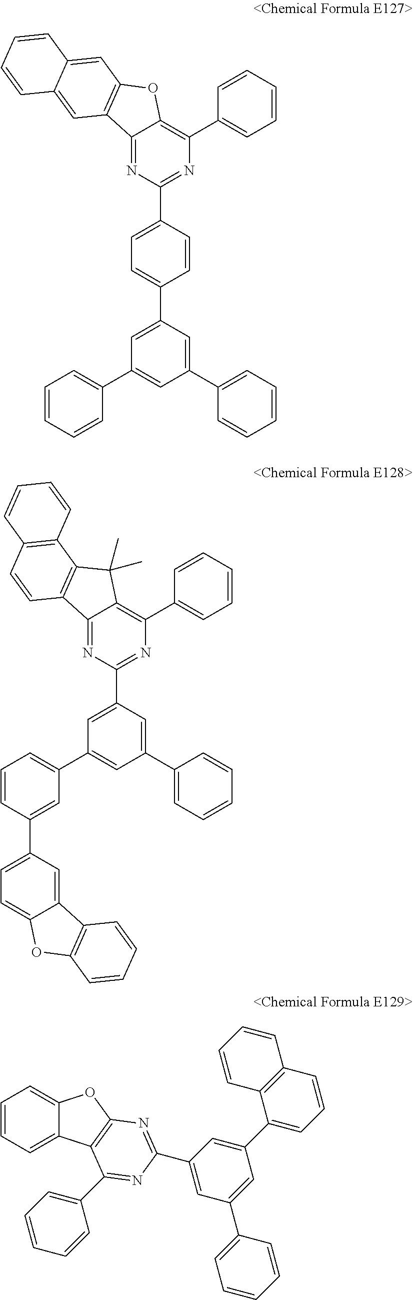 [SMILES: c1ccc(-c2cc(-c3ccccc3)cc(-c3ccc(-c4nc(-c5ccccc5)c5oc6cc7ccccc7cc6c5n4)cc3)c2)cc1 ; CC1(C)c2c(-c3ccccc3)nc(-c3cc(-c4ccccc4)cc(-c4cccc(-c5ccc6oc7ccccc7c6c5)c4)c3)nc2-c2ccc3ccccc3c21 ; c1ccc(-c2cc(-c3nc(-c4ccccc4)c4c(n3)oc3ccccc34)cc(-c3cccc4ccccc34)c2)cc1]

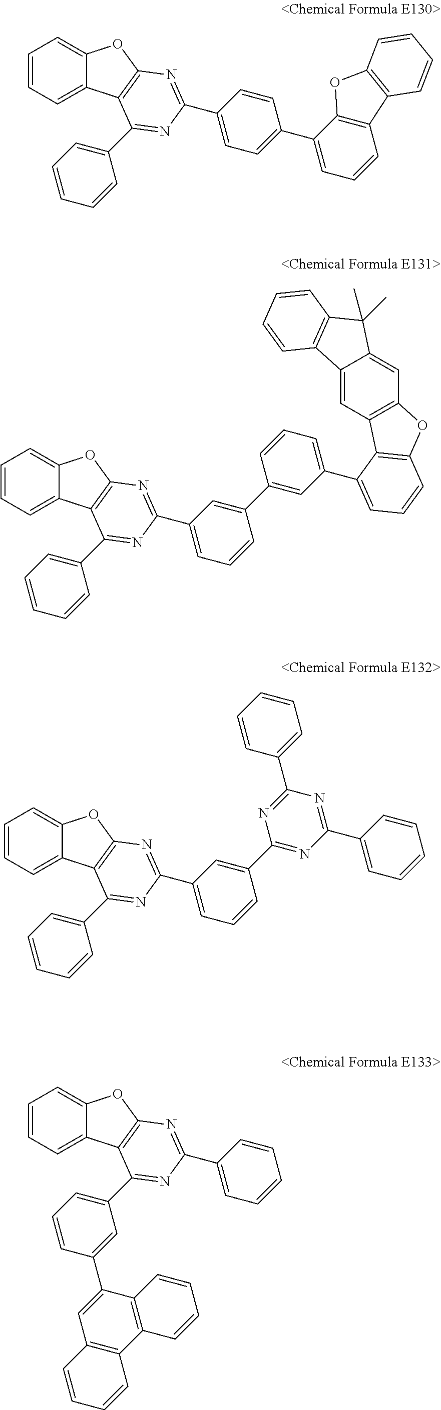 [SMILES: c1ccc(-c2nc(-c3ccc(-c4cccc5c4oc4ccccc45)cc3)nc3oc4ccccc4c23)cc1 ; CC1(C)c2ccccc2-c2cc3c(cc21)oc1cccc(-c2cccc(-c4cccc(-c5nc(-c6ccccc6)c6c(n5)oc5ccccc56)c4)c2)c13 ; c1ccc(-c2nc(-c3ccccc3)nc(-c3cccc(-c4nc(-c5ccccc5)c5c(n4)oc4ccccc45)c3)n2)cc1 ; c1ccc(-c2nc(-c3cccc(-c4cc5ccccc5c5ccccc45)c3)c3c(n2)oc2ccccc23)cc1]

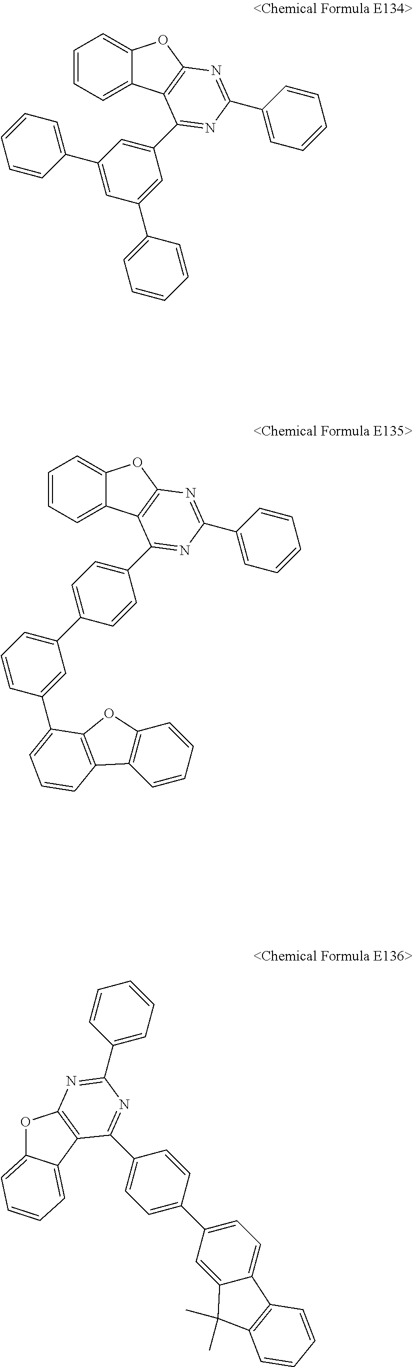 [SMILES: c1ccc(-c2cc(-c3ccccc3)cc(-c3nc(-c4ccccc4)nc4oc5ccccc5c34)c2)cc1 ; c1ccc(-c2nc(-c3ccc(-c4cccc(-c5cccc6c5oc5ccccc56)c4)cc3)c3c(n2)oc2ccccc23)cc1 ; CC1(C)c2ccccc2-c2ccc(-c3ccc(-c4nc(-c5ccccc5)nc5oc6ccccc6c45)cc3)cc21]

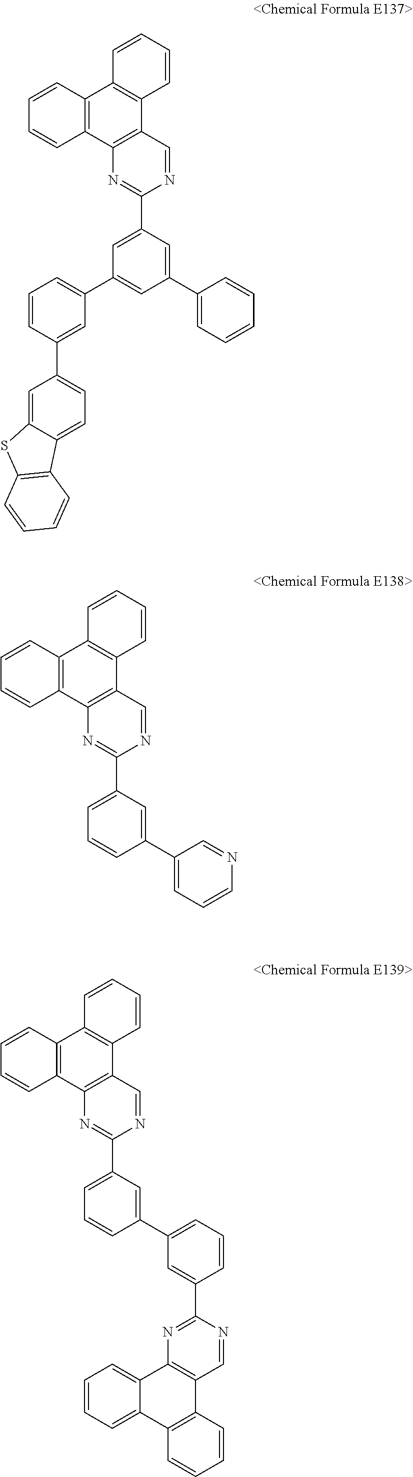 [SMILES: c1ccc(-c2cc(-c3cccc(-c4ccc5c(c4)sc4ccccc45)c3)cc(-c3ncc4c5ccccc5c5ccccc5c4n3)c2)cc1 ; c1cncc(-c2cccc(-c3ncc4c5ccccc5c5ccccc5c4n3)c2)c1 ; c1cc(-c2cccc(-c3ncc4c5ccccc5c5ccccc5c4n3)c2)cc(-c2ncc3c4ccccc4c4ccccc4c3n2)c1]

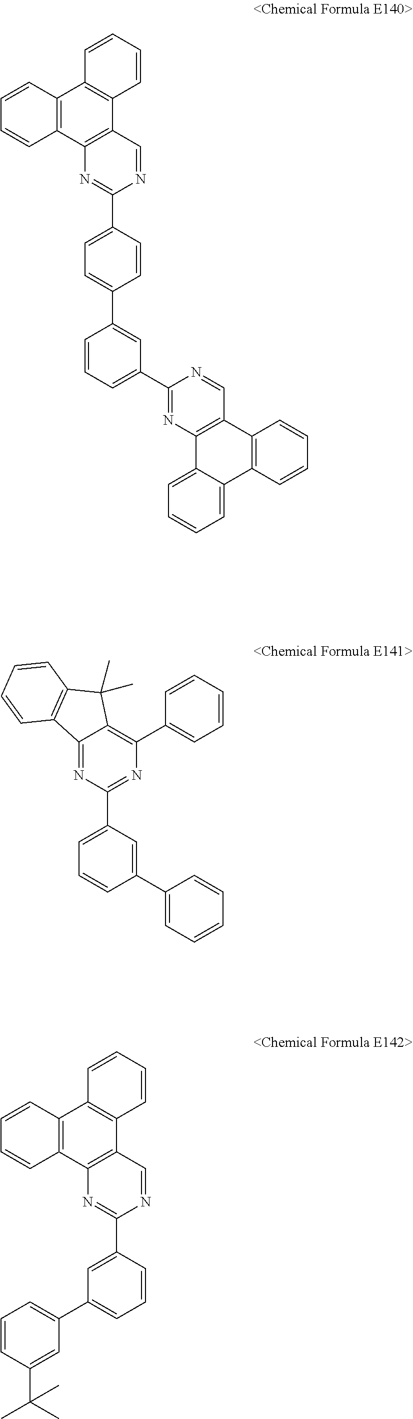 [SMILES: c1cc(-c2ccc(-c3ncc4c5ccccc5c5ccccc5c4n3)cc2)cc(-c2ncc3c4ccccc4c4ccccc4c3n2)c1 ; CC1(C)c2ccccc2-c2nc(-c3cccc(-c4ccccc4)c3)nc(-c3ccccc3)c21 ; CC(C)(C)c1cccc(-c2cccc(-c3ncc4c5ccccc5c5ccccc5c4n3)c2)c1]

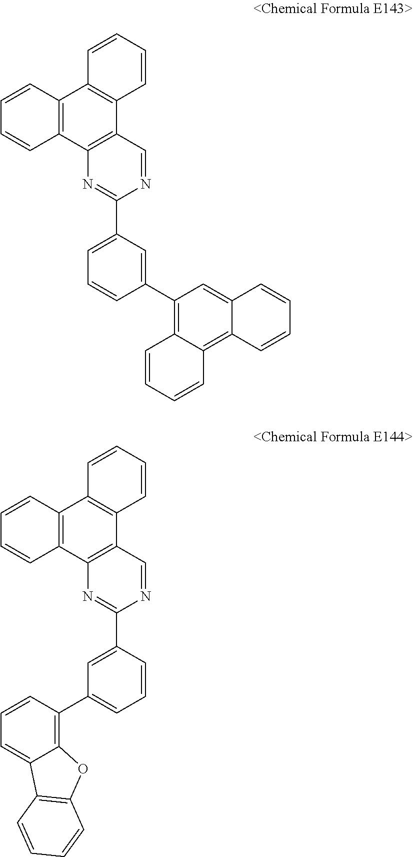 [SMILES: c1cc(-c2ncc3c4ccccc4c4ccccc4c3n2)cc(-c2cc3ccccc3c3ccccc23)c1 ; c1cc(-c2ncc3c4ccccc4c4ccccc4c3n2)cc(-c2cccc3c2oc2ccccc23)c1]

Meanwhile, when R₄ in Structural Formula 1 is a single bond connected to the linker L₁ in Chemical Formula A, the organic light-emitting diode of the present disclosure can operate at low voltages with an improved emission efficiency, enjoying a longer lifetime.

A particular embodiment of the present disclosure provides an organic light-emitting diode comprising: a first electrode; a second electrode facing the first electrode; and a light-emitting layer interposed between the first electrode and the second electrode, wherein at least one of the fused ring compounds represented by Chemical Formula A, and a hetero ring compound represented by Chemical Formula D are used as hosts in the light-emitting layer.

Here, the fused ring compound represented by Chemical Formula A and the hetero ring compound represented by Chemical Formula D may be combined at a weight ratio of 1:9 to 9:1.

In addition, the organic light-emitting diode according to the present disclosure may further comprise a dopant in the light-emitting layer. In this regard, the content of the dopant in the light-emitting layer may range about 0.01 to 20 parts by weight, based on 100 parts by weight of the host, but is not limited thereto.

The dopant compound may include at least one selected from the compounds represented by the following General Formula s (A-1) to (J-1), but is not limited thereto:

ML₁L₂L₃ [General Formula A-1]

wherein M is a metal selected from the group consisting of the elements of Groups 7, 8, 9, 10, 11, 13, 14, 15, and 16, with preference for Ir, Pt, Pd, Rh, Re, Os, Tl, Pb, Bi, In, Sn, Sb, Te, Au, and Ag; and L₁, L₂, and L₃ are ligands which are the same or different and are each independently any one selected from the following Structural Formula D, but are not limited thereto.

In the following Structural Formula D, “*” represents a site at which a coordinate bond with the metal ion M is formed:

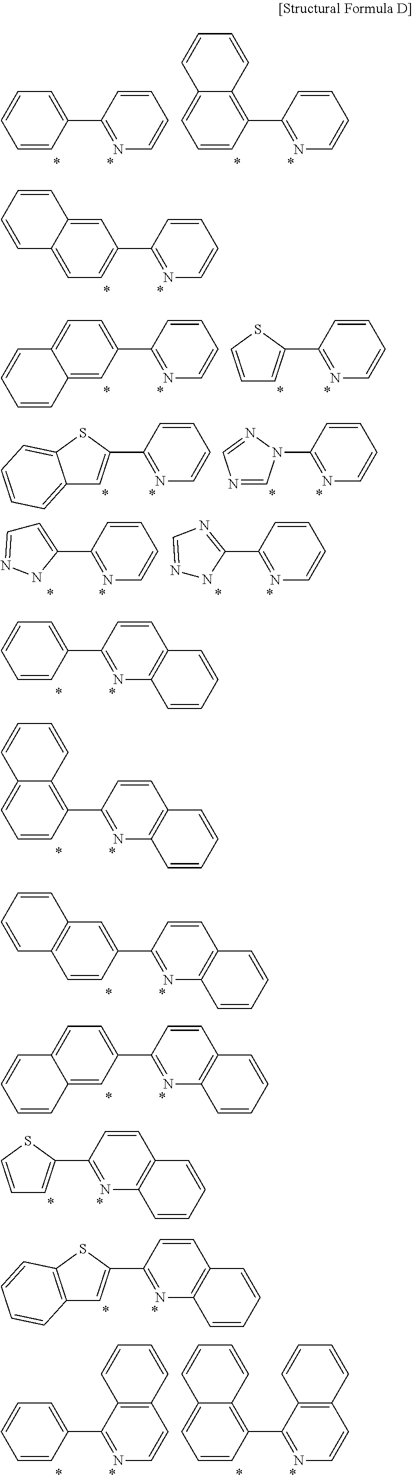

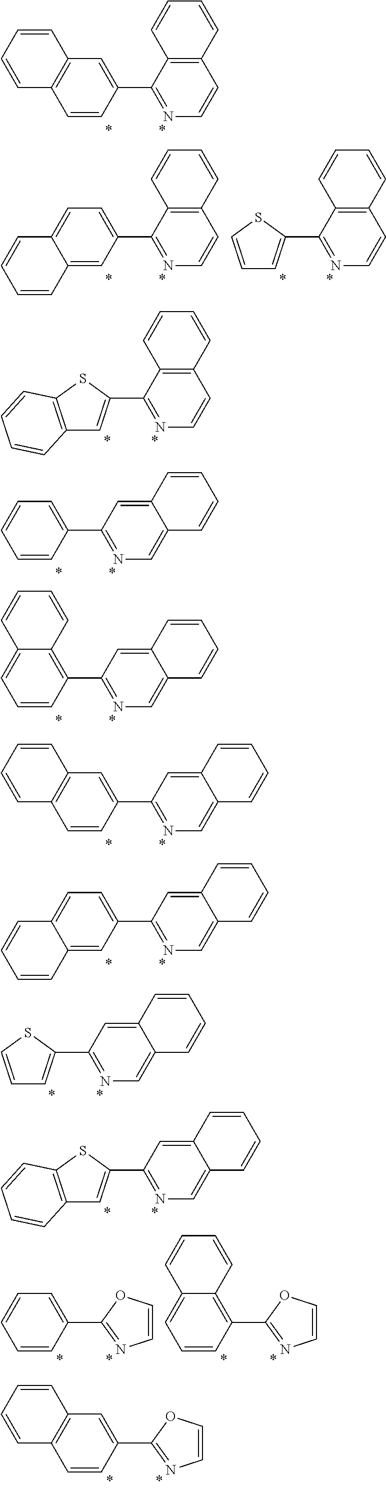

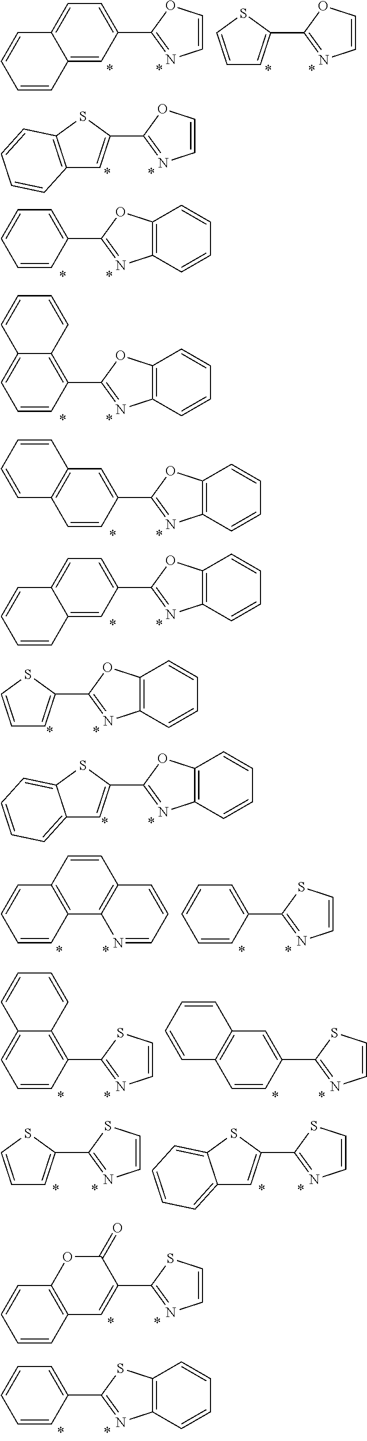

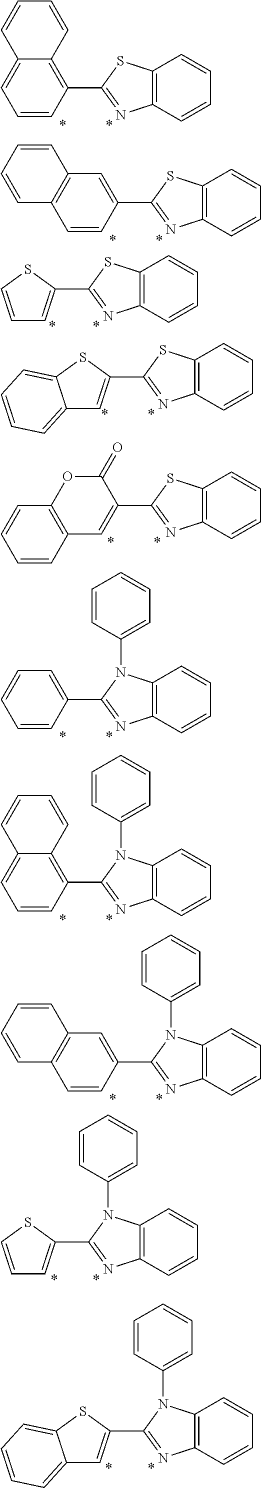

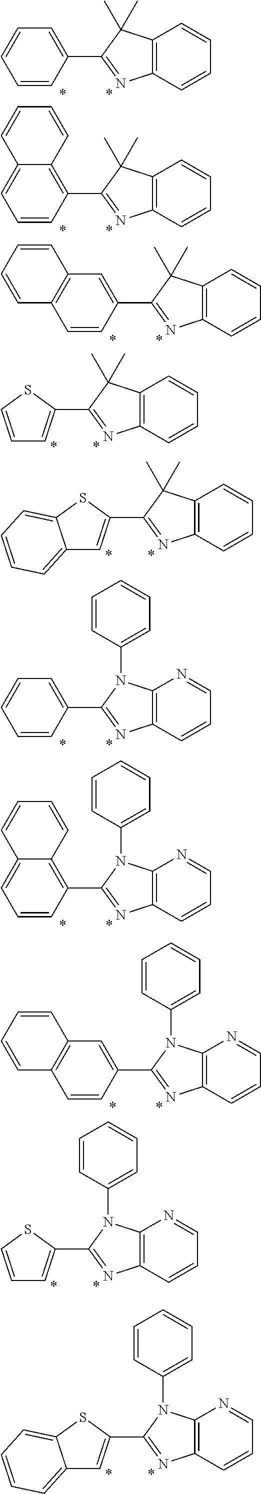

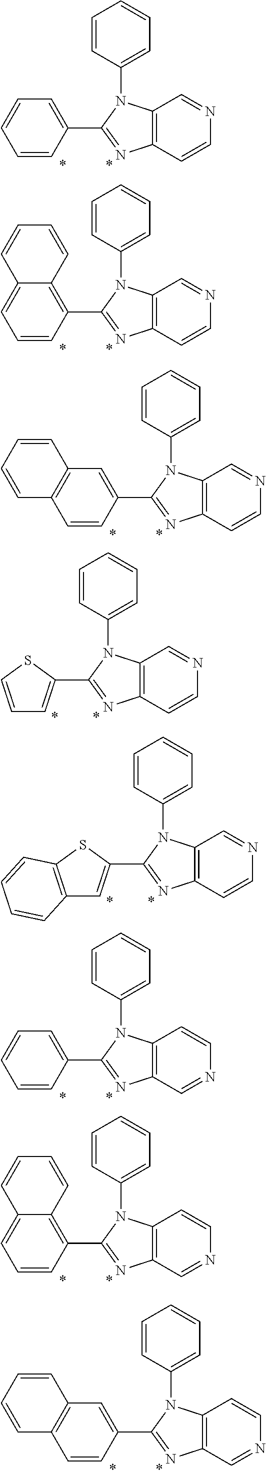

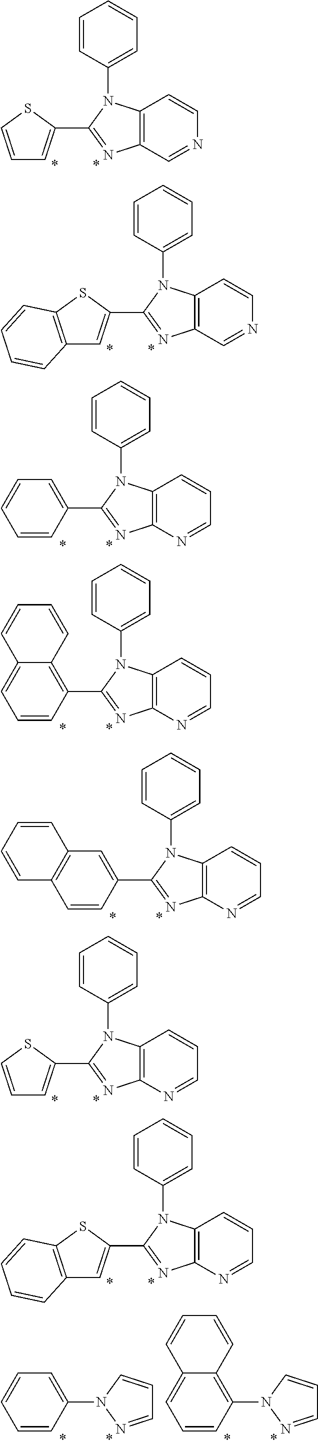

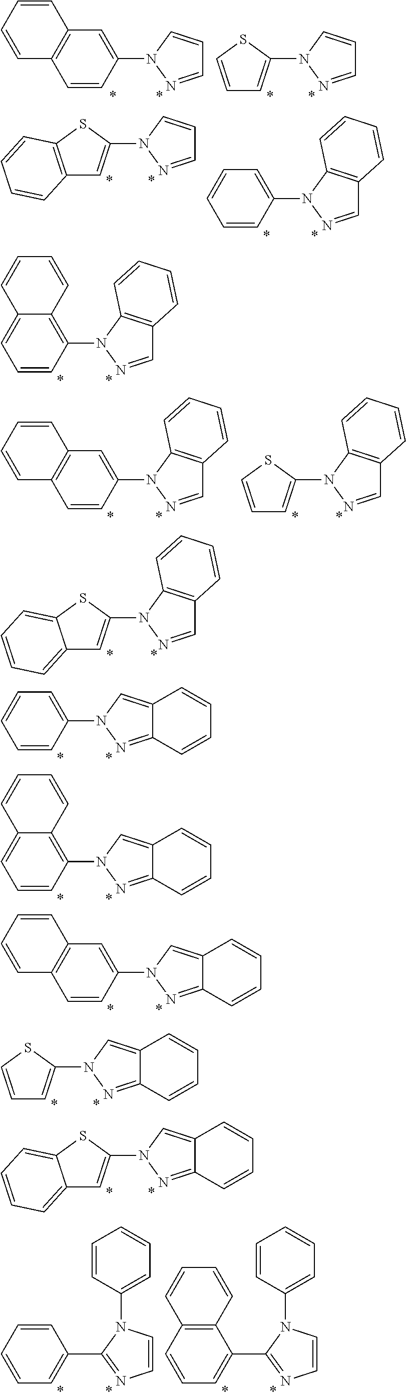

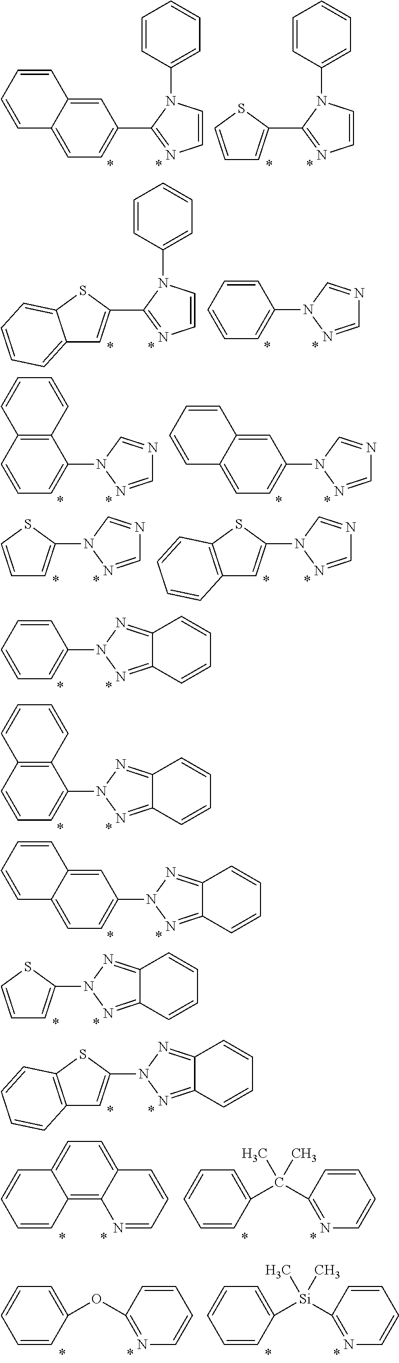

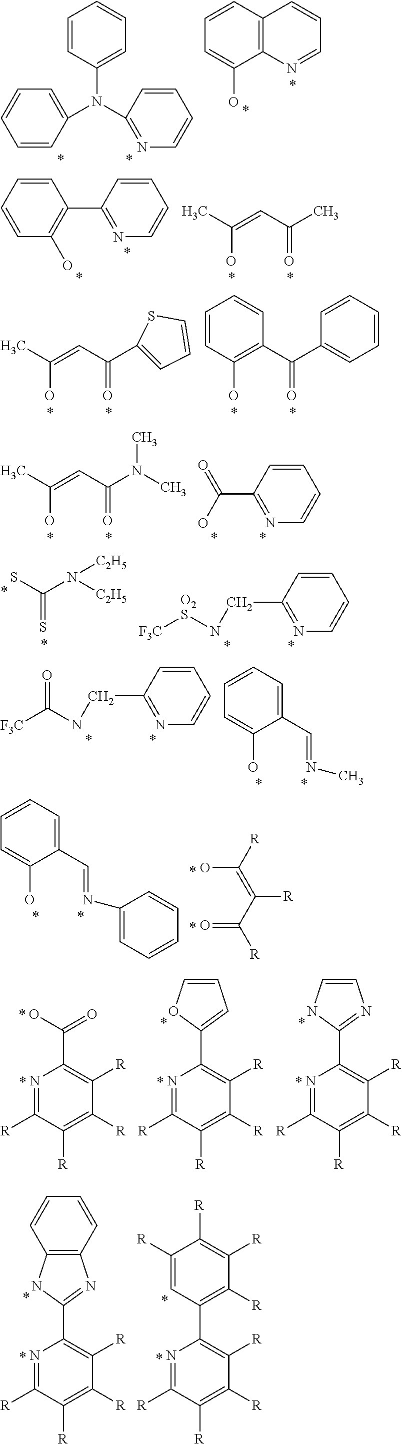

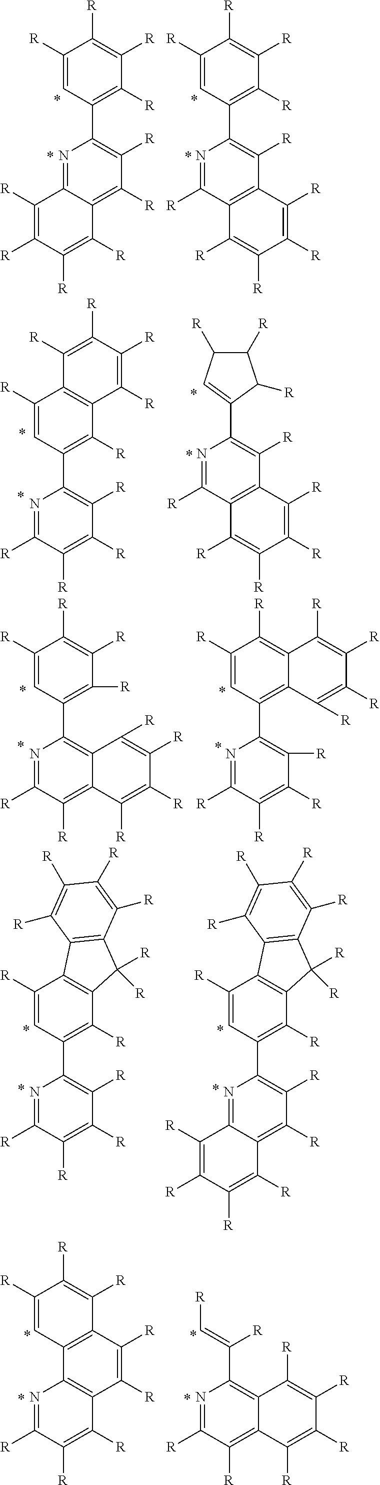

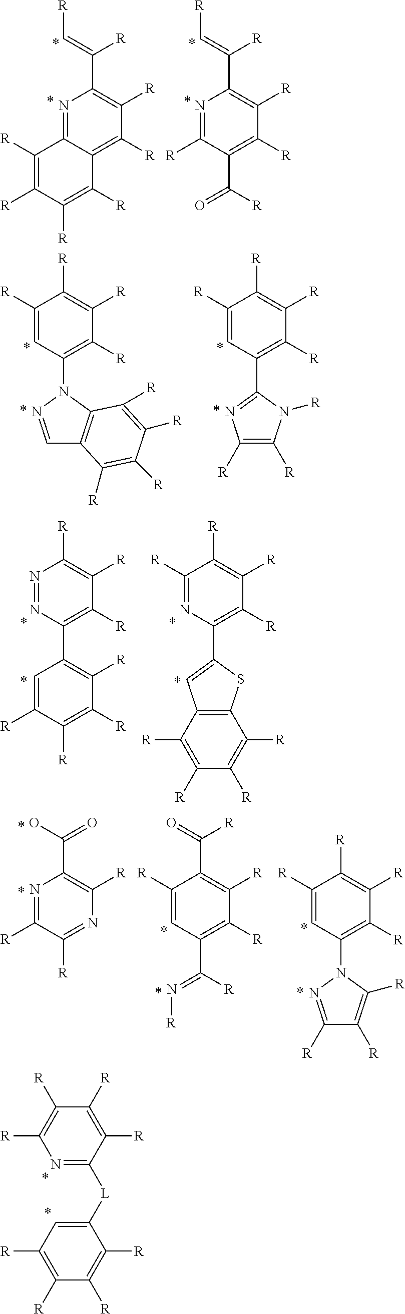

wherein,

R's, which may the same or different, are each independently any one selected from among a hydrogen atom, a deuterium atom, a halogen, a cyano, a substituted or unsubstituted alkyl of 1 to 30 carbon atoms, a substituted or unsubstituted aryl of 6 to 50 carbon atoms, a substituted or unsubstituted heteroaryl of 5 to 50 carbon atoms, a substituted or unsubstituted alkoxy of 1 to 30 carbon atoms, a substituted or unsubstituted cycloalkyl of 3 to 30 carbon atoms, a substituted or unsubstituted alkenyl of 2 to 30 carbon atoms, a substituted or unsubstituted alkylamino of 1 to 30 carbon atoms, a substituted or unsubstituted alkylsilyl of 1 to 30 carbon atoms, a substituted or unsubstituted arylamino of 6 to 30 carbon atoms, and a substituted or unsubstituted arylsilyl of 6 to 30 carbon atoms,

R's may each be further substituted independently with at least one substituent selected from among an alkyl of 1 to 20 carbon atoms, a cycloalkyl of 3 to 20 carbon atoms, an aryl of 6 to 40 carbon atoms, a heteroaryl of 3 to 20 carbon atoms, a cyano, a halogen, a deuterium atom, and a hydrogen atom;

R's may each be connected to an adjacent substituent via alkylene or alkenylene to form an aliphatic ring or a mono- or polycyclic ring, and

L may be connected to an adjacent substituent via alkylene or alkanylene to form a spiro ring or a fused ring.

According to an embodiment, the dopant represented by General Formula A-1 may be any one selected from among the following compounds:

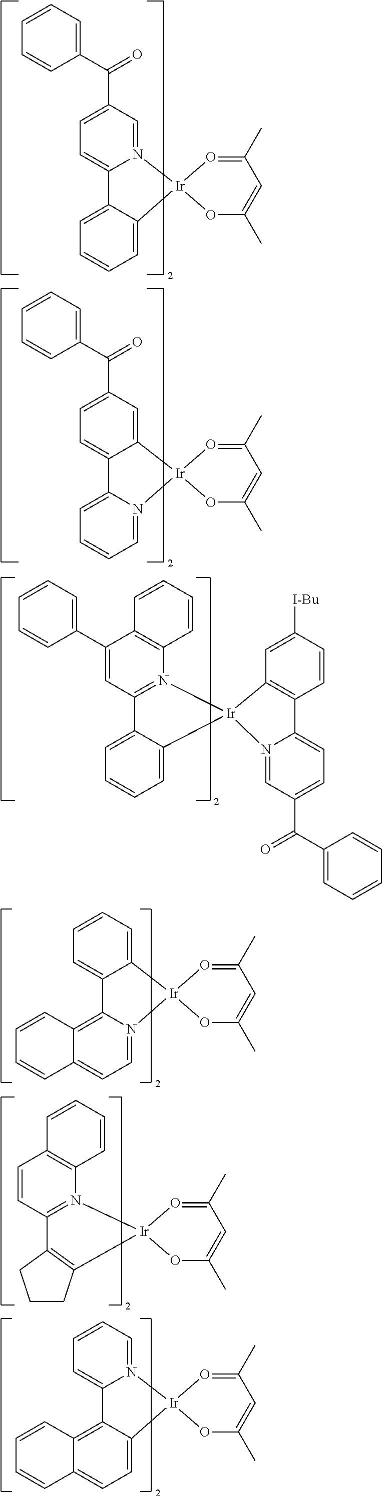

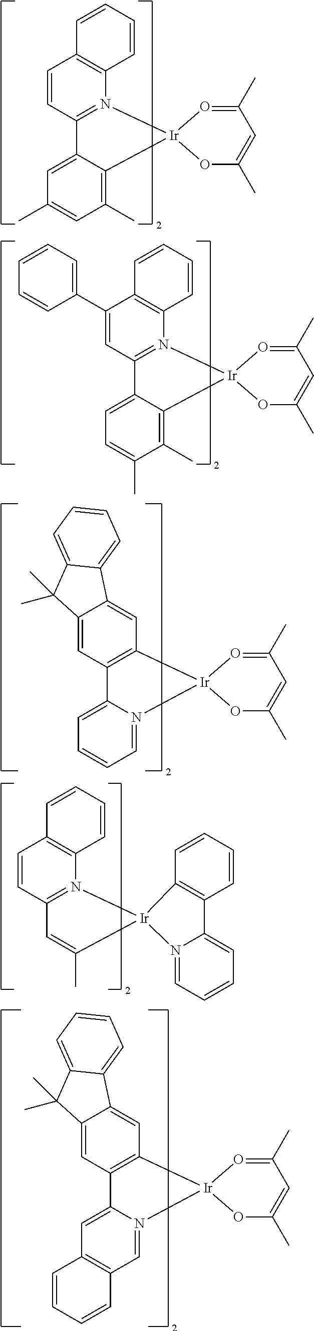

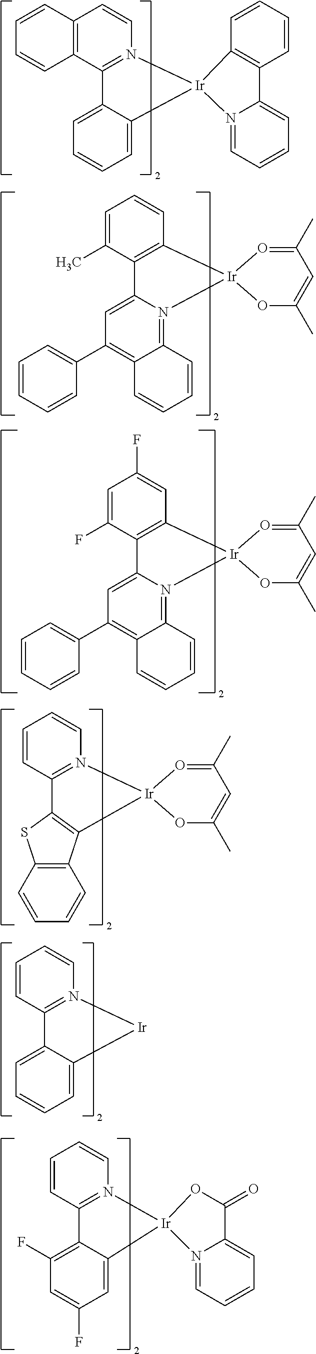

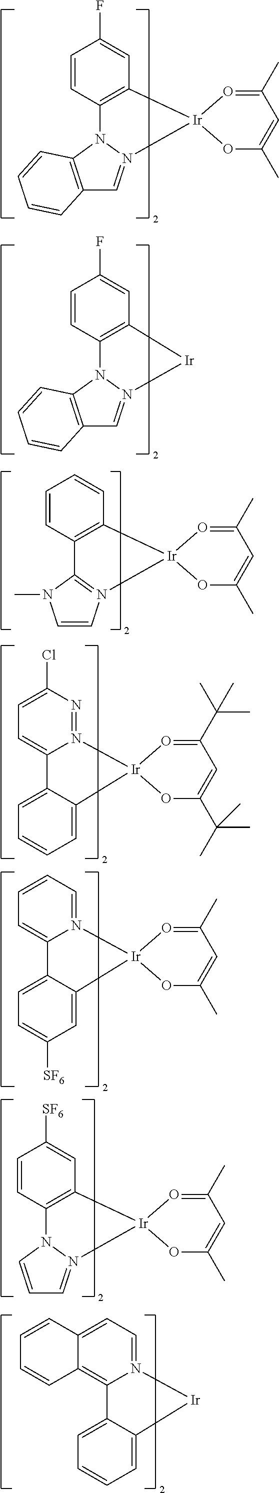

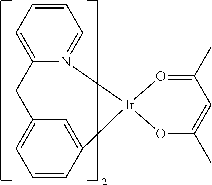

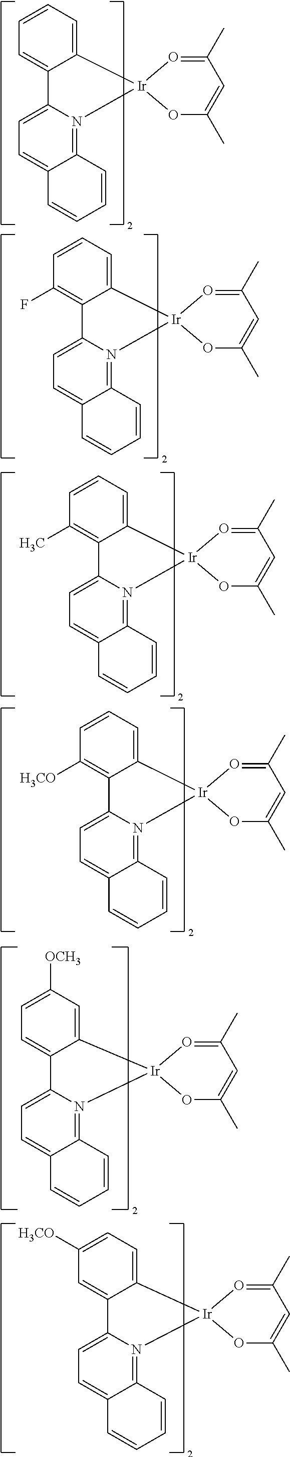

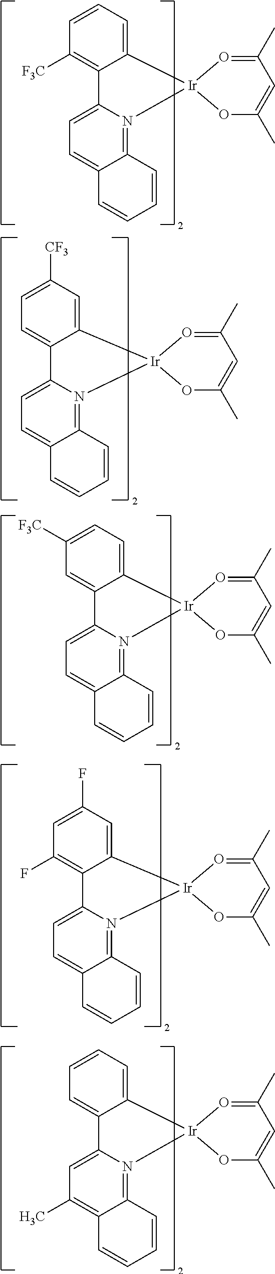

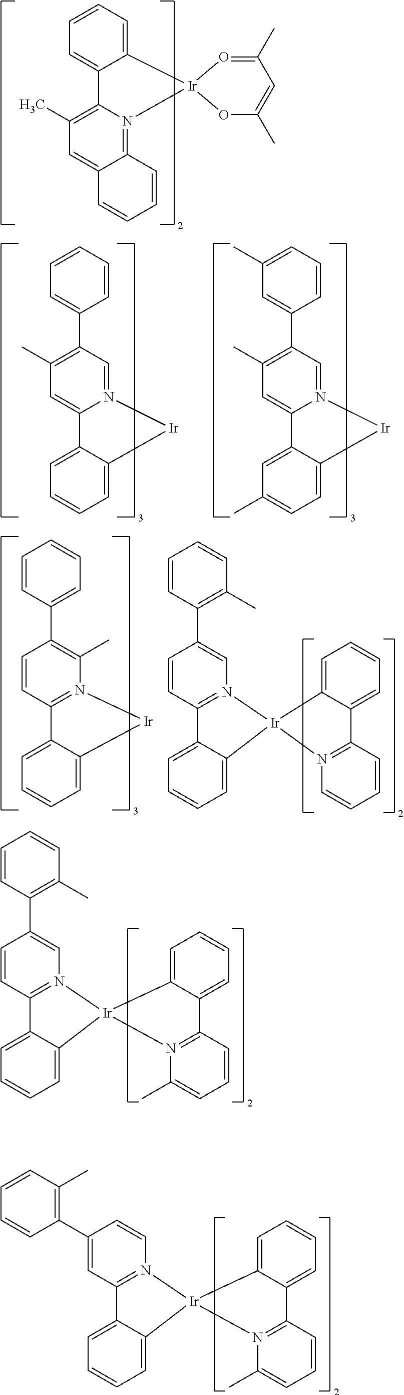

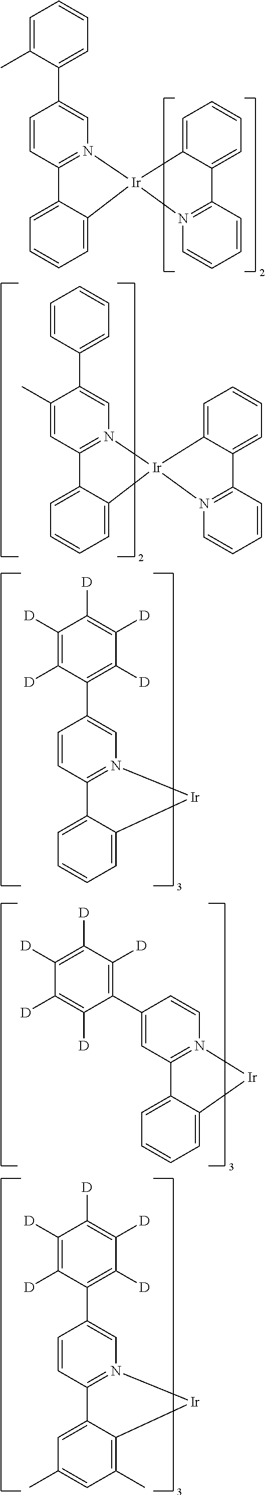

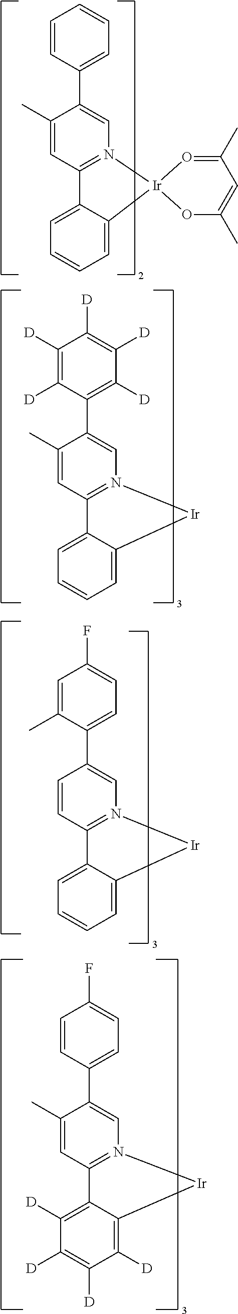

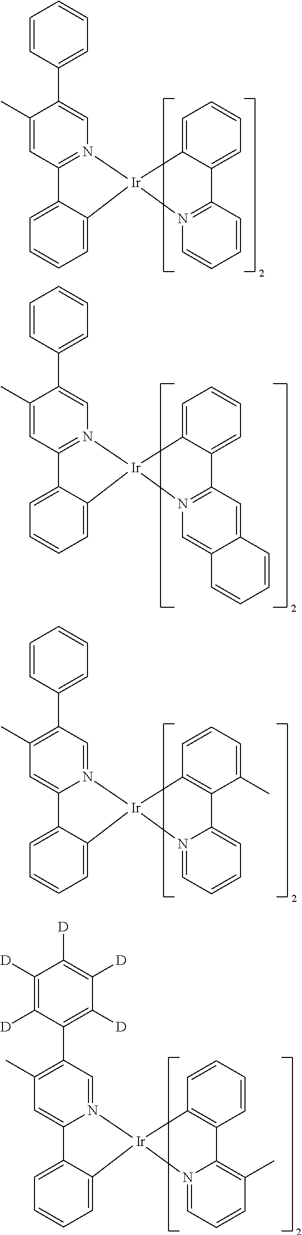

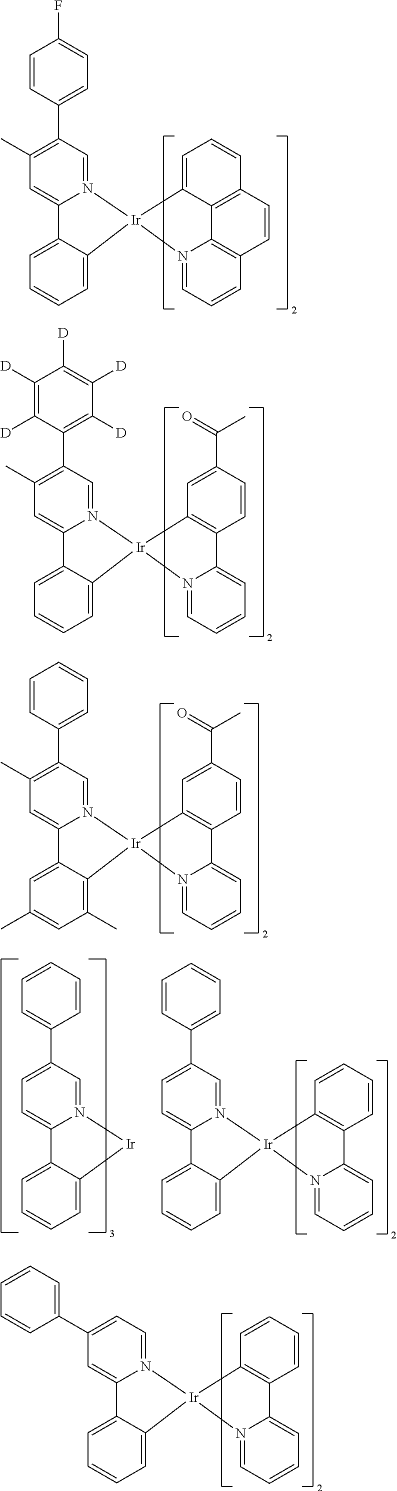

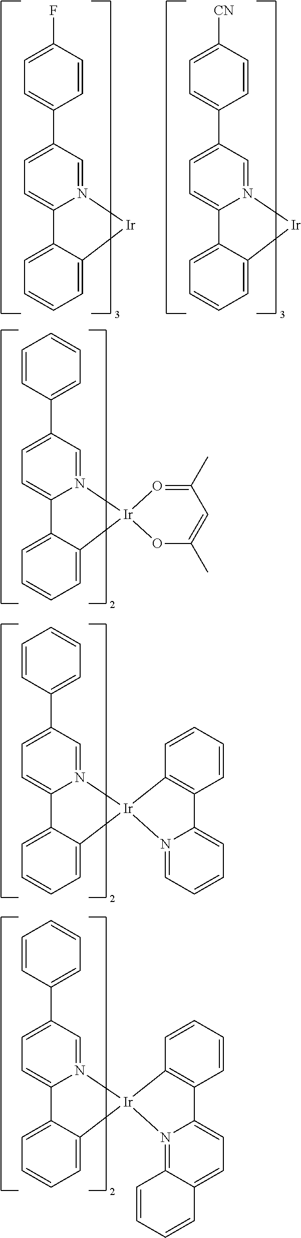

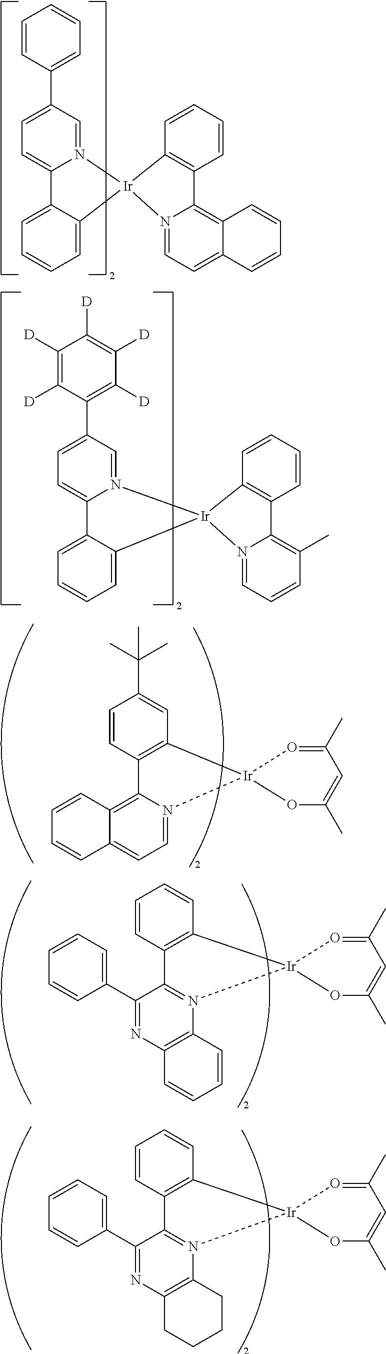

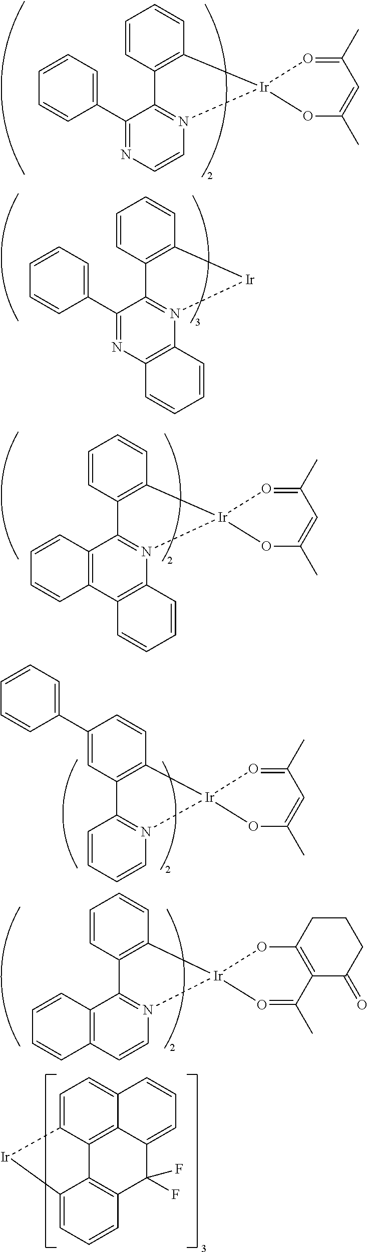

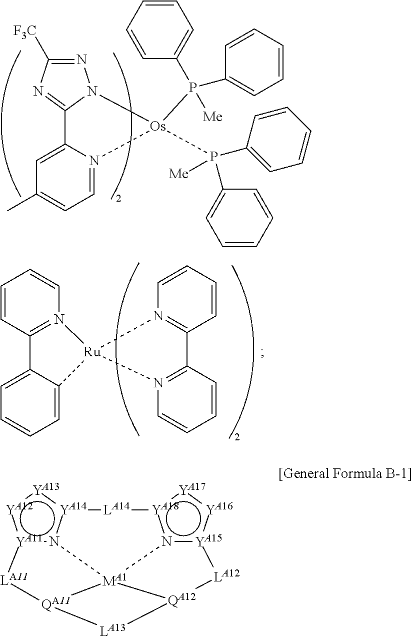

wherein,

M^{A1} is a metal ion that is same as defined in General Formula (A-1); Y^{A11}, Y^{A14}, Y^{A15}, and Y^{A18} each independently represent a carbon atom or a nitrogen atom; Y^{A12}, Y^{A13}, Y^{A16}, and Y^{A17} each independently represent a substituted or unsubstituted carbon atom, a substituted or unsubstituted nitrogen atom, an oxygen atom, or a sulfur atom; L^{A11}, L^{A12}, L^{A13}, and L^{A14} are each a linker that are the same as defined above; and Q^{A11} and Q^{A12} are each a structure that bears an atom bonding to M^{A1}.

Illustrative structures of the compounds represented by General Formula B-1 are as follows, but not limited thereto:

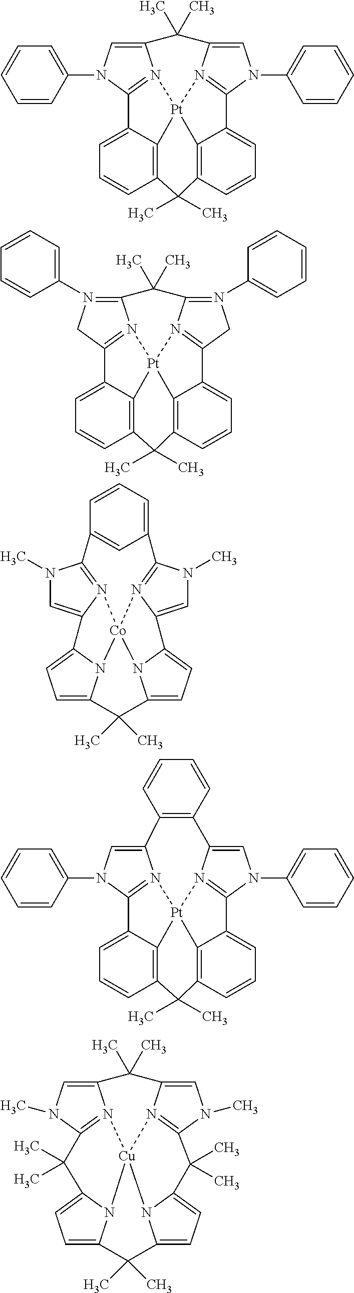

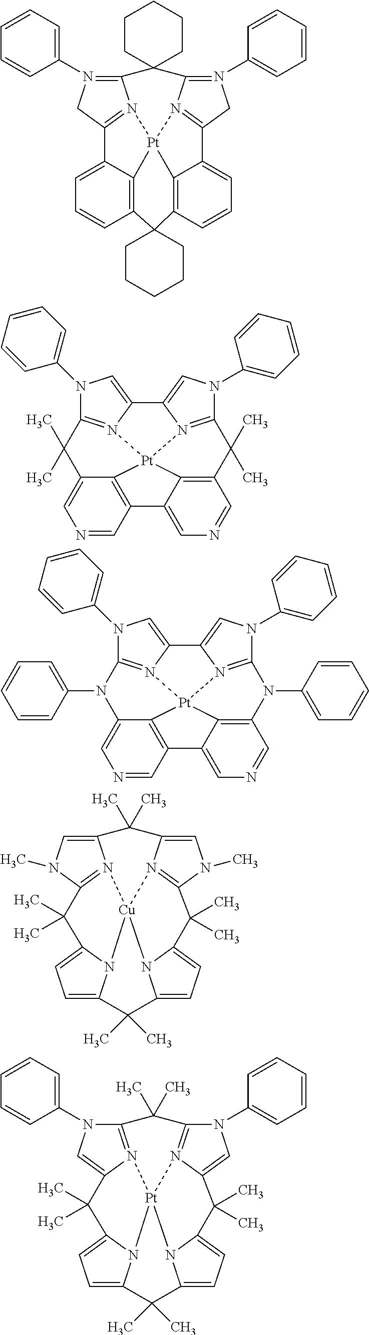

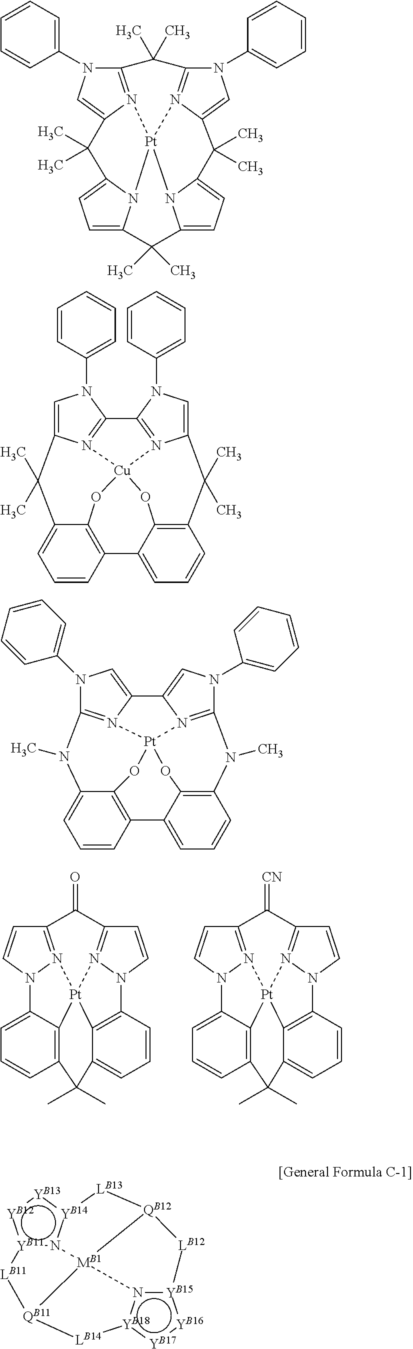

wherein,

M^{B1} is a metal ion that is same as defined in General Formula (A-1); Y^{B11}, Y^{B14}, Y^{B15}, and Y^{B18} each independently represent a carbon atom or a nitrogen atom; Y^{B12}, Y^{B13}, Y^{B16}, and Y^{B17} each independently represent a substituted or unsubstituted carbon atom, a substituted or unsubstituted nitrogen atom, an oxygen atom, or a sulfur atom; L^{B11}, L^{B12}, L^{B13}, and L^{B14} are each a linker that are the same as defined above; and Q^{B11} and Q^{B12} are each a structure that bears an atom bonding to M^{B1}.

Illustrative structures of the compounds represented by General Formula C-1 are as follows, but not limited thereto:

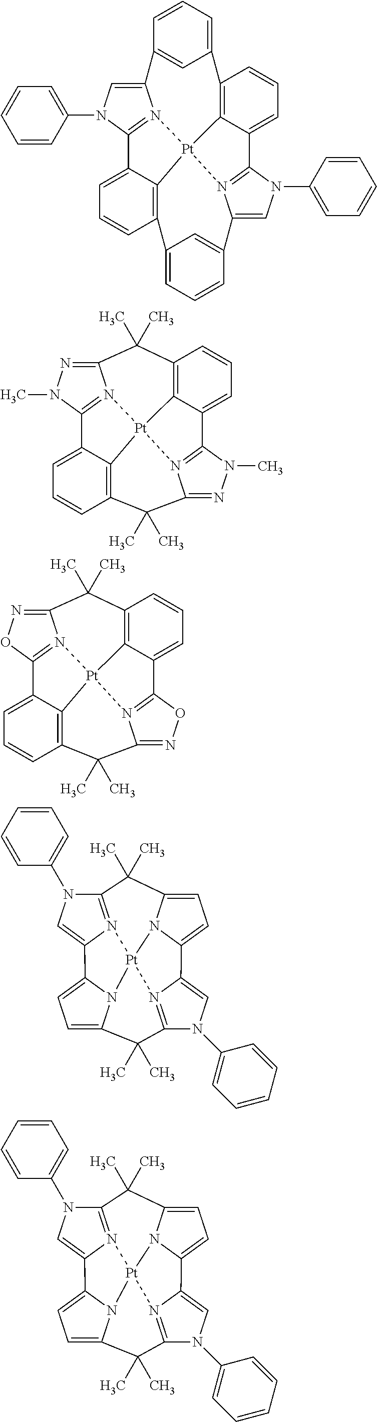

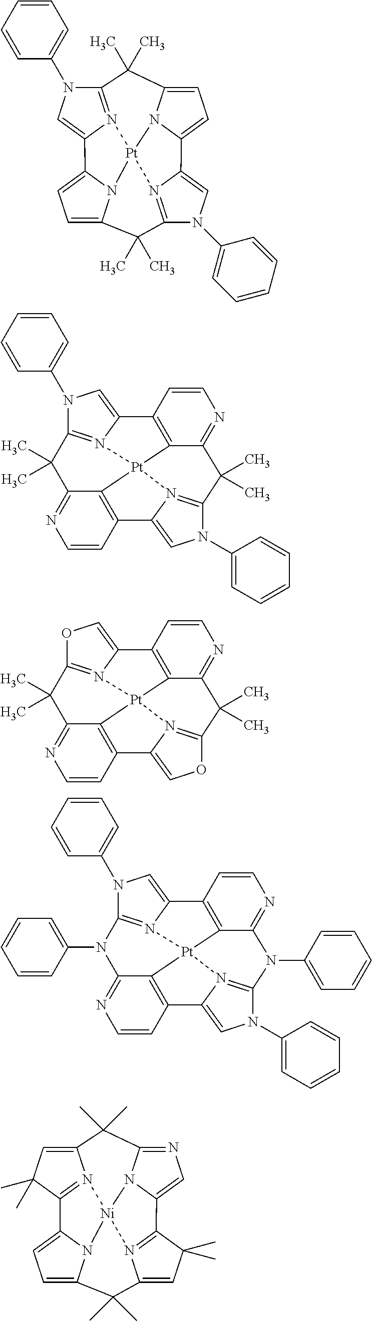

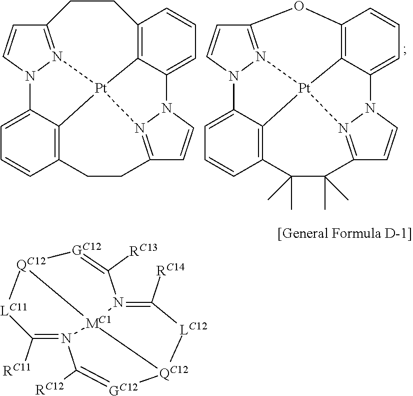

wherein,

M^{C1} is a metal ion that is same as defined in General Formula (A-1); R^{C11} and R^{c12} each independently represent a hydrogen atom, a substituent bonded therebetween to form a 5-membered ring, or a substituent not bonded therebetween; R^{C13}, and R^{c14} each independently represent a hydrogen atom, a substituent bonded therebetween to form a 5-membered ring, or a substituent not bonded therebetween; G^{C11} and G^{C12} each independently represent a nitrogen atom or a substituted or unsubstituted carbon atom; L^{C11} and L^{C12} are each a linker; and Q_{C11} and Q^{C12} are each a structure than bears an atom bonding to M¹.

Illustrative structures of the compounds represented by General Formula D-1 are as follows, but not limited thereto:

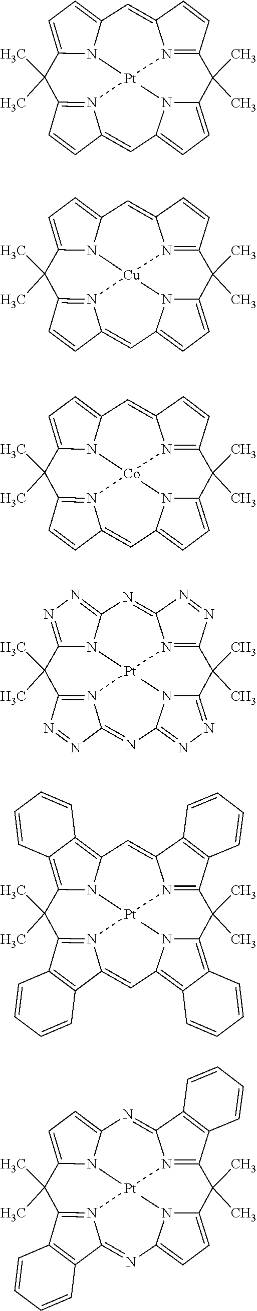

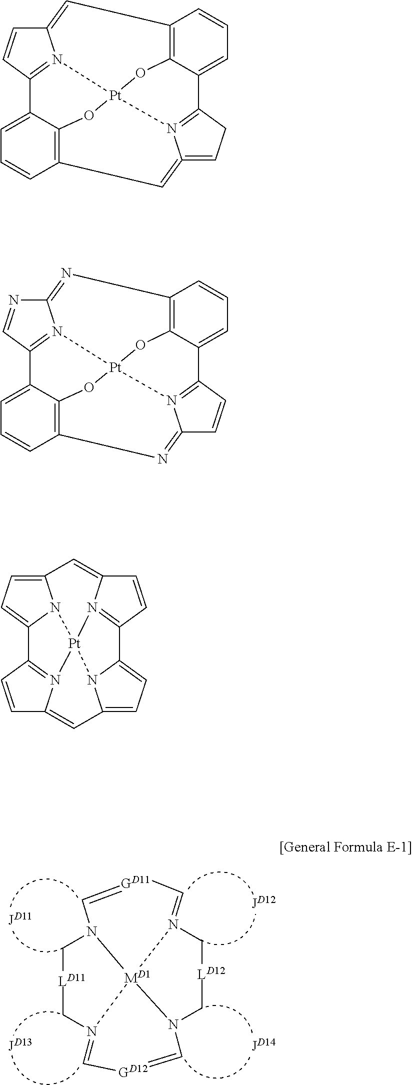

wherein,

M^{D1} is a metal ion that is same as defined in General Formula (A-1);

G^{D11} and G^{D12} each independently represent a nitrogen atom or a substituted or unsubstituted carbon atom; J^{D11}, J^{D12}, J^{D13}, and J^{D14} each independently represent an atom group necessary for forming a 5-membered ring; and L^{D11} and L^{D12} are each independently a linker.

The compounds represented by General Formula E-1 are illustrated as follows, but are not limited to:

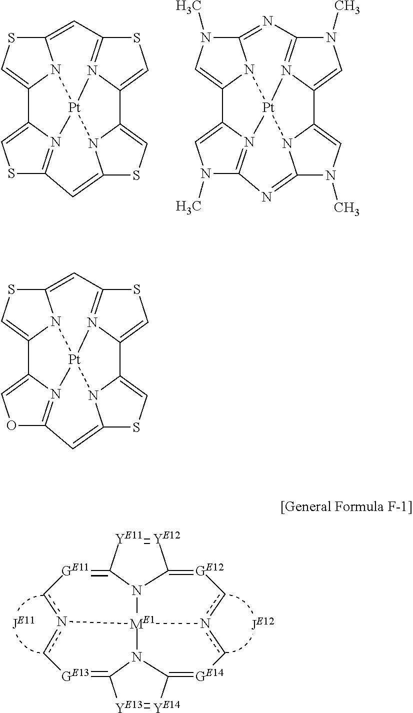

wherein,

M^{E1} is a metal ion that is same as defined in General

Formula (A-1); J^{E11} and J^{E12} each independently represent an atom group necessary for forming a 5-membered ring; G^{E11}, G^{E12}, G^{E13}, and G^{E14} each independently represent a nitrogen atom or a substituted or unsubstituted carbon atom; and Y^{E11}, Y^{E12}, Y^{E13}, and Y^{E14} each independently represent a nitrogen atom or a substituted or unsubstituted carbon atom.

Illustrative structures of the compounds represented by General Formula f-1 are as follows, but not limited thereto:

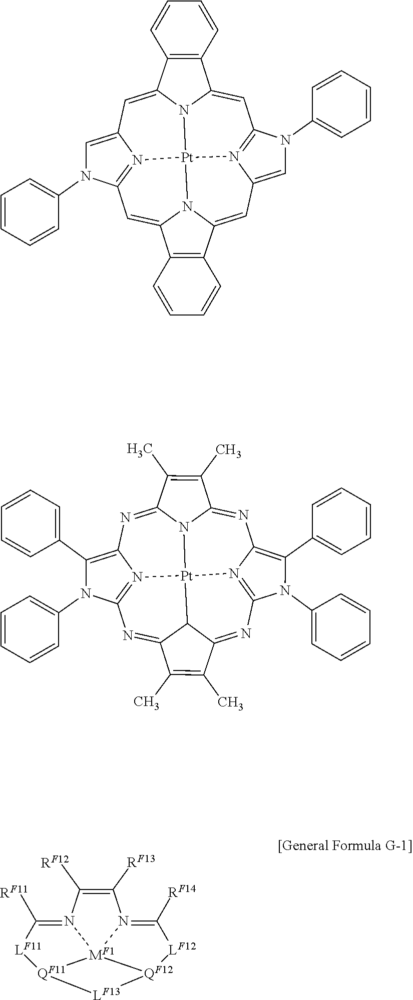

wherein,

M^{F1} is a metal ion that is same as defined in General Formula (A-1);

L^{F11}, L^{F12}, and L^{F13} are each independently a linker; R^{F11}, R^{F12}, R^{F13}, and R^{F14} are each independently a substituent, wherein a bond may be formed between R^{F11} and R^{F12}, between R^{F12} and R^{F13}, and between R^{F13} and R^{F14} to form respective rings, the rings formed by R^{F11} and R^{F12} and by R^{F13} and R^{F14} being respective 5-membered rings; and Q^{F11} and Q^{F12} are each a structure that bears an atom bonding to M^{F1}.

Illustrative structures of the compounds represented by General Formula G-1 are as follows, but not limited thereto:

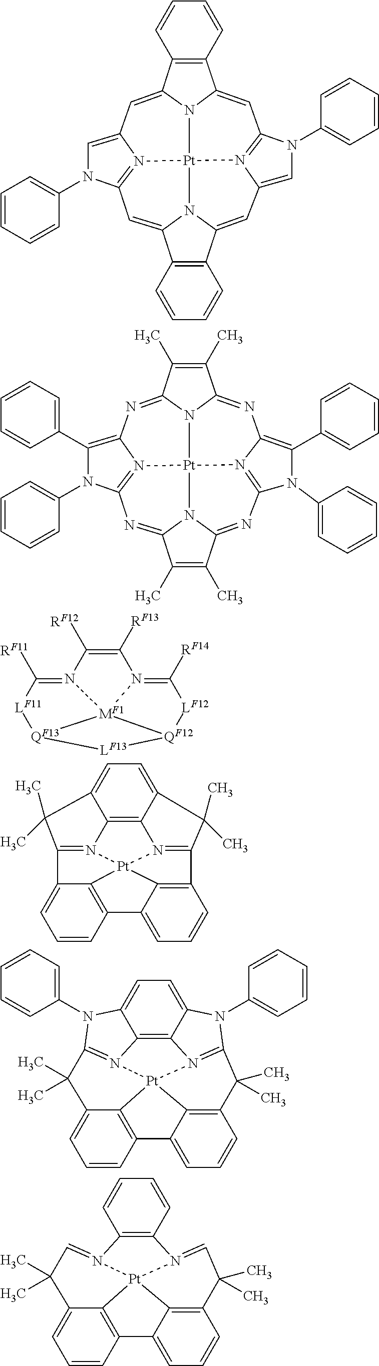

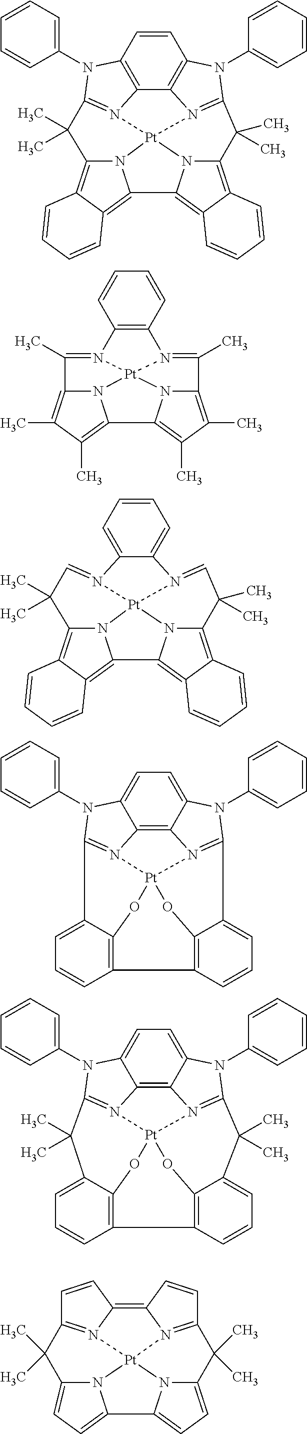

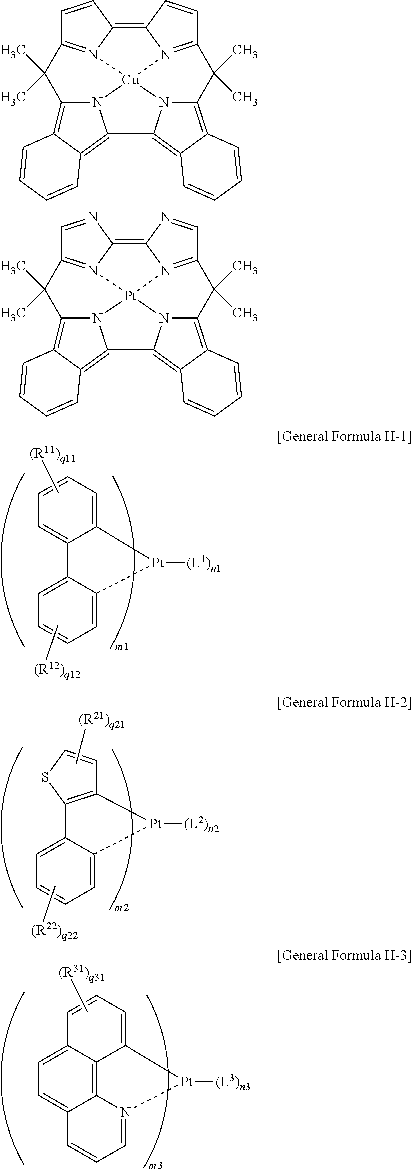

wherein,

R¹¹ and R¹² are each independently an alkyl, aryl or heteroaryl substituent and may form a fused ring with an adjacent substituent; and q11 and q12 are each independently an integer of 0-4 and preferably an integer of 0-2,

wherein when q11 and q12 are each independently an integer of 2-4, the corresponding multiple R¹¹'s and R¹²'s may be the same or different;

L¹ is a ligand bonded to platinum, preferably a ligand capable of forming an ortho-metalated platinum complex, a nitrogen-bearing heterocyclic ligand, a diketone ligand, or a halogen ligand, and more preferably a ligand capable of forming an ortho-metalated platinum complex, a bipyridyl ligand, or a phenanthroline ligand; and

n₁ is an integer of 0 to 3 and preferably 0; and m₁ is 1 or 2 and preferably 2.

In addition, n₁ and m₁ are set to allow the metal complex represented by General Formula H-1 to be a neutral complex.

In General Formula H-2, R²¹, R²², n2, m2, q22, and L² are as defined for R¹¹, R¹², n1, m1, q12, and L¹, respectively; and q21 is an integer of 0 to 2, with preference for 0.

In General Formula H-3, R³¹, n3, m3, and L³ are as defined for R¹¹, n1, m1, and L¹, respectively; and q31 is an integer of 0 to 8, preferably an integer of 0 to 2, and more preferably 0.

Concrete examples of General Formula H-1 to H-3 include, but are not limited to, the following compounds:

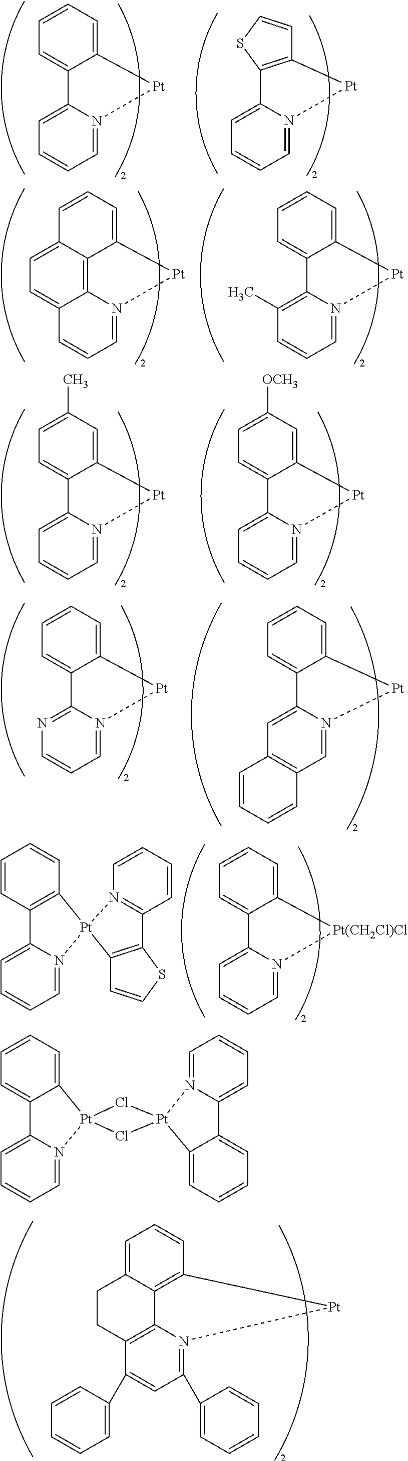

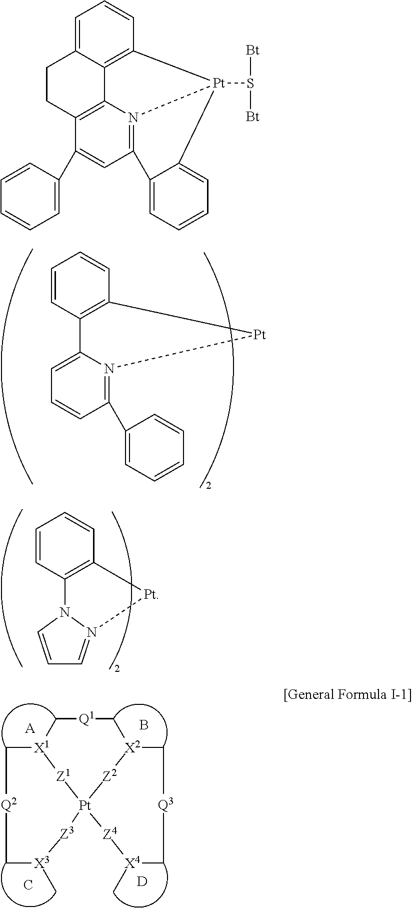

wherein,

any two of ring moieties A, B, C, and D are each a nitrogen-bearing hetero ring that may have a substituent thereon and the other two are each an aryl ring or heteroaryl ring that may have a substituent thereon, wherein a fused ring may be formed between ring moieties A and B, between ring moieties A and C, and/or between ring moieties B and D; any two of X¹, X², X³, and X⁴ are each a nitrogen atom forming a coordinate bond to the platinum atom and the other two are each a carbon atom or a nitrogen atom; Q¹, Q², and Q³ each represent independently a divalent atom (group) or a bond, with a proviso that Q1, Q2, and Q3 all do not represent a bond; and any two of Z¹, Z², Z³, and Z⁴ each represent independently a coordinate bond and the other two each represent independently a covalent bond, an oxygen atom, or a sulfur atom.

Concrete examples of General Formula I-1 include, but are not limited to, the following compounds:

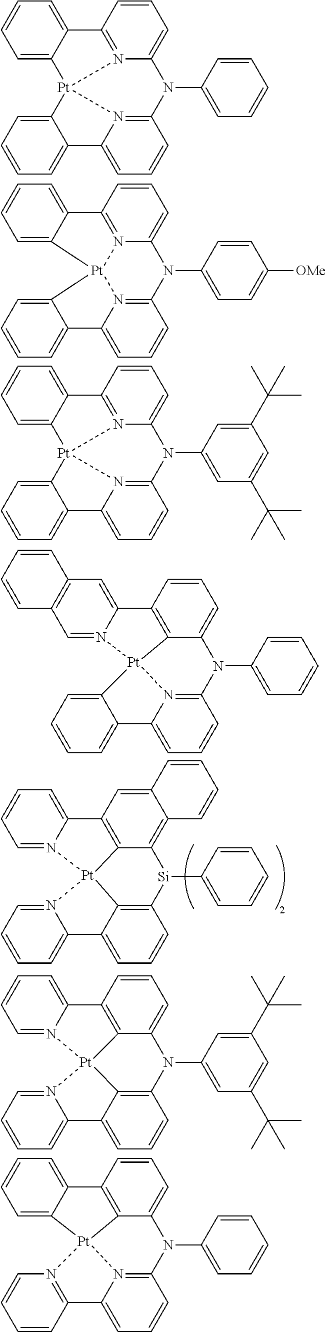

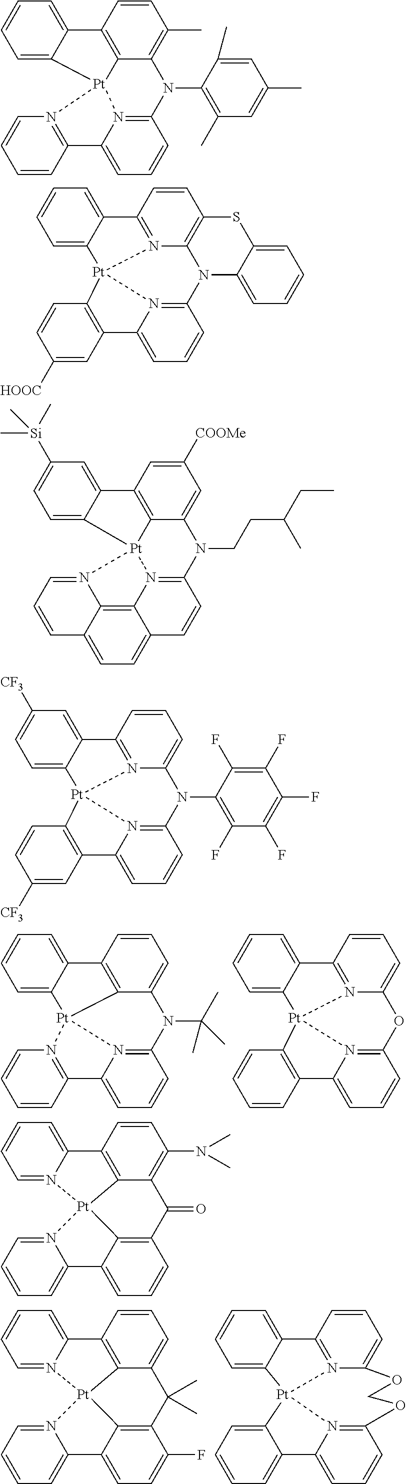

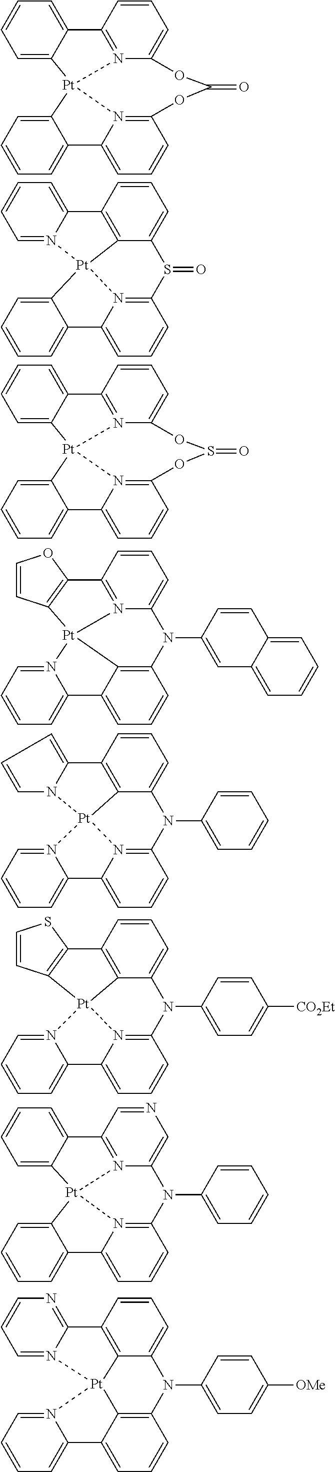

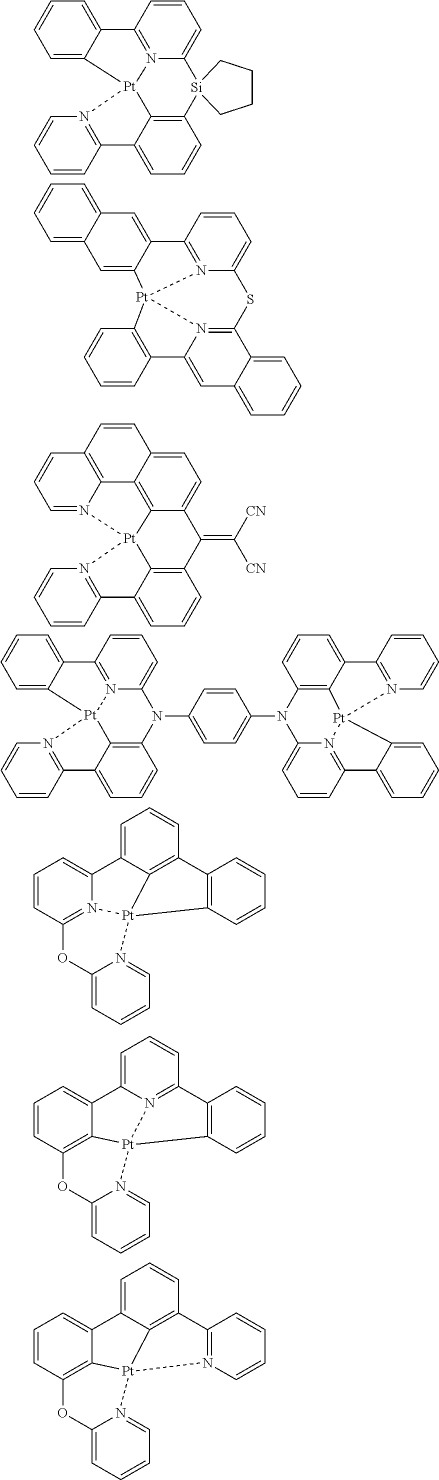

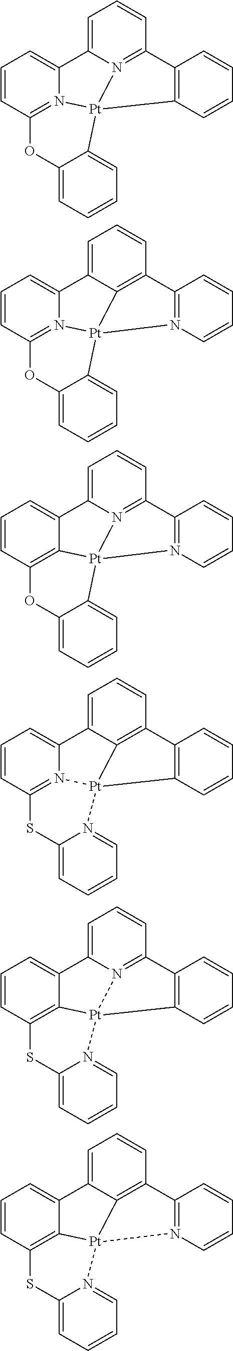

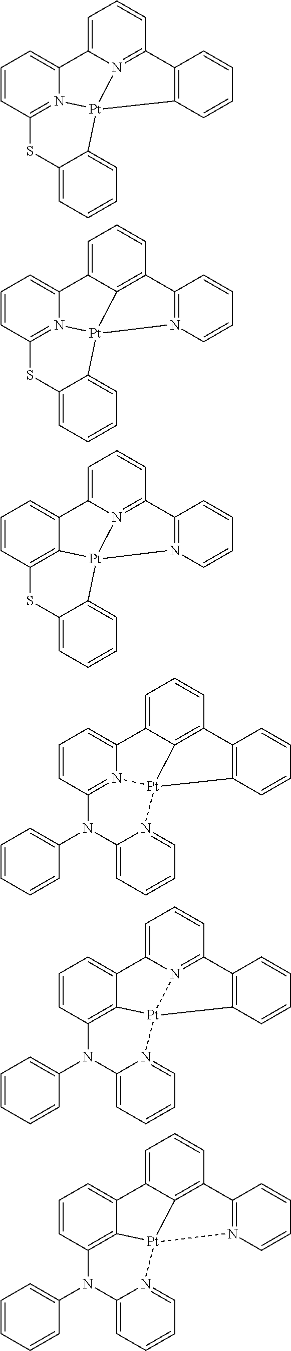

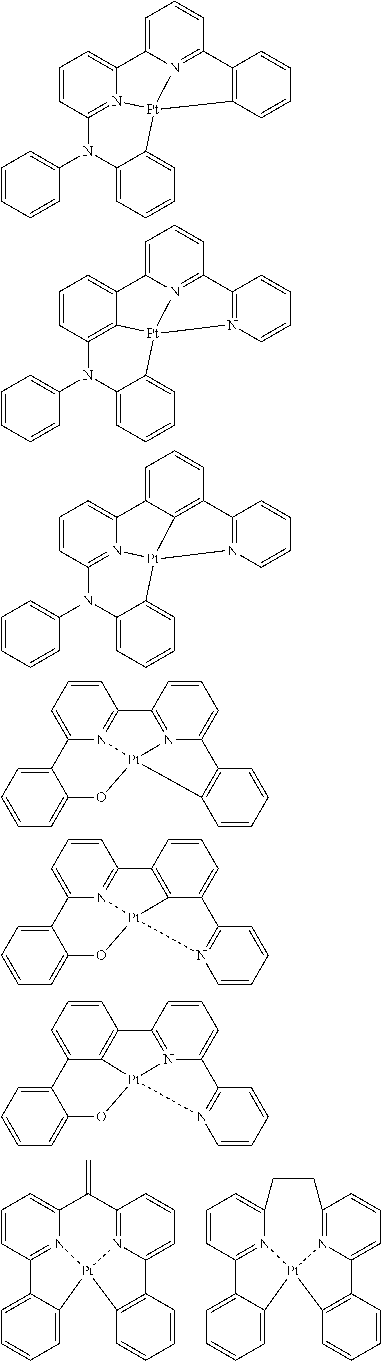

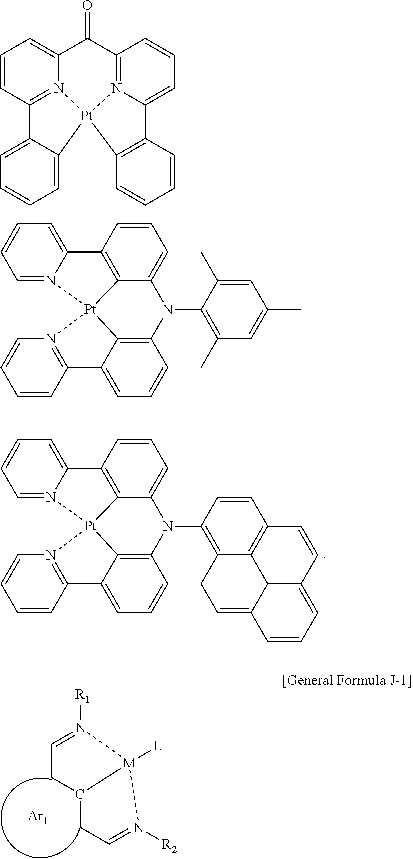

wherein,

M is a metal ion that is same as defined in General Formula A-1; Ar₁ represents a substituted or unsubstituted cyclic structure; the nitrogen atom (N) in each of the two azomethine bond (—C═N—) bonds to M, allowing the entire compound to serve as a tridentate ligand to M.

In addition, C in the Ar₁ moiety stands for a carbon atom as a member of the ring structure. Furthermore, R₁ and R₂, which may be the same or difference, are each independently a substituted or unsubstituted alkyl or aryl, and L represents a monodentate ligand.

In General Formula J-1, M is preferably Pt. In addition, Ar₁ is preferably selected from a 5-membered ring, a 6-membered ring, and a fused ring thereof.

Concrete examples of the compound of General Formula J-1 include, but are not limited to:

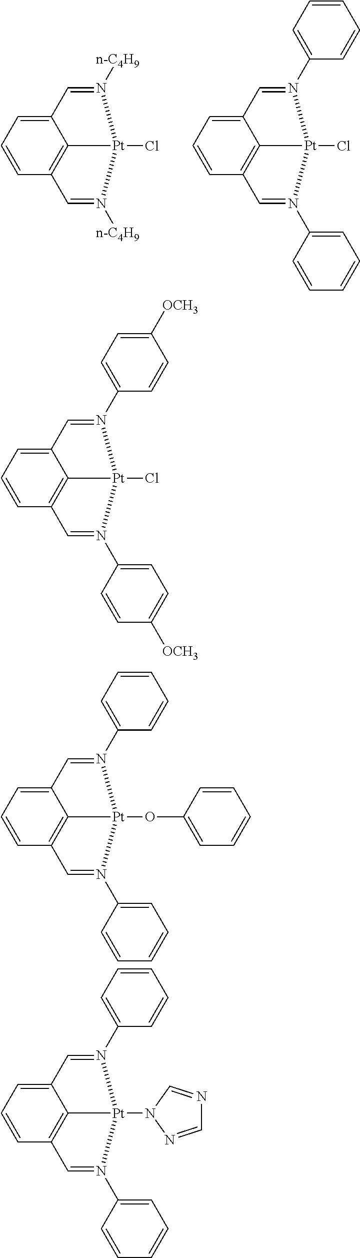

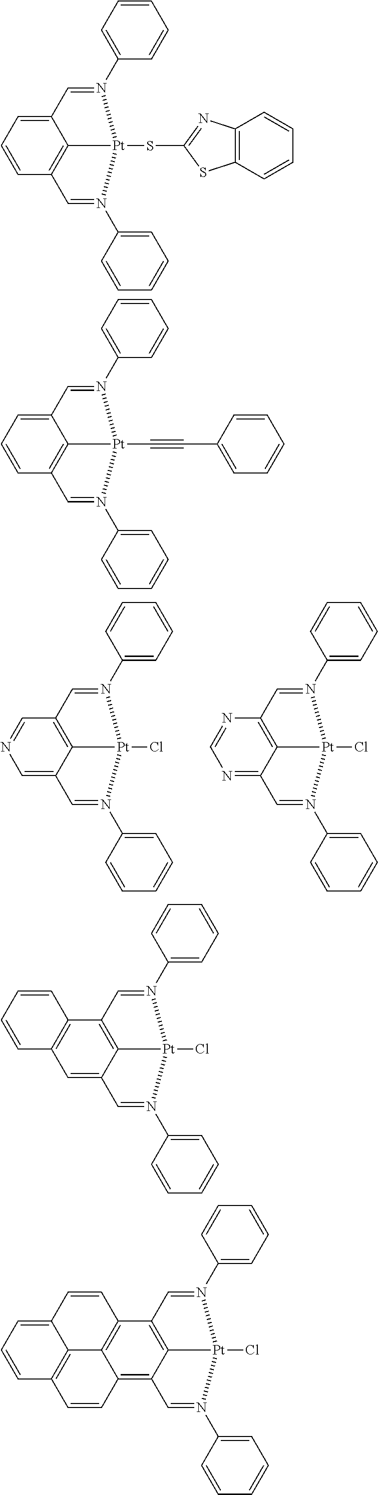

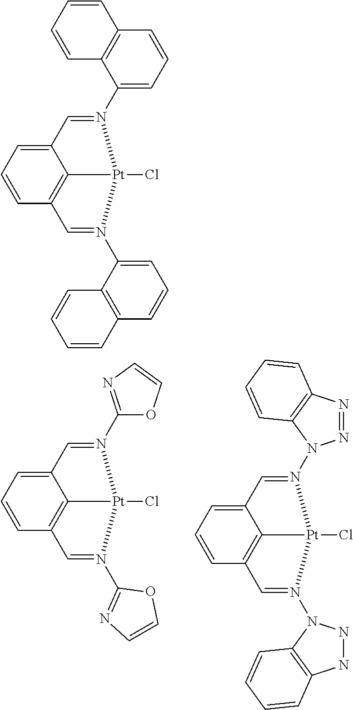

In addition, the light-emitting layer may contain various hosts and various dopants in addition to the host and the dopant.

Given the fused ring compound represented by Chemical Formula A and the hetero ring compound represented by Chemical Formula D in the light-emitting layer thereof, the organic light-emitting diode according to the present disclosure can be operated at a low voltage with more improved emission efficiency and long lifetime characteristics.

Moreover, the organic light-emitting diode according to the present disclosure may further at least one layer selected from a hole injection layer, a hole transport layer, a functional layer capable of both hole injection and hole transport, an electron transport layer, and an electron injecting layer in addition to the light-emitting layer.

Below, the organic light-emitting diode of the present disclosure is explained with reference to the drawing.

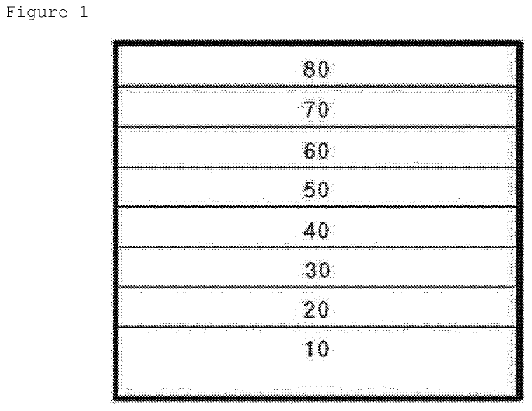

FIG. 1 is a schematic cross-sectional view of the structure of an organic light-emitting diode according to some embodiments of the present disclosure.

As shown in FIG. 1, the organic light-emitting diode comprises an anode 20, a hole transport layer 40, an organic light-emitting layer 50 containing a host and a dopant, an electron transport layer 60, and a cathode 80 in the order and, as such, corresponds to an organic light-emitting diode in which a first electrode and a second electrode serve as an anode and a cathode, respectively, with the deposition of a hole transport layer between the anode and the light-emitting layer and an electron transport layer between the light-emitting layer and the cathode.

In addition, the organic light-emitting diode according to an embodiment of the present disclosure may comprise a hole injection layer 30 between the anode 20 and the hole transport layer 40 and an electron injection layer 70 between the electron transport layer 60 and the cathode 80.

Reference is made to FIG. 1 with regard to the organic light-emitting diode of the present disclosure and a fabrication method therefor.

First, a substrate 10 is coated with an anode electrode material to form an anode 20. So long as it is used in a typical organic EL device, any substrate may be used as the substrate 10. Preferable is an organic substrate or transparent plastic substrate that exhibits excellent transparency, surface smoothness, ease of handling, and waterproofness. As the anode electrode material, indium tin oxide (ITO), indium zinc oxide (IZO), tin oxide (SnO₂), or zinc oxide (ZnO), which are transparent and superior in terms of conductivity, may be used.

A hole injection layer material is applied on the anode electrode 20 by thermal deposition in a vacuum or by spin coating to form a hole injection layer 30. Subsequently, using thermal deposition in a vacuum or spin coating, a hole transport layer material is applied to the hole injection layer 30 to form a hole transport layer 40.

No particular limitations are imparted to the hole injection layer material as long as it is one that is typically used in the art. For example, mention may be made of 2-TNATA [4,4′,4″-tris(2-naphthylphenyl-phenylamino)-triphenylamine], NPD[N,N′-di(1-naphthyl)-N,N′-diphenylbenzidine)], TPD[N,N′-diphenyl-N,N′-bis(3-methylphenyl)-1,1′-biphenyl-4,4′-diamine], or DNTPD[N,N′-diphenyl-N,N′-bis-[4-(phenyl-m-tolylamino)-phenyl]-biphenyl-4,4′-diamine], but the present disclosure is not limited thereby.

So long as it is typically used in the art, any material may be selected for the hole transport layer without particular limitation. Examples include, but are not limited to, N,N′-bis(3-methylphenyl)-N,N′-diphenyl-[1,1-biphenyl]-4,4′-diamine (TPD) and N,N′-di(naphthalen-1-yl)-N,N′-diphenylbenzidine (a-NPD).

Then, a light-emitting layer 50 is deposited on the hole transport layer 40 by deposition in a vacuum or by spin coating.

Here, the light-emitting layer may be composed of a host and a dopant. Materials for the dopant and the host are as described hereinbefore.

In some embodiments of the present disclosure, the light-emitting layer particularly ranges in thickness from 50 to 2,000 Å.

Following the deposition of the electron transport layer 60 on the light-emitting layer by a vacuum deposition method or a spin coating method, an electron injection layer 70 is formed. A cathode metal is deposited on the electron injection layer 70 by thermal deposition in a vacuum to form a cathode 80, thus obtaining an organic light-emitting diode (OLED).

A material for use in the electron transport layer functions to stably carry the electrons injected from the electron injection electrode (cathode), and may be an electron transport material known in the art. Examples of the electron transport material known in the art include quinoline derivatives, particularly, tris(8-quinolinorate)aluminum (Alq₃), TAZ, Balq, beryllium bis(benzoquinolin-10-olate) (Bebq2), compound 201, compound 202, and oxadiazole derivatives such as PBD, BMD, and BND, but are not limited thereto:

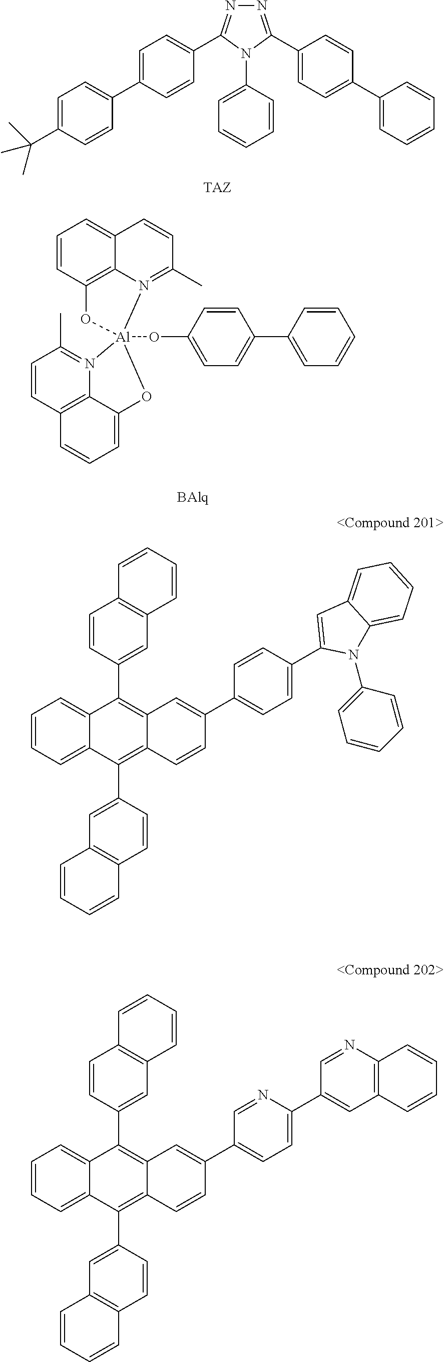

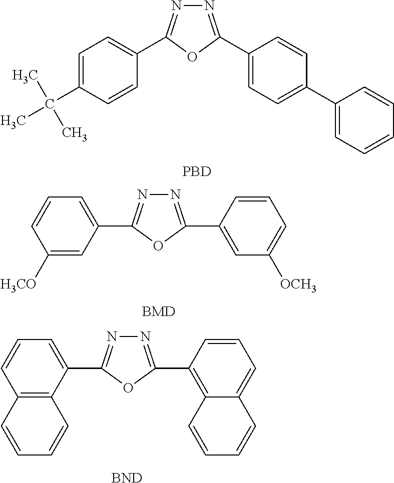

In addition, the electron transport layer in the organic light-emitting diode of the present disclosure may employ the organic metal compound represented by Chemical Formula F alone or in combination with the aforementioned electron transport layer material in the present disclosure:

Yₘ-M-(OA)ₙ [Chemical Formula F]

wherein,

Y is a ligand that contains two moieties respectively responsible for forming a single bond through a direct bond to M and for forming a coordinate bond with M, each moiety being selected from among C, N, O and S, and which is chelated by the single bond and the coordinate bond;

M is an alkali metal, an alkaline earth metal, an aluminum (Al) atom, or a boron (B) atom

wherein

when M is an alkali metal, m=1 and n=0;

when M is an alkaline earth metal, m=1 and n=1, or m=2 and n=0; or

when M is aluminum or a boron, m is an integer of 1 to 3 and n is an integer of 0 to 2, satisfying the relationship m+n=3; and

OA is a monodentate ligand capable of forming a single bond or a coordinate bond with M,

wherein

O is oxygen, and

A is selected from among a substituted or unsubstituted alkyl of 1 to 30 carbon atoms, a substituted or unsubstituted aryl of 5 to 50 carbon atoms, a substituted or unsubstituted alkenyl of 2 to 30 carbon atoms, a substituted or unsubstituted alkynyl of 2 to 20 carbon atoms, a substituted or unsubstituted cycloalkyl of 3 to 30 carbon atoms, a substituted or unsubstituted cycloalkenyl of 5 to 30 carbon atoms, and a substituted or unsubstituted heteroaryl of 2 to 50 carbon atoms bearing at least one of O, N, S, and Si as a heteroatom,

wherein the term ‘substituted’ in the expression “a substituted or unsubstituted” means having at least one substituent selected from the group consisting of a deuterium atom, a cyano, a halogen, a hydroxy, a nitro, an alkyl, an alkoxy, an alkylamino, an arylamino, a heteroarylamino, an alkylsilyl, an arylsilyl, an aryloxy, an aryl, a heteroaryl, a germanium, a phosphorus, and a boron.

In the present disclosure, Y's, which may be the same or different, are each independently one selected from among, but not limited to, the following [Structural Formula C1] to [Structural Formula C39]:

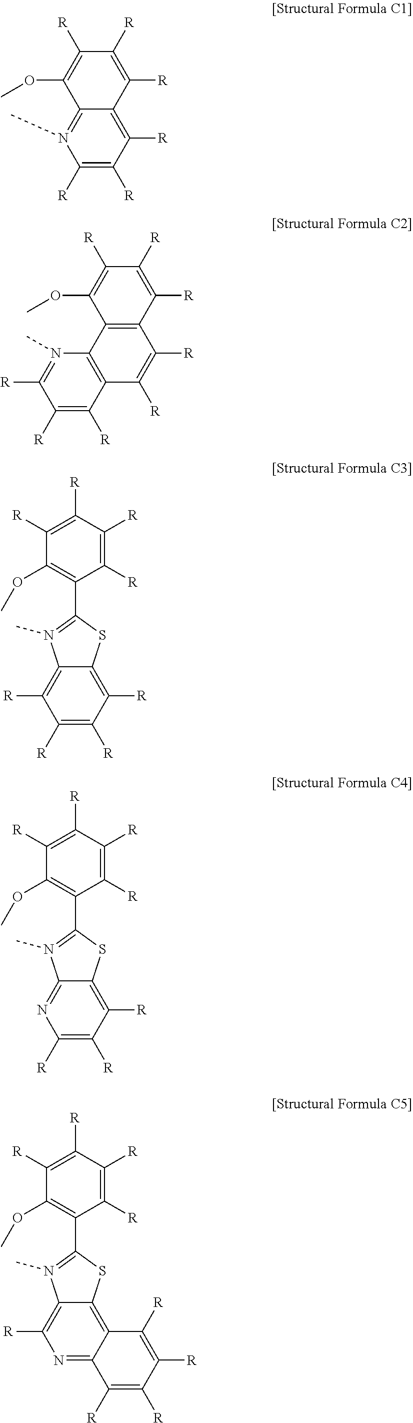

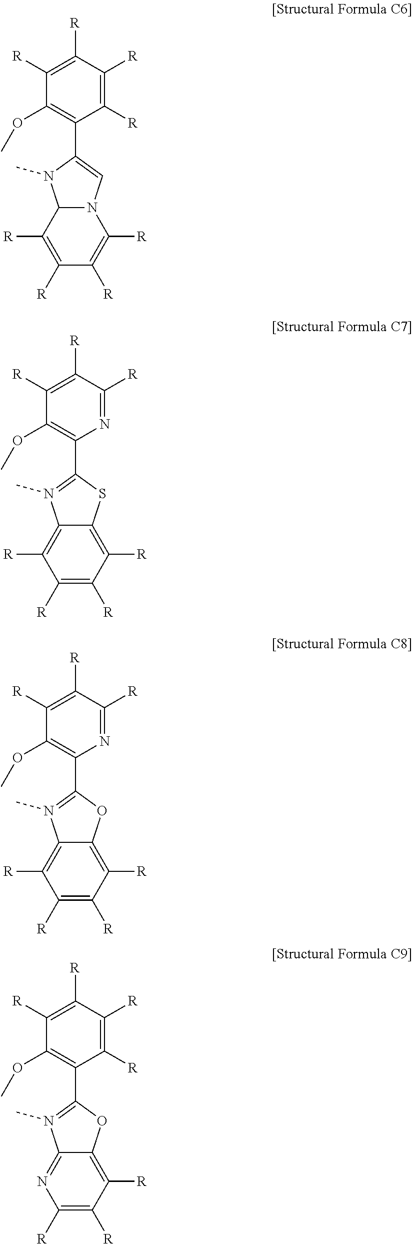

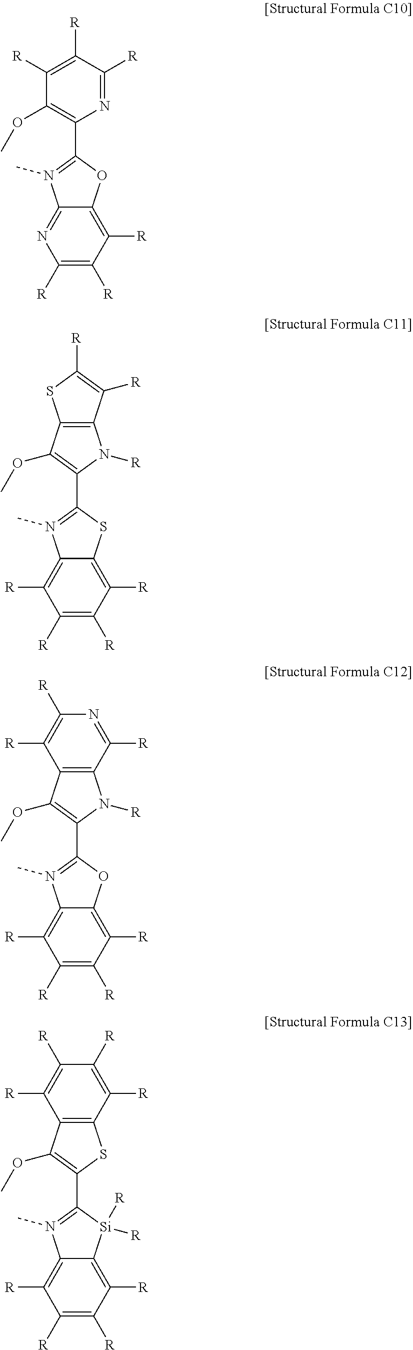

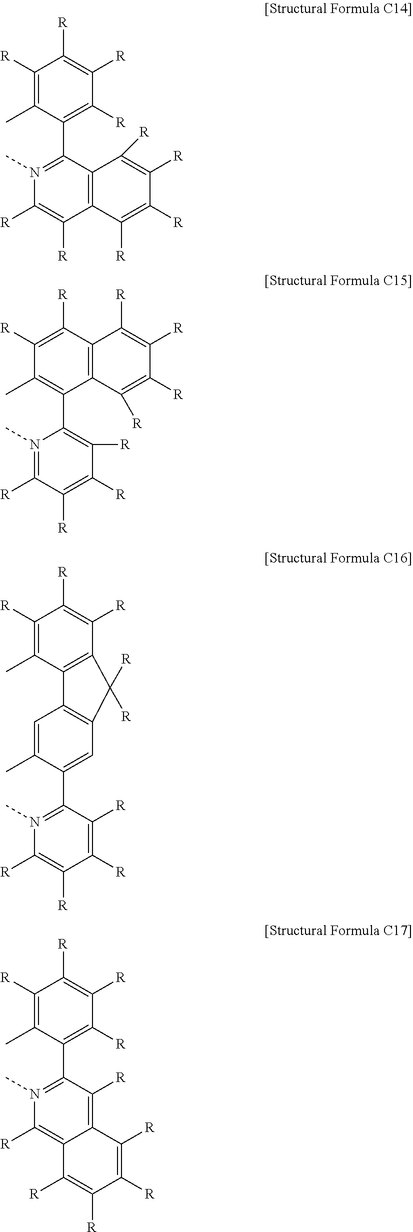

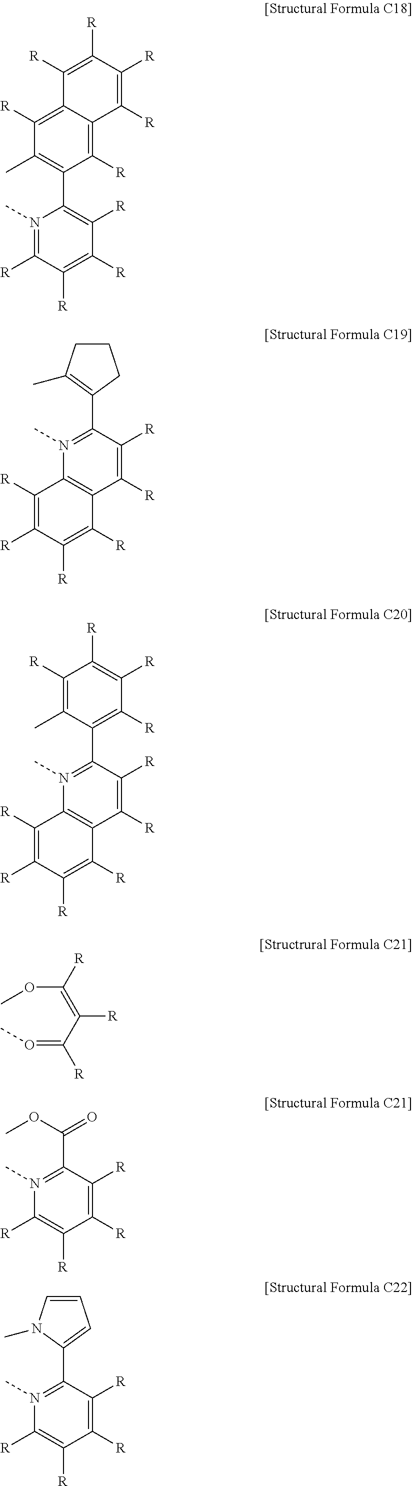

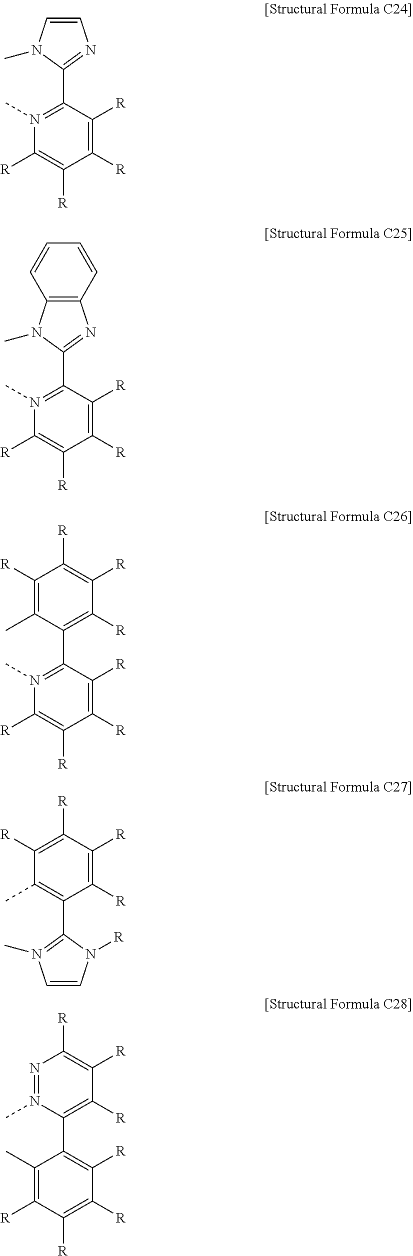

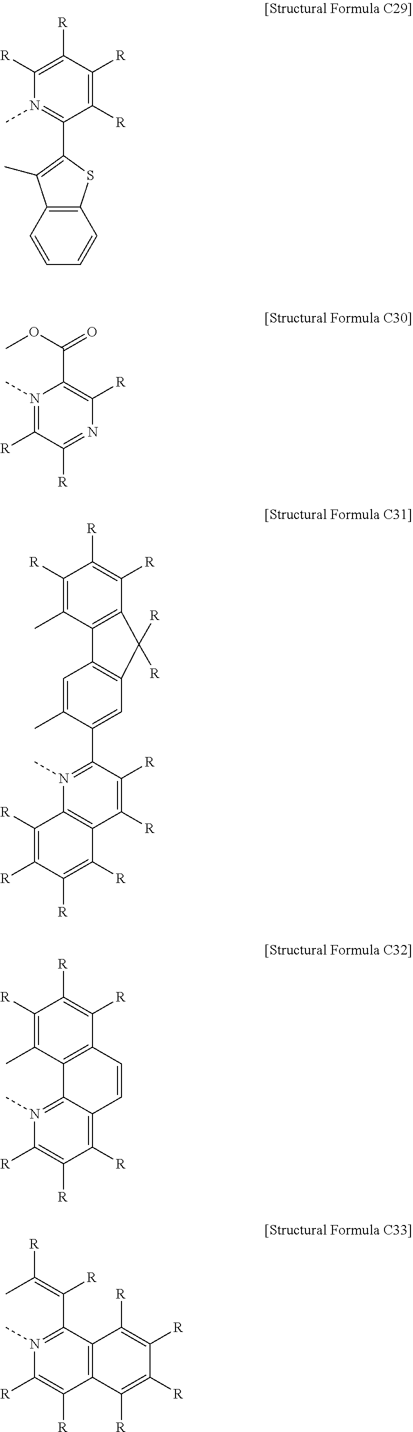

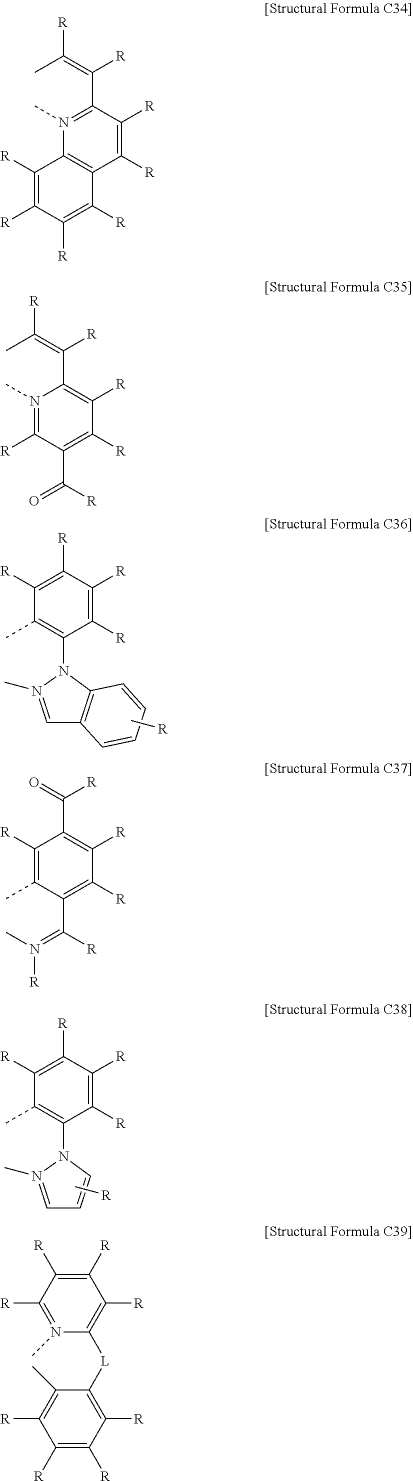

wherein,

R's, which may be the same or different, are each independently selected from among a hydrogen atom, a deuterium atom, a halogen, a cyano, a substituted or unsubstituted alkyl of 1 to 30 carbon atoms, a substituted or unsubstituted aryl of 6 to 30 carbon atoms, a substituted or unsubstituted heteroaryl of 3 to 30 carbon atoms, a substituted or unsubstituted alkoxy of 1 to 30 carbon atoms, a substituted or unsubstituted cycloalkyl of 3 to 30 carbon atoms, a substituted or unsubstituted alkenyl of 2 to 30 carbon atoms, a substituted or unsubstituted alkylamino of 1 to 30 carbon atoms, a substituted or unsubstituted alkylsilyl of 1 to 30 carbon atoms, a substituted or unsubstituted arylamino of 6 to 30 carbon atoms, and a substituted or unsubstituted arylsilyl of 6 to 30 carbon atoms, and may form a spiro or fused ring with an adjacent substituent via an alkylene or alkenylene linker.

An electron injection layer (EIL) that functions to facilitate electron injection from the cathode may be further deposited on the electron transport layer. No particular limitations are imparted to the material of EIL.

So long as it is conventionally used in the art, any material can be available for the electron injection layer without particular limitations. Examples include LiF, NaCl, CsF, NaF, Li₂O, and BaO. A deposition condition of the EIL may vary depending on the compound employed, but may be almost the same as that for the hole injection layer.

The electron injection layer may range in thickness from about 1 Å to about 100 Å and particularly from about 3 Å to about 90 Å. Given the thickness range for the electron injection layer, the diode can exhibit satisfactory electron injection properties without actually elevating a driving voltage.

In order to facilitate electron injection, the cathode may be made of a metal or metal alloy such as lithium (Li), magnesium (Mg), aluminum (Al), aluminum-lithium (Al—Li), calcium (Ca), magnesium-indium (Mg—In), and magnesium-silver (Mg—Ag). Alternatively, ITO or IZO may be employed to form a transparent cathode for a top-emitting organic light-emitting diode.

Moreover, the organic light-emitting diode of the present disclosure may further comprise a light-emitting layer containing a blue, green, or red luminescent material that emits radiations in the wavelength range of 380 nm to 800 nm. That is, the light-emitting layer in the present disclosure has a multilayer structure wherein the blue, green, or red luminescent material may be a fluorescent material or a phosphorescent material.

Furthermore, at least one selected from among the layers may be deposited using a single-molecule deposition process or a solution process.

Here, the deposition process is a process by which a material is vaporized in a vacuum or at a low pressure and deposited to form a layer, and the solution process is a method in which a material is dissolved in a solvent and applied for the formation of a thin film by means of inkjet printing, roll-to-roll coating, screen printing, spray coating, dip coating, spin coating, etc.

Also, the organic light-emitting diode of the present disclosure may be applied to a device selected from among flat display devices, flexible display devices, monochrome or grayscale flat illumination devices, and monochrome or grayscale flexible illumination devices.

A better understanding of the present disclosure may be obtained through the following examples which are set forth to illustrate, but are not to be construed as limiting the present disclosure.

### EXAMPLES

### Synthesis Example 1: Synthesis of Compound H1

### Synthesis Example 1-(1): Synthesis of Intermediate 1-a

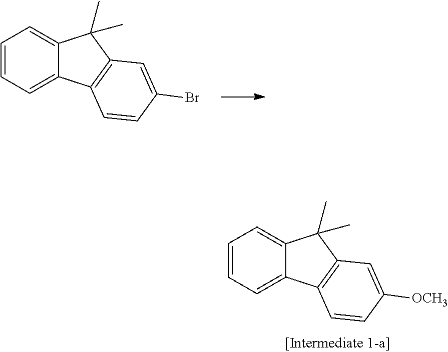 [SMILES: CC1(C)c2ccccc2-c2ccc(Br)cc21 ; COc1ccc2c(c1)C(C)(C)c1ccccc1-2]

In a round-bottom flask, 2-bromo-9,9-dimethylfluorene (50 g, 183 mmol), a sodium methoxide solution (59.3 g, 1098 mmol), copper iodide (10.4 g, 54.9 mmol), and methanol (200 ml) were refluxed for 12 hours under a nitrogen atmosphere. After completion of the reaction, the organic layer was concentrated in a vacuum. Column chromatographic separation and subsequent drying afforded [Intermediate 1-a] (33.2 g, 81%)

### Synthesis Example 1-(2): Synthesis of Intermediate 1-b

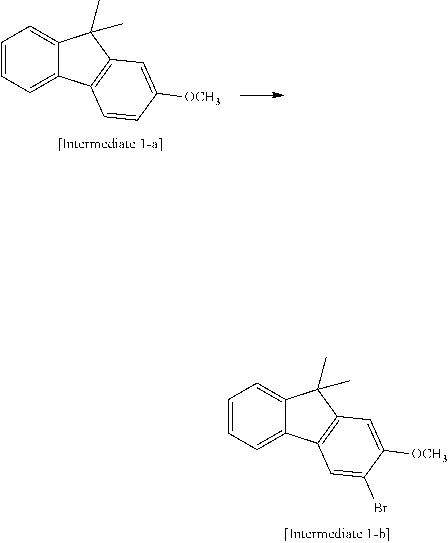 [SMILES: COc1ccc2c(c1)C(C)(C)c1ccccc1-2 ; COc1cc2c(cc1Br)-c1ccccc1C2(C)C]

In a round-bottom flask, [Intermediate 1-a] (30 g, 133 mmol), N-bromosuccinimide (23.8 g, 133 mmol), and dimethylformamide (600 ml) were stirred together at 50° C. for 12 hours under a nitrogen atmosphere. After completion of the reaction, the organic layer was concentrated in a vacuum. Column chromatographic separation and subsequent drying afforded [Intermediate 1-b]. (28 g, 69%)

### Synthesis Example 1-(3): Synthesis of Intermediate 1-c

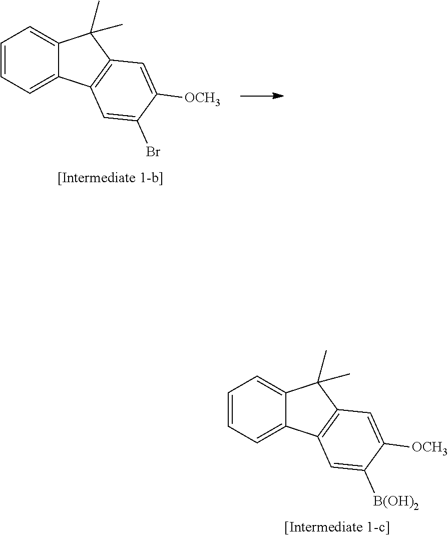 [SMILES: COc1cc2c(cc1Br)-c1ccccc1C2(C)C ; COc1cc2c(cc1B(O)O)-c1ccccc1C2(C)C]

In a round-bottom flask, [Intermediate 1-b] (28 g, 92.4 mmol) was mixed with tetrahydrofuran (280 ml) and cooled to −78° C. under a nitrogen atmosphere, followed by slowly adding drops of 1.6 M butyl lithium (75.1 ml, 120 mmol). One hour later, trimethyl borate (12.5 g, 120 mmol) was slowly fed into the flask, with the low temperature maintained. Subsequently, the reaction mixture was heated to room temperature and then stirred. After completion of the reaction, the organic layer was concentrated in a vacuum, recrystallized in hexane, and dried to afford [Intermediate 1-c]. (21 g, 85%)

### Synthesis Example 1-(4): Synthesis of Intermediate 1-d

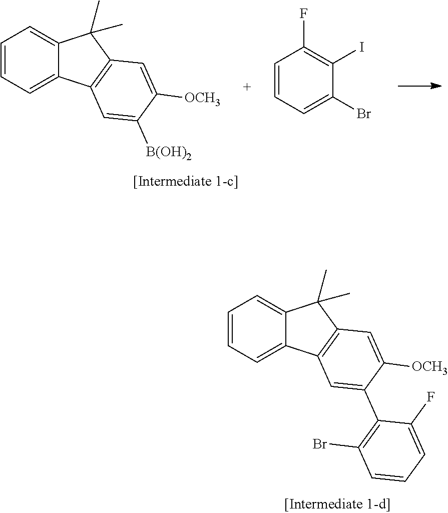 [SMILES: COc1cc2c(cc1B(O)O)-c1ccccc1C2(C)C ; Fc1cccc(Br)c1I ; COc1cc2c(cc1-c1c(F)cccc1Br)-c1ccccc1C2(C)C]

[Intermediate 1-c](21 g, 78.3 mmol), 1-bromo-3-fluoro-2-iodobenzene (18 g, 86.2 mmol), tetrakis(triphenylphosphine)palladium (1.8 g, 2 mmol), potassium carbonate (21.7 g, 156.6 mmol), toluene (105 ml), 1,4-dioxane (105 ml), and water (42 ml) were placed under a nitrogen atmosphere in a round-bottom flask and fluxed for 12 hours. After completion of the reaction, the reaction mixture was layer separated, and the organic layer was concentrated at a reduced pressure. Column chromatographic separation and subsequent drying yielded [Intermediate 1-d]. (20.7 g, 67%)

### Synthesis Example 1-(5): Synthesis of Intermediate 1-e

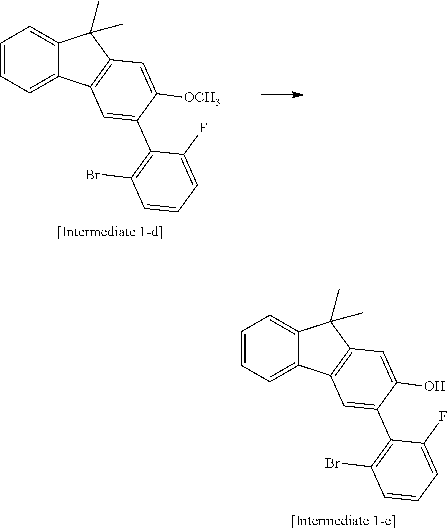 [SMILES: COc1cc2c(cc1-c1c(F)cccc1Br)-c1ccccc1C2(C)C ; CC1(C)c2ccccc2-c2cc(-c3c(F)cccc3Br)c(O)cc21]

In a round-bottom flask, [Intermediate 1-d] (30 g, 75.5 mmol) and dichloromethane (300 ml) were placed under a nitrogen atmosphere, cooled to 0° C., and then slowly added with drops of a dilution of borontribromide (56.7 g, 226.5 mmol) in dichloromethane (150 ml). The reaction mixture was heated to room temperature and stirred for 6 hours. After completion of the reaction, the organic layer was concentrated in a vacuum. Column chromatographic separation and subsequent drying afforded [Intermediate 1-e]. (21.3 g, 74%)

### Synthesis Example 1-(6): Synthesis of Intermediate 1-f

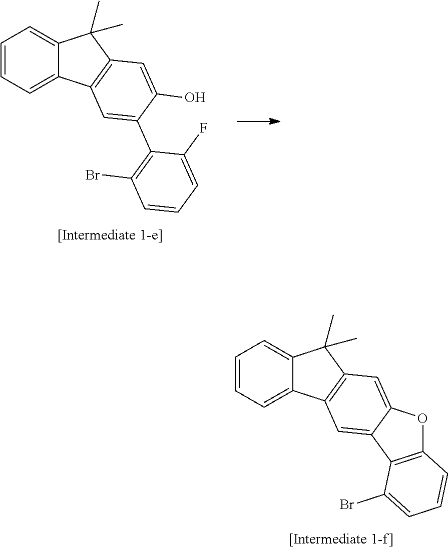 [SMILES: CC1(C)c2ccccc2-c2cc(-c3c(F)cccc3Br)c(O)cc21 ; CC1(C)c2ccccc2-c2cc3c(cc21)oc1cccc(Br)c13]

In a round-bottom flask, [Intermediate 1-e] (20 g, 52.2 mmol), potassium carbonate (11 g, 83.5 mmol), and 1-methyl-2-pyrrolidinone (200 ml) were stirred together at 150° C. for 12 hours under a nitrogen. After completion of the reaction, the organic layer was concentrated in a vacuum. Column chromatographic separation and subsequent drying afforded [Intermediate 1-f]. (13.5 g, 71%)

### Synthesis Example 1-(7): Synthesis of Compound H1

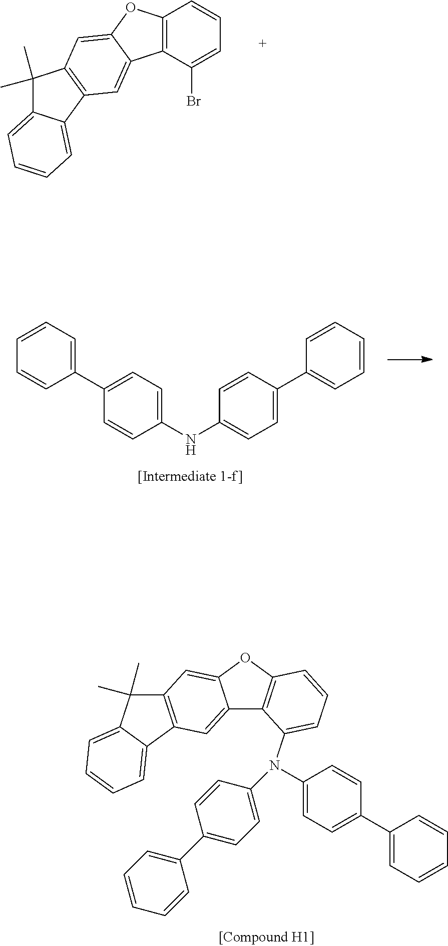 [SMILES: CC1(C)c2ccccc2-c2cc3c(cc21)oc1cccc(Br)c13 ; c1ccc(-c2ccc(Nc3ccc(-c4ccccc4)cc3)cc2)cc1 ; CC1(C)c2ccccc2-c2cc3c(cc21)oc1cccc(N(c2ccc(-c4ccccc4)cc2)c2ccc(-c4ccccc4)cc2)c13]

In a round-bottom flask, [Intermediate 1-f](10 g, 27.5 mmol), bis(biphenyl-4-yl)amine (10.6 g, 33.0 mmol), tris(dibenzylideneacetone)palladium (0.5 g, 0.6 mmol), 2,2′-bis(diphenylphosphino)-1,1′-binaphthyl (1.6 g, 1.1 mmol), sodium-tert-butoxide (5.3 g, 55.1 mmol), and toluene (100 ml) were stirred together for 12 hours under reflux in a nitrogen atmosphere. After completion of the reaction, layers were separated. The organic layer thus obtained was concentrated in a vacuum, followed by purification through column chromatography to afford [Compound H1]. (7.6 g, 46%)

MS (MALDI-TOF): m/z 603.26 [Mt]

### Synthesis Example 2: Synthesis of Compound H2

### Synthesis Example 2-(1): Synthesis of Compound H2

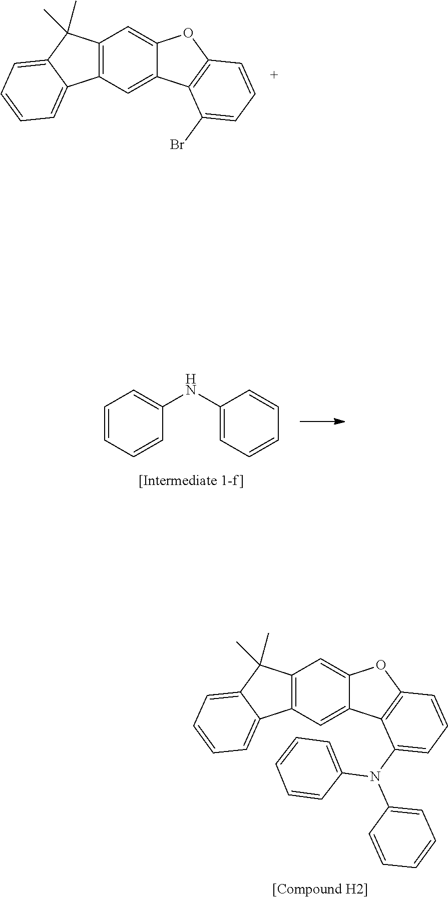 [SMILES: CC1(C)c2ccccc2-c2cc3c(cc21)oc1cccc(Br)c13 ; c1ccc(Nc2ccccc2)cc1 ; CC1(C)c2ccccc2-c2cc3c(cc21)oc1cccc(N(c2ccccc2)c2ccccc2)c13]

The same procedure as in Synthesis Example 1-(7) was carried out, with the exception that diphenylamine was used instead of bis(4-biphenyl)amine, to afford [Compound H2]. (5.8 g, 58%)

MS (MALDI-TOF): m/z 451.19[M⁺]

### Synthesis Example 3: Synthesis of Compound H3

### Synthesis Example 3-(1): Synthesis of Compound H3

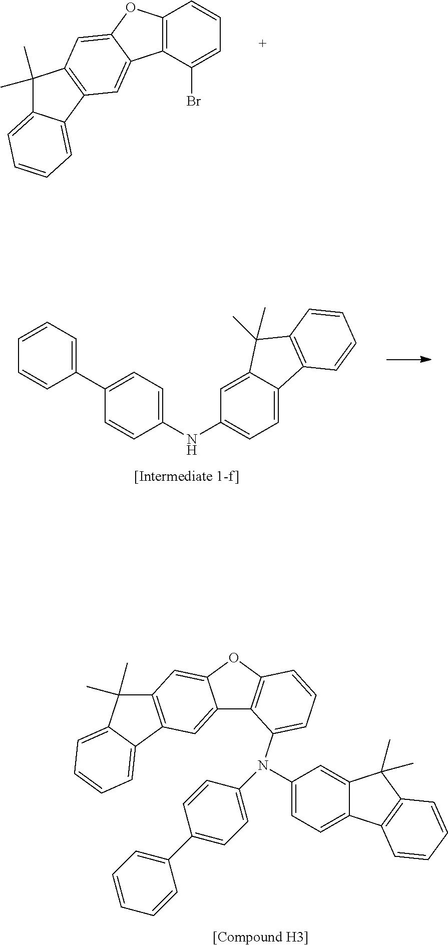 [SMILES: CC1(C)c2ccccc2-c2cc3c(cc21)oc1cccc(Br)c13 ; CC1(C)c2ccccc2-c2ccc(Nc3ccc(-c4ccccc4)cc3)cc21 ; CC1(C)c2ccccc2-c2ccc(N(c3ccc(-c4ccccc4)cc3)c3cccc4oc5cc6c(cc5c34)-c3ccccc3C6(C)C)cc21]

The same procedure as in Synthesis Example 1-(7) was carried out, with the exception that N-([1,1′-biphenyl]4-yl)-9,9-dimethyl-9H-fluorene-2-amine was used instead of bis(4-biphenyl)amine, to afford [Compound H3]. (6.1 g, 72%)

MS (MALDI-TOF): m/z 643.29[M⁺]

### Synthesis Example 4: Synthesis of Compound H4

### Synthesis Example 4-(1): Synthesis of Intermediate 4-a

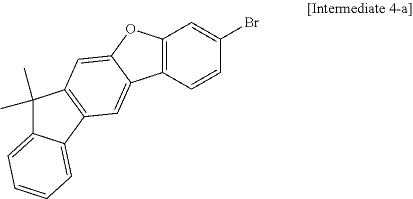 [SMILES: CC1(C)c2ccccc2-c2cc3c(cc21)oc1cc(Br)ccc13]

The same procedures as in Synthesis Examples 1-(1) to 1-(6) were carried out, with the exception that 1-bromo-3-fluoro-4-iodobenzene was used, instead of 1-bromo-3-fluoro-2-iodobenzene, in Synthesis Example 1-(4), to afford [Intermediate 4-a]. (17 g, 66%)

### Synthesis Example 4-(2): Synthesis of Compound H4

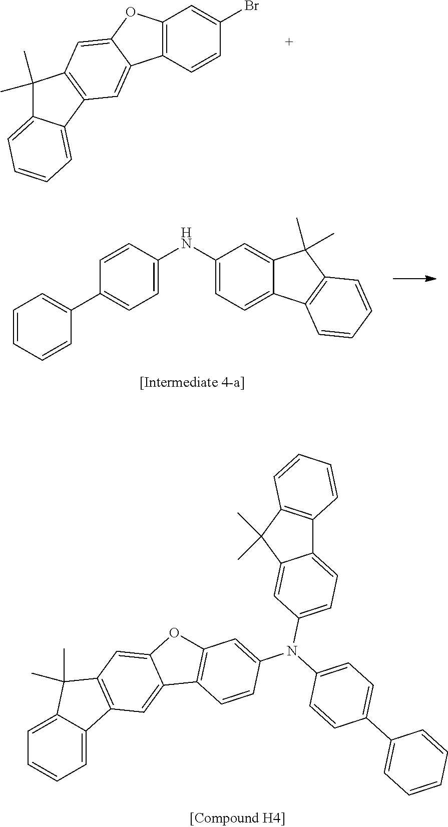 [SMILES: CC1(C)c2ccccc2-c2cc3c(cc21)oc1cc(Br)ccc13 ; CC1(C)c2ccccc2-c2ccc(Nc3ccc(-c4ccccc4)cc3)cc21 ; CC1(C)c2ccccc2-c2ccc(N(c3ccc(-c4ccccc4)cc3)c3ccc4c(c3)oc3cc5c(cc34)-c3ccccc3C5(C)C)cc21]

The same procedure as in Synthesis Example 1-(7) was carried out, with the exception that [Intermediate 4-a] and N-([1,1′-biphenyl]4-yl)-9,9-dimethyl-9H-fluorene-2-amine were used instead of [Intermediate 1-f] and bis(4-biphenyl)amine, respectively, to afford [Compound H4]. (11.3 g, 74%)

MS (MALDI-TOF): m/z 643.29[M⁺]

### Synthesis Example 5: Synthesis of Compound H7

### Synthesis Example 5-(1): Synthesis of Intermediate 5-a

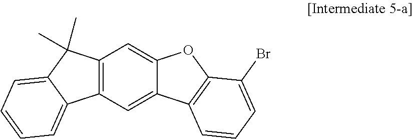 [SMILES: CC1(C)c2ccccc2-c2cc3c(cc21)oc1c(Br)cccc13]

The same procedures as in Synthesis Examples 1-(1) to 1-(6) were carried out, with the exception that 1-bromo-2-fluoro-3-iodobenzene was used, instead of 1-bromo-3-fluoro-2-iodobenzene, in Synthesis Example 1-(4), to afford [Intermediate 5-a]. (13.8 g, 78%)

### Synthesis Example 5-(2): Synthesis of Compound H7

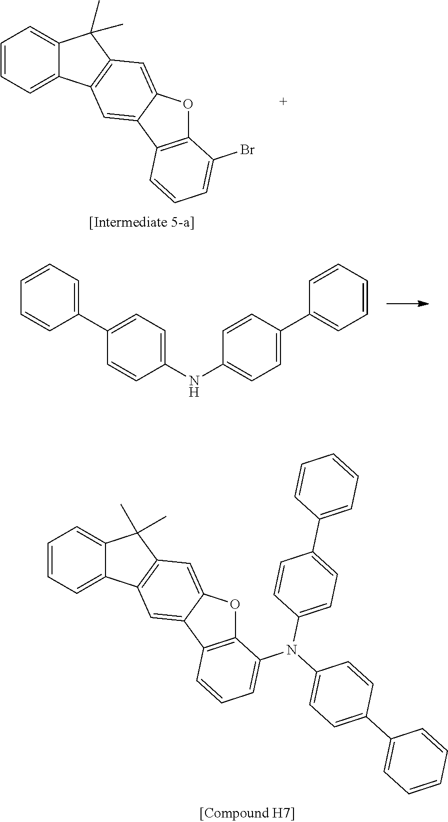 [SMILES: CC1(C)c2ccccc2-c2cc3c(cc21)oc1c(Br)cccc13 ; c1ccc(-c2ccc(Nc3ccc(-c4ccccc4)cc3)cc2)cc1 ; CC1(C)c2ccccc2-c2cc3c(cc21)oc1c(N(c2ccc(-c4ccccc4)cc2)c2ccc(-c4ccccc4)cc2)cccc13]

The same procedure as in Synthesis Example 1-(7) was carried out, with the exception that [Intermediate 5-a] was used instead of [Intermediate 1-f], to afford [Compound H7]. (8.9 g, 55%)

MS (MALDI-TOF): m/z 603.26[M⁺]

### Synthesis Example 6: Synthesis of Compound H9

### Synthesis Example 6-(1): Synthesis of Intermediate 6-a

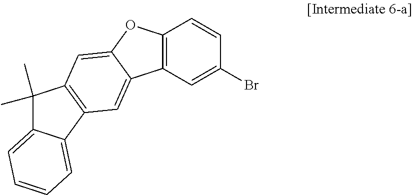 [SMILES: CC1(C)c2ccccc2-c2cc3c(cc21)oc1ccc(Br)cc13]

The same procedures as in Synthesis Examples 1-(1) to 1-(6) were carried out, with the exception that 4-bromo-1-fluoro-2-iodobenzene was used, instead of 1-bromo-3-fluoro-2-iodobenzene, in Synthesis Example 1-(4), to afford [Intermediate 6-a]. (19.2 g, 85%)

### Synthesis Example 6-(2): Synthesis of Compound H9

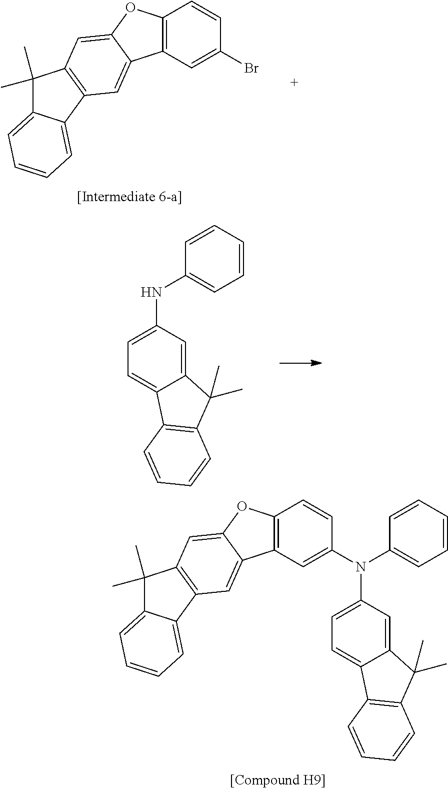 [SMILES: CC1(C)c2ccccc2-c2cc3c(cc21)oc1ccc(Br)cc13 ; CC1(C)c2ccccc2-c2ccc(Nc3ccccc3)cc21 ; CC1(C)c2ccccc2-c2ccc(N(c3ccccc3)c3ccc4oc5cc6c(cc5c4c3)-c3ccccc3C6(C)C)cc21]

The same procedure as in Synthesis Example 1-(7) was carried out, with the exception that [Intermediate 6-a] and N-phenyl-(9,9-dimethyl-9H-fluoren-2-yl)amine were used instead of [Intermediate 1-f] and bis(4-biphenyl)amine, respectively, to afford [Compound H9]. (11.1 g, 78%)

MS (MALDI-TOF): m/z 567.26[M⁺]

### Synthesis Example 7: Synthesis of Compound H93

### Synthesis Example 7-(1): Synthesis of Intermediate 7-a

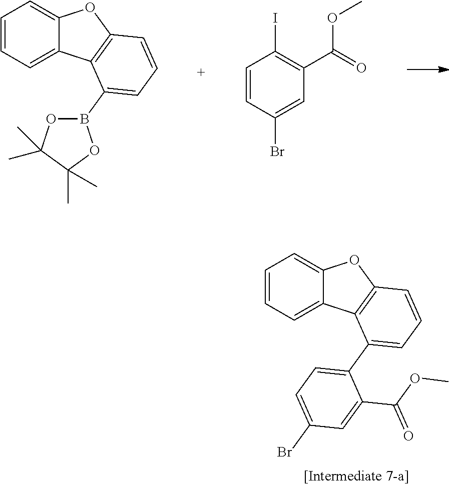 [SMILES: CC1(C)OB(c2cccc3oc4ccccc4c23)OC1(C)C ; COC(=O)c1cc(Br)ccc1I ; COC(=O)c1cc(Br)ccc1-c1cccc2oc3ccccc3c12]

The same procedure as in Synthesis Example 1-(4) was carried out, with the exception that 1-dibenzofuran borate and 5-bromo-2-iodobenzoic acid methyl ester was used instead of [Intermediate 1-c] and 1-bromo-3-fluoro-2-iodobenzene, respectively, to afford [Intermediate 7-a]. (33.5 g, 74%)

### Synthesis Example 7-(2): Synthesis of Intermediate 7-b

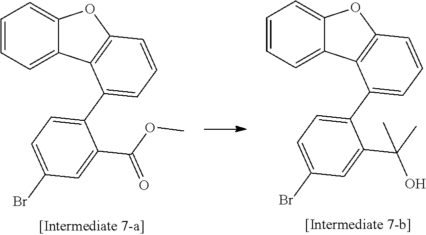 [SMILES: COC(=O)c1cc(Br)ccc1-c1cccc2oc3ccccc3c12 ; CC(C)(O)c1cc(Br)ccc1-c1cccc2oc3ccccc3c12]

In a round-bottom flask, [Intermediate 7-a] (33.5 g, 88 mmol) was added to tetrahydrofuran (150 ml) and cooled to −10° C. before slow addition of drops of 3 M methyl magnesium bromide (85 ml, 254 mmol) thereto. After the temperature was elevated to 40° C., stirring was performed for 4 hrs. Then, the temperature was reduced to −10° C. and drops of 2 N HCl (70 ml) were slowly added. Subsequently, an aqueous ammonium chloride solution (70 ml) was added, followed by elevation to room temperature. After completion of the reaction, the reaction mixture was washed with water and extracted with ethyl acetate. Layer separation gave the organic layer which was then concentrated in a vacuum and separated by column chromatography to afford [Intermediate 7-b]. (27 g, 81%)

### Synthesis Example 7-(3): Synthesis of Intermediate 7-c

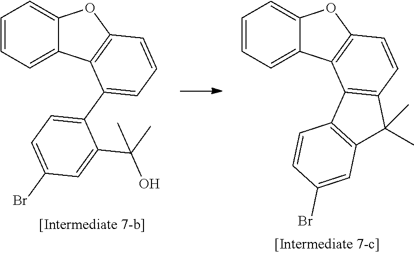 [SMILES: CC(C)(O)c1cc(Br)ccc1-c1cccc2oc3ccccc3c12 ; CC1(C)c2cc(Br)ccc2-c2c1ccc1oc3ccccc3c21]

In a round-bottom flask, [Intermediate 7-b] (27 g, 70.8 mmol) was stirred, together with phosphoric acid (70 ml), at room temperature for 12 hours under a nitrogen atmosphere. After completion of the reaction, extraction was conducted with ethyl acetate and water. The organic layer thus formed was concentrated, followed by isolation through column chromatography and subsequent drying to afford [Intermediate 7-c]. (17.6 g, 68%)

### Synthesis Example 7-(4): Synthesis of Compound H81

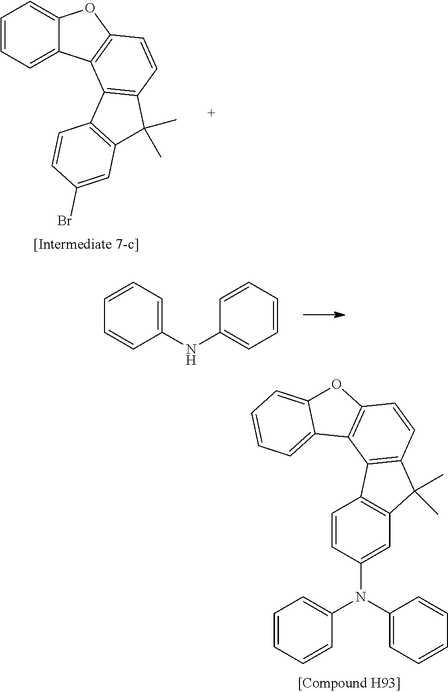 [SMILES: CC1(C)c2cc(Br)ccc2-c2c1ccc1oc3ccccc3c21 ; c1ccc(Nc2ccccc2)cc1 ; CC1(C)c2cc(N(c3ccccc3)c3ccccc3)ccc2-c2c1ccc1oc3ccccc3c21]

The same procedure as in Synthesis Example 1-(7) was carried out, with the exception that [Intermediate 7-c] and diphenylamine were used instead of [Intermediate 1-f] and bis(4-biphenyl)amine, respectively, to afford [Compound H93]. (12.2 g, 56%)

MS (MALDI-TOF): m/z 451.19[M⁺]

### Synthesis Example 8: Synthesis of Compound H94

### Synthesis Example 8-(1): Synthesis of Intermediate 8-a

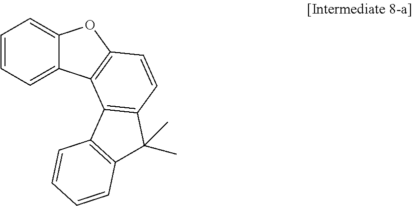 [SMILES: CC1(C)c2ccccc2-c2c1ccc1oc3ccccc3c21]

The same procedures as in Synthesis Example 7-(1) to 7-(3) were carried out, with the exception that o-iodo-methyl-benzoic acid was used, instead of 5-bromo-2-iodobenzoic acid methylester, in Synthesis Example 7-(1), to afford [Intermediate 8-a]. (12.3 g, 66%)

### Synthesis Example 8-(2): Synthesis of Intermediate 8-b

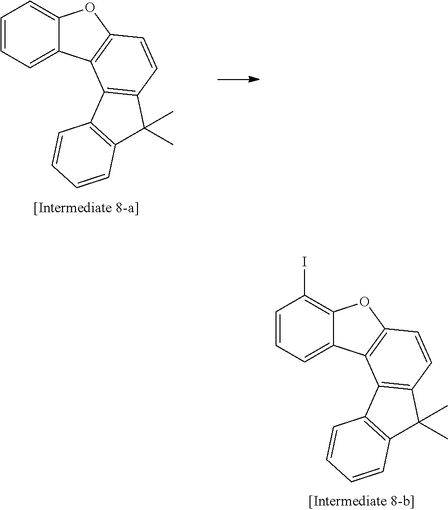 [SMILES: CC1(C)c2ccccc2-c2c1ccc1oc3ccccc3c21 ; CC1(C)c2ccccc2-c2c1ccc1oc3c(I)cccc3c21]

In a round-bottom flask, [Intermediate 8-a] (15 g, 52.8 mmol) was mixed with tetrahydrofuran (105 ml) under a nitrogen atmosphere and then chilled to −78° C. before slow addition of drops of 1.6 M n-butyl lithium (46.2 ml, 7.4 mmol). After stirring at room temperature for 12 hours, the reaction mixture was chilled again to −78° C. and then added slowly with iodine (16.1 g, 63.3 mmol) while the temperature was kept low. Thereafter, stirring was continued for 1 hr at room temperature. After completion of the reaction, the mixture was separated into layers. The organic layer thus formed was concentrated in a vacuum and isolated by column chromatography, followed by recrystallization in hexane and subsequent drying to afford [Intermediate 8-b]. (8 g, 37%)

### Synthesis Example 8-(3): Synthesis of Compound H94

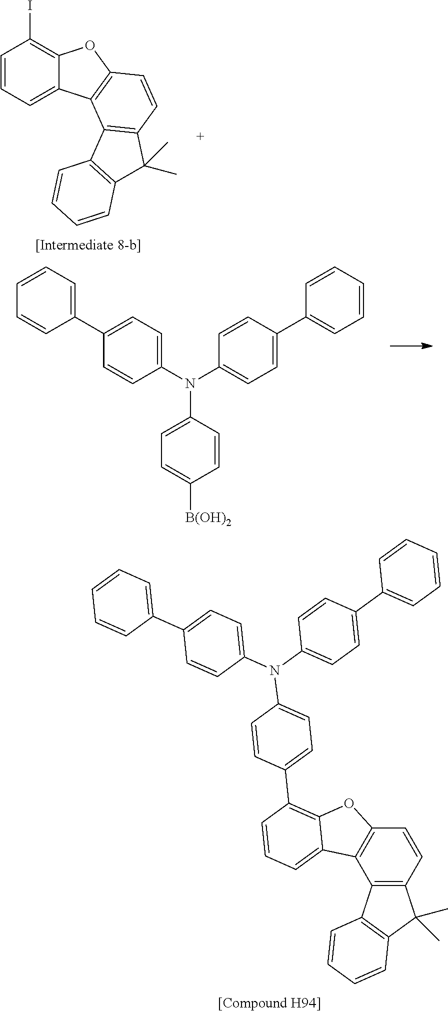 [SMILES: CC1(C)c2ccccc2-c2c1ccc1oc3c(I)cccc3c21 ; OB(O)c1ccc(N(c2ccc(-c3ccccc3)cc2)c2ccc(-c3ccccc3)cc2)cc1 ; CC1(C)c2ccccc2-c2c1ccc1oc3c(-c4ccc(N(c5ccc(-c6ccccc6)cc5)c5ccc(-c6ccccc6)cc5)cc4)cccc3c21]

The same procedure as in Synthesis Example 1-(4) was carried out, with the exception that (4-(di([1,1′-biphenyl]-4-yl)amino)phenyl)boronic acid and [Intermediate 8-b] were used instead of [Intermediate 1-c] and 1-bromo-3-fluoro-2-iodobenzene, to afford [Compound H94]. (6.9 g, 52%)

MS (MALDI-TOF): m/z 679.29[M⁺]

### Synthesis Example 9: Synthesis of Compound H105

### Synthesis Example 9-(1): Synthesis of Intermediate 9-a

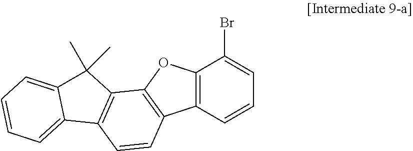 [SMILES: CC1(C)c2ccccc2-c2ccc3c(oc4c(Br)cccc43)c21]

The same procedures as in Synthesis Example 7-(1) to 7-(3) were carried out, with the exception that dibenzofuran-3-boronic acid and methyl-2-bromobenzoate were used, instead of 1-dibenzofuran borate and 5-bromo-2-iodobenzoic acid methylester in Synthesis Example 7-(1), to afford <Intermediate 9-a>. (11.1 g, 77%)

### Synthesis Example 9-(2): Synthesis of Intermediate 9-b

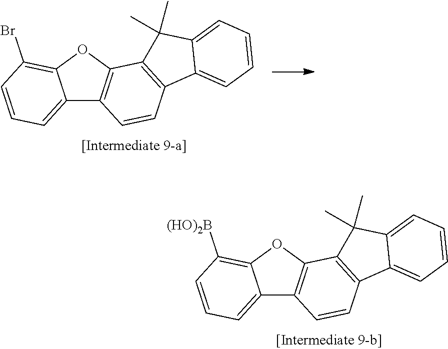 [SMILES: CC1(C)c2ccccc2-c2ccc3c(oc4c(Br)cccc43)c21 ; CC1(C)c2ccccc2-c2ccc3c(oc4c(B(O)O)cccc43)c21]

The same procedure as in Synthesis Example 1-(3) was carried out, with the exception that [Intermediate 9-a] was used instead of [Intermediate 1-b], to afford [Intermediate 9-b]. (9.2 g, 68%)

### Synthesis Example 9-(3): Synthesis of Compound H105

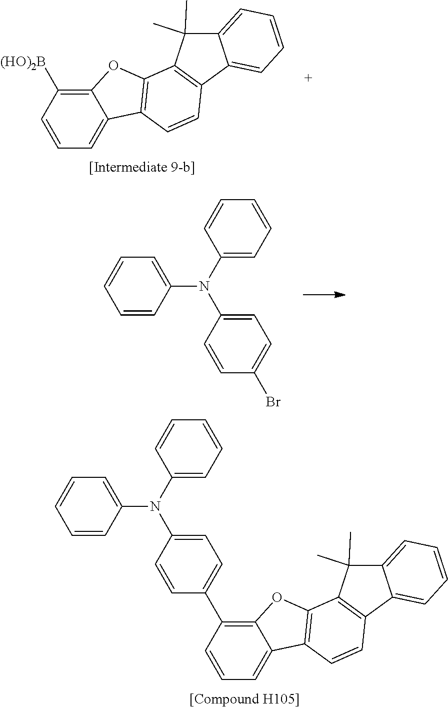 [SMILES: CC1(C)c2ccccc2-c2ccc3c(oc4c(B(O)O)cccc43)c21 ; Brc1ccc(N(c2ccccc2)c2ccccc2)cc1 ; CC1(C)c2ccccc2-c2ccc3c(oc4c(-c5ccc(N(c6ccccc6)c6ccccc6)cc5)cccc43)c21]

The same procedure as in Synthesis Example 1-(4) was carried out, with the exception that [Intermediate 9-b] and (4-bromophenyl)diphenylamine were used instead of [Intermediate 1-c] and 1-bromo-3-fluoro-2-iodobenzene, respectively, to afford [Compound H105]. (7.9 g, 63%)

MS (MALDI-TOF): m/z 527.22[M⁺]

### Synthesis Example 10: Synthesis of Compound H109

### Synthesis Example 10-(1): Synthesis of Intermediate 10-a

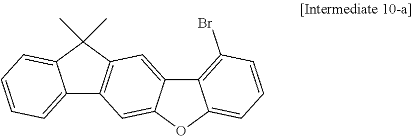 [SMILES: CC1(C)c2ccccc2-c2cc3oc4cccc(Br)c4c3cc21]

The same procedures as in Synthesis Examples 1-(1) to 1-(6) were carried out, with the exception that 3-bromo-9,9-dimethylfluorene was used instead of 2-bromo-9,9-dimethylfluorene in Synthesis Example 1-(1), to afford [Intermediate 10-a]. (13.1 g, 79%)

### Synthesis Example 10-(2): Synthesis of Compound H109

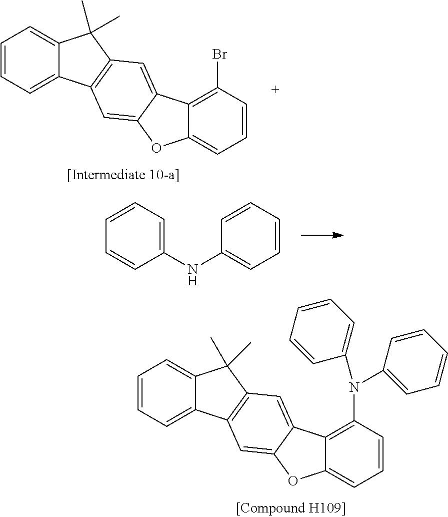 [SMILES: CC1(C)c2ccccc2-c2cc3oc4cccc(Br)c4c3cc21 ; c1ccc(Nc2ccccc2)cc1 ; CC1(C)c2ccccc2-c2cc3oc4cccc(N(c5ccccc5)c5ccccc5)c4c3cc21]

The same procedure as in Synthesis Example 1-(7) was carried out, with the exception that [Intermediate 10-a] and diphenylamine were used instead of [Intermediate 1-f] and bis(4-biphenyl)amine, to afford [Compound H109]. (10.9 g, 62%)

MS (MALDI-TOF): m/z 451.19[M⁺]

### Synthesis Example 11: Synthesis of Compound H110

### Synthesis Example 11-(1): Synthesis of Intermediate 11-a

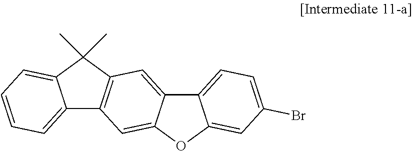 [SMILES: CC1(C)c2ccccc2-c2cc3oc4cc(Br)ccc4c3cc21]

The same procedures as in Synthesis Examples 1-(1) to 1-(6) were carried out, with the exception that 3-bromo-9,9-dimethylfluorene and 1-bromo-3-fluoro-4-iodobenzene were used instead of 2-bromo-9,9-dimethylfluorene in Synthesis Example 1-(1) and 1-bromo-3-fluoro-2-iodobenzene in Synthesis Example 1-(4), respectively, to afford [Intermediate 11-a]. (9.5 g, 79%)

### Synthesis Example 11-(2): Synthesis of Compound H110

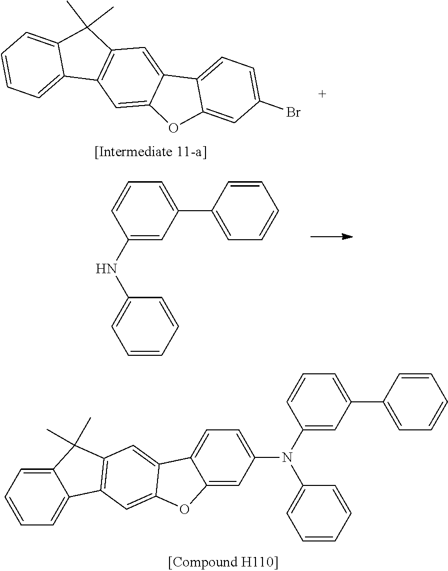 [SMILES: CC1(C)c2ccccc2-c2cc3oc4cc(Br)ccc4c3cc21 ; c1ccc(Nc2cccc(-c3ccccc3)c2)cc1 ; CC1(C)c2ccccc2-c2cc3oc4cc(N(c5ccccc5)c5cccc(-c6ccccc6)c5)ccc4c3cc21]

The same procedure as in Synthesis Example 1-(7) was carried out, with the exception that [Intermediate 11-a] and N-phenyl-[1,1′-biphenyl]-3-amine were used instead of [Intermediate 1-f] and bis(4-biphenyl)amine, respectively, to afford [Compound H110]. (7.9 g, 84%)

MS (MALDI-TOF): m/z 527.22[M⁺]

### Synthesis Example 12: Synthesis of Compound H111

### Synthesis Example 12-(1): Synthesis of Intermediate 12-a

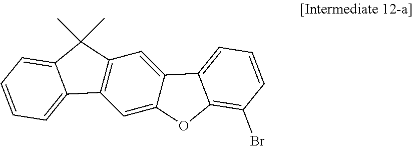 [SMILES: CC1(C)c2ccccc2-c2cc3oc4c(Br)cccc4c3cc21]

The same procedures as in Synthesis Examples 1-(1) to 1-(6) were carried out, with the exception that 3-bromo-9,9-dimethylfluorene and 1-bromo-2-fluoro-3-iodobenzene were used instead of 2-bromo-9,9-dimethylfluorene in Synthesis Example 1-(1) and 1-bromo-3-fluoro-2-iodobenzene in Synthesis Example 1-(4), respectively, to afford [Intermediate 12-a]. (12.3 g, 82%)

### Synthesis Example 12-(2): Synthesis of Compound H111

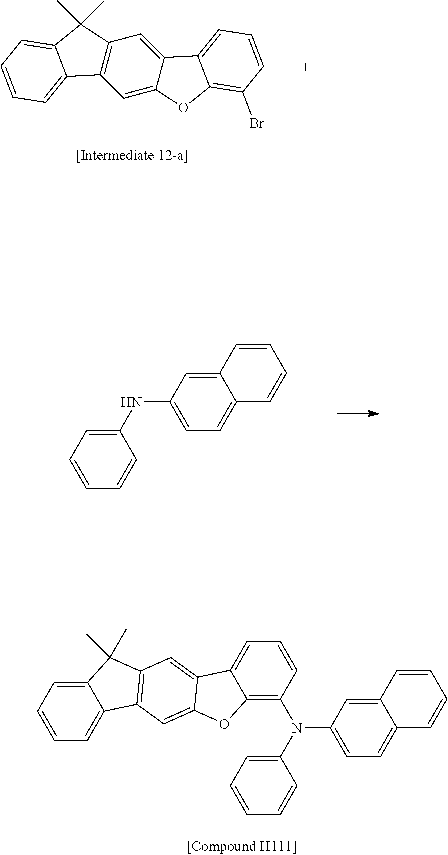 [SMILES: CC1(C)c2ccccc2-c2cc3oc4c(Br)cccc4c3cc21 ; c1ccc(Nc2ccc3ccccc3c2)cc1 ; CC1(C)c2ccccc2-c2cc3oc4c(N(c5ccccc5)c5ccc6ccccc6c5)cccc4c3cc21]

The same procedure as in Synthesis Example 1-(7) was carried out, with the exception that [Intermediate 12-a] and N-phenyl-2-naphthylamine were used instead of [Intermediate 1-f] and bis(4-biphenyl)amine, respectively, to afford [Compound H111]. (9.8 g, 61%)

MS (MALDI-TOF): m/z 501.21[M⁺]

### Synthesis Example 13: Synthesis of Compound H112

### Synthesis Example 13-(1): Synthesis of Intermediate 13-a

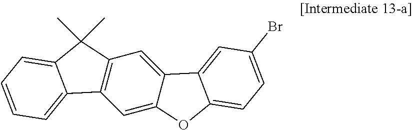 [SMILES: CC1(C)c2ccccc2-c2cc3oc4ccc(Br)cc4c3cc21]

The same procedures as in Synthesis Examples 1-(1) to 1-(6) were carried out, with the exception that 3-bromo-9,9-dimethylfluorene and 4-bromo-1-fluoro-2-iodobenzene were used instead of 2-bromo-9,9-dimethylfluorene in Synthesis Example 1-(1) and 1-bromo-3-fluoro-2-iodobenzene in Synthesis Example 1-(4), to afford [Intermediate 13-a]. (10.3 g, 77%)

### Synthesis Example 13-(2): Synthesis of Compound H112

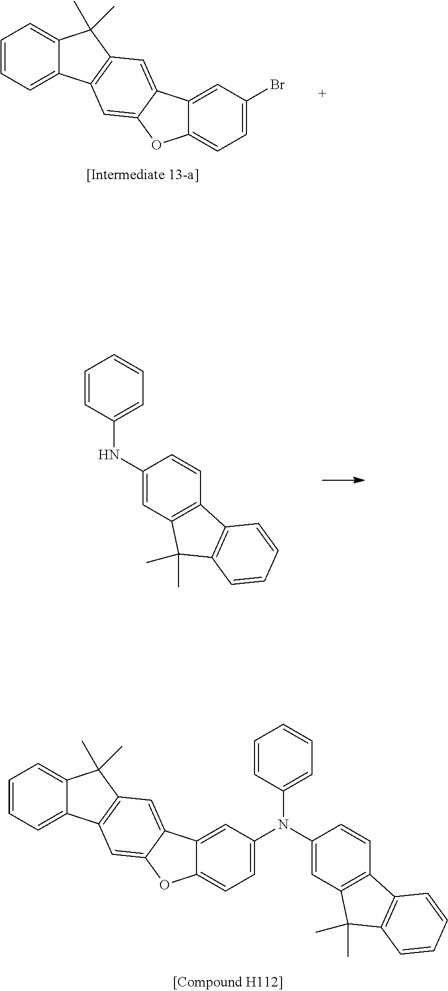 [SMILES: CC1(C)c2ccccc2-c2cc3oc4ccc(Br)cc4c3cc21 ; CC1(C)c2ccccc2-c2ccc(Nc3ccccc3)cc21 ; CC1(C)c2ccccc2-c2ccc(N(c3ccccc3)c3ccc4oc5cc6c(cc5c4c3)C(C)(C)c3ccccc3-6)cc21]

The same procedure as in Synthesis Example 1-(7) was carried out, with the exception that [Intermediate 13-a] and N-phenyl-(9,9-dimethyl-9H-fluoren-2-yl)amine were used instead of [Intermediate 1-f] and bis(4-biphenyl)amine, to afford [Compound H112]. (7.8 g, 71%)

MS (MALDI-TOF): m/z 567.26[M⁺]

### Synthesis Example 14: Synthesis of Compound H137

### Synthesis Example 14-(1): Synthesis of Intermediate 14-a

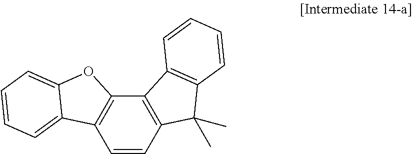 [SMILES: CC1(C)c2ccccc2-c2c1ccc1c2oc2ccccc21]

The same procedures as in Synthesis Examples 7-(1) to 7-(3) were carried out, with the exception that 4-dibenzofuran boronic acid and 2-bromobenzoic acid methylester were used instead of 1-dibenzofuran borate and 5-bromo-2-iodobenzoic acid methylester in Synthesis Example 7-(1), respectively, to afford [Intermediate 14-a]. (8.3 g, 77%)

### Synthesis Example 14-(2): Synthesis of Intermediate 14-b

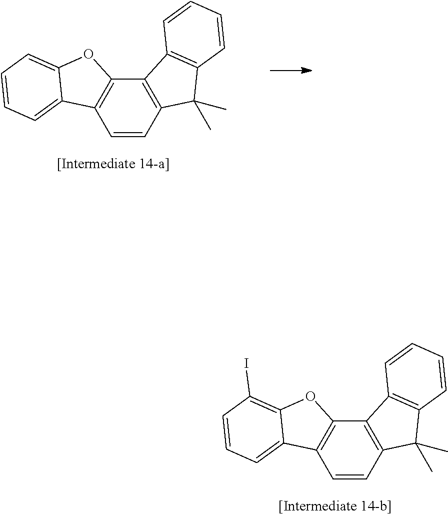 [SMILES: CC1(C)c2ccccc2-c2c1ccc1c2oc2ccccc21 ; CC1(C)c2ccccc2-c2c1ccc1c2oc2c(I)cccc21]

The same procedure as in Synthesis Example 8-(1) was carried out, with the exception that [Intermediate 14-a] was used instead of [Intermediate 8-a], to afford [Intermediate 14-b]. (6.5 g, 76%)

### Synthesis Example 14-(3): Synthesis of Compound H137

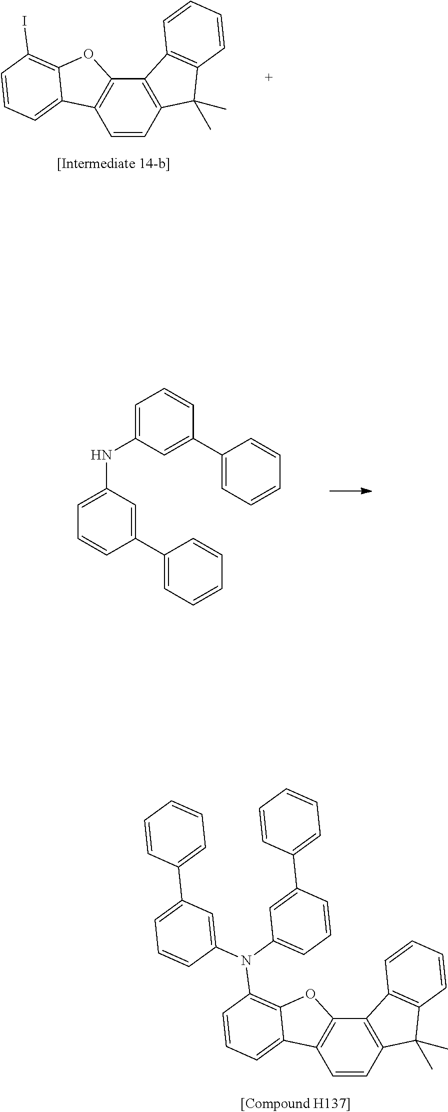 [SMILES: CC1(C)c2ccccc2-c2c1ccc1c2oc2c(I)cccc21 ; c1ccc(-c2cccc(Nc3cccc(-c4ccccc4)c3)c2)cc1 ; CC1(C)c2ccccc2-c2c1ccc1c2oc2c(N(c3cccc(-c4ccccc4)c3)c3cccc(-c4ccccc4)c3)cccc21]

The same procedure as in Synthesis Example 1-(7) was carried out, with the exception that Intermediate 14-b] and bis([1,1′-biphenyl]-3-yl)amine were used instead of [Intermediate 1-f] and bis(4-biphenyl)amine, respectively, to afford [Compound H137]. (5 g, 55%)

MS (MALDI-TOF): m/z 603.26[M⁺]

### Synthesis Example 15: Synthesis of Compound H138

### Synthesis Example 15-(1): Synthesis of Intermediate 15-a

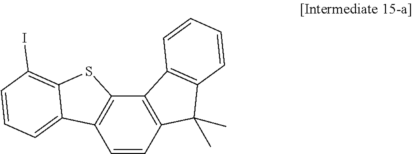 [SMILES: CC1(C)c2ccccc2-c2c1ccc1c2sc2c(I)cccc21]

The same procedure as in Synthesis Example 14-(1) was carried out, with the exception that 4-dibenzothiophene boronic acid was used instead of 4-dibenzofuran boronic acid, to afford [Intermediate 15-a]. (24 g, 75%)

### Synthesis Example 15-(2): Synthesis of Compound H138

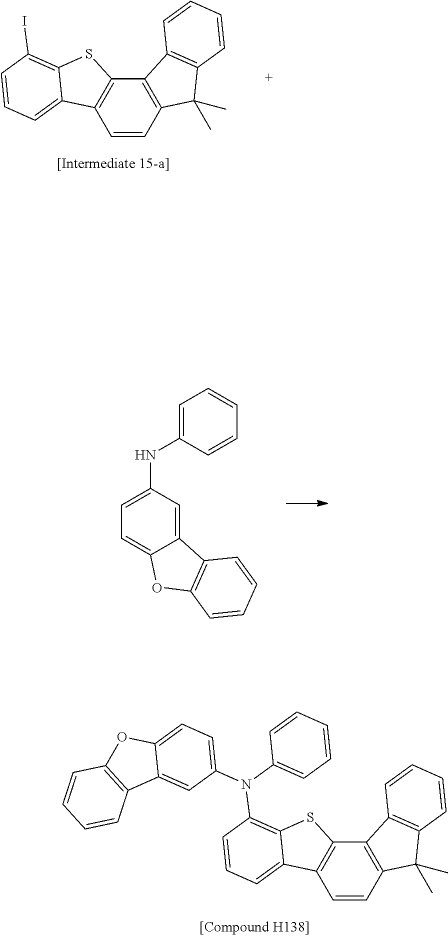 [SMILES: CC1(C)c2ccccc2-c2c1ccc1c2sc2c(I)cccc21 ; c1ccc(Nc2ccc3oc4ccccc4c3c2)cc1 ; CC1(C)c2ccccc2-c2c1ccc1c2sc2c(N(c3ccccc3)c3ccc4oc5ccccc5c4c3)cccc21]

The same procedure as in Synthesis Example 1-(7) was carried out, with the exception that [Intermediate 15-a] and N-(dibenzofuran-2-yl)-N-phenylamine were used instead of [Intermediate 1-f] and bis(4-biphenyl)amine, respectively, to afford [Compound H138]. (18.3 g, 67%)

MS (MALDI-TOF): m/z 557.18[M⁺]

### Synthesis Example 16: Synthesis of Compound H180

### Synthesis Example 16-(1): Synthesis of Intermediate 16-a

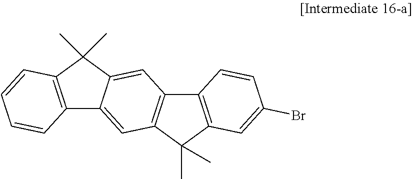 [SMILES: CC1(C)c2ccccc2-c2cc3c(cc21)-c1ccc(Br)cc1C3(C)C]

The same procedures as in Synthesis Examples 7-(1) to 7-(3) was carried out, with the exception that 9,9′-dimethyl-fluorene-2-boronic acid was used instead of 1-dibenzofuran borate in Synthesis Example 7-(1), to afford [Intermediate 16-a]. (8.3 g, 65%)

### Synthesis Example 16-(2): Synthesis of Compound H180

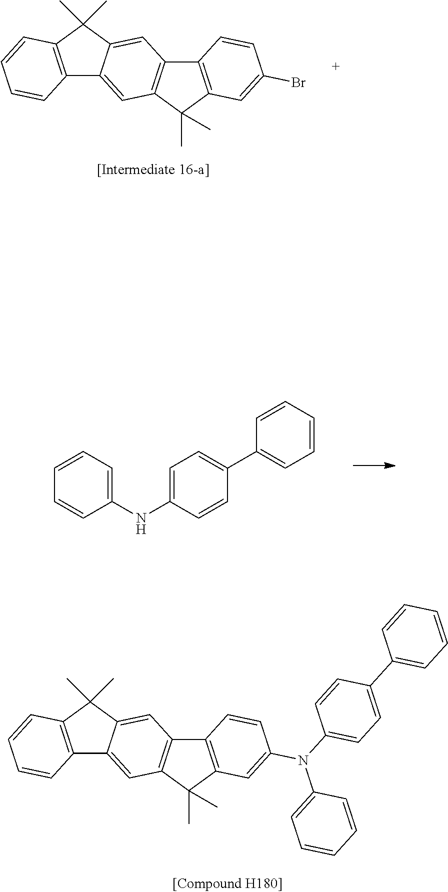 [SMILES: CC1(C)c2ccccc2-c2cc3c(cc21)-c1ccc(Br)cc1C3(C)C ; c1ccc(Nc2ccc(-c3ccccc3)cc2)cc1 ; CC1(C)c2ccccc2-c2cc3c(cc21)-c1ccc(N(c2ccccc2)c2ccc(-c4ccccc4)cc2)cc1C3(C)C]

The same procedure as in Synthesis Example 1-(7) was carried out, with the exception that [Intermediate 16-A] and 4-phenyldiphenylamine were used instead of [Intermediate 1-f] and bis(4-biphenyl)amine, to afford [Compound H180]. (6.7 g, 72%)

MS (MALDI-TOF): m/z 553.28[M⁺]

### Synthesis Example 17: Synthesis of Chemical Formula E1

### Synthesis Example 17-(1): Synthesis of Intermediate 17-a

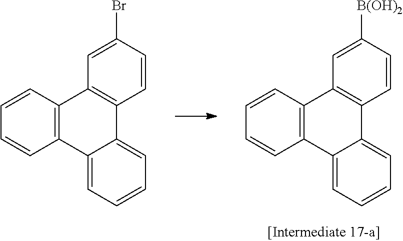 [SMILES: Brc1ccc2c3ccccc3c3ccccc3c2c1 ; OB(O)c1ccc2c3ccccc3c3ccccc3c2c1]

The same procedure as in Synthesis Example 1-(3) was carried out, with the exception that 2-bromobenzophenanthrene was used instead of [Intermediate 1-b], to afford [Intermediate 17-a]. (36.3 g, 82%)

### Synthesis Example 17-(2): Synthesis of Intermediate 17-b

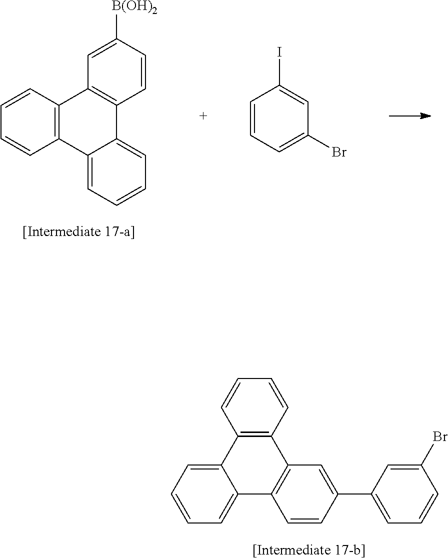 [SMILES: OB(O)c1ccc2c3ccccc3c3ccccc3c2c1 ; Brc1cccc(I)c1 ; Brc1cccc(-c2ccc3c4ccccc4c4ccccc4c3c2)c1]

The same procedure as in Synthesis Example 1-(4) was carried out, with the exception that [Intermediate 17-a] and 1-bromo-3-iodobenzene were used instead of [Intermediate 1-c] and 1-bromo-3-fluoro-2-iodobenzene, respectively, to afford [Intermediate 17-b]. (21.1 g, 75%)

### Synthesis Example 17-(3): Synthesis of Intermediate 17-c

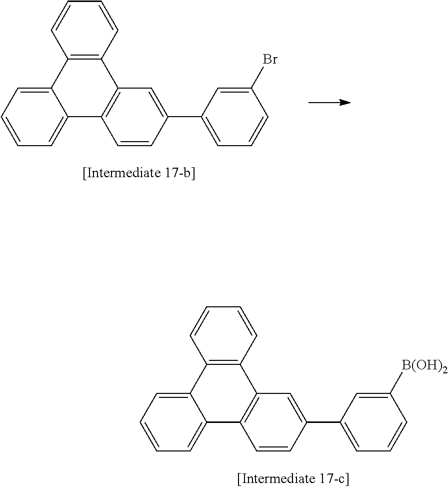 [SMILES: Brc1cccc(-c2ccc3c4ccccc4c4ccccc4c3c2)c1 ; OB(O)c1cccc(-c2ccc3c4ccccc4c4ccccc4c3c2)c1]

The same procedure as in Synthesis Example 1-(3) was carried out, with the exception that [Intermediate 17-b] was used instead of [Intermediate 1-b], to afford [Intermediate 17-c]. (18.3 g, 77%)

### Synthesis Example 17-(4): Synthesis of Chemical Formula E1

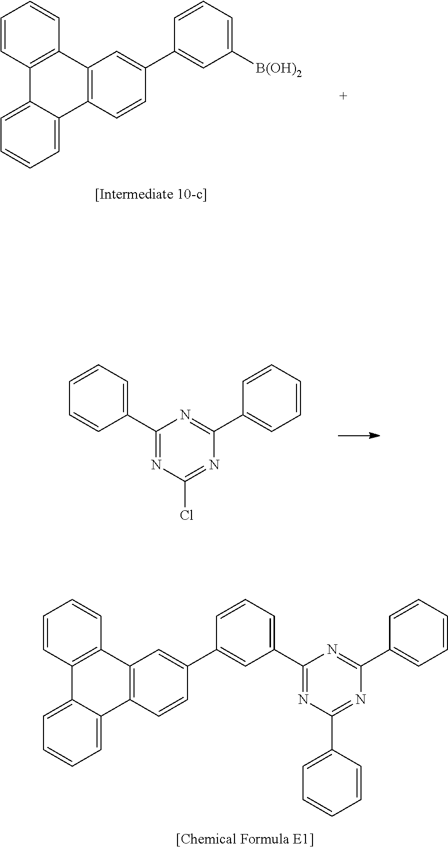 [SMILES: OB(O)c1cccc(-c2ccc3c4ccccc4c4ccccc4c3c2)c1 ; Clc1nc(-c2ccccc2)nc(-c2ccccc2)n1 ; c1ccc(-c2nc(-c3ccccc3)nc(-c3cccc(-c4ccc5c6ccccc6c6ccccc6c5c4)c3)n2)cc1]

The same procedure as in Synthesis Example 1-(4) was carried out, with the exception that [Intermediate 17-c] and 2-chloro-4,6-diphenyl-1,3,5-triazine were used instead of [Intermediate 1-c] and 1-bromo-3-fluoro-2-iodobenzene, respectively, to afford [Chemical Formula E1]. (22.5 g, 75%)

MS (MALDI-TOF): m/z 535.20[M⁺]

### Synthesis Example 18. Chemical Formula E4

### Synthesis Example 18-(1): Synthesis of Intermediate 18-a

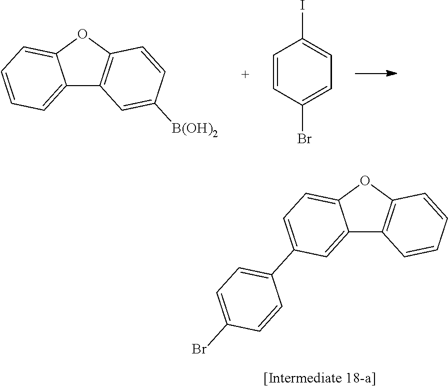 [SMILES: OB(O)c1ccc2oc3ccccc3c2c1 ; Brc1ccc(I)cc1 ; Brc1ccc(-c2ccc3oc4ccccc4c3c2)cc1]

The same procedure as in Synthesis Example 1-(4) was carried out, with the exception that dibenzofuran-2-boronic acid and 1-bromo-4-iodobenzene were used instead of [Intermediate 1-c] and 1-bromo-3-fluoro-2-iodobenzene, to afford [Intermediate 18-a]. (35 g, 46%)

### Synthesis Example 18-(2): Synthesis of Intermediate 18-b

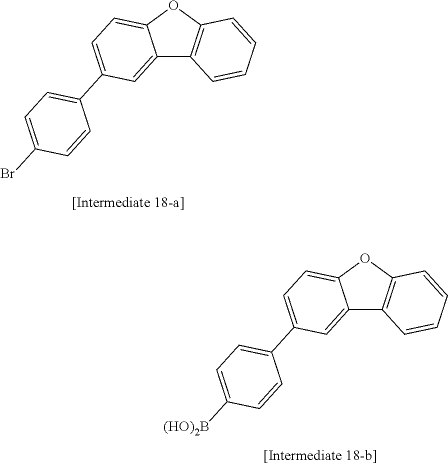 [SMILES: Brc1ccc(-c2ccc3oc4ccccc4c3c2)cc1 ; OB(O)c1ccc(-c2ccc3oc4ccccc4c3c2)cc1]

The same procedure as in Synthesis Example 1-(3) was carried out, with the exception that [Intermediate 18-a] was used instead of [Intermediate 1-b], to afford [Intermediate 18-b]. (27 g, 71%)

### Synthesis Example 18-(3): Chemical Formula E4

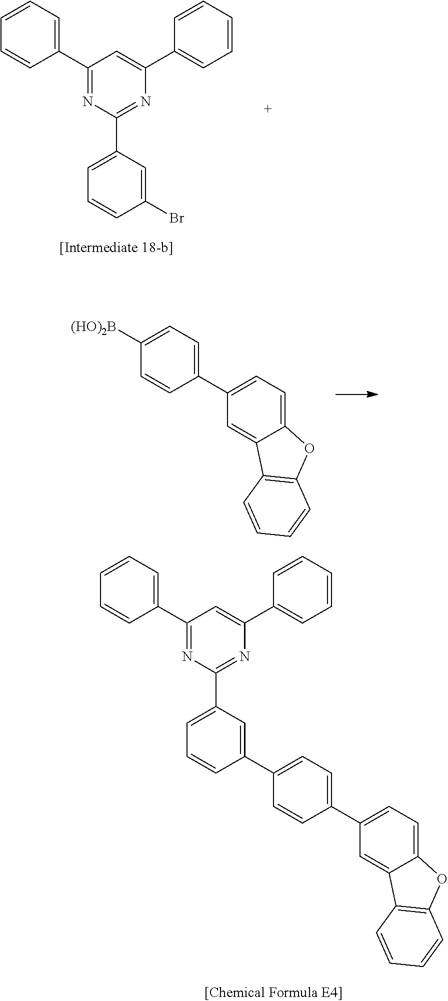

The same procedure as in Synthesis Example 1-(4) was carried out, with the exception that [Intermediate 18-b] and 2-(3-bromophenyl)-4,6-diphenylpyrimidine were used instead of [Intermediate 1-c] and 1-bromo-3-fluoro-2-iodobenzene, respectively, to afford [Chemical Formula E4]. (16.3 g, 74%)

MS (MALDI-TOF): m/z 550.20[M⁺]

### Synthesis Example 19. Chemical Formula E15

### Synthesis Example 19-(1): Synthesis of Intermediate 19-a

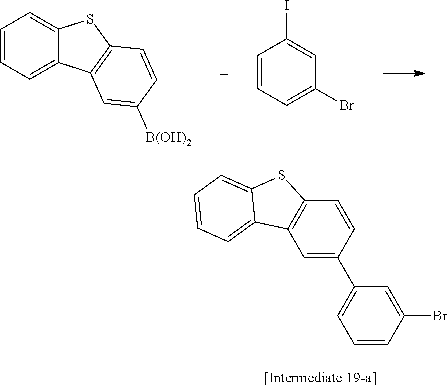 [SMILES: OB(O)c1ccc2sc3ccccc3c2c1 ; Brc1cccc(I)c1 ; Brc1cccc(-c2ccc3sc4ccccc4c3c2)c1]

The same procedure as in Synthesis Example 1-(4) was carried out, with the exception that dibenzothien-2-yl boronic acid and 1-bromo-3-iodobenzene were used instead of [Intermediate 1-c] and 1-bromo-3-fluoro-2-iodobenzene, respectively, to afford [Intermediate 19-a]. (22 g, 57%)

### Synthesis Example 19-(2): Synthesis of Intermediate 19-b

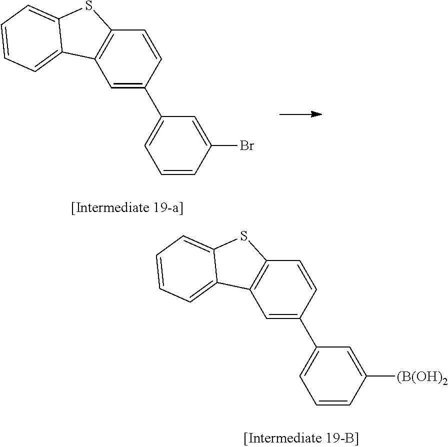

The same procedure as in Synthesis Example 1-(3) was carried out, with the exception that [Intermediate 19-a] was used instead of [Intermediate 1-b], to afford [Intermediate 19-b]. (15 g, 66%)

### Synthesis Example 19-(3): Synthesis of Chemical Formula Ely

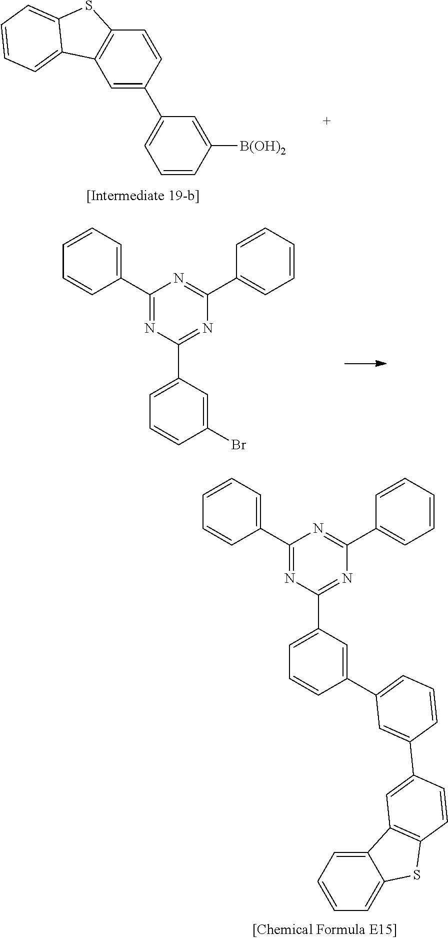

The same procedure as in Synthesis Example 1-(4) was carried out, with the exception that [Intermediate 19-a] and 2-(3-bromophenyl)-4,6-diphenyl-1,3,5triazine were used instead of [Intermediate 1-c] and 1-bromo-3-fluoro-2-iodobenzene, to afford [Chemical Formula E15]. (12 g, 71%)

MS (MALDI-TOF): m/z 567.18[M⁺]

### Synthesis Example 20: Synthesis of Chemical Formula E36

### Synthesis Example 20-(1): Synthesis of Intermediate 20-a

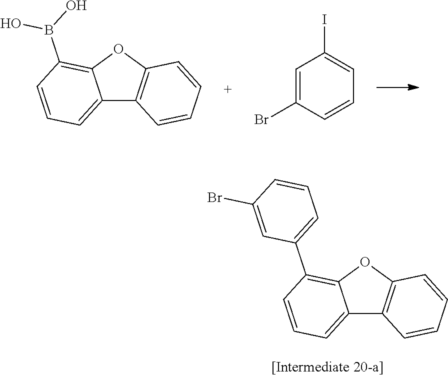 [SMILES: OB(O)c1cccc2c1oc1ccccc12 ; Brc1cccc(I)c1 ; Brc1cccc(-c2cccc3c2oc2ccccc23)c1]

The same procedure as in Synthesis Example 1-(4) was carried out, with the exception that 4-dibenzofuran boronic acid and 3-bromoiodobenzene were used instead of [Intermediate 1-c] and 1-bromo-3-fluoro-2-iodobenzene, respectively, to afford [Intermediate 20-a]. (29 g, 59%)

### Synthesis Example 20-(2): Synthesis of Intermediate 20-b

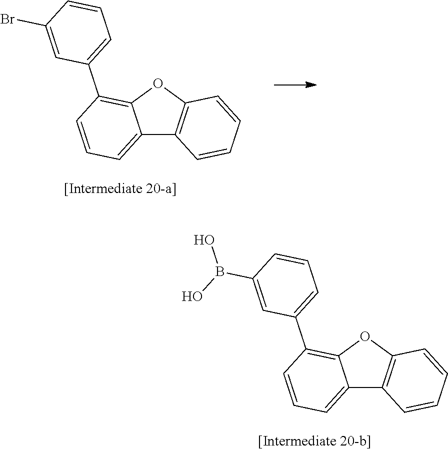 [SMILES: Brc1cccc(-c2cccc3c2oc2ccccc23)c1 ; OB(O)c1cccc(-c2cccc3c2oc2ccccc23)c1]

The same procedure as in Synthesis Example 1-(3) was carried out, with the exception that [Intermediate 20-a] was used instead of [Intermediate 1-b], to afford [Intermediate 20-b]. (22 g, 79%)

### Synthesis Example 20-(3): Chemical Formula E36

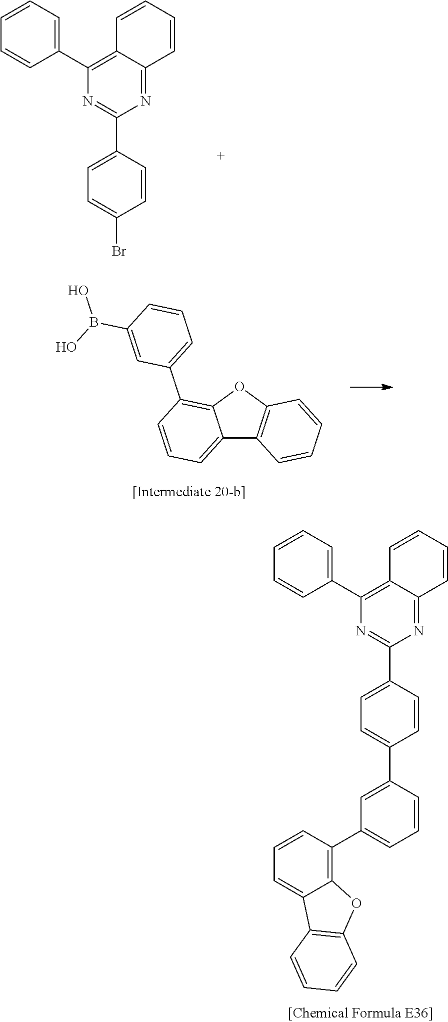 [SMILES: Brc1ccc(-c2nc(-c3ccccc3)c3ccccc3n2)cc1 ; OB(O)c1cccc(-c2cccc3c2oc2ccccc23)c1 ; c1ccc(-c2nc(-c3ccc(-c4cccc(-c5cccc6c5oc5ccccc56)c4)cc3)nc3ccccc23)cc1]

The same procedure as in Synthesis Example 1-(4) was carried out, with the exception that [Intermediate 20-b] and 2-(4-bromo-phenyl)-4-phenyl-quinazoline were used instead of [Intermediate 1-c] and 1-bromo-3-fluoro-2-iodobenzene, respectively, to afford [Chemical Formula E36]. (17 g, 61%)

MS (MALDI-TOF): m/z 524.19[M⁺]

### Synthesis Example 21: Synthesis of Chemical Formula E59

### Synthesis Example 21-(1): Synthesis of Intermediate 21-a

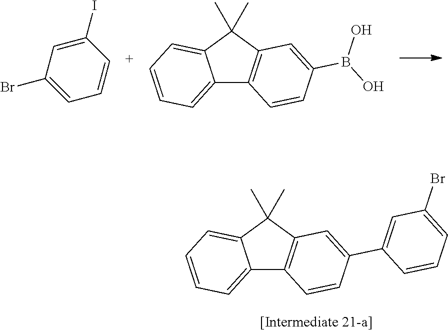

The same procedure as in Synthesis Example 1-(4) was carried out, with the exception that 9,9-dimethyl fluorene-2-boronic acid and 3-bromoiodobenzen were used instead of [Intermediate 1-c] and 1-bromo-3-fluoro-2-iodobenzene, respectively, to afford [Intermediate 21-a]. (38 g, 69%)

### Synthesis Example 21-(2): Synthesis of Intermediate 21-b

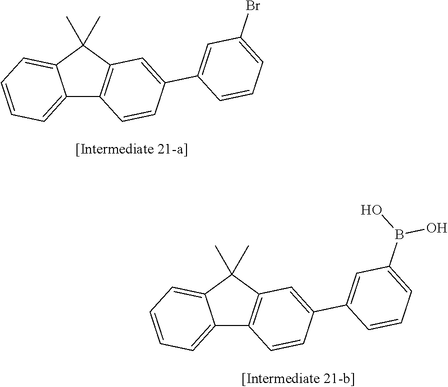 [SMILES: CC1(C)c2ccccc2-c2ccc(-c3cccc(Br)c3)cc21 ; CC1(C)c2ccccc2-c2ccc(-c3cccc(B(O)O)c3)cc21]

The same procedure as in Synthesis Example 1-(3) was carried out, with the exception that [Intermediate 21-a] was used instead of [Intermediate 1-b], to afford [Intermediate 21-b]. (31 g, 82%)

### Synthesis Example 21-(3): Chemical Formula E59

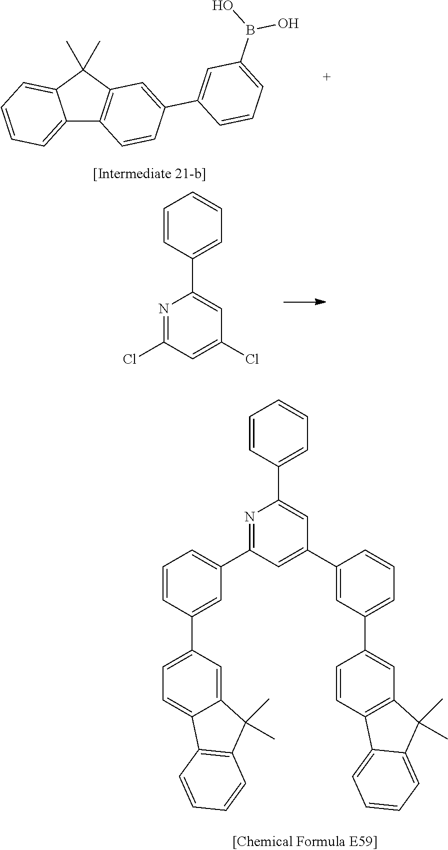 [SMILES: CC1(C)c2ccccc2-c2ccc(-c3cccc(B(O)O)c3)cc21 ; Clc1cc(Cl)nc(-c2ccccc2)c1 ; CC1(C)c2ccccc2-c2ccc(-c3cccc(-c4cc(-c5ccccc5)nc(-c5cccc(-c6ccc7c(c6)C(C)(C)c6ccccc6-7)c5)c4)c3)cc21]

The same procedure as in Synthesis Example 1-(4) was carried out, with the exception that [Intermediate 21-b] and 2,4-dichloro-6-phenylpyridine were used instead of [Intermediate 1-c] and 1-bromo-3-fluoro-2-iodobenzene, respectively, to afford [Chemical Formula E59]. (8.5 g, 49%)

MS (MALDI-TOF): m/z 691.32[M⁺]

### Synthesis Example 22: Synthesis of Chemical Formula E112

### Synthesis Example 22-(1): Synthesis of Intermediate 22-a

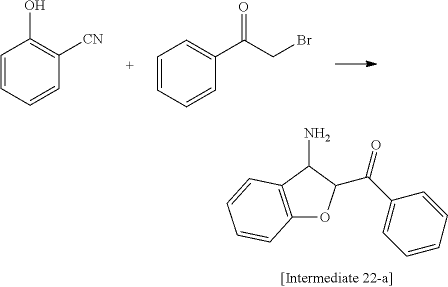 [SMILES: N#Cc1ccccc1O ; O=C(CBr)c1ccccc1 ; NC1c2ccccc2OC1C(=O)c1ccccc1]

In a 2-L round bottom flask reactor, a mixture of 2-cyanophenol (24.5 g, 205.6 mmol), 2-bromoacetophenone (40.9 g, 205.4 mmol), potassium carbonate (85.3 g, 617 mmol), and acetone (980 mL) was stirred at 60° C. for 12 hrs. After completion of the reaction, the reaction solution was cooled to room temperature and filtered with acetone. The filtrate was concentrated, followed by recrystallization with heptane to afford [Intermediate 22-a]. (37 g, 75.2%)

### Synthesis Example 22-(2): Synthesis of Intermediate 22-b

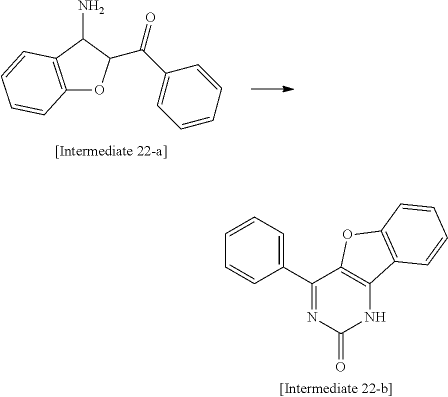 [SMILES: NC1c2ccccc2OC1C(=O)c1ccccc1 ; O=c1nc(-c2ccccc2)c2oc3ccccc3c2[nH]1]

In a 300-mL round-bottom flask reactor, a mixture of [Intermediate 22-a] (14 g, 58.5 mmol), urea (11.7 g, 195 mmol), and acetic acid (70 mL) was stirred under reflux for 12 hrs. After completion of the reaction, the reaction solution was added with an excess of water to form precipitates which were filtered. The filtrate was hot slurried with methanol, filtered, and dried to afford [Intermediate 22-b]. (9.3 g, 60.6%)

### Synthesis Example 22-(3): Synthesis of Intermediate 22-c

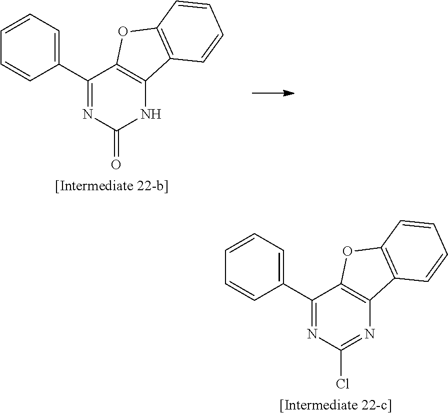 [SMILES: O=c1nc(-c2ccccc2)c2oc3ccccc3c2[nH]1 ; Clc1nc(-c2ccccc2)c2oc3ccccc3c2n1]

In a 300-mL round-bottom flask reactor, [Intermediate 22-b] (9.3 g, 35.5 mmol) and phosphorus oxychloride (45 mL) were stirred together under reflux for 12 hrs. After completion of the reaction, the reaction solution was slowly added to an excess of water at 0° C. to form precipitates which were then filtered. The solid thus obtained was dissolved in dichlorobenzene and then filtration was conducted in a vacuum while the solution was in a hot state. Recrystallization gave [Intermediate 22-c]. (7.0 g, 70.3%)

### Synthesis Example 22-(4): Synthesis of Intermediate 22-d

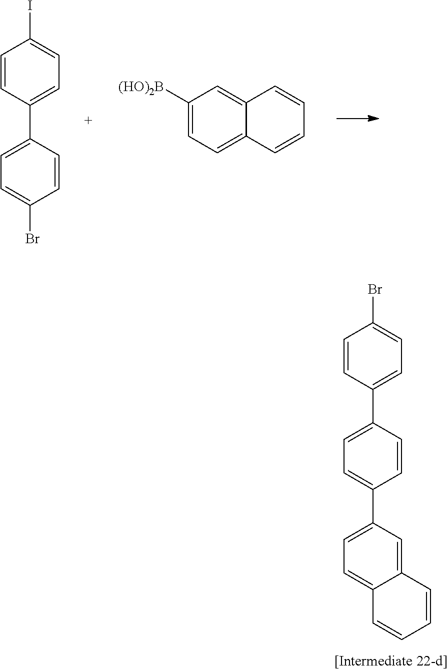 [SMILES: Brc1ccc(-c2ccc(I)cc2)cc1 ; OB(O)c1ccc2ccccc2c1 ; Brc1ccc(-c2ccc(-c3ccc4ccccc4c3)cc2)cc1]

The same procedure as in Synthesis Example 1-(4) was carried out, with the exception that naphthalene-2-boronic acid and 4-bromo-4-iodobiphenyl were used instead of [Intermediate 1-c] and 1-bromo-3-fluoro-2-iodobenzene, respectively, to afford [Intermediate 22-d]. (13 g, 66%)

### Synthesis Example 22-(5): Synthesis of Intermediate 22-e

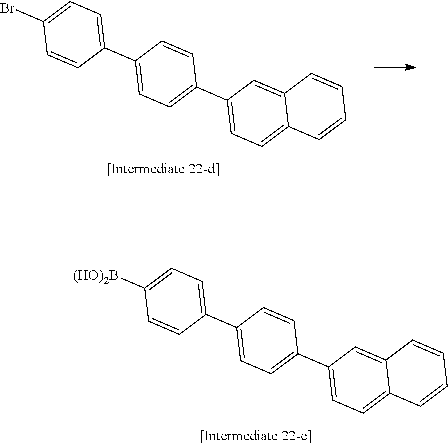 [SMILES: Brc1ccc(-c2ccc(-c3ccc4ccccc4c3)cc2)cc1 ; OB(O)c1ccc(-c2ccc(-c3ccc4ccccc4c3)cc2)cc1]

The same procedure as in Synthesis Example 1-(3) was carried out, with the exception that [Intermediate 22-d] was used instead of 2-bromobenzophenanthrene, to afford [Intermediate 22-e]. (10.3 g, 72%)

### Synthesis Example 22-(6): Synthesis of Chemical Formula E112

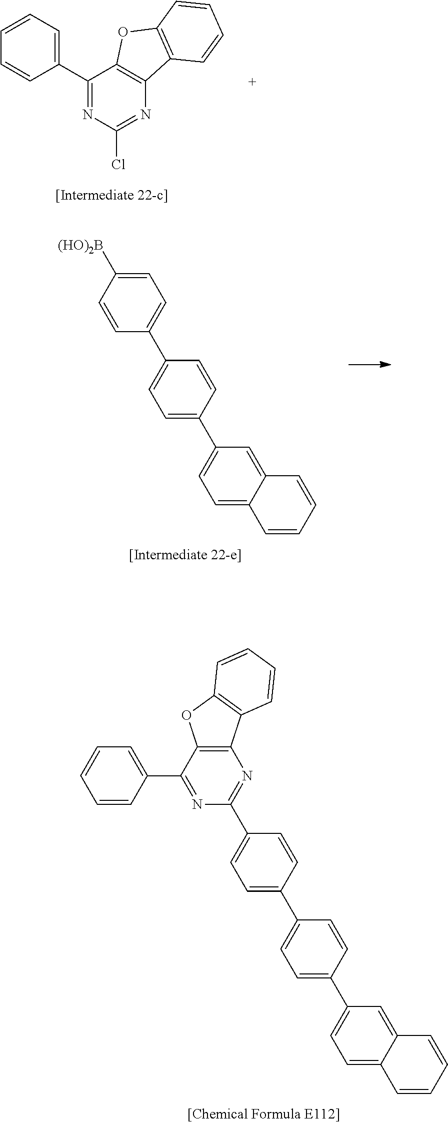 [SMILES: Clc1nc(-c2ccccc2)c2oc3ccccc3c2n1 ; OB(O)c1ccc(-c2ccc(-c3ccc4ccccc4c3)cc2)cc1 ; c1ccc(-c2nc(-c3ccc(-c4ccc(-c5ccc6ccccc6c5)cc4)cc3)nc3c2oc2ccccc23)cc1]

The same procedure as in Synthesis Example 1-(4) was carried out, with the exception that [Intermediate 22-e] and [Intermediate 22-c] were used instead of [Intermediate 1-c] and 1-bromo-3-fluoro-2-iodobenzene, respectively, to afford [Chemical Formula E112]. (5.5 g, 55%)

MS (MALDI-TOF): m/z 524.19[M⁺]

### Synthesis Example 23: Synthesis of Chemical Formula E143

### Synthesis Example 23-(1): Synthesis of Chemical Formula E143

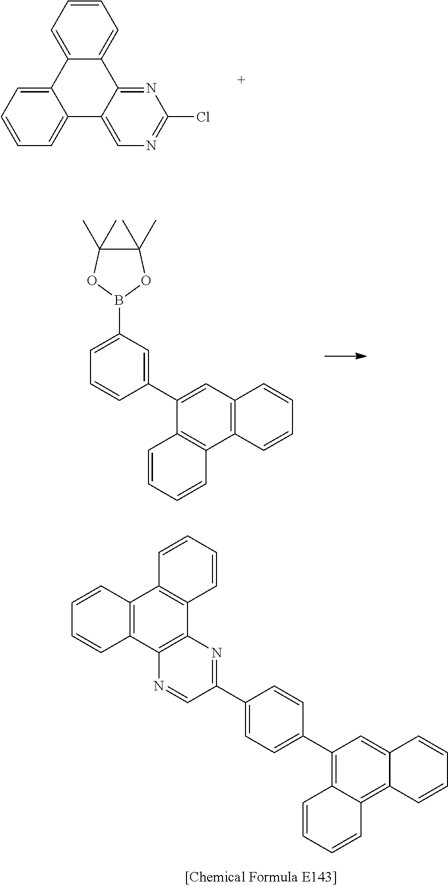

The same procedure as in Synthesis Example 1-(4) was carried out, with the exception that 4,4,5,5-tetramethyl-2-(3-(phenanthren-9-yl)phenyl)-1,3,2,-dioxaborolane and 2-chloranil phenanthro(9,10-d)pyrimidine were used instead of [Intermediate 1-c] and 1-bromo-3-fluoro-2-iodobenzene, respectively, to afford [Chemical Formula E143]. (5.4 g, 47%)

MS (MALDI-TOF): m/z 482.18 [Mt]

### Example: Fabrication of Organic Light-Emitting Diodes

### Examples 1-16

An ITO glass substrate was patterned to have a translucent area of 2 mm×2 mm and cleansed. The ITO glass was mounted in a vacuum chamber that was then set to have a base pressure of 1×10⁻⁶ torr. On the ITO glass substrate, films were sequentially formed of HATCN (50 Å) and NPD (900 Å), followed by the formation of a light-emitting layer (300 Å) composed of a combination of Compounds H1 to H180 and Chemical Formulas E1 to E143 at a weight ratio of 5:5, as listed in Table 1, with the green phosphorescent dopant (GD) doped at 7 wt % thereinto. On the light-emitting layer, films were formed of ET:Liq=1:1 (300 Å), Liq(10 Å), and Al (1,000 Å) in the order. The organic light-emitting diodes thus obtained were measured at 0.4 mA for luminescence properties.

### [HATCN] [NPD]

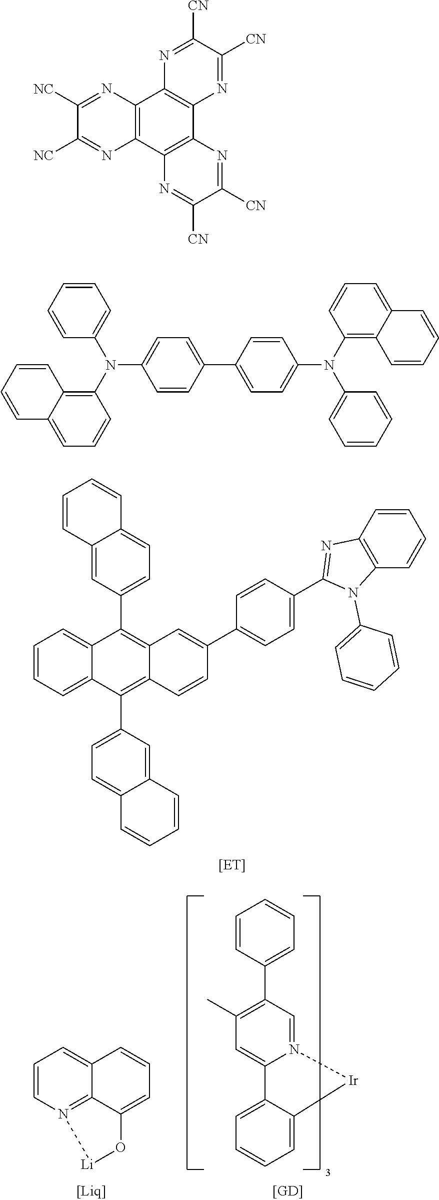

### Comparative Examples 1-9

Organic light-emitting diodes were fabricated using the same manner as in Example 1, with the exception that the light-emitting layer was formed of only one host, that is, by co-depositing one of Compounds H1 to E111, and 7 wt % of GD (only the first host used), or one of Chemical Formulas E1 to E112, and 7 wt % of GD (only the second host used).

### Comparative Example 10

An organic light-emitting diode was fabricated in the same manner as in Examples 1 to 16, with the exception that CBP, which is typically used as a phosphorescent host, was employed instead of the compounds (host) according to the present disclosure. The structure of CBP is as follows:

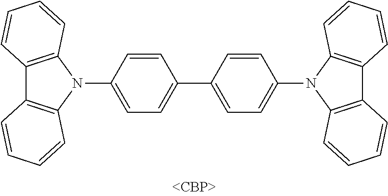 [SMILES: c1ccc2c(c1)c1ccccc1n2-c1ccc(-c2ccc(-n3c4ccccc4c4ccccc43)cc2)cc1]

### Evaluation Example

Driving voltages, luminance, light colors, and lifetimes of the organic light-emitting diodes fabricated according to Examples 1 to 16 and Comparative Examples 1 to 10 are listed in Table 1, below. Here, T95 refers to the time taken for the luminance to decrease to 95% of the initial luminance (2000 cd/m²).

TABLE 1

| | | 2^{nd} Cpd. | | | | | | |
|---|---|---|---|---|---|---|---|---|
| | | (Chem- | | | | | | |
| | 1^{st} | ical | | Driving | Emission | | | T95 |
| Ex. | Cpd. | Formula | Wt. | Volt. | Efficiency | | | 6000nit |
| # | # | #) | Ratio | (V) | (cd/A) | CIEx | CIEy | (h) |
| 1 | H1 | E1 | 5:5 | 3.4 | 72 | 0.330 | 0.663 | 198 |
| 2 | H2 | E1 | 5:5 | 3.6 | 70 | 0.339 | 0.661 | 194 |
| 3 | H3 | E1 | 5:5 | 3.5 | 71 | 0.330 | 0.662 | 197 |
| 4 | H4 | E36 | 5:5 | 3.7 | 64 | 0.331 | 0.659 | 96 |
| 5 | H7 | E36 | 5:5 | 3.6 | 62 | 0.327 | 0.660 | 87 |
| 6 | H9 | E36 | 5:5 | 3.7 | 61 | 0.331 | 0.662 | 82 |
| 7 | H93 | E36 | 5:5 | 3.6 | 65 | 0.337 | 0.661 | 86 |
| 8 | H94 | E59 | 5:5 | 3.8 | 66 | 0.330 | 0.664 | 89 |
| 9 | H105 | E59 | 5:5 | 3.6 | 67 | 0.333 | 0.661 | 91 |
| 10 | H109 | E59 | 5:5 | 3.6 | 69 | 0.327 | 0.664 | 184 |
| 11 | H110 | E112 | 5:5 | 3.5 | 60 | 0.333 | 0.663 | 83 |
| 12 | H111 | E112 | 5:5 | 3.8 | 68 | 0.331 | 0.659 | 85 |
| 13 | H112 | E112 | 5:5 | 3.7 | 63 | 0.334 | 0.662 | 87 |
| 14 | H137 | E143 | 5:5 | 3.7 | 58 | 0.336 | 0.638 | 88 |
| 15 | H138 | E143 | 5:5 | 3.8 | 63 | 0.328 | 0.641 | 87 |
| 16 | H180 | E143 | 5:5 | 3.6 | 61 | 0.333 | 0.657 | 81 |
| C.1 | H1 | | 1 | 4.7 | 10 | 0.329 | 0.664 | 8 |
| C.2 | H3 | | 1 | 4.8 | 6 | 0.327 | 0.667 | 7 |
| C.3 | H93 | — | 1 | 4.7 | 7 | 0.324 | 0.658 | 6 |
| C.4 | H105 | — | 1 | 4.8 | 7 | 0.327 | 0.660 | 4 |
| C.5 | H111 | — | 1 | 4.7 | 7 | 0.324 | 0.658 | 6 |
| C.6 | — | E1 | 1 | 3.6 | 35 | 0.331 | 0.632 | 22 |
| C.7 | — | E15 | 1 | 3.7 | 37 | 0.325 | 0.629 | 25 |
| C.8 | — | E59 | 1 | 3.8 | 39 | 0.324 | 0.643 | 17 |
| C.9 | — | E112 | 1 | 3.5 | 37 | 0.326 | 0.657 | 18 |
| C.10 | CBP | | 1 | 6.8 | 36 | 0.335 | 0.628 | 12 |

As is understood from the data of Table 1, the organic light-emitting diodes fabricated according to Examples 1 to 16 were observed to be superior to those of Comparative Examples 1 to 10 in terms of driving voltage, emission efficiency, and lifetime. Particularly, the lifetimes of the organic light-emitting diodes of Examples 1 to 3 and 10 were about twice as long as those of the organic light-emitting diodes of the other Examples.

### Examples 17-23

An ITO glass substrate was patterned to have a translucent area of 2 mm×2 mm and cleansed. The ITO glass was mounted in a vacuum chamber that was then set to have a base pressure of 1×10⁻⁶ torr. On the ITO glass substrate, films were sequentially formed of HATCN (50 Å) and NPD (1500 Å), followed by the formation of a light-emitting layer (400 Å) composed of a combination of Compounds H1 to H137 and Chemical Formulas E1 to E143 at a weight ratio of 5:5, as listed in Table 2, with the red phosphorescent dopant (RD) doped at 5 wt % thereinto. On the light-emitting layer, films were formed of ET:Liq=1:1 (300 Å), Liq (10 Å), and Al (1,000 Å) in the order. The organic light-emitting diodes thus obtained were measured at 0.4 mA for luminescence properties.

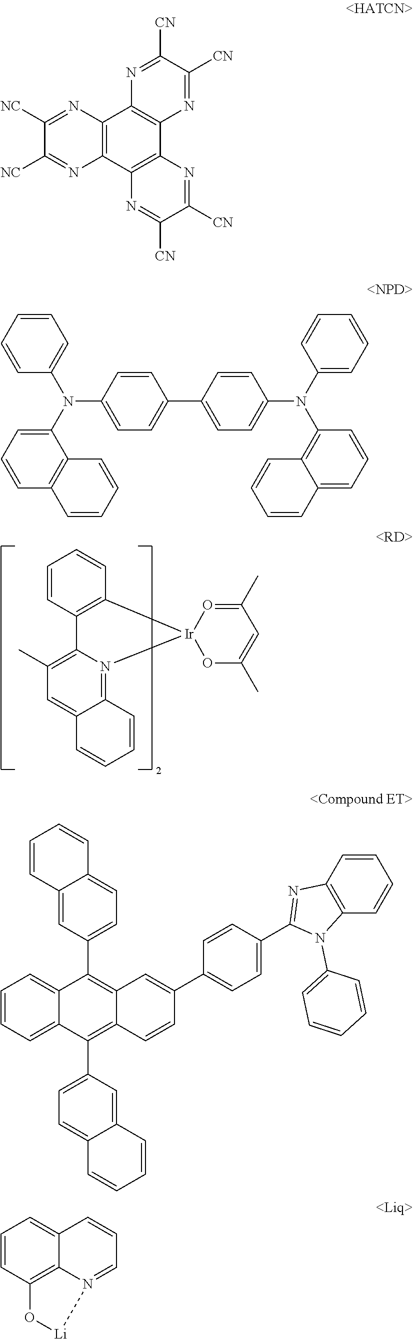

### Comparative Examples 11-14

Organic light-emitting diodes were fabricated using the same manner as in Examples 17 to 23, with the exception that the light-emitting layer was formed of only one host, that is, by co-depositing one of Compounds H1 to H17, and 5 wt % of RD (only the first host used), or one of Chemical Formulas E1 to E59, and 5 wt % of RD (only the second host used).

### Comparative Example 15

An organic light-emitting diode was fabricated in the same manner as in Examples 17 to 23, with the exception that BAlq, which is typically used as a phosphorescent host, was employed instead of the compounds (host) according to the present disclosure. The structure of BAlq is as follows:

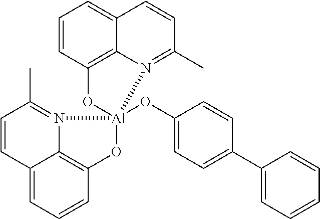

### Evaluation Example

Driving Voltages, Luminance, Light Colors, and Lifetimes of the organic light-emitting diodes fabricated according to Examples 17 to 23 and Comparative Examples 11 to 15 are listed in Table 2, below.

TABLE 2

| | | 2^{nd} Cpd. | | | | | | |
|---|---|---|---|---|---|---|---|---|
| | | (Chem- | | | | | | |
| | 1^{st} | ical | | Driving | Emission | | | T95 |
| Ex. | Cpd. | Formula | Wt. | Volt. | Efficiency | | | 6000nit |
| # | # | #) | Ratio | (V) | (cd/A) | CIEx | CIEy | (h) |
| 17 | H1 | E1 | 5:5 | 3.6 | 23.8 | 0.663 | 0.330 | 235 |
| 18 | H3 | E4 | 5:5 | 3.5 | 22.8 | 0.661 | 0.339 | 230 |
| 19 | H7 | E36 | 5:5 | 3.7 | 22.1 | 0.662 | 0.330 | 162 |
| 20 | H105 | E36 | 5:5 | 4.0 | 19.8 | 0.659 | 0.331 | 151 |
| 21 | H109 | E59 | 5:5 | 3.7 | 22.1 | 0.660 | 0.327 | 212 |
| 22 | H110 | E59 | 5:5 | 4.1 | 21.4 | 0.664 | 0330 | 156 |
| 23 | H137 | E143 | 5:5 | 4.1 | 20.6 | 0.664 | 0.327 | 146 |
| C. 11 | H1 | — | 1 | 4.7 | 5.1 | 0.663 | 0.331 | 12 |
| C. 12 | H7 | — | 1 | 4.5 | 4.9 | 0.668 | 0.328 | 8 |
| C. 13 | — | E4 | 1 | 3.2 | 10.0 | 0.665 | 0.335 | 20 |
| C. 14 | — | E36 | 1 | 3.3 | 8.5 | 0.658 | 0.333 | 22 |
| C. 15 | BAlq | | 1 | 6.2 | 14.7 | 0.665 | 0.334 | 40 |

As is understood from the data of Table 2, the organic light-emitting diodes fabricated according to Examples 17 to 23 were observed to exhibit low driving voltages and high emission efficiencies and particularly remarkably improved lifetime, compared to those of Comparative Examples 11 to 15. Inter alia, the lifetimes of the organic light-emitting diodes of Examples 17, 18 and 21 were about twice as long as those of the organic light-emitting diodes of the other Examples.

### INDUSTRIAL APPLICABILITY

The organic light-emitting diodes according to the present disclosure can operate at low voltages and exhibit improved efficiencies and lifetimes, compared to those according to the prior art and, as such, are industrially applicable.

1. An organic light-emitting diode comprising:
a first electrode;
a second electrode facing the first electrode;
a light-emitting layer interposed between the first electrode and the second electrode, wherein the light-emitting layer contains at least one of fused ring compounds represented by the following Chemical Formula A and at least one of hetero ring compounds represented by the following Chemical Formula D: 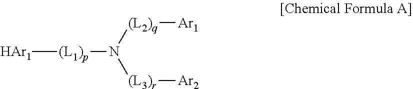
wherein,
Ar₁ and Ar₂, which are same or different, are each independently any one selected from a hydrogen atom, a deuterium atom, a halogen, a cyano, a substituted or unsubstituted alkyl of 1 to 20 carbon atoms, a substituted or unsubstituted cycloalkyl of 3 to 20 carbon atoms, a substituted or unsubstituted alkoxy of 1 to 20 carbon atoms, a substituted or unsubstituted aryloxy of 6 to 30 carbon atoms, a substituted or unsubstituted alkylthio of 1 to 20 carbon atoms, a substituted or unsubstituted arylthio of 6 to 30 carbon atoms, a substituted or unsubstituted alkylsilyl of 3 to 50 carbon atoms, a substituted or unsubstituted arylsilyl of 6 to 50 carbon atoms, a substituted or unsubstituted aromatic hydrocarbon of 6 to 30 carbon atoms, and a substituted or unsubstituted hetero ring of 5 to 30 carbon atoms and each bond to an adjacent radical to form an aliphatic, aromatic, heteroaliphatic, or heteroaromatic fused ring,
linkers L₁ to L₃, which are same or different, are each independently a single bond or selected from a substituted or unsubstituted arylene of 6 to 60 carbon atoms and a substituted or unsubstituted heteroarylene of 2 to 60 carbon atoms,
p, q, and r are each an integer of 0 to 3 wherein any of p, q, and r is 2 or greater, the corresponding linkers L₁'s to L₃'s are same or different,
HAr₁ is represented by the following [Structural Formula 1]: 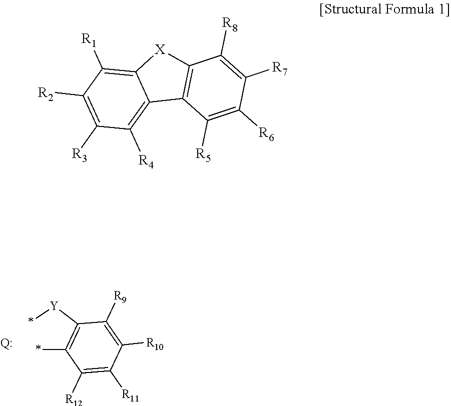
wherein,
X and Y, which are same or different, are each independently any one selected from O, S, and CR₁₃R₁₄,
R₁ to R₁₄, which are same or different, are each independently any one selected from a hydrogen atom, a deuterium atom, a halogen, a cyano, a substituted or unsubstituted alkyl of 1 to 20 carbon atoms, a substituted or unsubstituted cycloalkyl of 3 to 20 carbon atoms, a substituted or unsubstituted alkoxy of 1 to 20 carbon atoms, a substituted or unsubstituted aryloxy of 6 to 30 carbon atoms, a substituted or unsubstituted alkylthio of 1 to 20 carbon atoms, a substituted or unsubstituted arylthio of 6 to 30 carbon atoms, a substituted or unsubstituted alkylsilyl of 3 to 50 carbon atoms, a substituted or unsubstituted arylsilyl of 6 to 50 carbon atoms, a substituted or unsubstituted aromatic hydrocarbon of 6 to 30 carbon atoms, and a substituted or unsubstituted hetero ring of 5 to 30 carbon atoms as ring members and each bond to an adjacent radical to form an aliphatic, aromatic, heteroaliphatic, or heteroaromatic fused ring,
two adjacent radicals of R₅ to R₈ are each a single bond connected to * in the Structural Formula Q
any one of R₁ to R₁₂ in Structural Formula 1 representing HAr₁ is a single bond connected to the linker L₁ in Chemical Formula A; 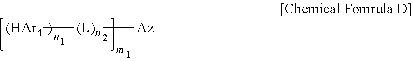
wherein,
HAr₄ is a substituted or unsubstituted aryl of 6 to 30 carbon atoms, or a substituted or unsubstituted heteroaryl of 3 to 30 carbon atoms,
L is a single bond, or any one selected from a substituted or unsubstituted arylene of 6 to 60 carbon atoms and a substituted or unsubstituted heteroarylene of 2 to 60 carbon atoms,
n₁ and n₂ are each an integer of 0 to 3 wherein when any of n₁ and n₂ is two or greater, the corresponding multiple HAr₄ or L are the same or different,
m₁ is an integer of 1 to 4 wherein when m₁ is 2 or greater, the corresponding HAr₄- and L-bearing moieties within the parentheses 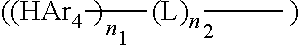
are same or different,
Az is represented by any one of the following [Structural Formula 2] to [Structural Formula 8]: 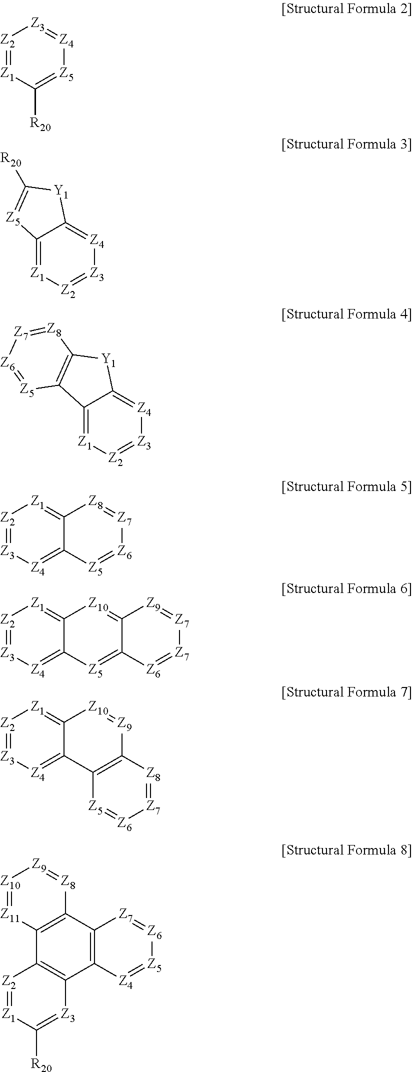
wherein,
Z₁ is N or CR₂₁,
Z₂ is N or CR₂₂,
Z₃ is N or CR₂₃,
Z₄ is N or CR₂₄,
Z₅ is N or CR₂₅,
Z₆ is N or CR₂₆,
Z₇ is N or CR₂₇,
Z₈ is N or CR₂₈,
Z₉ is N or CR₂₉,
Z₁₀ is N or CR₃₀,
Z₁₁ is N or CR₃₁,
Y₁ is any one of O, S, NR₃₂, and CR₃₃R₃₄,
at least one of Z₁ to Z₅ in Structural Formula 2 is N, and m₁ substituents of the substituents R₂₀ to R₂₅ are each a single bond connected to the linker L so that the aromatic ring moiety of Structural Formula 2 has m₁ single bonds to the linker L,
at least one of Z₁ to Z₅ in Structural Formula 3 is N, and m₁ substituents of the substituents R₂₀ to R₂₅ are each a single bond connected to the linker L so that the aromatic ring moiety of Structural Formula 3 has m₁ single bonds to the linker L,
at least one of Z₁ to Z₈ in Structural Formula 4 is N, and m₁ substituents of the substituents R₂₁ to R₂₈ are each a single bond connected to the linker L so that the aromatic ring moiety of Structural Formula 4 has m₁ single bonds to the linker L,
at least one of Z₁ to Z₈ in Structural Formula 5 is N, and m₁ substituents of the substituents R₂₁ to R₂₈ are each a single bond connected to the linker L so that the aromatic ring moiety of Structural Formula 5 has m₁ single bonds to the linker L,
at least one of Z₁ to Z₁₀ in Structural Formula 6 is N, and m₁ substituents of the substituents R₂₁ to R₃₀ are each a single bond connected to the linker L so that the aromatic ring moiety of Structural Formula 6 has m₁ single bonds to the linker L,
at least one of Z₁ to Z₁₀ in Structural Formula 7 is N, and m₁ substituents of the substituents R₂₁ to R₃₀ are each a single bond connected to the linker L so that the aromatic ring moiety of Structural Formula 7 has m₁ single bonds to the linker L,
at least one of Z₁ to Z₁₁ in Structural Formula 8 is N, and m₁ substituents of the substituents R₂₀ to R₃₁ are each a single bond connected to the linker L so that the aromatic ring moiety of Structural Formula 8 has m₁ single bonds to the linker L,
R₂₀ to R₃₄, which are same or different, are each independently any one selected from a hydrogen atom, a deuterium atom, a halogen, a cyano, a substituted or unsubstituted alkyl of 1 to 20 carbon atoms, a substituted or unsubstituted cycloalkyl of 3 to 20 carbon atoms, a substituted or unsubstituted alkoxy of 1 to 20 carbon atoms, a substituted or unsubstituted aryloxy of 6 to 30 carbon atoms, a substituted or unsubstituted alkylthio of 1 to 20 carbon atoms, a substituted or unsubstituted arylthio of 6 to 30 carbon atoms, a substituted or unsubstituted alkylsilyl of 3 to 50 carbon atoms, a substituted or unsubstituted arylsilyl of 6 to 50 carbon atoms, a substituted or unsubstituted aromatic hydrocarbon of 6 to 30 carbon atoms, and a substituted or unsubstituted hetero ring of 5 to 30 carbon atoms and each bond to an adjacent radical to form an aliphatic, aromatic, hetero aliphatic or heteroaromatic fused ring,
wherein the term “substituted” in the expression “substituted or unsubstituted” used for [Chemical Formula A] and [Chemical Formula D] means having at least one substituent selected from the group consisting of a deuterium atom, a cyano, a halogen, a hydroxy, a nitro, an alkyl of 1 to 24 carbon atoms, a halogenated alkyl of 1 to 24 carbon atoms, an alkenyl of 2 to 24 carbon atoms, an alkynyl of 2 to 24 carbon atoms, a heteroalkyl of 1 to 24 carbon atoms, an aryl of 6 to 24 carbon atoms, an arylalkyl of 7 to 24 carbon atoms, a heteroaryl of 2 to 24 carbon atoms or a heteroarylalkyl of 2 to 24 carbon atoms, an alkoxy of 1 to 24 carbon atoms, an alkylamino of 1 to 24 carbon atoms, an arylamino of 6 to 24 carbon atoms, a heteroarylamino of 1 to 24 carbon atoms, an alkylsilyl of 1 to 24 carbon atoms, an arylsilyl of 6 to 24 carbon atoms, and an aryloxy of 6 to 24 carbon atoms.

2. The organic light-emitting diode of claim 1, wherein Az represented by [Structural Formula 2] to [Structural Formula 8] are each any one selected from the following E1 to E24: 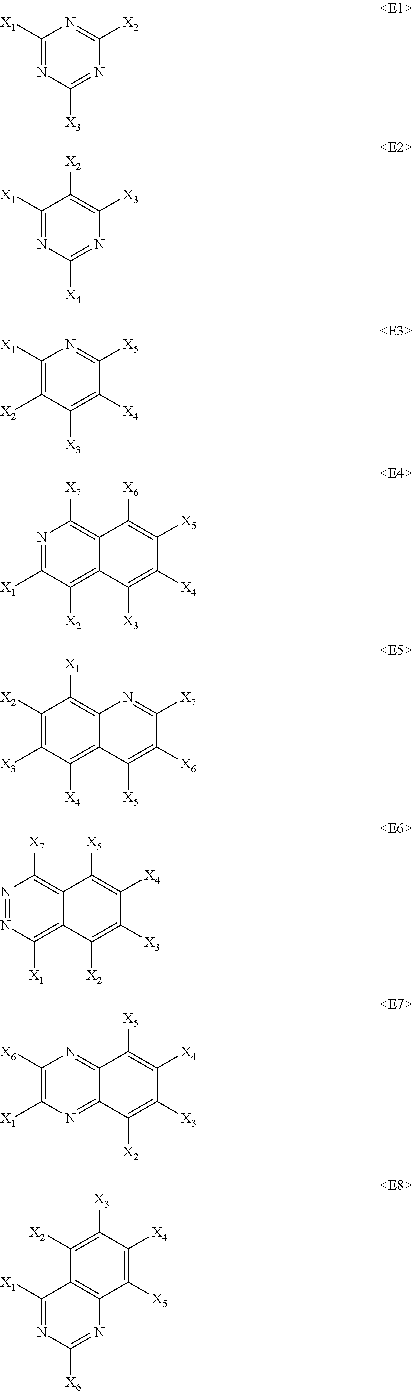 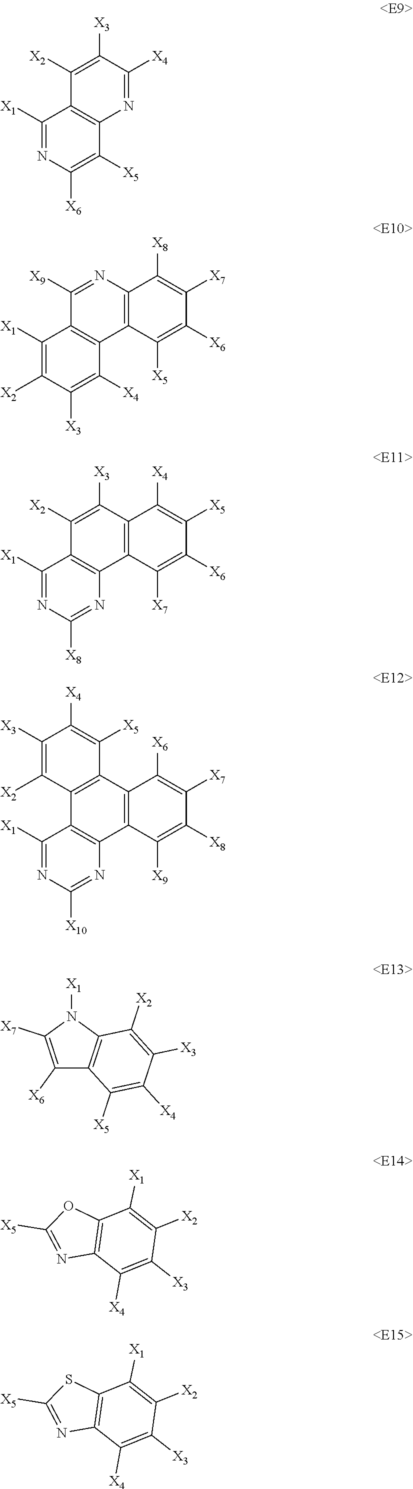 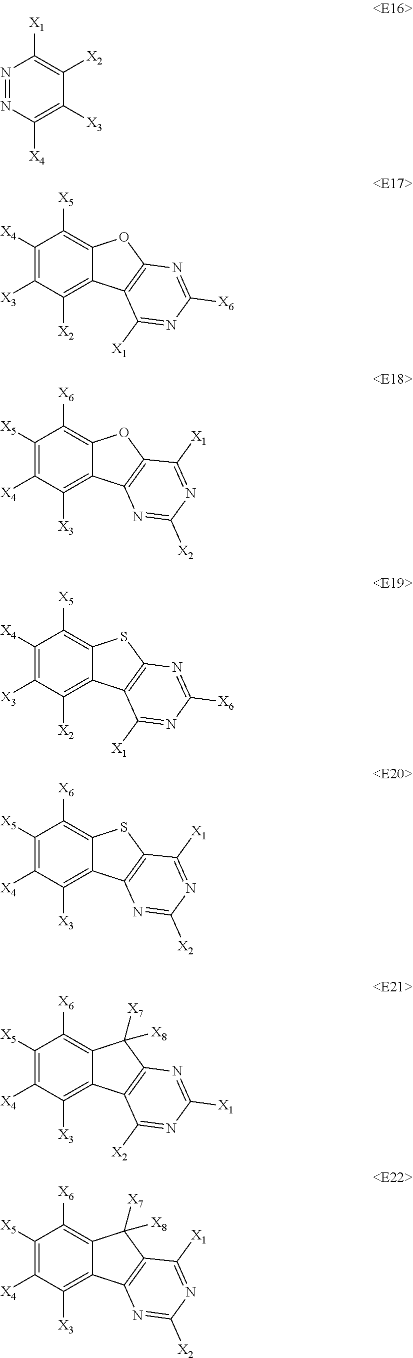 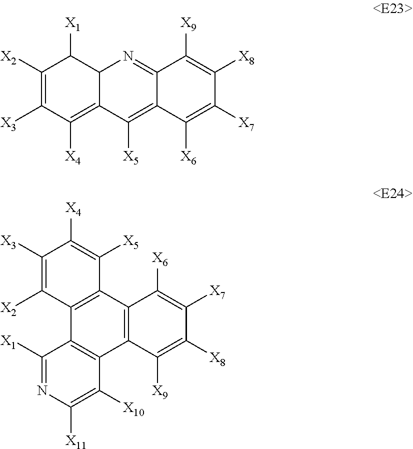
wherein,
X₁ to X₁₁, which are same or different, are each independently selected from a hydrogen atom, a deuterium atom, a halogen, a nitrile, a substituted or unsubstituted alkyl of 1 to 30 carbon atoms, a substituted or unsubstituted cycloalkyl of 3 to 30 carbon atoms, a substituted or unsubstituted aryl of 6 to 30 carbon atoms, or a substituted or unsubstituted heteroaryl of 3 to 30 carbon atoms,
m₁ substituents of the substituents X₁ to X₁₁ in E1 to E24 are each a single bond connected to the linker L in Chemical Formula D.

3. The organic light-emitting diode of claim 1, wherein the linkers L₁ to L₃ of Chemical Formula A, which are same or different, are each independently a single bond or any one selected from the following [Structural Formula 22] to [Structural Formula 30], and p, q, and r are each 1 or 2: 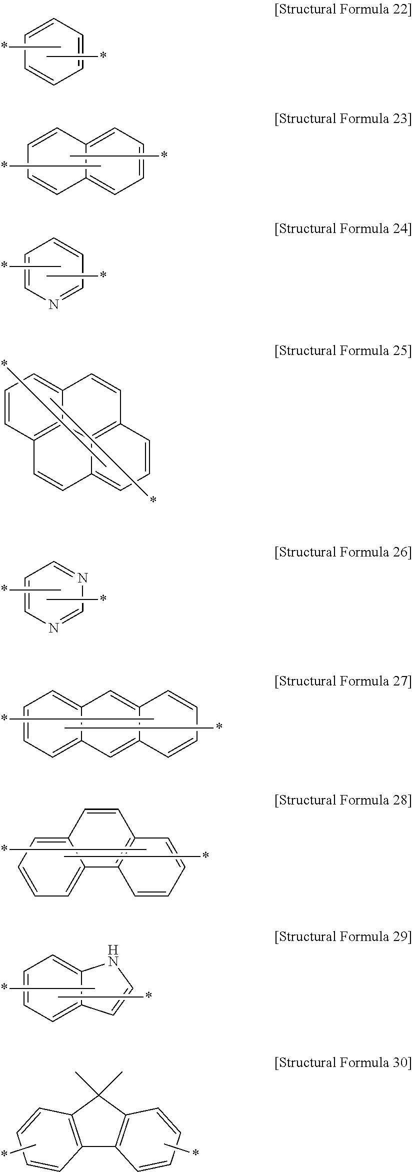
wherein each of the unsubstituted carbon atoms of the aromatic ring moiety are bound with a hydrogen atom or a deuterium atom.

4. The organic light-emitting diode of claim 1, wherein the linker L of Chemical Formula D is a single bond or any one selected from the following [Structural Formula 22] to [Structural Formula 30], and n₂ of Chemical Formula D is 1 or 2: 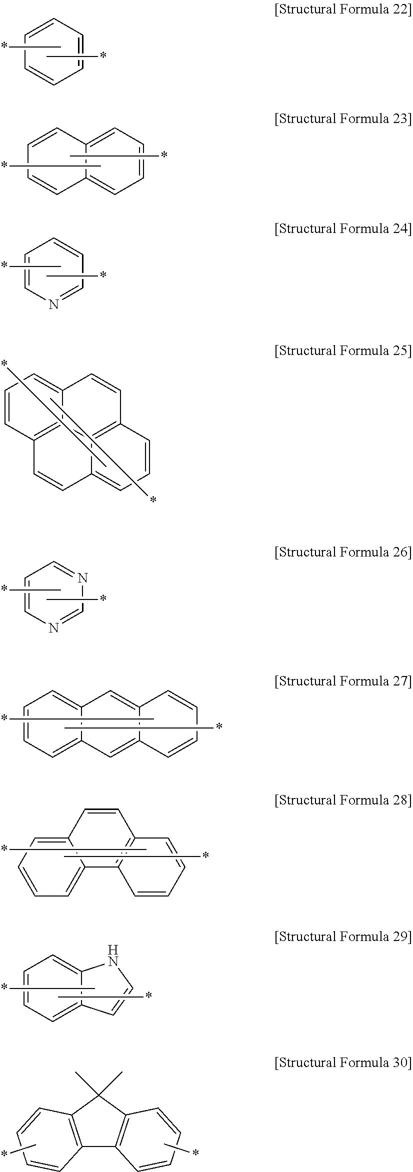
wherein, each of the unsubstituted carbon atoms of the aromatic ring moiety is bound with a hydrogen atom or a deuterium atom.

5. The organic light-emitting diode of claim 1, wherein Ar₁ and Ar₂ in Chemical Formula A, which are same or different, are each independently any one selected from a substituted or unsubstituted aryl of 6 to 30 carbon atoms, and a substituted or unsubstituted heteroaryl of 3 to 30 carbon atoms.

6. The organic light-emitting diode of claim 1, wherein R₂₀ to R₃₁ in Chemical Formula D, which are same or different, are each independently any one selected from a hydrogen atom, a deuterium atom, a halogen, a cyano, a substituted or unsubstituted alkyl of 1 to 30 carbon atoms, a substituted or unsubstituted cycloalkyl of 3 to 30 carbon atoms, a substituted or unsubstituted aryl of 6 to 30 carbon atoms, and a substituted or unsubstituted heteroaryl of 3 to 30 carbon atoms.

7. The organic light-emitting diode of claim 1, wherein at least one of HAr₄ in Chemical Formula D is a fused ring represented by the following [Structural Formula 9] or [Structural Formula 10]: 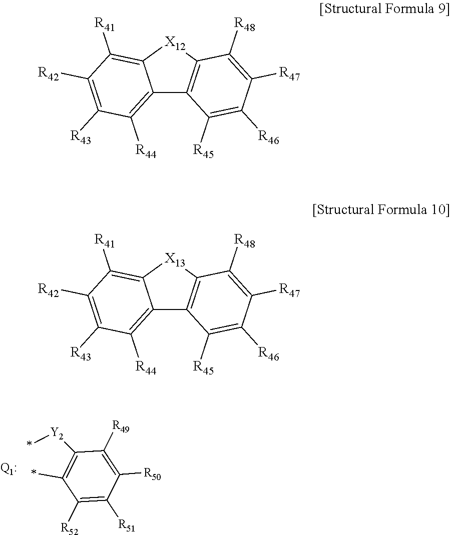
wherein,
X₁₂ is any one selected from O, S, NR₄₉, and CR₅₀R₅₁,
any one of R₄₁ to R₄₈ in Structural Formula 9 is a single bond connected to the linker L in Chemical Formula D,
X₁₃ is any one selected from O, S, NR₅₃, and CR₅₄R₅₅,
Y₂ is any one selected from O, S, NR₅₆, and CR₅₇R₅₈,
any one of R₄₁ to R₅₂ in Structural Formula 10 is a single bond connected to the linker L in Chemical Formula D,
two adjacent substituents of the substituents R₄₅ to R₄₈ are each a single bond connected to respective * in Structural Formula Q1,
R₄₁ to R₅₈, which are same or different, are each independently any one selected from a hydrogen atom, a deuterium atom, a halogen, a cyano, a substituted or unsubstituted alkyl of 1 to 20 carbon atoms, a substituted or unsubstituted cycloalkyl of 3 to 20 carbon atoms, a substituted or unsubstituted alkoxy of 1 to 20 carbon atoms, a substituted or unsubstituted aryloxy of 6 to 30 carbon atoms, a substituted or unsubstituted alkylthio of 1 to 20 carbon atoms, a substituted or unsubstituted arylthio of 6 to 30 carbon atoms, a substituted or unsubstituted alkylsilyl of 3 to 50 carbon atoms, a substituted or unsubstituted arylsilyl of 6 to 50 carbon atoms, a substituted or unsubstituted aromatic hydrocarbon of 6 to 30 carbon atoms, and a substituted or unsubstituted hetero ring of 5 to 30 carbon atoms.

8. The organic light-emitting diode of claim 1, wherein Ar₁ or Ar₂ in Chemical Formula A is a substituent represented by the following Structural Formula 11: 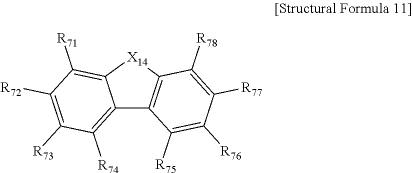
wherein,
X₁₄ is any one selected from O, S, and CR₇₉R₈₀,
R₇₁ to R₈₀, which are same or different, are each independently any one selected from a hydrogen atom, a deuterium atom, a halogen, a cyano, a substituted or unsubstituted alkyl of 1 to 20 carbon atoms, a substituted or unsubstituted cycloalkyl of 3 to 20 carbon atoms, a substituted or unsubstituted alkoxy of 1 to 20 carbon atoms, a substituted or unsubstituted aryloxy of 6 to 30 carbon atoms, a substituted or unsubstituted alkylthio of 1 to 20 carbon atoms, a substituted or unsubstituted arylthio of 6 to 30 carbon atoms, a substituted or unsubstituted alkylsilyl of 3 to 50 carbon atoms, a substituted or unsubstituted arylsilyl of 6 to 50 carbon atoms, a substituted or unsubstituted aromatic hydrocarbon of 6 to 30 carbon atoms, and a substituted or unsubstituted hetero ring of 5 to 30 carbon atoms, and
any one of R₇₁ to R₇₈ is a single bond connected to the linker L₂ or L₃ in Chemical Formula A.

9. The organic light-emitting diode of claim 1, wherein any one of R₉ to R₁₂ in Chemical Formula A is a single bond connected to the linker L₁.

10. The organic light-emitting diode of claim 1, wherein the fused ring compound represented by Chemical Formula A is any one selected from the group consisting of the compounds represented by Compounds H1 to H208, but is not limited thereto:

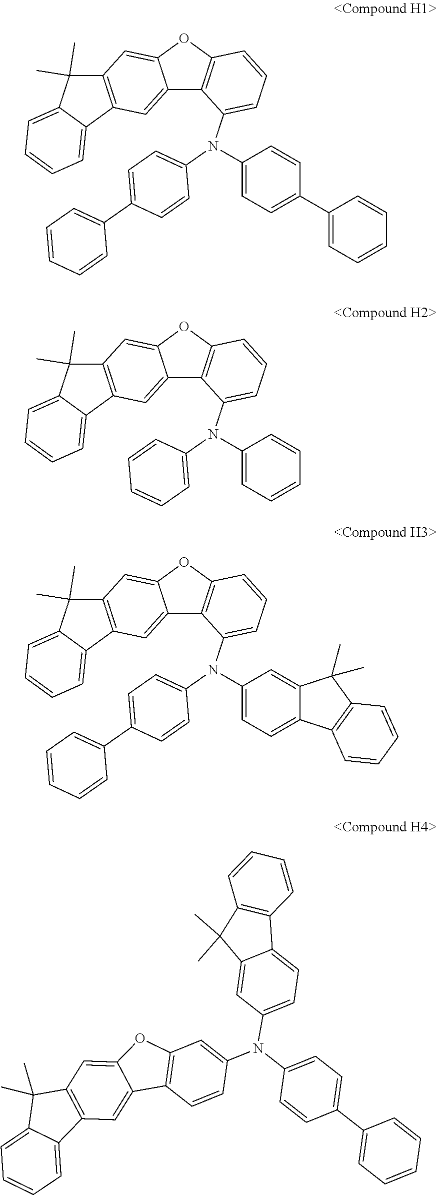 [SMILES: CC1(C)c2ccccc2-c2cc3c(cc21)oc1cccc(N(c2ccc(-c4ccccc4)cc2)c2ccc(-c4ccccc4)cc2)c13 ; CC1(C)c2ccccc2-c2cc3c(cc21)oc1cccc(N(c2ccccc2)c2ccccc2)c13 ; CC1(C)c2ccccc2-c2ccc(N(c3ccc(-c4ccccc4)cc3)c3cccc4oc5cc6c(cc5c34)-c3ccccc3C6(C)C)cc21 ; CC1(C)c2ccccc2-c2ccc(N(c3ccc(-c4ccccc4)cc3)c3ccc4c(c3)oc3cc5c(cc34)-c3ccccc3C5(C)C)cc21]

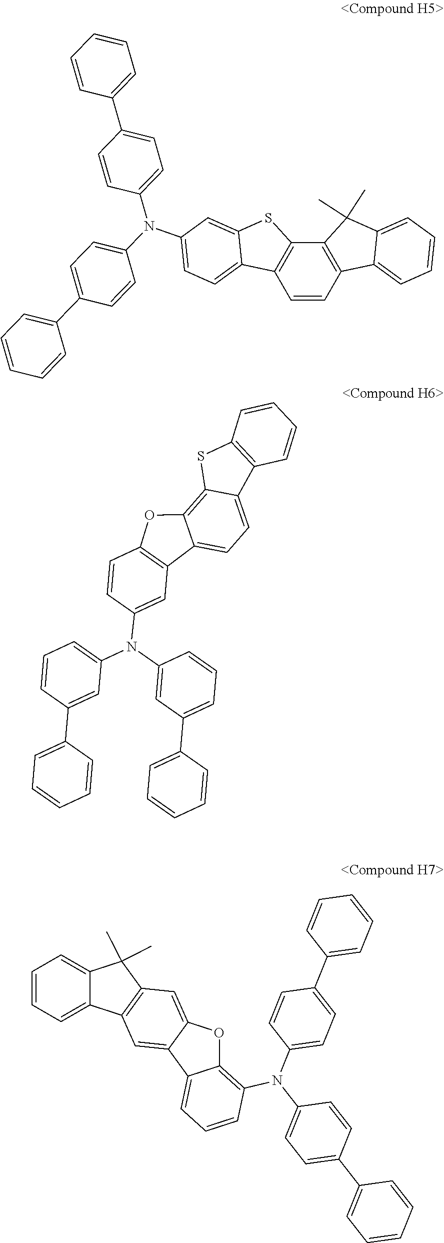 [SMILES: CC1(C)c2ccccc2-c2ccc3c(sc4cc(N(c5ccc(-c6ccccc6)cc5)c5ccc(-c6ccccc6)cc5)ccc43)c21 ; c1ccc(-c2cccc(N(c3cccc(-c4ccccc4)c3)c3ccc4oc5c(ccc6c7ccccc7sc65)c4c3)c2)cc1 ; CC1(C)c2ccccc2-c2cc3c(cc21)oc1c(N(c2ccc(-c4ccccc4)cc2)c2ccc(-c4ccccc4)cc2)cccc13]

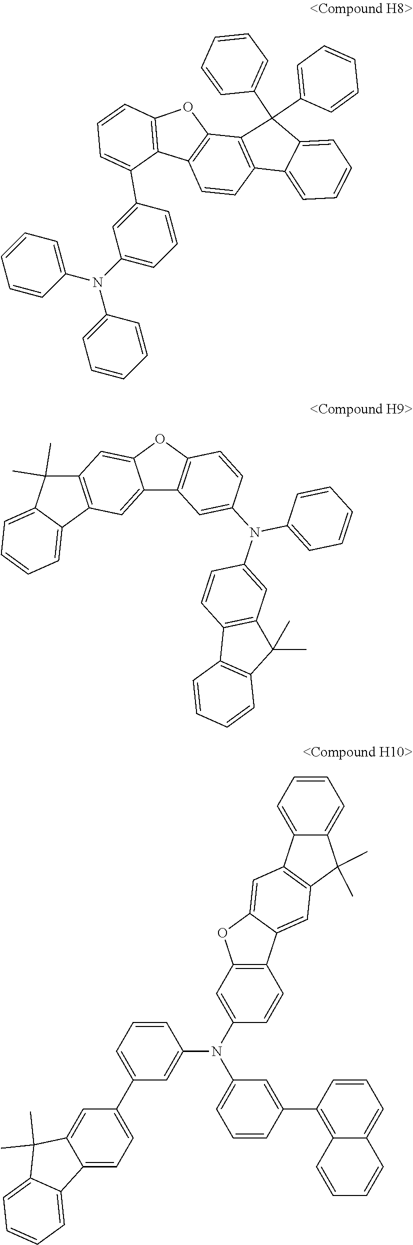 [SMILES: c1ccc(N(c2ccccc2)c2cccc(-c3cccc4oc5c6c(ccc5c34)-c3ccccc3C6(c3ccccc3)c3ccccc3)c2)cc1 ; CC1(C)c2ccccc2-c2ccc(N(c3ccccc3)c3ccc4oc5cc6c(cc5c4c3)-c3ccccc3C6(C)C)cc21 ; CC1(C)c2ccccc2-c2ccc(-c3cccc(N(c4cccc(-c5cccc6ccccc56)c4)c4ccc5c(c4)oc4cc6c(cc45)C(C)(C)c4ccccc4-6)c3)cc21]

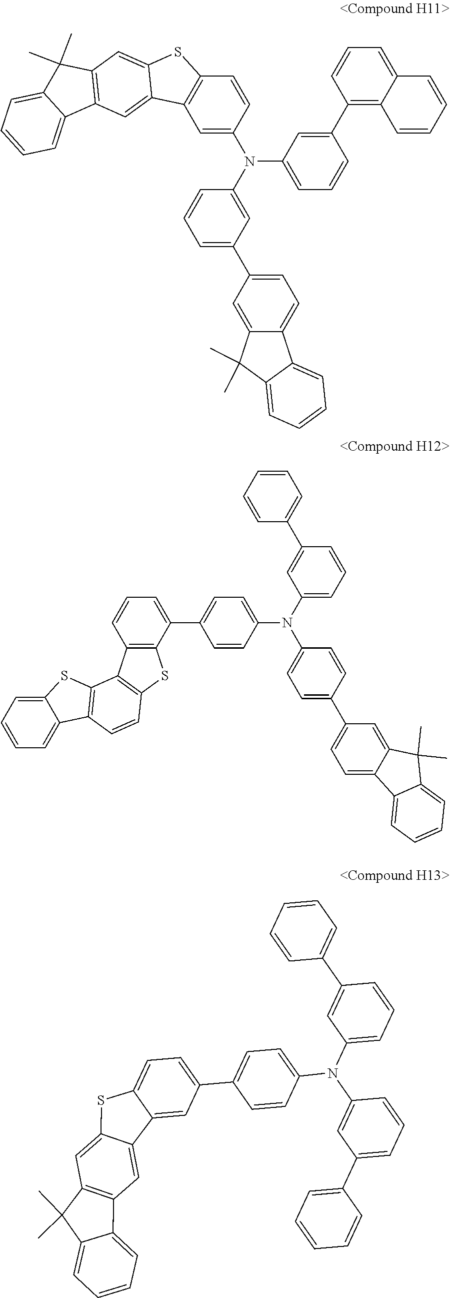

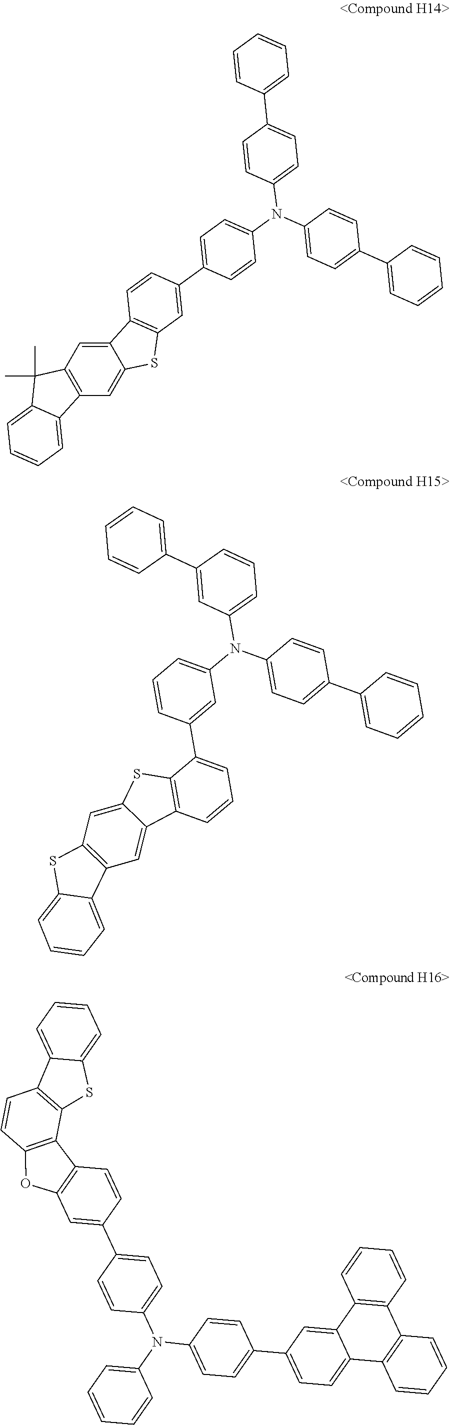 [SMILES: CC1(C)c2ccccc2-c2cc3sc4cc(-c5ccc(N(c6ccc(-c7ccccc7)cc6)c6ccc(-c7ccccc7)cc6)cc5)ccc4c3cc21 ; c1ccc(-c2ccc(N(c3cccc(-c4ccccc4)c3)c3cccc(-c4cccc5c4sc4cc6sc7ccccc7c6cc45)c3)cc2)cc1 ; c1ccc(N(c2ccc(-c3ccc4c(c3)oc3ccc5c6ccccc6sc5c34)cc2)c2ccc(-c3ccc4c5ccccc5c5ccccc5c4c3)cc2)cc1]

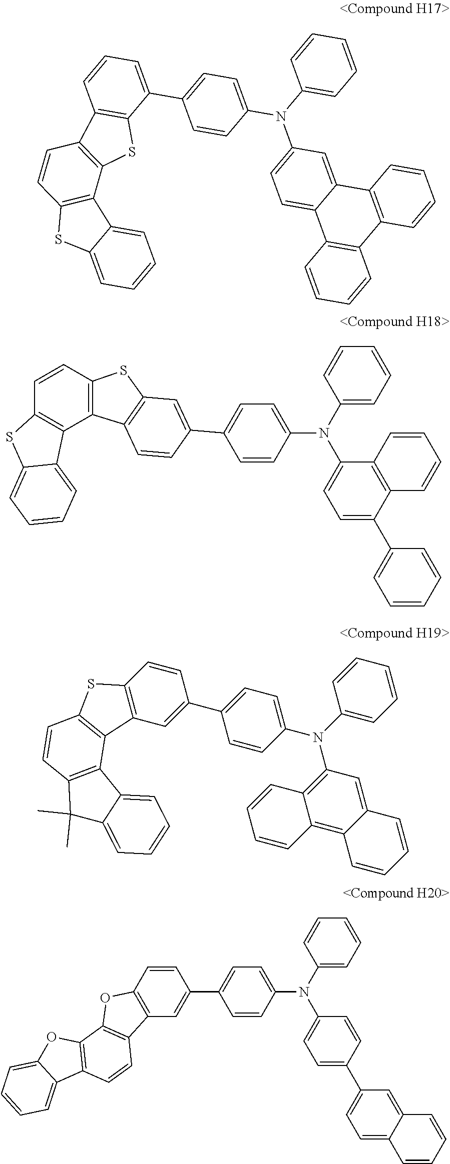

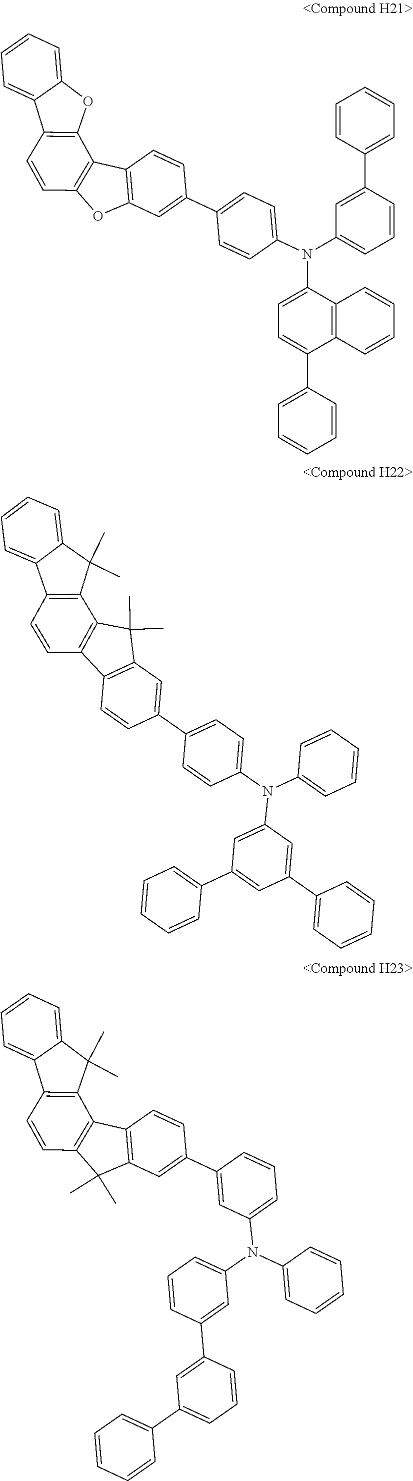 [SMILES: c1ccc(-c2cccc(N(c3ccc(-c4ccc5c(c4)oc4ccc6c7ccccc7oc6c45)cc3)c3ccc(-c4ccccc4)c4ccccc34)c2)cc1 ; CC1(C)c2ccccc2-c2ccc3c(c21)C(C)(C)c1cc(-c2ccc(N(c4ccccc4)c4cc(-c5ccccc5)cc(-c5ccccc5)c4)cc2)ccc1-3 ; CC1(C)c2cc(-c3cccc(N(c4ccccc4)c4cccc(-c5cccc(-c6ccccc6)c5)c4)c3)ccc2-c2c1ccc1c2C(C)(C)c2ccccc2-1]

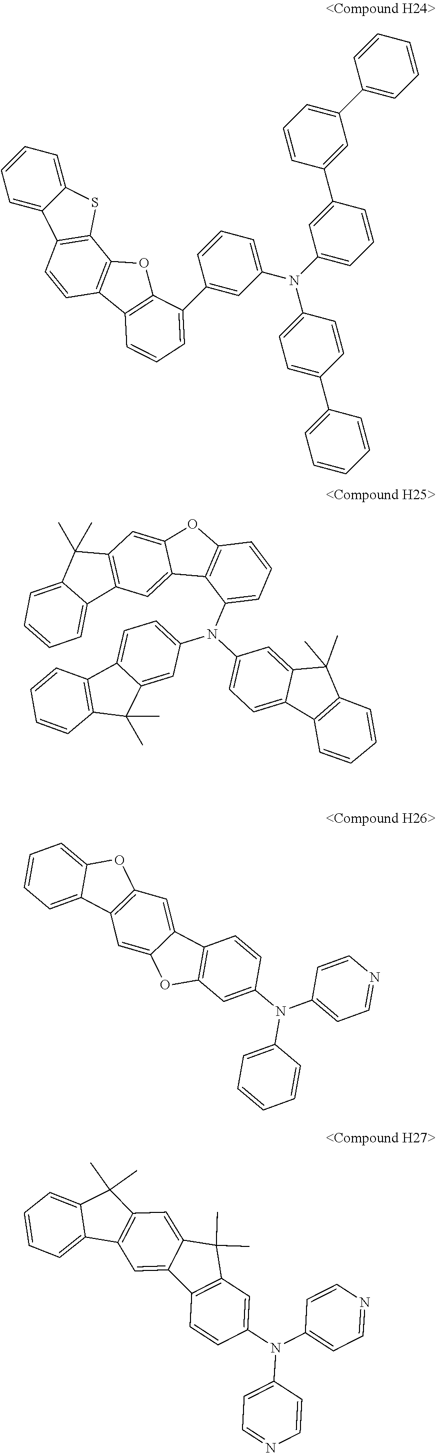 [SMILES: c1ccc(-c2ccc(N(c3cccc(-c4cccc(-c5ccccc5)c4)c3)c3cccc(-c4cccc5c4oc4c5ccc5c6ccccc6sc54)c3)cc2)cc1 ; CC1(C)c2ccccc2-c2ccc(N(c3ccc4c(c3)C(C)(C)c3ccccc3-4)c3cccc4oc5cc6c(cc5c34)-c3ccccc3C6(C)C)cc21 ; c1ccc(N(c2ccncc2)c2ccc3c(c2)oc2cc4c(cc23)oc2ccccc24)cc1 ; CC1(C)c2ccccc2-c2cc3c(cc21)C(C)(C)c1cc(N(c2ccncc2)c2ccncc2)ccc1-3]

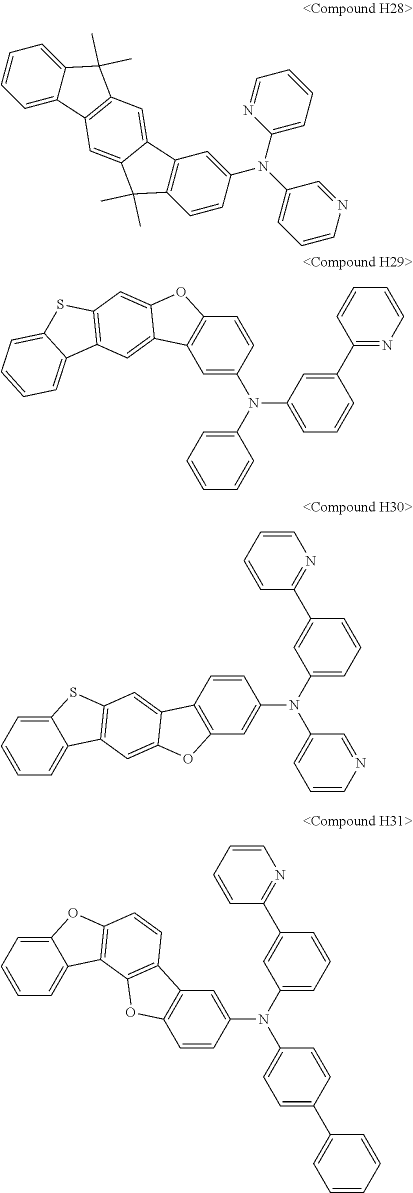 [SMILES: CC1(C)c2ccccc2-c2cc3c(cc21)-c1cc(N(c2cccnc2)c2ccccn2)ccc1C3(C)C ; c1ccc(N(c2cccc(-c3ccccn3)c2)c2ccc3oc4cc5sc6ccccc6c5cc4c3c2)cc1 ; c1ccc(-c2cccc(N(c3cccnc3)c3ccc4c(c3)oc3cc5c(cc34)sc3ccccc35)c2)nc1 ; c1ccc(-c2ccc(N(c3cccc(-c4ccccn4)c3)c3ccc4oc5c(ccc6oc7ccccc7c65)c4c3)cc2)cc1]

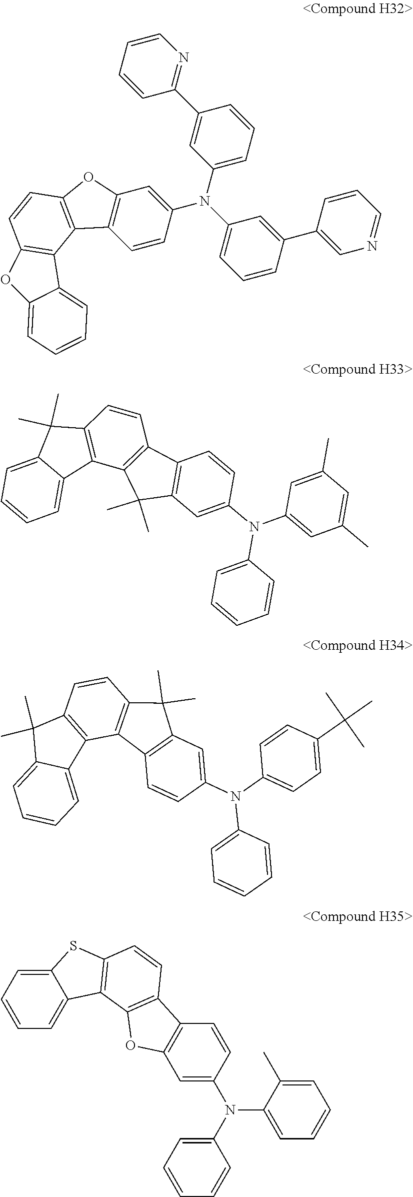

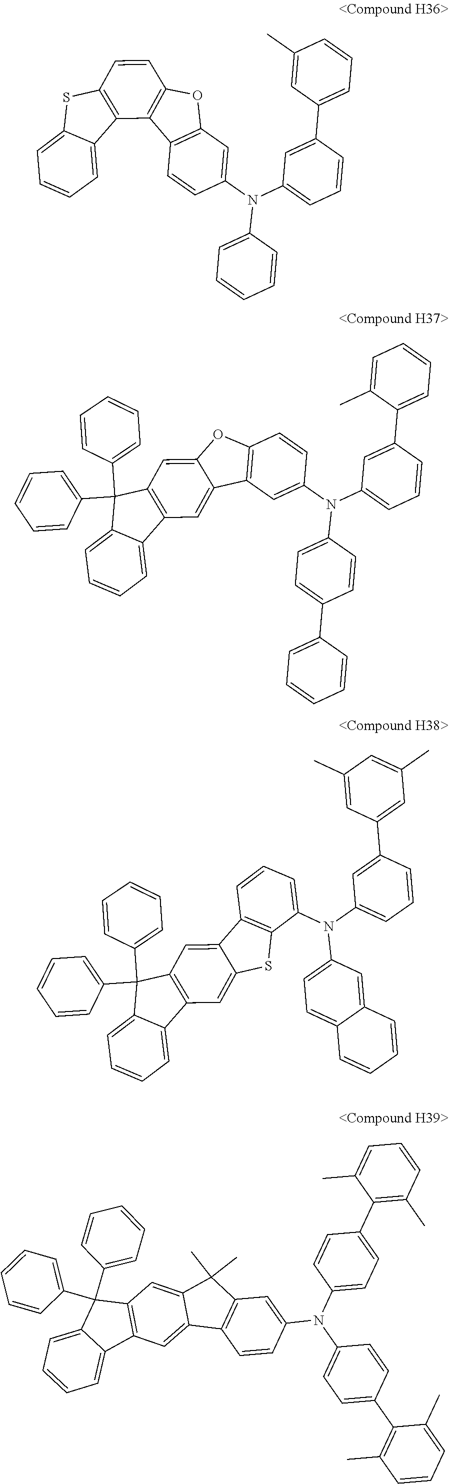 [SMILES: Cc1cccc(-c2cccc(N(c3ccccc3)c3ccc4c(c3)oc3ccc5sc6ccccc6c5c34)c2)c1 ; Cc1ccccc1-c1cccc(N(c2ccc(-c3ccccc3)cc2)c2ccc3oc4cc5c(cc4c3c2)-c2ccccc2C5(c2ccccc2)c2ccccc2)c1 ; Cc1cc(C)cc(-c2cccc(N(c3ccc4ccccc4c3)c3cccc4c3sc3cc5c(cc34)C(c3ccccc3)(c3ccccc3)c3ccccc3-5)c2)c1 ; Cc1cccc(C)c1-c1ccc(N(c2ccc(-c3c(C)cccc3C)cc2)c2ccc3c(c2)C(C)(C)c2cc4c(cc2-3)-c2ccccc2C4(c2ccccc2)c2ccccc2)cc1]

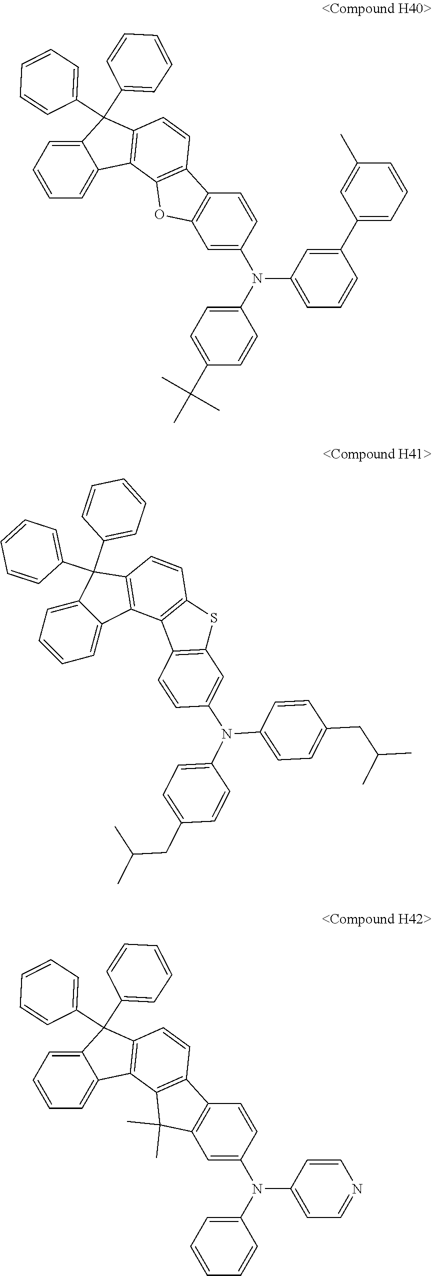

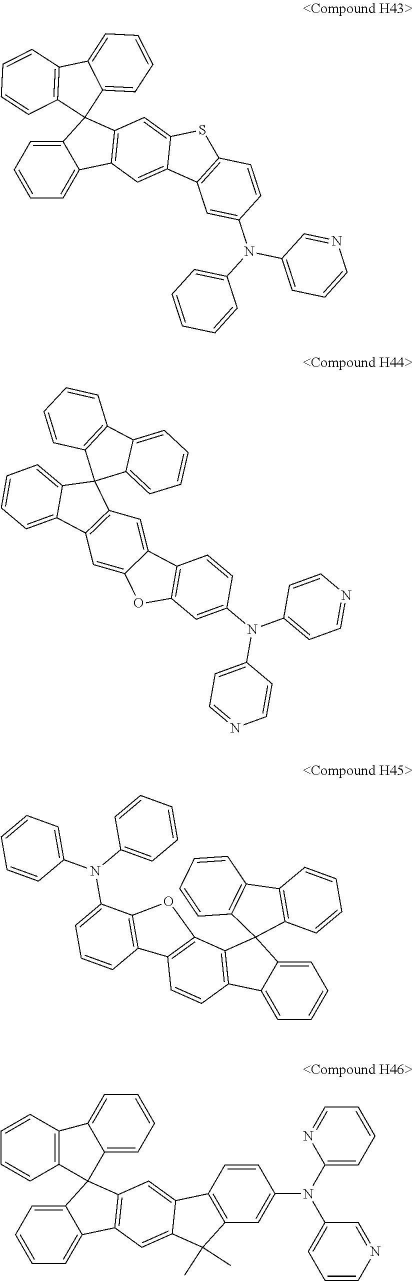

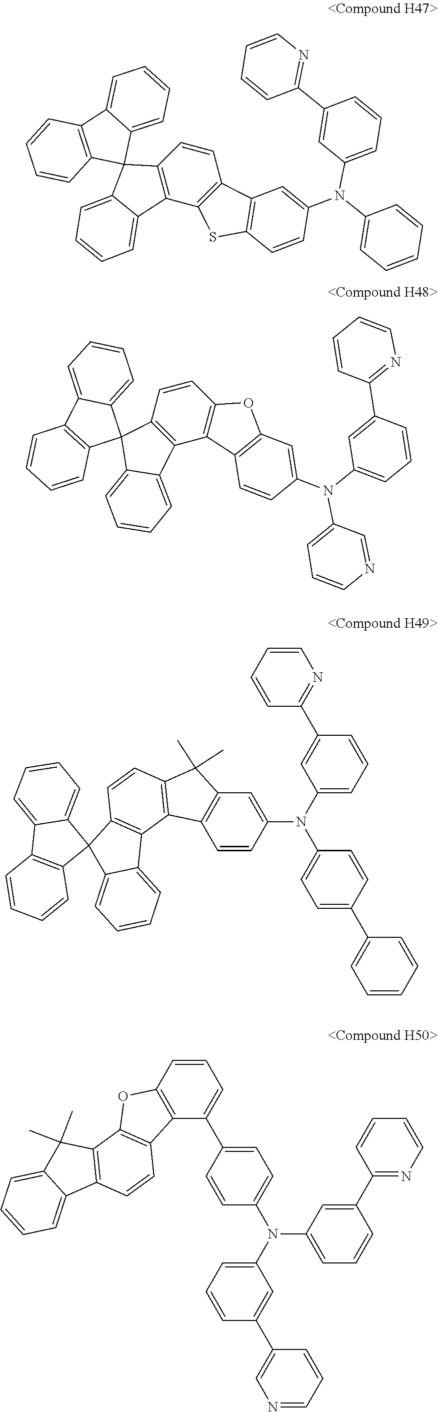 [SMILES: c1ccc(N(c2cccc(-c3ccccn3)c2)c2ccc3sc4c5c(ccc4c3c2)C2(c3ccccc3-c3ccccc32)c2ccccc2-5)cc1 ; c1ccc(-c2cccc(N(c3cccnc3)c3ccc4c(c3)oc3ccc5c(c34)-c3ccccc3C53c4ccccc4-c4ccccc43)c2)nc1 ; CC1(C)c2cc(N(c3ccc(-c4ccccc4)cc3)c3cccc(-c4ccccn4)c3)ccc2-c2c1ccc1c2-c2ccccc2C12c1ccccc1-c1ccccc12 ; CC1(C)c2ccccc2-c2ccc3c(oc4cccc(-c5ccc(N(c6cccc(-c7cccnc7)c6)c6cccc(-c7ccccn7)c6)cc5)c43)c21]

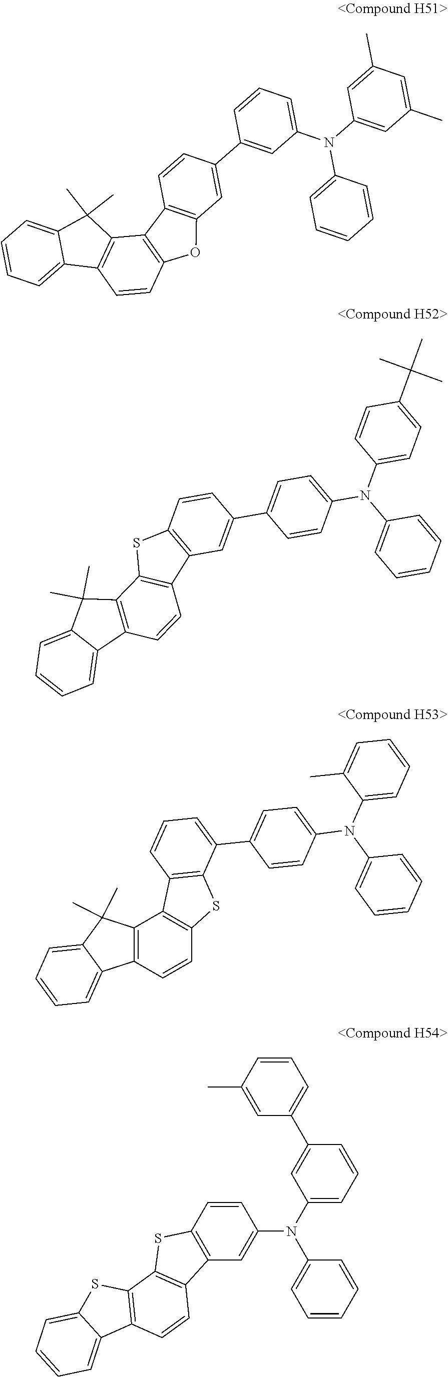 [SMILES: Cc1cc(C)cc(N(c2ccccc2)c2cccc(-c3ccc4c(c3)oc3ccc5c(c34)C(C)(C)c3ccccc3-5)c2)c1 ; CC(C)(C)c1ccc(N(c2ccccc2)c2ccc(-c3ccc4sc5c6c(ccc5c4c3)-c3ccccc3C6(C)C)cc2)cc1 ; Cc1ccccc1N(c1ccccc1)c1ccc(-c2cccc3c2sc2ccc4c(c23)C(C)(C)c2ccccc2-4)cc1 ; Cc1cccc(-c2cccc(N(c3ccccc3)c3ccc4sc5c(ccc6c7ccccc7sc65)c4c3)c2)c1]

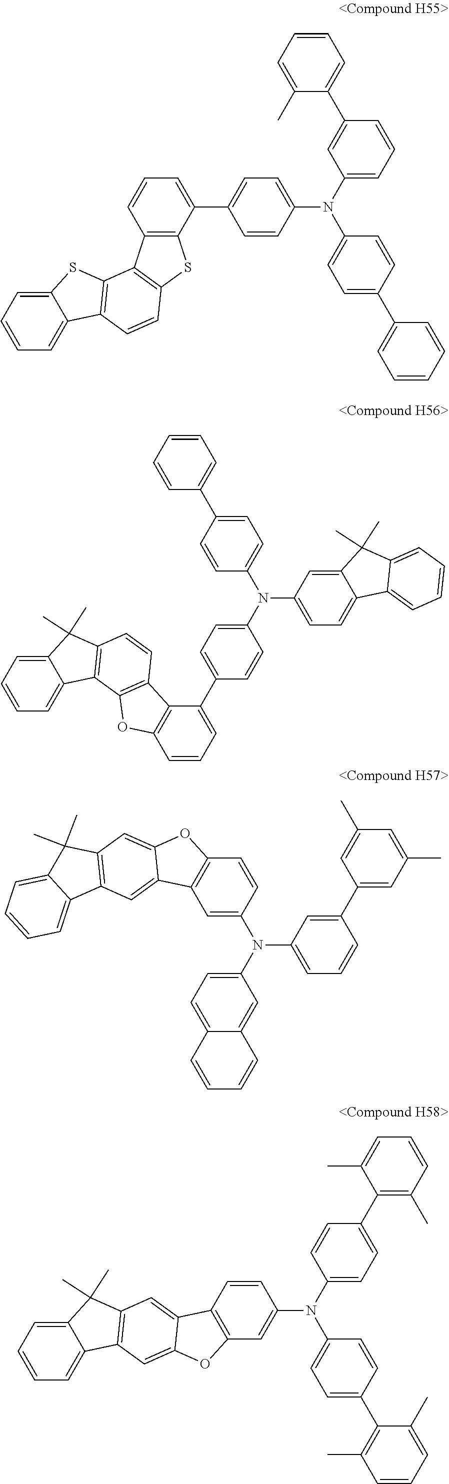 [SMILES: Cc1ccccc1-c1cccc(N(c2ccc(-c3ccccc3)cc2)c2ccc(-c3cccc4c3sc3ccc5c6ccccc6sc5c34)cc2)c1 ; CC1(C)c2ccccc2-c2ccc(N(c3ccc(-c4ccccc4)cc3)c3ccc(-c4cccc5oc6c7c(ccc6c45)C(C)(C)c4ccccc4-7)cc3)cc21 ; Cc1cc(C)cc(-c2cccc(N(c3ccc4ccccc4c3)c3ccc4oc5cc6c(cc5c4c3)-c3ccccc3C6(C)C)c2)c1 ; Cc1cccc(C)c1-c1ccc(N(c2ccc(-c3c(C)cccc3C)cc2)c2ccc3c(c2)oc2cc4c(cc23)C(C)(C)c2ccccc2-4)cc1]

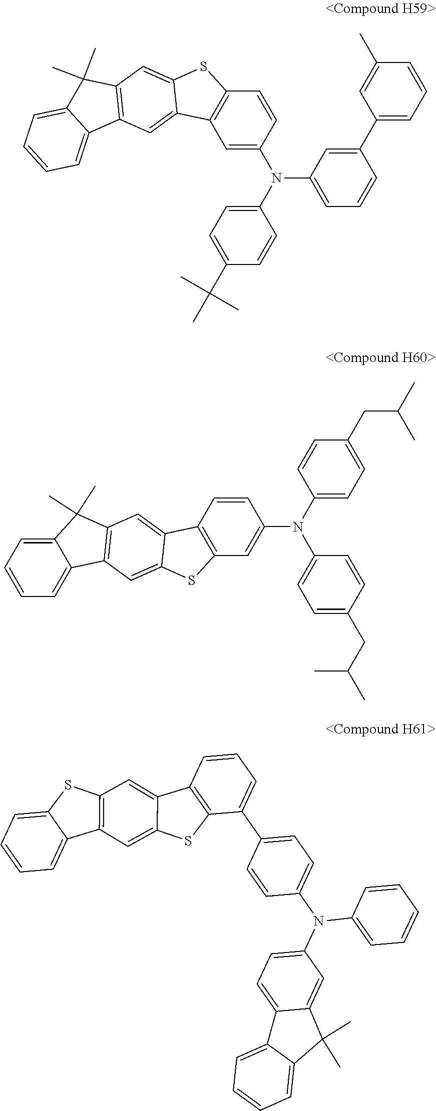 [SMILES: Cc1cccc(-c2cccc(N(c3ccc(C(C)(C)C)cc3)c3ccc4sc5cc6c(cc5c4c3)-c3ccccc3C6(C)C)c2)c1 ; CC(C)Cc1ccc(N(c2ccc(CC(C)C)cc2)c2ccc3c(c2)sc2cc4c(cc23)C(C)(C)c2ccccc2-4)cc1 ; CC1(C)c2ccccc2-c2ccc(N(c3ccccc3)c3ccc(-c4cccc5c4sc4cc6c(cc45)sc4ccccc46)cc3)cc21]

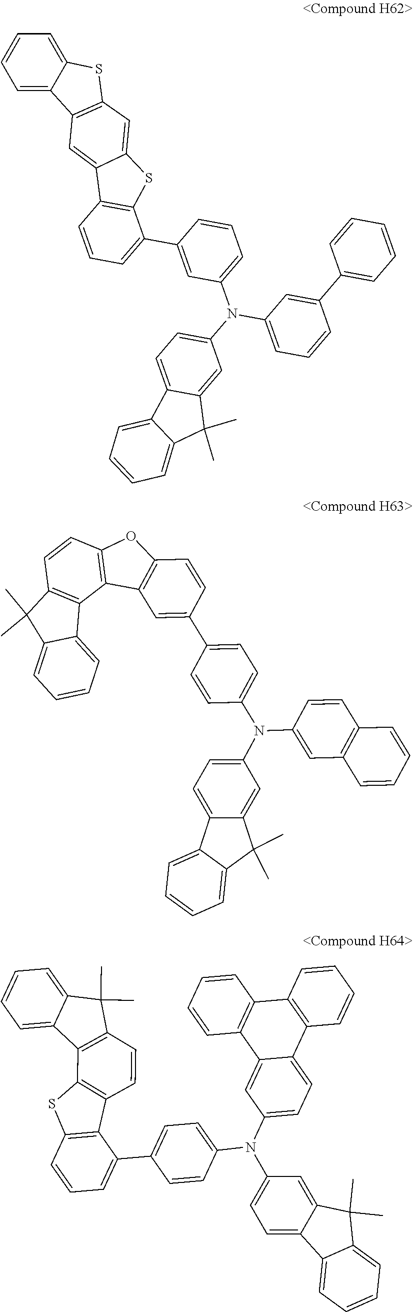 [SMILES: CC1(C)c2ccccc2-c2ccc(N(c3cccc(-c4ccccc4)c3)c3cccc(-c4cccc5c4sc4cc6sc7ccccc7c6cc45)c3)cc21 ; CC1(C)c2ccccc2-c2ccc(N(c3ccc(-c4ccc5oc6ccc7c(c6c5c4)-c4ccccc4C7(C)C)cc3)c3ccc4ccccc4c3)cc21 ; CC1(C)c2ccccc2-c2ccc(N(c3ccc(-c4cccc5sc6c7c(ccc6c45)C(C)(C)c4ccccc4-7)cc3)c3ccc4c5ccccc5c5ccccc5c4c3)cc21]

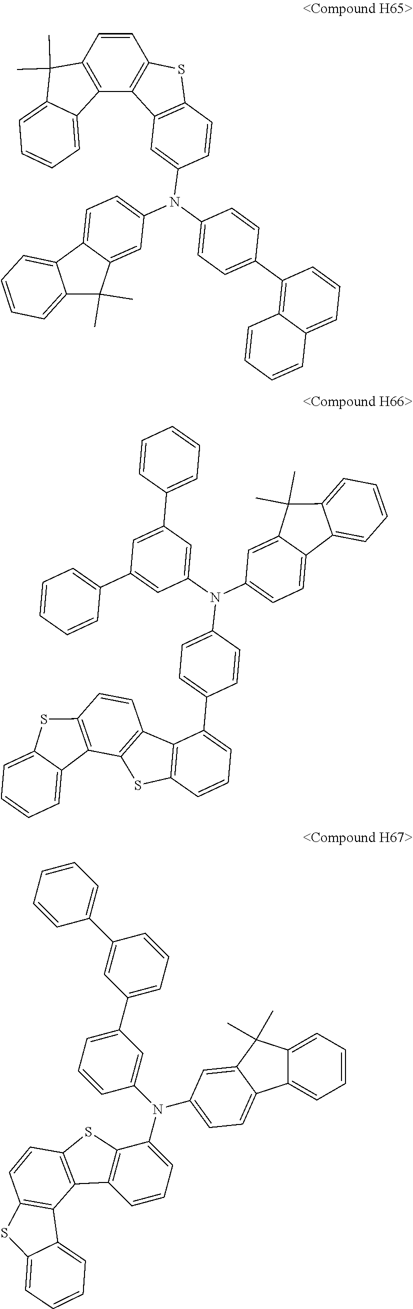 [SMILES: CC1(C)c2ccccc2-c2ccc(N(c3ccc(-c4cccc5ccccc45)cc3)c3ccc4sc5ccc6c(c5c4c3)-c3ccccc3C6(C)C)cc21 ; CC1(C)c2ccccc2-c2ccc(N(c3ccc(-c4cccc5sc6c(ccc7sc8ccccc8c76)c45)cc3)c3cc(-c4ccccc4)cc(-c4ccccc4)c3)cc21 ; CC1(C)c2ccccc2-c2ccc(N(c3cccc(-c4cccc(-c5ccccc5)c4)c3)c3cccc4c3sc3ccc5sc6ccccc6c5c34)cc21]

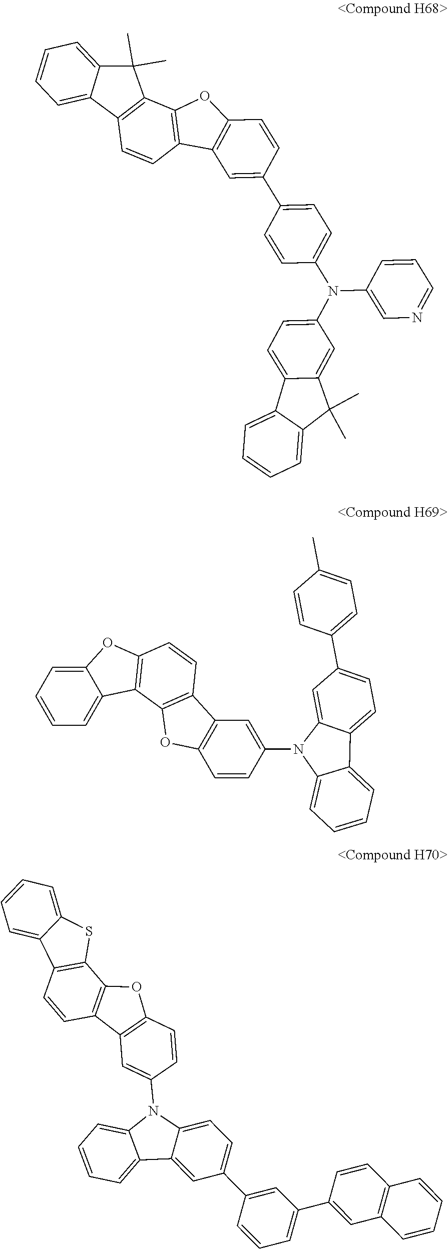 [SMILES: CC1(C)c2ccccc2-c2ccc(N(c3ccc(-c4ccc5oc6c7c(ccc6c5c4)-c4ccccc4C7(C)C)cc3)c3cccnc3)cc21 ; Cc1ccc(-c2ccc3c4ccccc4n(-c4ccc5oc6c(ccc7oc8ccccc8c76)c5c4)c3c2)cc1 ; c1cc(-c2ccc3ccccc3c2)cc(-c2ccc3c(c2)c2ccccc2n3-c2ccc3oc4c(ccc5c6ccccc6sc54)c3c2)c1]

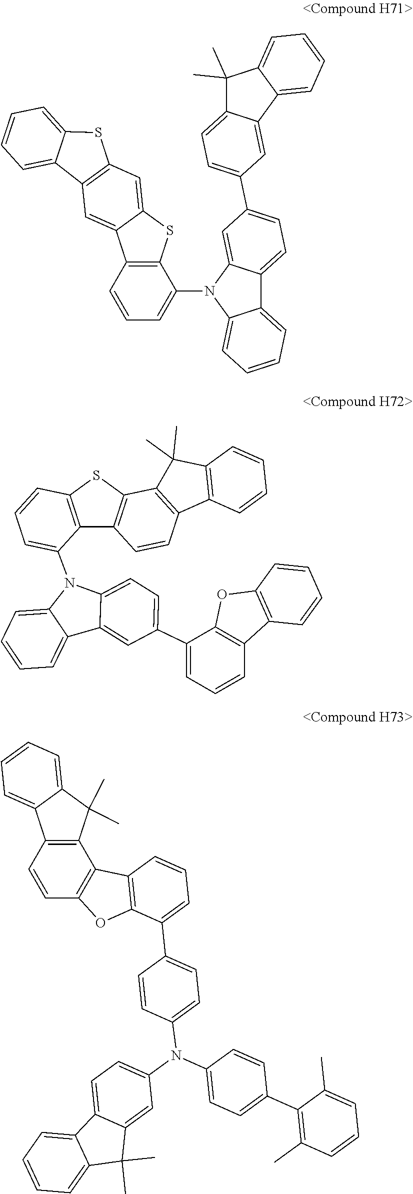 [SMILES: CC1(C)c2ccccc2-c2cc(-c3ccc4c5ccccc5n(-c5cccc6c5sc5cc7sc8ccccc8c7cc56)c4c3)ccc21 ; CC1(C)c2ccccc2-c2ccc3c(sc4cccc(-n5c6ccccc6c6cc(-c7cccc8c7oc7ccccc78)ccc65)c43)c21 ; Cc1cccc(C)c1-c1ccc(N(c2ccc(-c3cccc4c3oc3ccc5c(c34)C(C)(C)c3ccccc3-5)cc2)c2ccc3c(c2)C(C)(C)c2ccccc2-3)cc1]

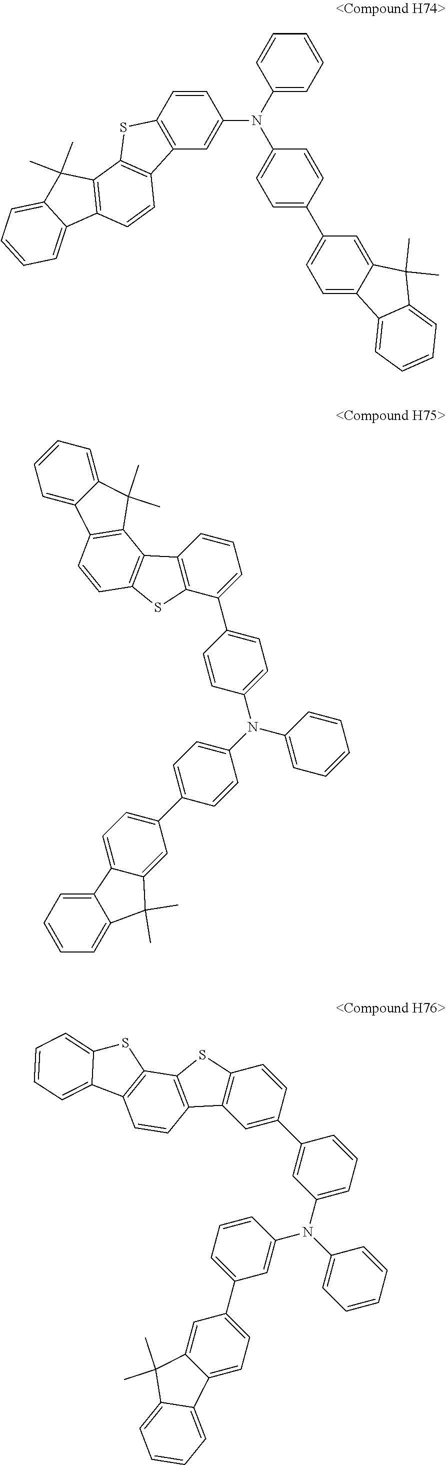 [SMILES: CC1(C)c2ccccc2-c2ccc(-c3ccc(N(c4ccccc4)c4ccc5sc6c7c(ccc6c5c4)-c4ccccc4C7(C)C)cc3)cc21 ; CC1(C)c2ccccc2-c2ccc(-c3ccc(N(c4ccccc4)c4ccc(-c5cccc6c5sc5ccc7c(c56)C(C)(C)c5ccccc5-7)cc4)cc3)cc21 ; CC1(C)c2ccccc2-c2ccc(-c3cccc(N(c4ccccc4)c4cccc(-c5ccc6sc7c(ccc8c9ccccc9sc87)c6c5)c4)c3)cc21]

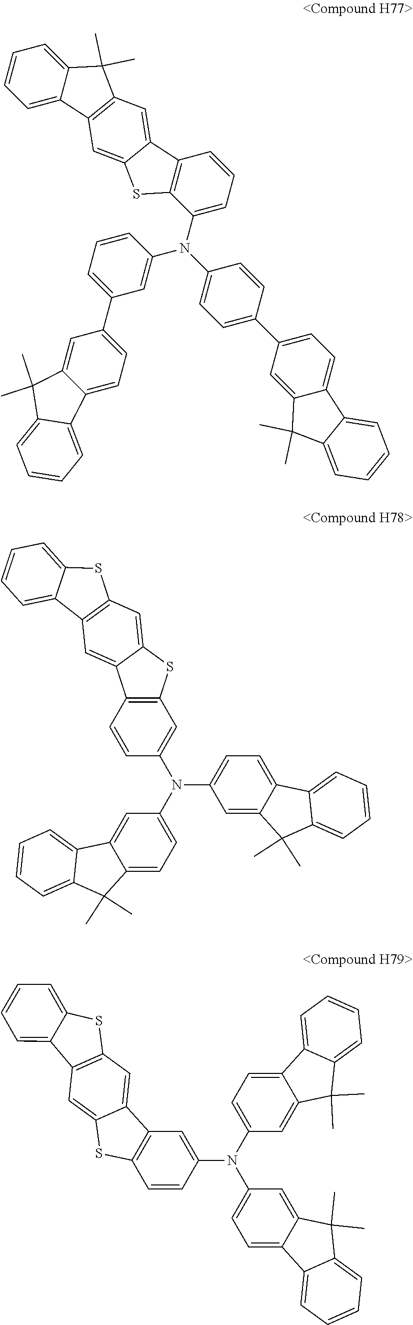 [SMILES: CC1(C)c2ccccc2-c2ccc(-c3ccc(N(c4cccc(-c5ccc6c(c5)C(C)(C)c5ccccc5-6)c4)c4cccc5c4sc4cc6c(cc45)C(C)(C)c4ccccc4-6)cc3)cc21 ; CC1(C)c2ccccc2-c2cc(N(c3ccc4c(c3)C(C)(C)c3ccccc3-4)c3ccc4c(c3)sc3cc5sc6ccccc6c5cc34)ccc21 ; CC1(C)c2ccccc2-c2ccc(N(c3ccc4c(c3)C(C)(C)c3ccccc3-4)c3ccc4sc5cc6c(cc5c4c3)sc3ccccc36)cc21]

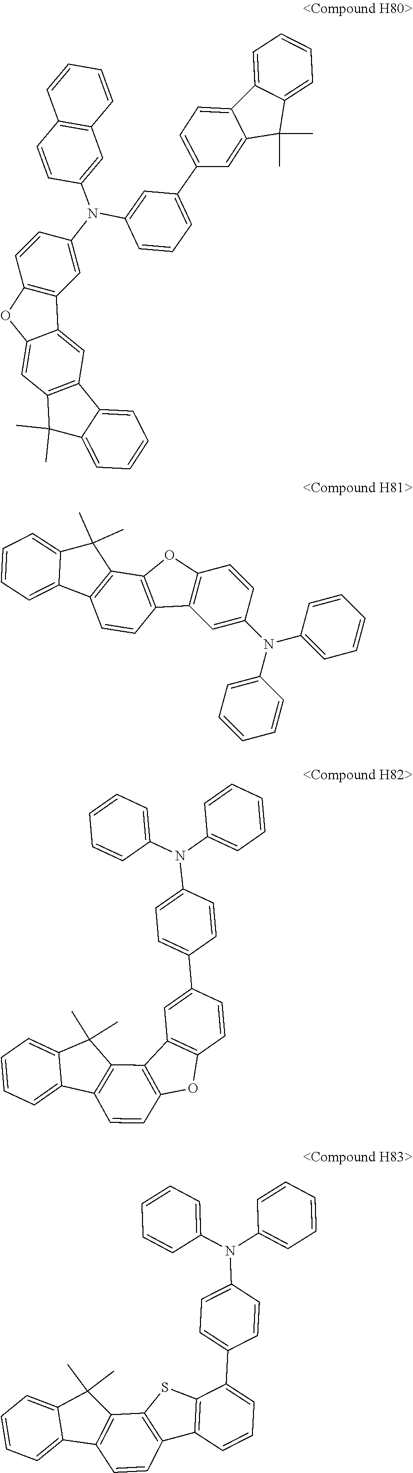

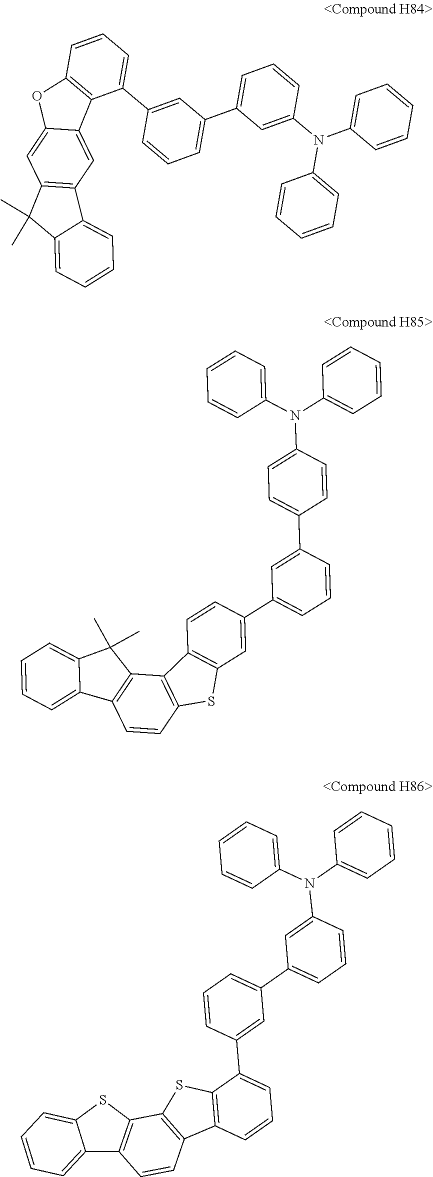 [SMILES: CC1(C)c2ccccc2-c2cc3c(cc21)oc1cccc(-c2cccc(-c4cccc(N(c5ccccc5)c5ccccc5)c4)c2)c13 ; CC1(C)c2ccccc2-c2ccc3sc4cc(-c5cccc(-c6ccc(N(c7ccccc7)c7ccccc7)cc6)c5)ccc4c3c21 ; c1ccc(N(c2ccccc2)c2cccc(-c3cccc(-c4cccc5c4sc4c5ccc5c6ccccc6sc54)c3)c2)cc1]

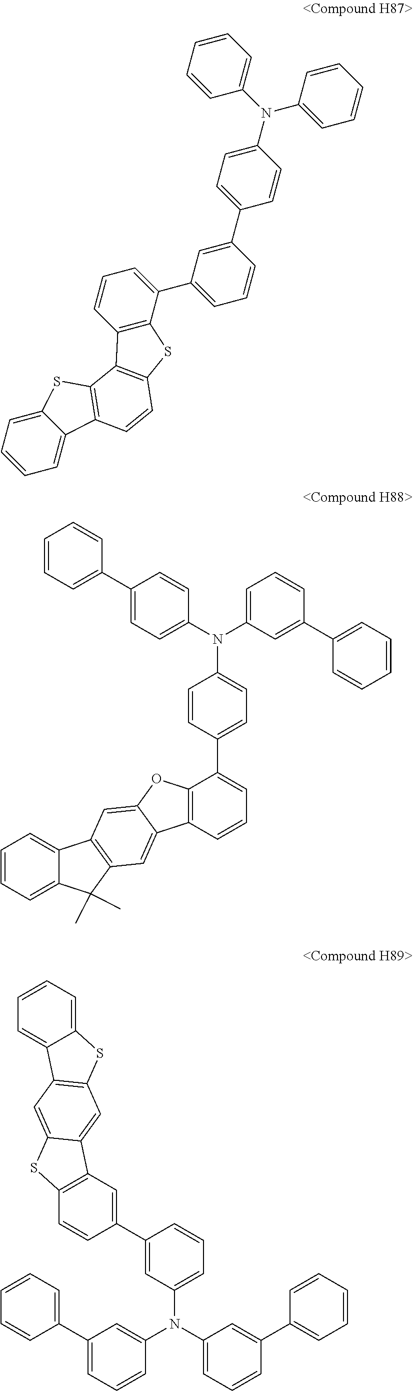 [SMILES: c1ccc(N(c2ccccc2)c2ccc(-c3cccc(-c4cccc5c4sc4ccc6c7ccccc7sc6c45)c3)cc2)cc1 ; CC1(C)c2ccccc2-c2cc3oc4c(-c5ccc(N(c6ccc(-c7ccccc7)cc6)c6cccc(-c7ccccc7)c6)cc5)cccc4c3cc21 ; c1ccc(-c2cccc(N(c3cccc(-c4ccccc4)c3)c3cccc(-c4ccc5sc6cc7c(cc6c5c4)sc4ccccc47)c3)c2)cc1]

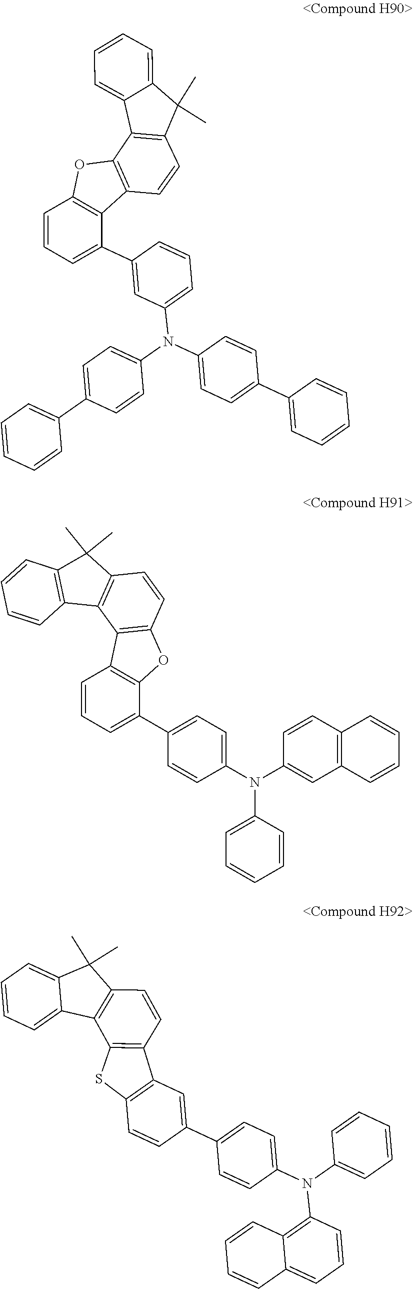 [SMILES: CC1(C)c2ccccc2-c2c1ccc1c2oc2cccc(-c3cccc(N(c4ccc(-c5ccccc5)cc4)c4ccc(-c5ccccc5)cc4)c3)c21 ; CC1(C)c2ccccc2-c2c1ccc1oc3c(-c4ccc(N(c5ccccc5)c5ccc6ccccc6c5)cc4)cccc3c21 ; CC1(C)c2ccccc2-c2c1ccc1c2sc2ccc(-c3ccc(N(c4ccccc4)c4cccc5ccccc45)cc3)cc21]

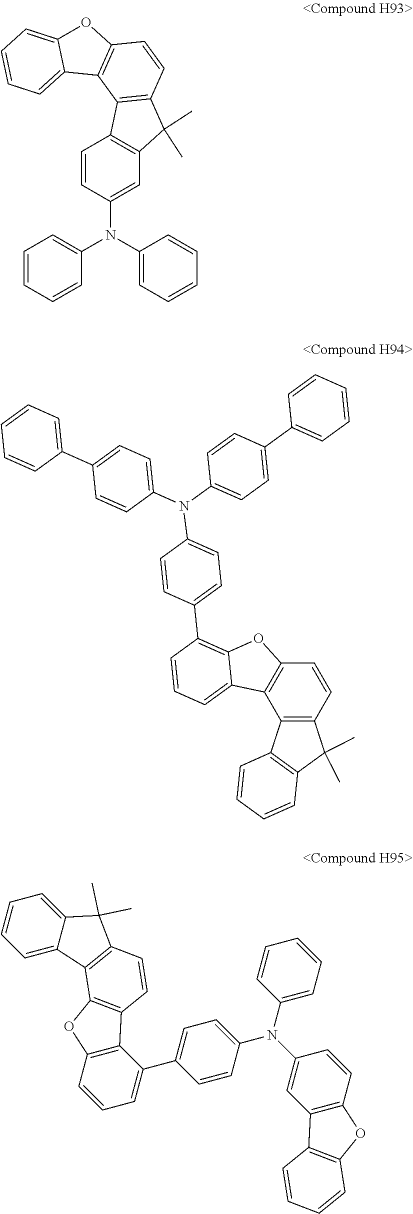 [SMILES: CC1(C)c2cc(N(c3ccccc3)c3ccccc3)ccc2-c2c1ccc1oc3ccccc3c21 ; CC1(C)c2ccccc2-c2c1ccc1oc3c(-c4ccc(N(c5ccc(-c6ccccc6)cc5)c5ccc(-c6ccccc6)cc5)cc4)cccc3c21 ; CC1(C)c2ccccc2-c2c1ccc1c2oc2cccc(-c3ccc(N(c4ccccc4)c4ccc5oc6ccccc6c5c4)cc3)c21]

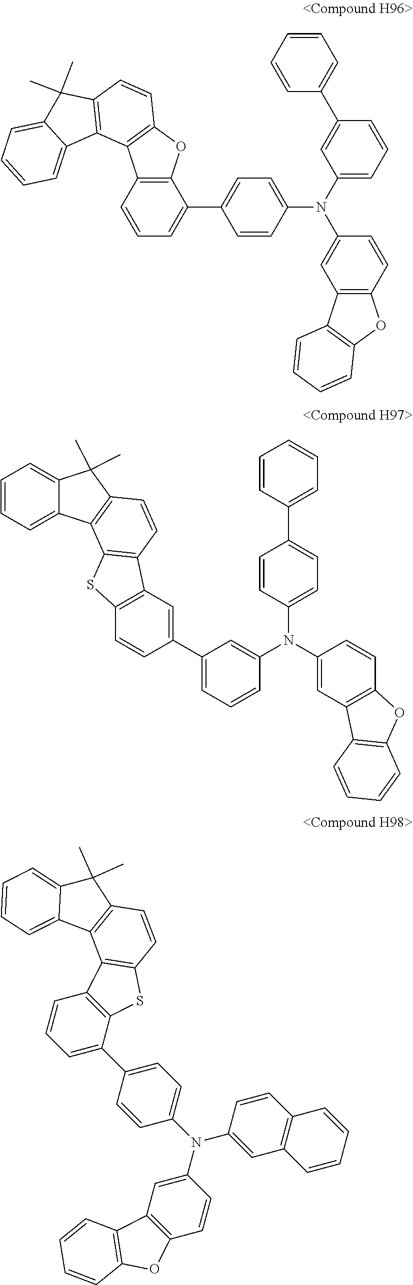 [SMILES: CC1(C)c2ccccc2-c2c1ccc1oc3c(-c4ccc(N(c5cccc(-c6ccccc6)c5)c5ccc6oc7ccccc7c6c5)cc4)cccc3c21 ; CC1(C)c2ccccc2-c2c1ccc1c2sc2ccc(-c3cccc(N(c4ccc(-c5ccccc5)cc4)c4ccc5oc6ccccc6c5c4)c3)cc21 ; CC1(C)c2ccccc2-c2c1ccc1sc3c(-c4ccc(N(c5ccc6ccccc6c5)c5ccc6oc7ccccc7c6c5)cc4)cccc3c21]

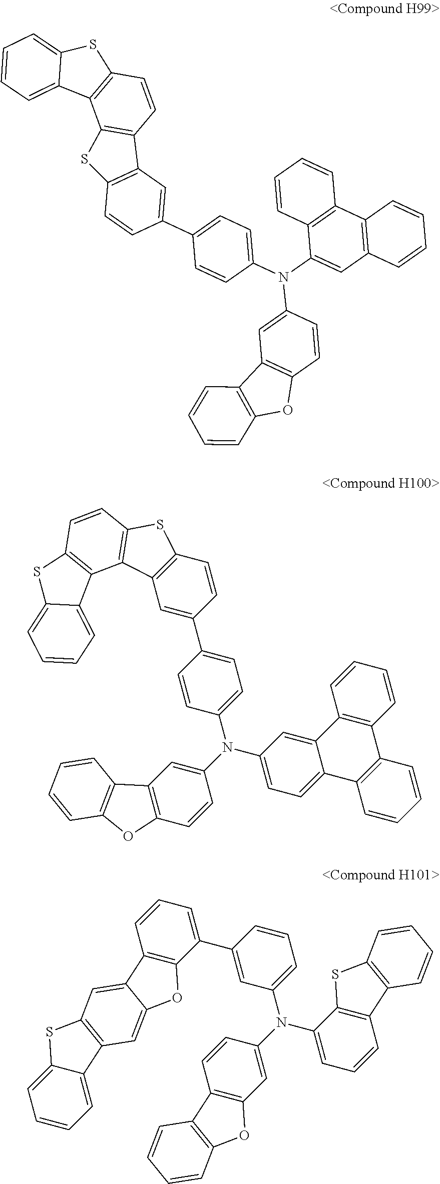 [SMILES: c1ccc2c(c1)cc(N(c1ccc(-c3ccc4sc5c(ccc6sc7ccccc7c65)c4c3)cc1)c1ccc3oc4ccccc4c3c1)c1ccccc12 ; c1ccc2c(c1)oc1ccc(N(c3ccc(-c4ccc5sc6ccc7sc8ccccc8c7c6c5c4)cc3)c3ccc4c5ccccc5c5ccccc5c4c3)cc12 ; c1cc(-c2cccc3c2oc2cc4c(cc23)sc2ccccc24)cc(N(c2ccc3c(c2)oc2ccccc23)c2cccc3c2sc2ccccc23)c1]

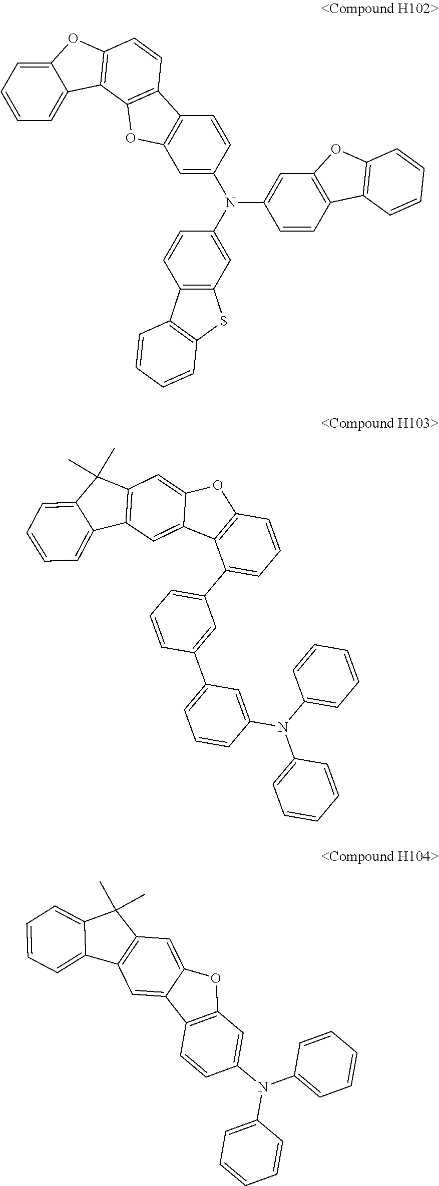 [SMILES: c1ccc2c(c1)oc1cc(N(c3ccc4c(c3)oc3c4ccc4oc5ccccc5c43)c3ccc4c(c3)sc3ccccc34)ccc12 ; CC1(C)c2ccccc2-c2cc3c(cc21)oc1cccc(-c2cccc(-c4cccc(N(c5ccccc5)c5ccccc5)c4)c2)c13 ; CC1(C)c2ccccc2-c2cc3c(cc21)oc1cc(N(c2ccccc2)c2ccccc2)ccc13]

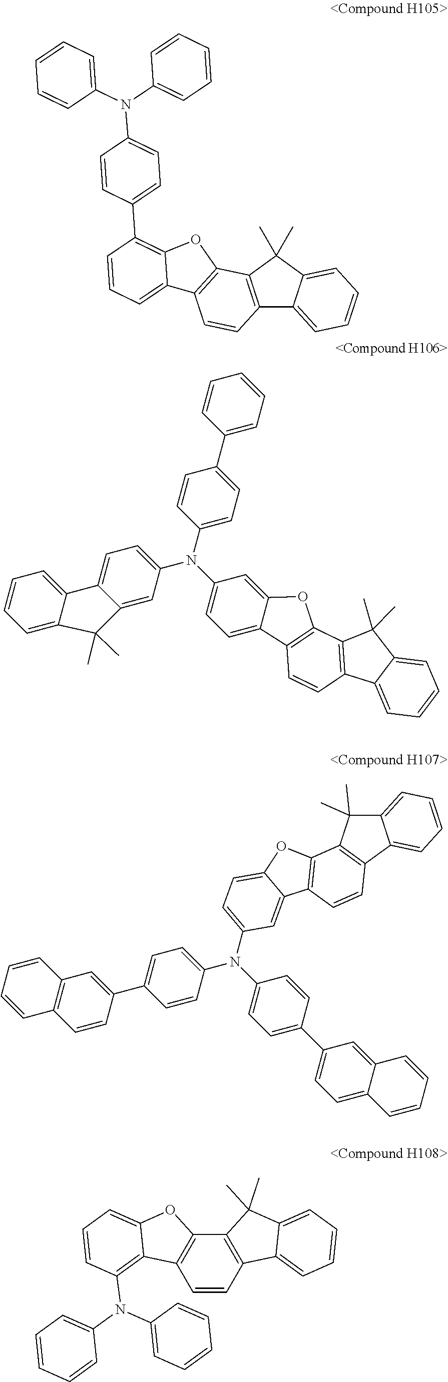

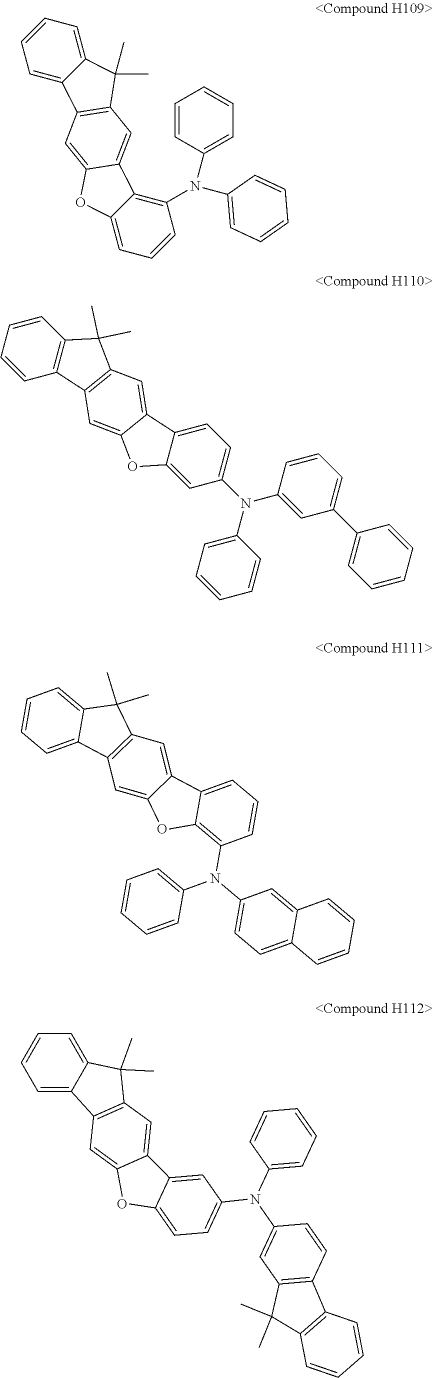 [SMILES: CC1(C)c2ccccc2-c2cc3oc4cccc(N(c5ccccc5)c5ccccc5)c4c3cc21 ; CC1(C)c2ccccc2-c2cc3oc4cc(N(c5ccccc5)c5cccc(-c6ccccc6)c5)ccc4c3cc21 ; CC1(C)c2ccccc2-c2cc3oc4c(N(c5ccccc5)c5ccc6ccccc6c5)cccc4c3cc21 ; CC1(C)c2ccccc2-c2ccc(N(c3ccccc3)c3ccc4oc5cc6c(cc5c4c3)C(C)(C)c3ccccc3-6)cc21]

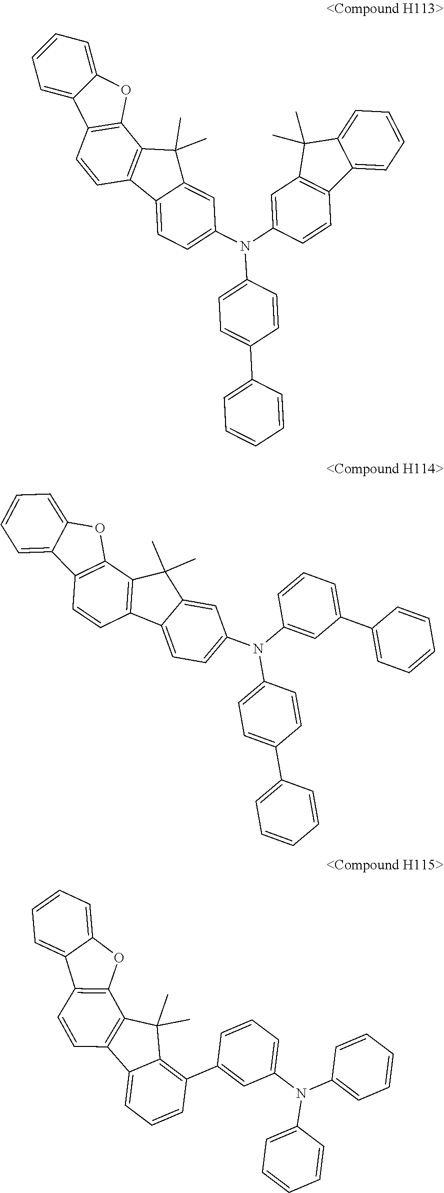 [SMILES: CC1(C)c2ccccc2-c2ccc(N(c3ccc(-c4ccccc4)cc3)c3ccc4c(c3)C(C)(C)c3c-4ccc4c3oc3ccccc34)cc21 ; CC1(C)c2cc(N(c3ccc(-c4ccccc4)cc3)c3cccc(-c4ccccc4)c3)ccc2-c2ccc3c(oc4ccccc43)c21 ; CC1(C)c2c(-c3cccc(N(c4ccccc4)c4ccccc4)c3)cccc2-c2ccc3c(oc4ccccc43)c21]

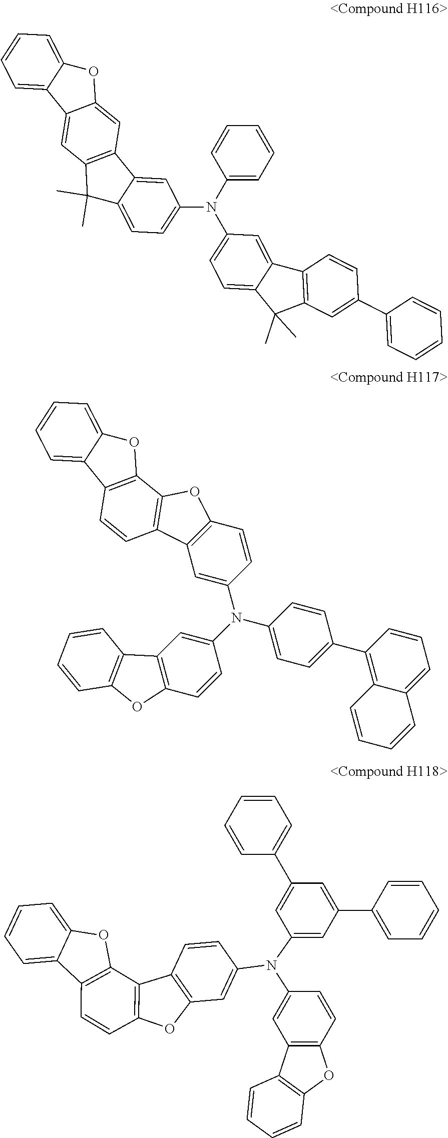 [SMILES: CC1(C)c2ccc(N(c3ccccc3)c3ccc4c(c3)-c3cc5oc6ccccc6c5cc3C4(C)C)cc2-c2ccc(-c3ccccc3)cc21 ; c1ccc2c(-c3ccc(N(c4ccc5oc6ccccc6c5c4)c4ccc5oc6c(ccc7c8ccccc8oc76)c5c4)cc3)cccc2c1 ; c1ccc(-c2cc(-c3ccccc3)cc(N(c3ccc4c(c3)oc3ccc5c6ccccc6oc5c34)c3ccc4oc5ccccc5c4c3)c2)cc1]

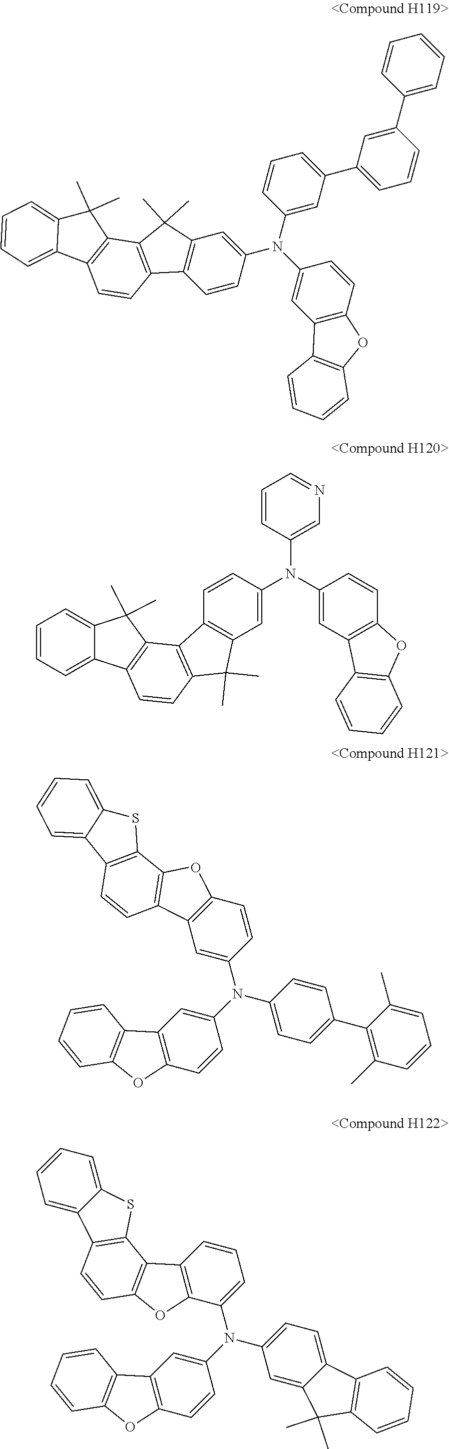 [SMILES: CC1(C)c2ccccc2-c2ccc3c(c21)C(C)(C)c1cc(N(c2cccc(-c4cccc(-c5ccccc5)c4)c2)c2ccc4oc5ccccc5c4c2)ccc1-3 ; CC1(C)c2cc(N(c3cccnc3)c3ccc4oc5ccccc5c4c3)ccc2-c2c1ccc1c2C(C)(C)c2ccccc2-1 ; Cc1cccc(C)c1-c1ccc(N(c2ccc3oc4ccccc4c3c2)c2ccc3oc4c(ccc5c6ccccc6sc54)c3c2)cc1 ; CC1(C)c2ccccc2-c2ccc(N(c3ccc4oc5ccccc5c4c3)c3cccc4c3oc3ccc5c6ccccc6sc5c34)cc21]

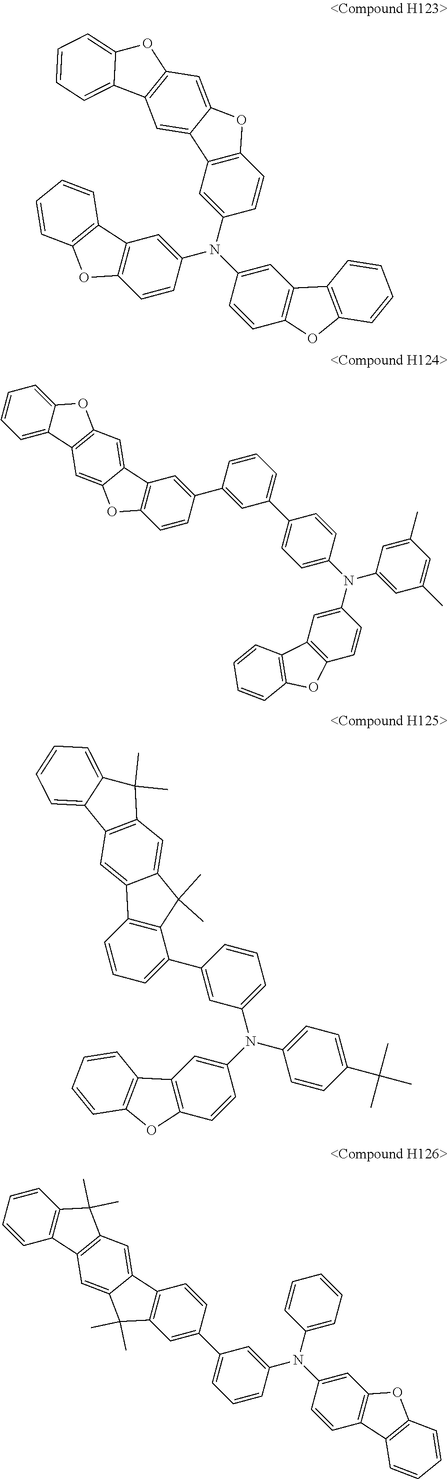 [SMILES: c1ccc2c(c1)oc1ccc(N(c3ccc4oc5ccccc5c4c3)c3ccc4oc5cc6oc7ccccc7c6cc5c4c3)cc12 ; Cc1cc(C)cc(N(c2ccc(-c3cccc(-c4ccc5oc6cc7c(cc6c5c4)oc4ccccc47)c3)cc2)c2ccc3oc4ccccc4c3c2)c1 ; CC(C)(C)c1ccc(N(c2cccc(-c3cccc4c3C(C)(C)c3cc5c(cc3-4)-c3ccccc3C5(C)C)c2)c2ccc3oc4ccccc4c3c2)cc1 ; CC1(C)c2ccccc2-c2cc3c(cc21)-c1ccc(-c2cccc(N(c4ccccc4)c4ccc5c(c4)oc4ccccc45)c2)cc1C3(C)C]

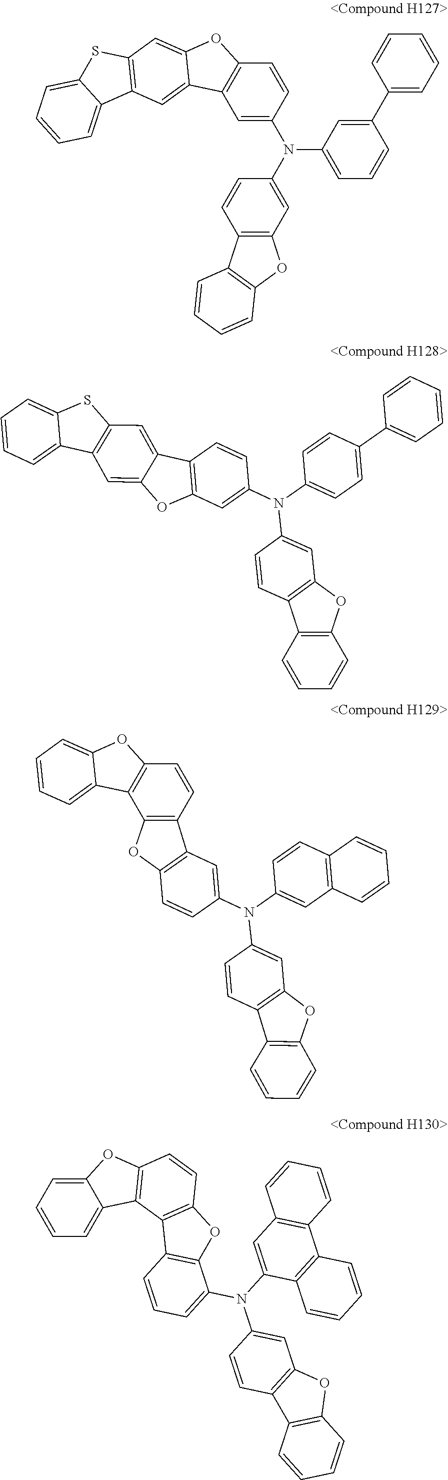 [SMILES: c1ccc(-c2cccc(N(c3ccc4c(c3)oc3ccccc34)c3ccc4oc5cc6sc7ccccc7c6cc5c4c3)c2)cc1 ; c1ccc(-c2ccc(N(c3ccc4c(c3)oc3ccccc34)c3ccc4c(c3)oc3cc5c(cc34)sc3ccccc35)cc2)cc1 ; c1ccc2cc(N(c3ccc4c(c3)oc3ccccc34)c3ccc4oc5c(ccc6oc7ccccc7c65)c4c3)ccc2c1 ; c1ccc2c(c1)cc(N(c1ccc3c(c1)oc1ccccc13)c1cccc3c1oc1ccc4oc5ccccc5c4c13)c1ccccc12]

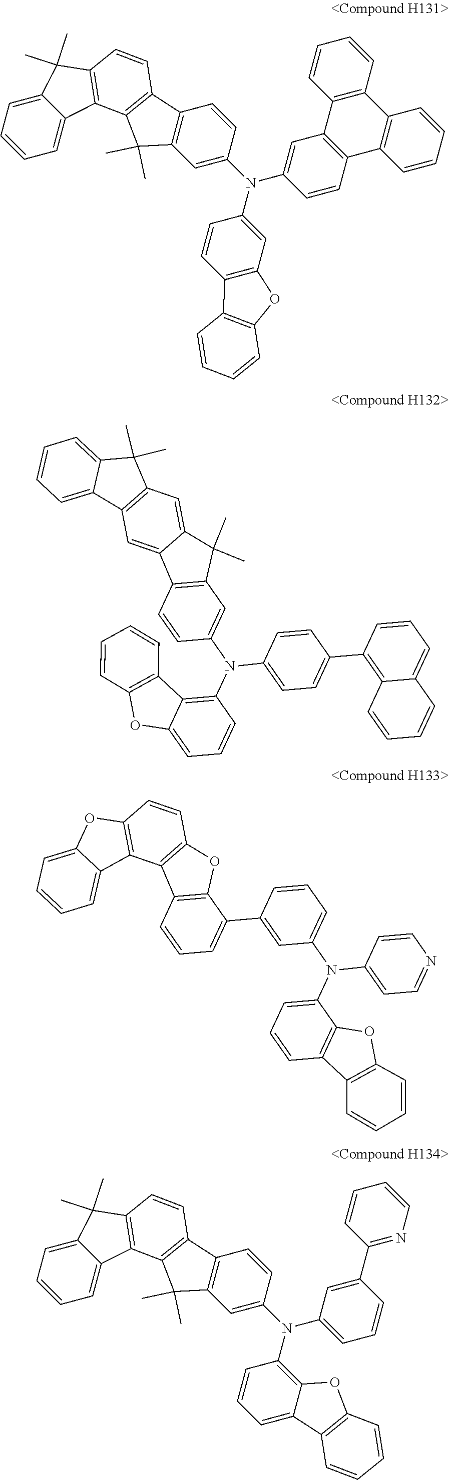 [SMILES: CC1(C)c2ccccc2-c2c1ccc1c2C(C)(C)c2cc(N(c3ccc4c(c3)oc3ccccc34)c3ccc4c5ccccc5c5ccccc5c4c3)ccc2-1 ; CC1(C)c2ccccc2-c2cc3c(cc21)C(C)(C)c1cc(N(c2ccc(-c4cccc5ccccc45)cc2)c2cccc4oc5ccccc5c24)ccc1-3 ; c1cc(-c2cccc3c2oc2ccc4oc5ccccc5c4c23)cc(N(c2ccncc2)c2cccc3c2oc2ccccc23)c1 ; CC1(C)c2ccccc2-c2c1ccc1c2C(C)(C)c2cc(N(c3cccc(-c4ccccn4)c3)c3cccc4c3oc3ccccc34)ccc2-1]

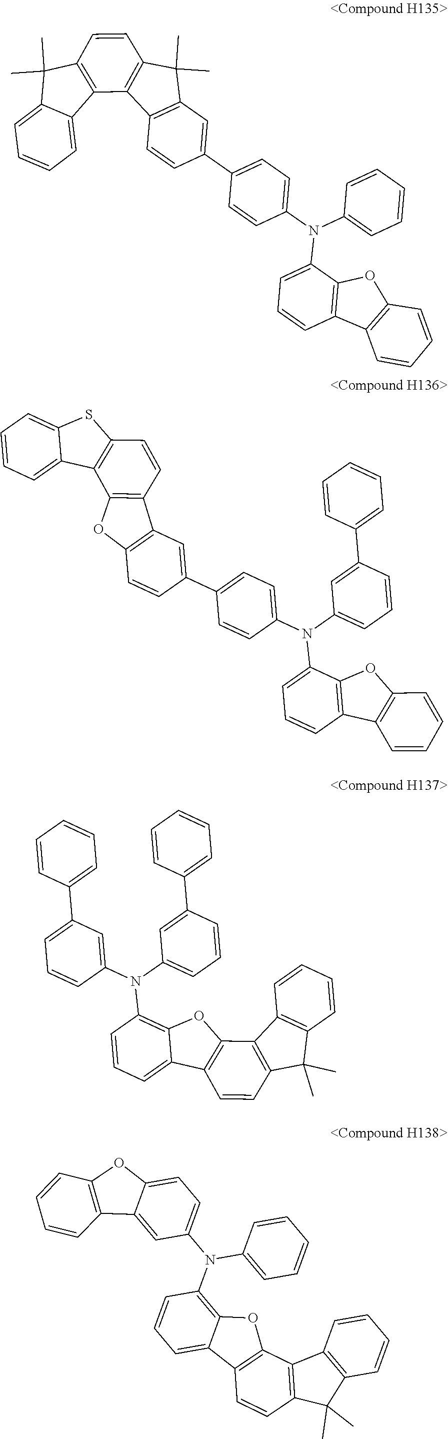 [SMILES: CC1(C)c2ccccc2-c2c1ccc1c2-c2ccc(-c3ccc(N(c4ccccc4)c4cccc5c4oc4ccccc45)cc3)cc2C1(C)C ; c1ccc(-c2cccc(N(c3ccc(-c4ccc5oc6c(ccc7sc8ccccc8c76)c5c4)cc3)c3cccc4c3oc3ccccc34)c2)cc1 ; CC1(C)c2ccccc2-c2c1ccc1c2oc2c(N(c3cccc(-c4ccccc4)c3)c3cccc(-c4ccccc4)c3)cccc21 ; CC1(C)c2ccccc2-c2c1ccc1c2oc2c(N(c3ccccc3)c3ccc4oc5ccccc5c4c3)cccc21]

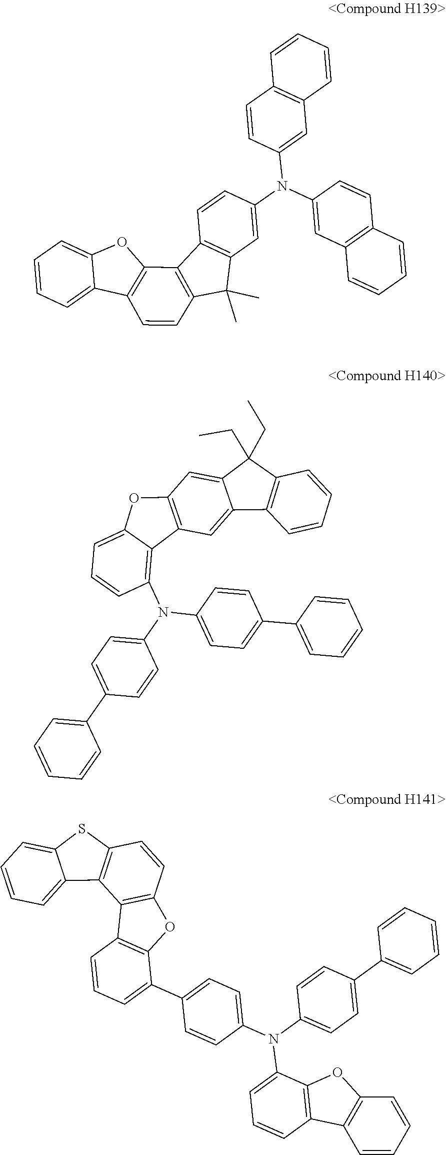 [SMILES: CC1(C)c2cc(N(c3ccc4ccccc4c3)c3ccc4ccccc4c3)ccc2-c2c1ccc1c2oc2ccccc21 ; CCC1(CC)c2ccccc2-c2cc3c(cc21)oc1cccc(N(c2ccc(-c4ccccc4)cc2)c2ccc(-c4ccccc4)cc2)c13 ; c1ccc(-c2ccc(N(c3ccc(-c4cccc5c4oc4ccc6sc7ccccc7c6c45)cc3)c3cccc4c3oc3ccccc34)cc2)cc1]

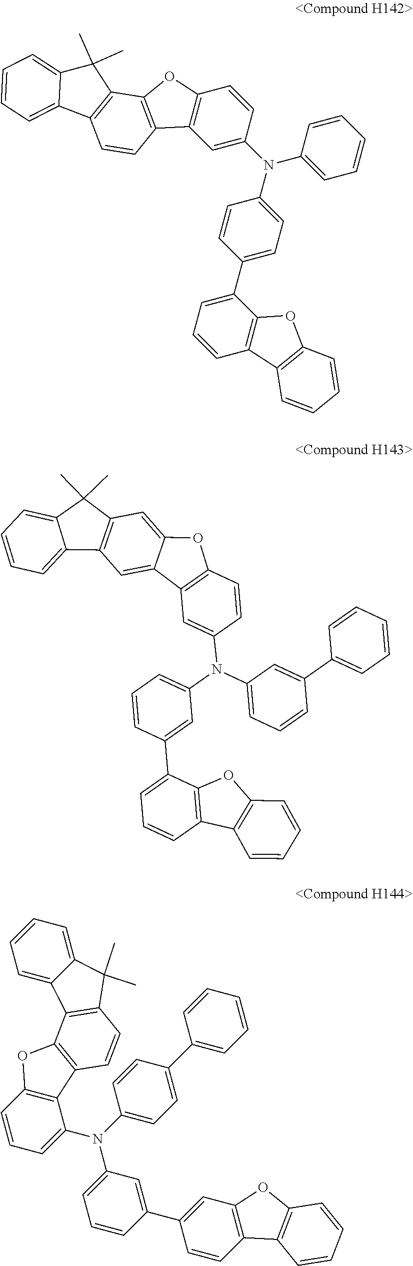 [SMILES: CC1(C)c2ccccc2-c2ccc3c(oc4ccc(N(c5ccccc5)c5ccc(-c6cccc7c6oc6ccccc67)cc5)cc43)c21 ; CC1(C)c2ccccc2-c2cc3c(cc21)oc1ccc(N(c2cccc(-c4ccccc4)c2)c2cccc(-c4cccc5c4oc4ccccc45)c2)cc13 ; CC1(C)c2ccccc2-c2c1ccc1c2oc2cccc(N(c3ccc(-c4ccccc4)cc3)c3cccc(-c4ccc5c(c4)oc4ccccc45)c3)c21]

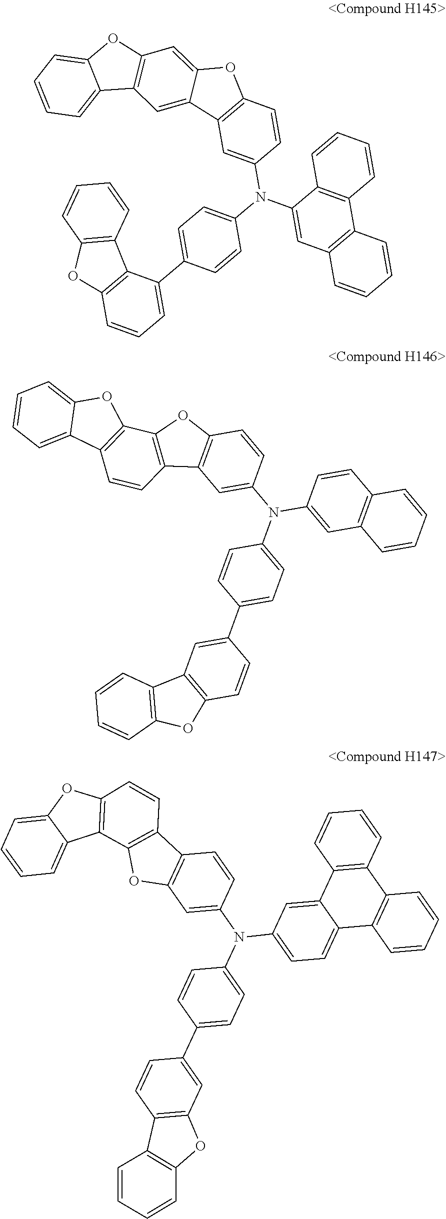

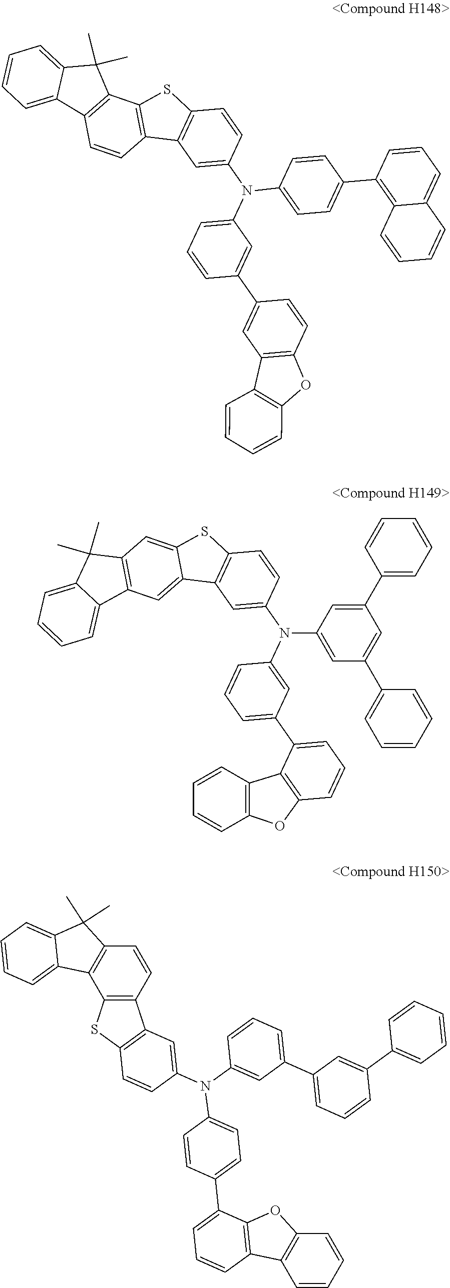 [SMILES: CC1(C)c2ccccc2-c2ccc3c(sc4ccc(N(c5ccc(-c6cccc7ccccc67)cc5)c5cccc(-c6ccc7oc8ccccc8c7c6)c5)cc43)c21 ; CC1(C)c2ccccc2-c2cc3c(cc21)sc1ccc(N(c2cc(-c4ccccc4)cc(-c4ccccc4)c2)c2cccc(-c4cccc5oc6ccccc6c45)c2)cc13 ; CC1(C)c2ccccc2-c2c1ccc1c2sc2ccc(N(c3ccc(-c4cccc5c4oc4ccccc45)cc3)c3cccc(-c4cccc(-c5ccccc5)c4)c3)cc21]

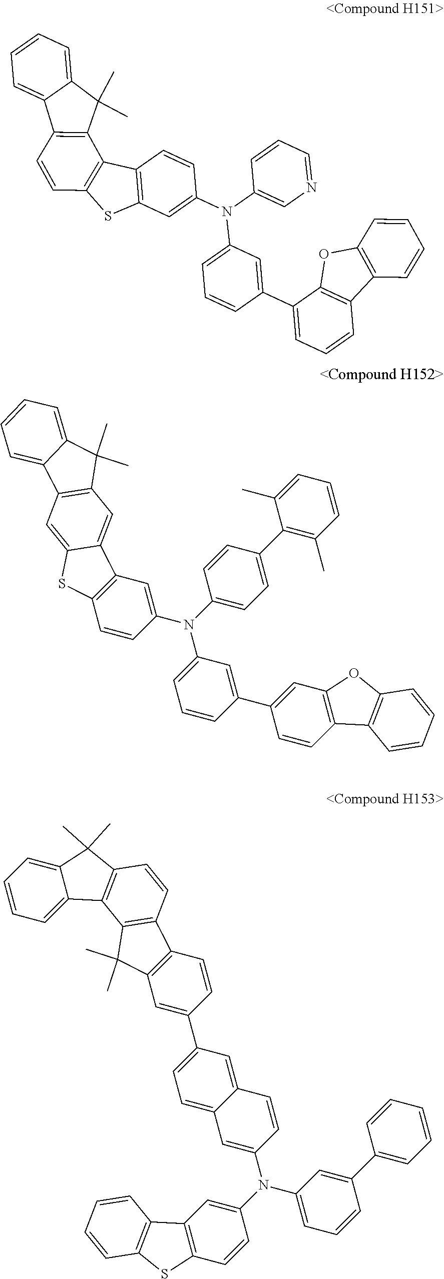 [SMILES: CC1(C)c2ccccc2-c2ccc3sc4cc(N(c5cccnc5)c5cccc(-c6cccc7c6oc6ccccc67)c5)ccc4c3c21 ; Cc1cccc(C)c1-c1ccc(N(c2cccc(-c3ccc4c(c3)oc3ccccc34)c2)c2ccc3sc4cc5c(cc4c3c2)C(C)(C)c2ccccc2-5)cc1 ; CC1(C)c2ccccc2-c2c1ccc1c2C(C)(C)c2cc(-c3ccc4cc(N(c5cccc(-c6ccccc6)c5)c5ccc6sc7ccccc7c6c5)ccc4c3)ccc2-1]

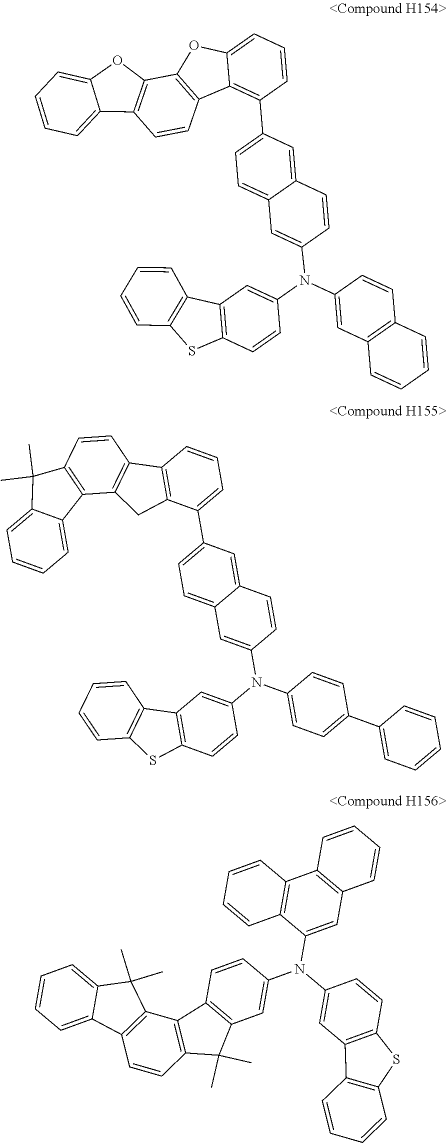 [SMILES: c1ccc2cc(N(c3ccc4cc(-c5cccc6oc7c(ccc8c9ccccc9oc87)c56)ccc4c3)c3ccc4sc5ccccc5c4c3)ccc2c1 ; CC1(C)c2ccccc2-c2c1ccc1c2Cc2c(-c3ccc4cc(N(c5ccc(-c6ccccc6)cc5)c5ccc6sc7ccccc7c6c5)ccc4c3)cccc2-1 ; CC1(C)c2cc(N(c3ccc4sc5ccccc5c4c3)c3cc4ccccc4c4ccccc34)ccc2-c2c1ccc1c2C(C)(C)c2ccccc2-1]

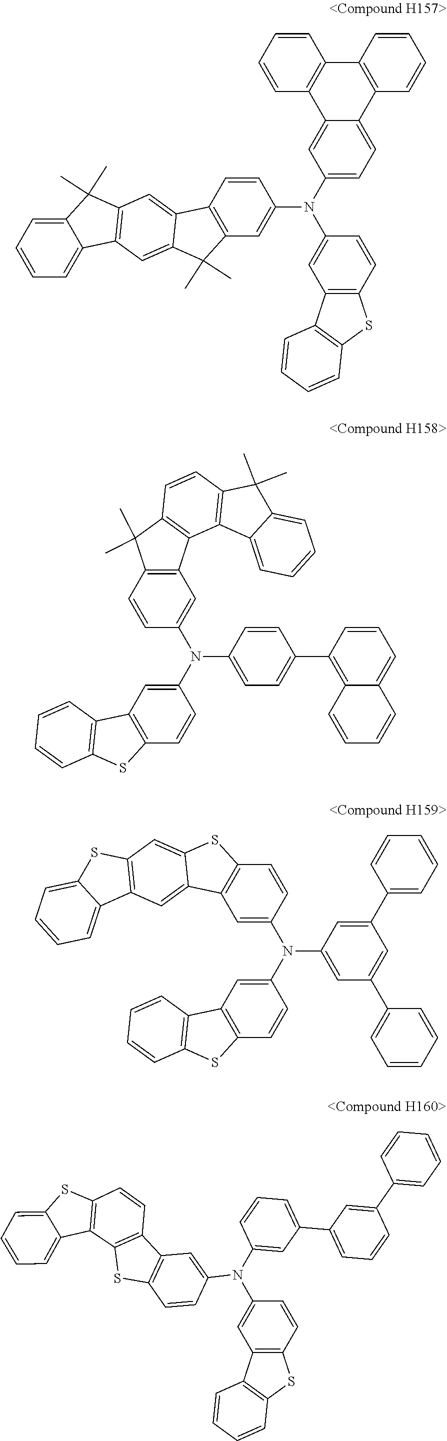 [SMILES: CC1(C)c2ccccc2-c2cc3c(cc21)-c1ccc(N(c2ccc4sc5ccccc5c4c2)c2ccc4c5ccccc5c5ccccc5c4c2)cc1C3(C)C ; CC1(C)c2ccccc2-c2c1ccc1c2-c2cc(N(c3ccc(-c4cccc5ccccc45)cc3)c3ccc4sc5ccccc5c4c3)ccc2C1(C)C ; c1ccc(-c2cc(-c3ccccc3)cc(N(c3ccc4sc5ccccc5c4c3)c3ccc4sc5cc6sc7ccccc7c6cc5c4c3)c2)cc1 ; c1ccc(-c2cccc(-c3cccc(N(c4ccc5sc6ccccc6c5c4)c4ccc5sc6c(ccc7sc8ccccc8c76)c5c4)c3)c2)cc1]

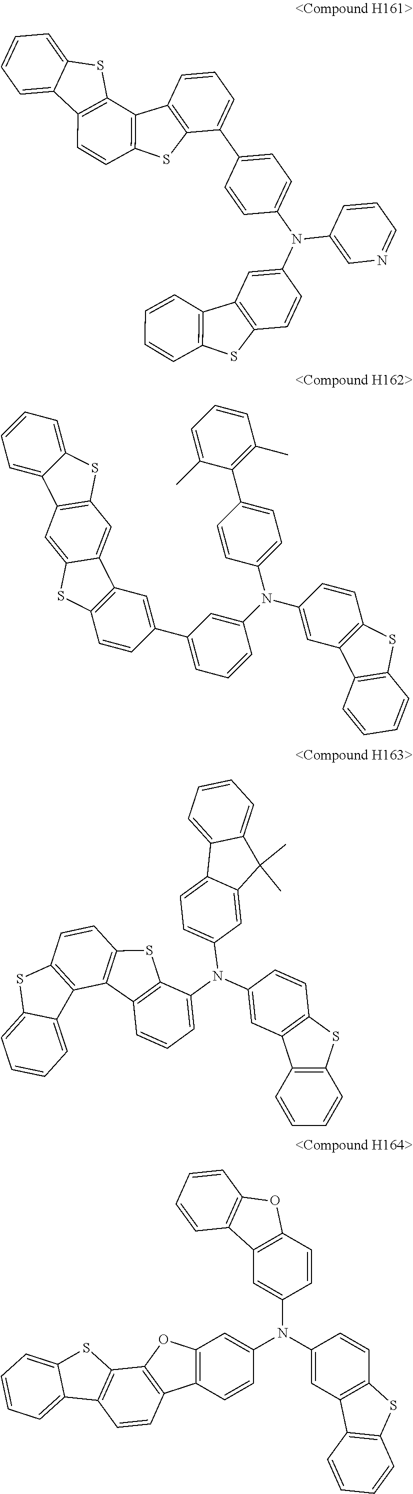 [SMILES: c1cncc(N(c2ccc(-c3cccc4c3sc3ccc5c6ccccc6sc5c34)cc2)c2ccc3sc4ccccc4c3c2)c1 ; Cc1cccc(C)c1-c1ccc(N(c2cccc(-c3ccc4sc5cc6c(cc5c4c3)sc3ccccc36)c2)c2ccc3sc4ccccc4c3c2)cc1 ; CC1(C)c2ccccc2-c2ccc(N(c3ccc4sc5ccccc5c4c3)c3cccc4c3sc3ccc5sc6ccccc6c5c34)cc21 ; c1ccc2c(c1)oc1ccc(N(c3ccc4c(c3)oc3c4ccc4c5ccccc5sc43)c3ccc4sc5ccccc5c4c3)cc12]

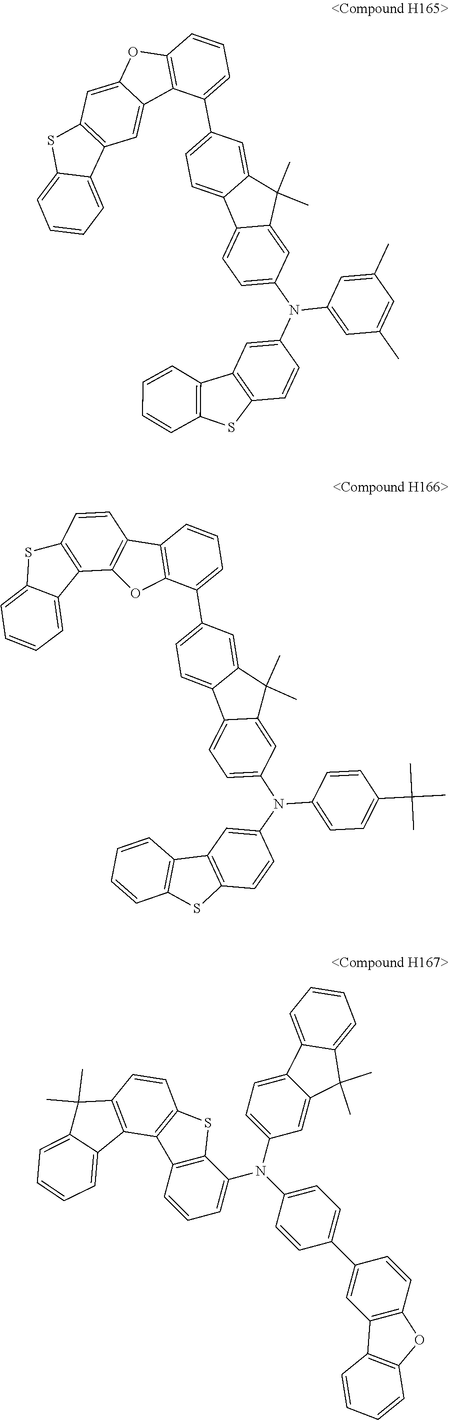 [SMILES: Cc1cc(C)cc(N(c2ccc3c(c2)C(C)(C)c2cc(-c4cccc5oc6cc7sc8ccccc8c7cc6c45)ccc2-3)c2ccc3sc4ccccc4c3c2)c1 ; CC(C)(C)c1ccc(N(c2ccc3c(c2)C(C)(C)c2cc(-c4cccc5c4oc4c5ccc5sc6ccccc6c54)ccc2-3)c2ccc3sc4ccccc4c3c2)cc1 ; CC1(C)c2ccccc2-c2ccc(N(c3ccc(-c4ccc5oc6ccccc6c5c4)cc3)c3cccc4c3sc3ccc5c(c34)-c3ccccc3C5(C)C)cc21]

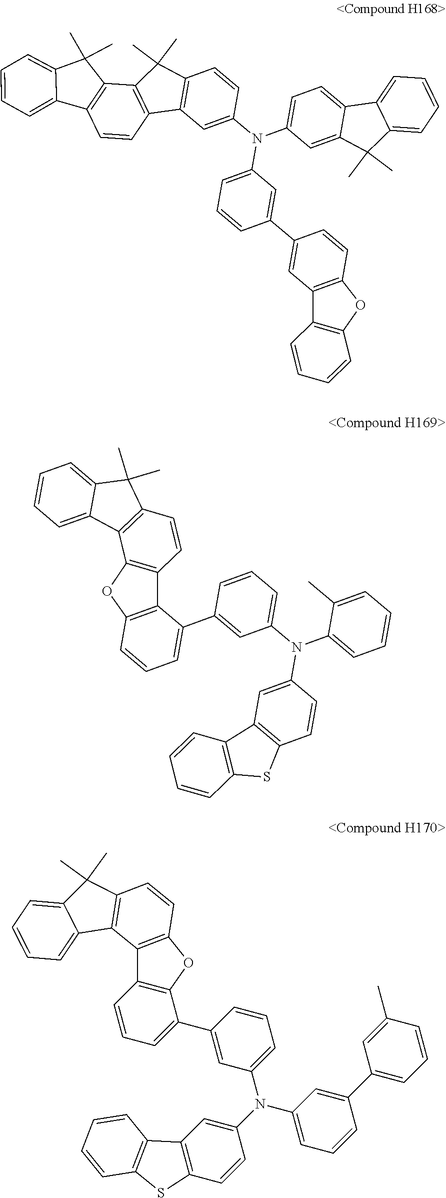

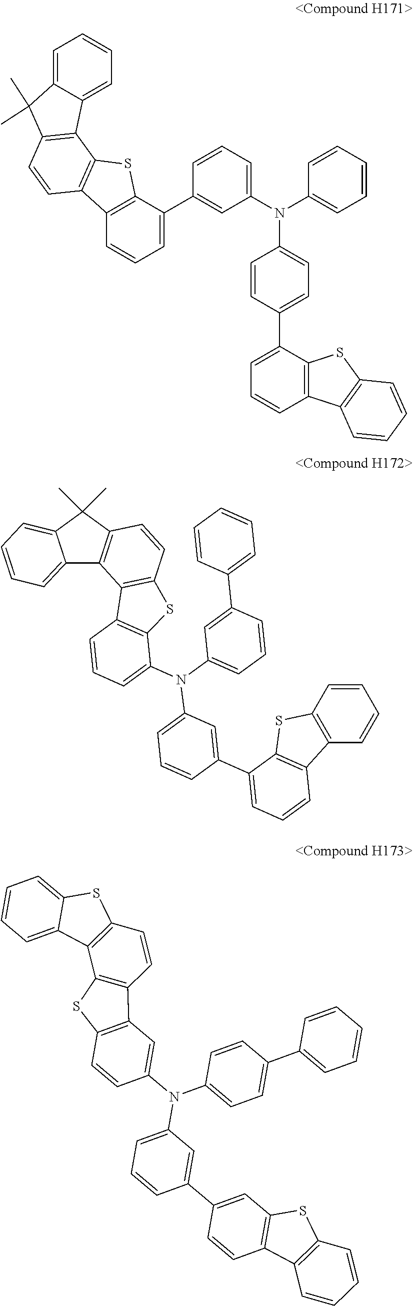 [SMILES: CC1(C)c2ccccc2-c2c1ccc1c2sc2c(-c3cccc(N(c4ccccc4)c4ccc(-c5cccc6c5sc5ccccc56)cc4)c3)cccc21 ; CC1(C)c2ccccc2-c2c1ccc1sc3c(N(c4cccc(-c5ccccc5)c4)c4cccc(-c5cccc6c5sc5ccccc56)c4)cccc3c21 ; c1ccc(-c2ccc(N(c3cccc(-c4ccc5c(c4)sc4ccccc45)c3)c3ccc4sc5c(ccc6sc7ccccc7c65)c4c3)cc2)cc1]

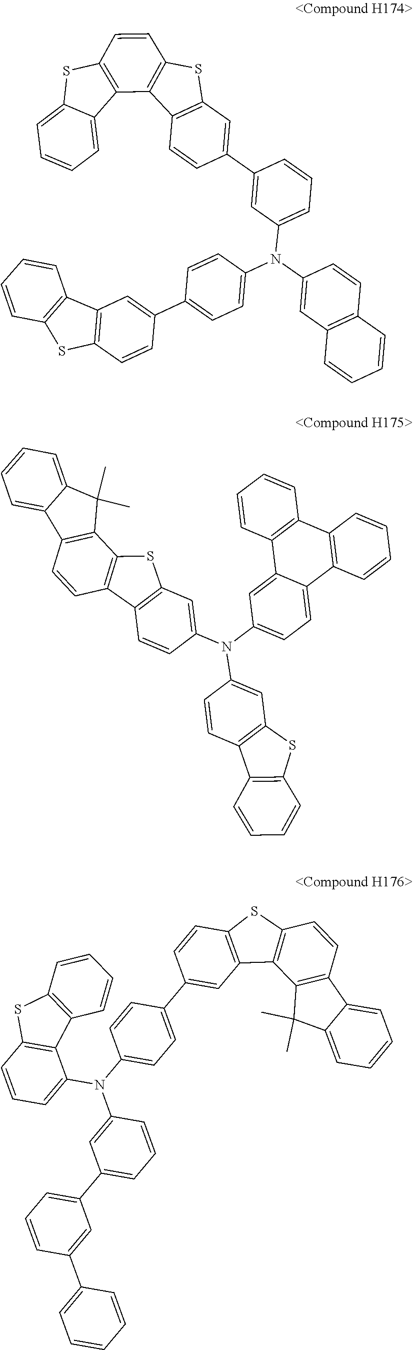 [SMILES: c1cc(-c2ccc3c(c2)sc2ccc4sc5ccccc5c4c23)cc(N(c2ccc(-c3ccc4sc5ccccc5c4c3)cc2)c2ccc3ccccc3c2)c1 ; CC1(C)c2ccccc2-c2ccc3c(sc4cc(N(c5ccc6c(c5)sc5ccccc56)c5ccc6c7ccccc7c7ccccc7c6c5)ccc43)c21 ; CC1(C)c2ccccc2-c2ccc3sc4ccc(-c5ccc(N(c6cccc(-c7cccc(-c8ccccc8)c7)c6)c6cccc7sc8ccccc8c67)cc5)cc4c3c21]

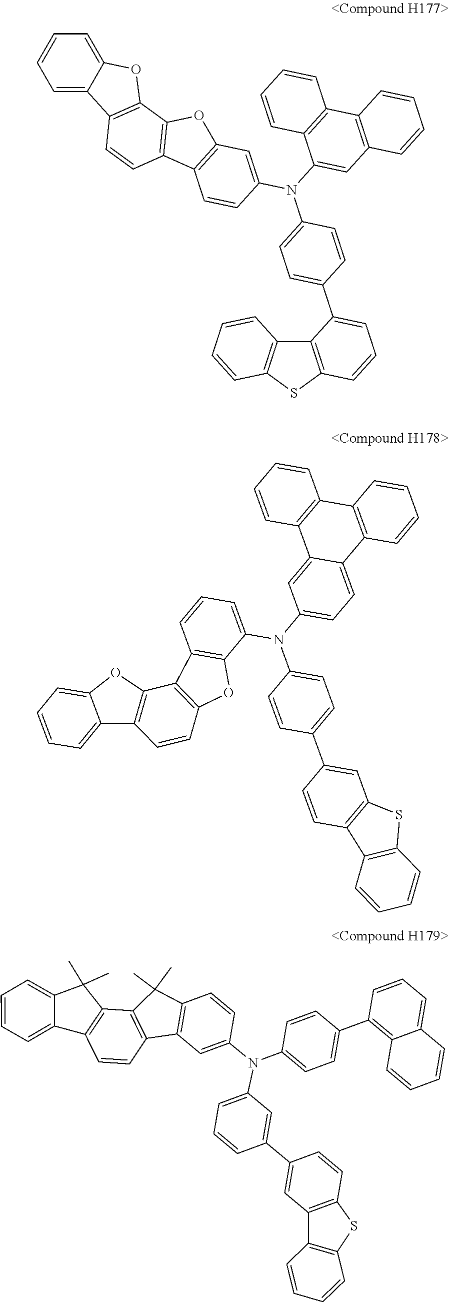 [SMILES: c1ccc2c(c1)cc(N(c1ccc(-c3cccc4sc5ccccc5c34)cc1)c1ccc3c(c1)oc1c3ccc3c4ccccc4oc31)c1ccccc12 ; c1ccc2c(c1)oc1c2ccc2oc3c(N(c4ccc(-c5ccc6c(c5)sc5ccccc56)cc4)c4ccc5c6ccccc6c6ccccc6c5c4)cccc3c21 ; CC1(C)c2ccccc2-c2ccc3c(c21)C(C)(C)c1ccc(N(c2ccc(-c4cccc5ccccc45)cc2)c2cccc(-c4ccc5sc6ccccc6c5c4)c2)cc1-3]

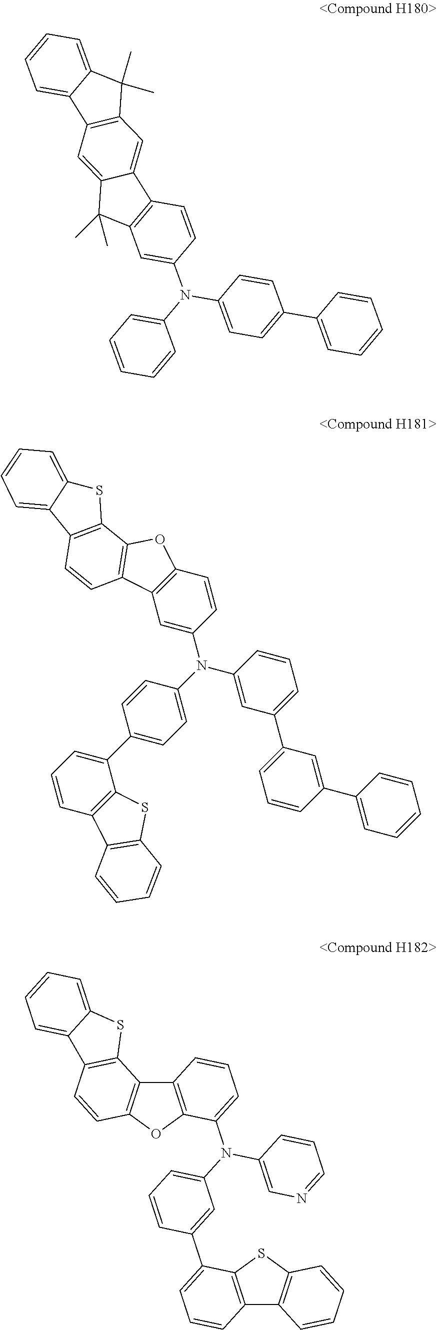 [SMILES: CC1(C)c2ccccc2-c2cc3c(cc21)-c1ccc(N(c2ccccc2)c2ccc(-c4ccccc4)cc2)cc1C3(C)C ; c1ccc(-c2cccc(-c3cccc(N(c4ccc(-c5cccc6c5sc5ccccc56)cc4)c4ccc5oc6c(ccc7c8ccccc8sc76)c5c4)c3)c2)cc1 ; c1cncc(N(c2cccc(-c3cccc4c3sc3ccccc34)c2)c2cccc3c2oc2ccc4c5ccccc5sc4c23)c1]

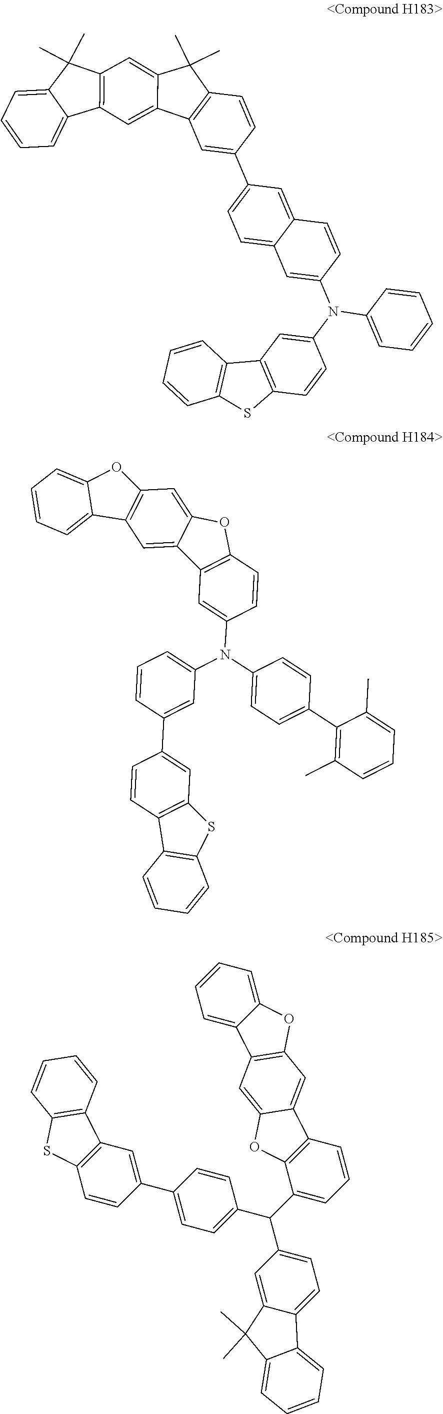 [SMILES: CC1(C)c2ccccc2-c2cc3c(cc21)C(C)(C)c1ccc(-c2ccc4cc(N(c5ccccc5)c5ccc6sc7ccccc7c6c5)ccc4c2)cc1-3 ; Cc1cccc(C)c1-c1ccc(N(c2cccc(-c3ccc4c(c3)sc3ccccc34)c2)c2ccc3oc4cc5oc6ccccc6c5cc4c3c2)cc1 ; CC1(C)c2ccccc2-c2ccc(C(c3ccc(-c4ccc5sc6ccccc6c5c4)cc3)c3cccc4c3oc3cc5c(cc34)oc3ccccc35)cc21]

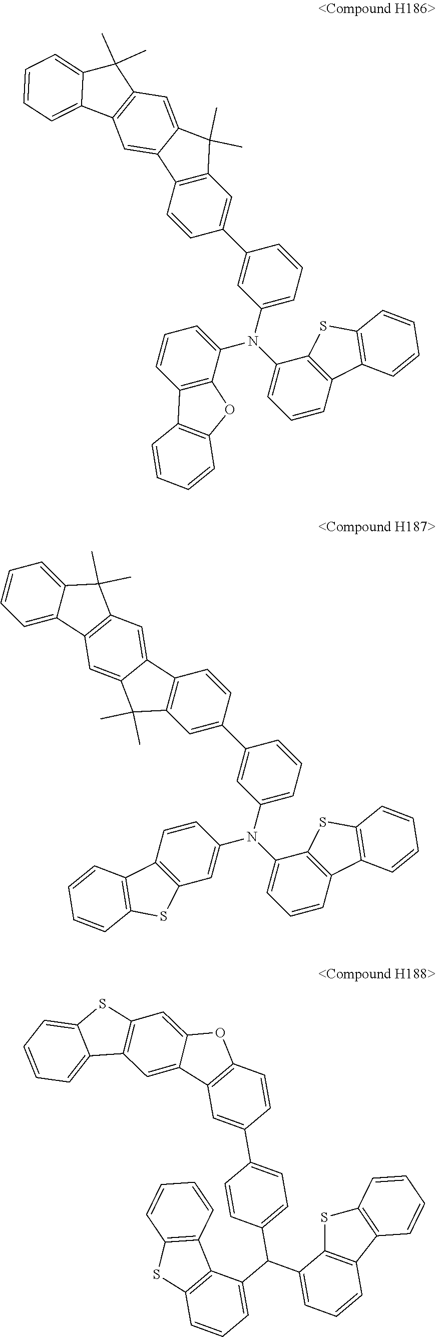 [SMILES: CC1(C)c2ccccc2-c2cc3c(cc21)C(C)(C)c1cc(-c2cccc(N(c4cccc5c4oc4ccccc45)c4cccc5c4sc4ccccc45)c2)ccc1-3 ; CC1(C)c2ccccc2-c2cc3c(cc21)-c1ccc(-c2cccc(N(c4ccc5c(c4)sc4ccccc45)c4cccc5c4sc4ccccc45)c2)cc1C3(C)C ; c1ccc2c(c1)sc1cc3oc4ccc(-c5ccc(C(c6cccc7c6sc6ccccc67)c6cccc7sc8ccccc8c67)cc5)cc4c3cc12]

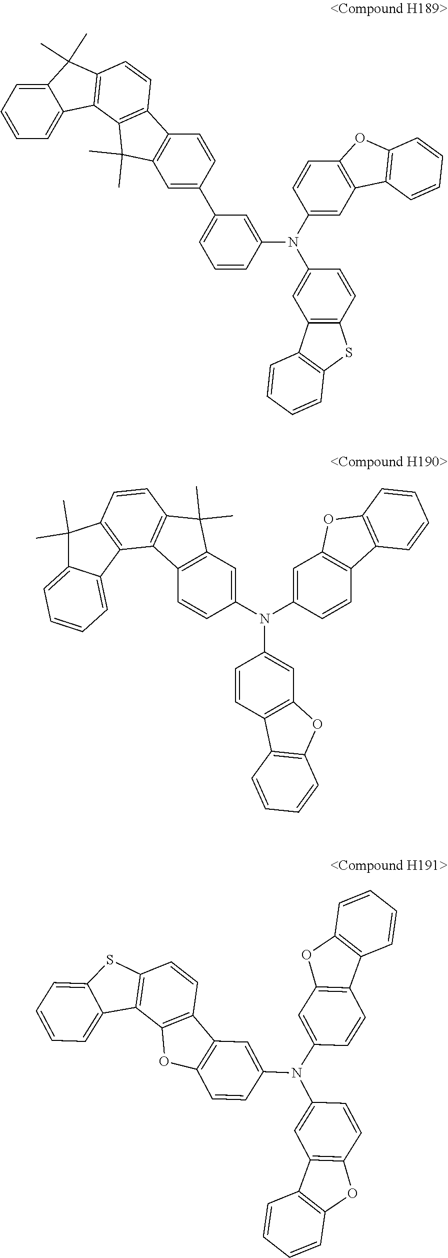 [SMILES: CC1(C)c2ccccc2-c2c1ccc1c2C(C)(C)c2cc(-c3cccc(N(c4ccc5oc6ccccc6c5c4)c4ccc5sc6ccccc6c5c4)c3)ccc2-1 ; CC1(C)c2ccccc2-c2c1ccc1c2-c2ccc(N(c3ccc4c(c3)oc3ccccc34)c3ccc4c(c3)oc3ccccc34)cc2C1(C)C ; c1ccc2c(c1)oc1cc(N(c3ccc4oc5ccccc5c4c3)c3ccc4oc5c(ccc6sc7ccccc7c65)c4c3)ccc12]

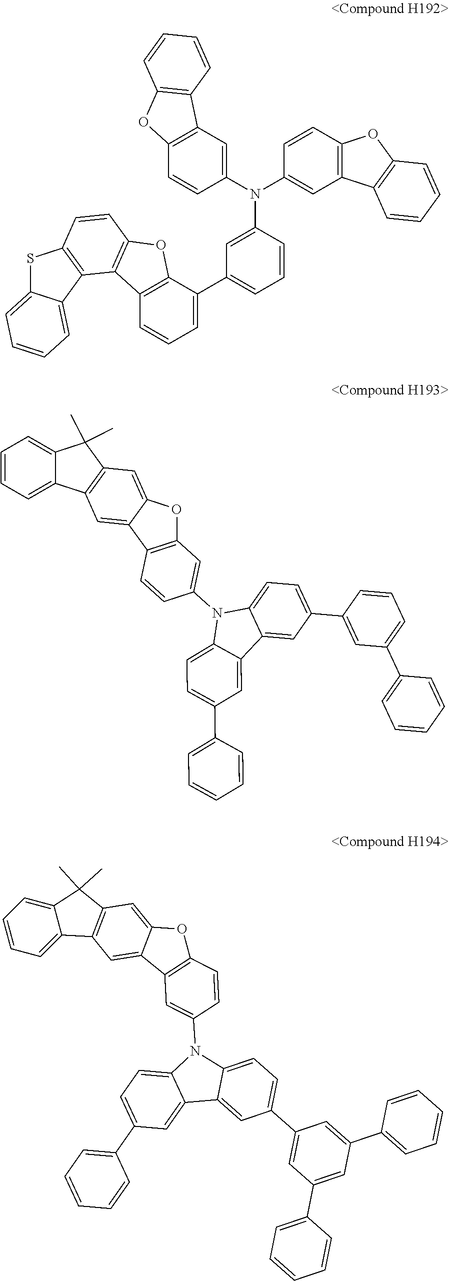 [SMILES: c1cc(-c2cccc3c2oc2ccc4sc5ccccc5c4c23)cc(N(c2ccc3oc4ccccc4c3c2)c2ccc3oc4ccccc4c3c2)c1 ; CC1(C)c2ccccc2-c2cc3c(cc21)oc1cc(-n2c4ccc(-c5ccccc5)cc4c4cc(-c5cccc(-c6ccccc6)c5)ccc42)ccc13 ; CC1(C)c2ccccc2-c2cc3c(cc21)oc1ccc(-n2c4ccc(-c5ccccc5)cc4c4cc(-c5cc(-c6ccccc6)cc(-c6ccccc6)c5)ccc42)cc13]

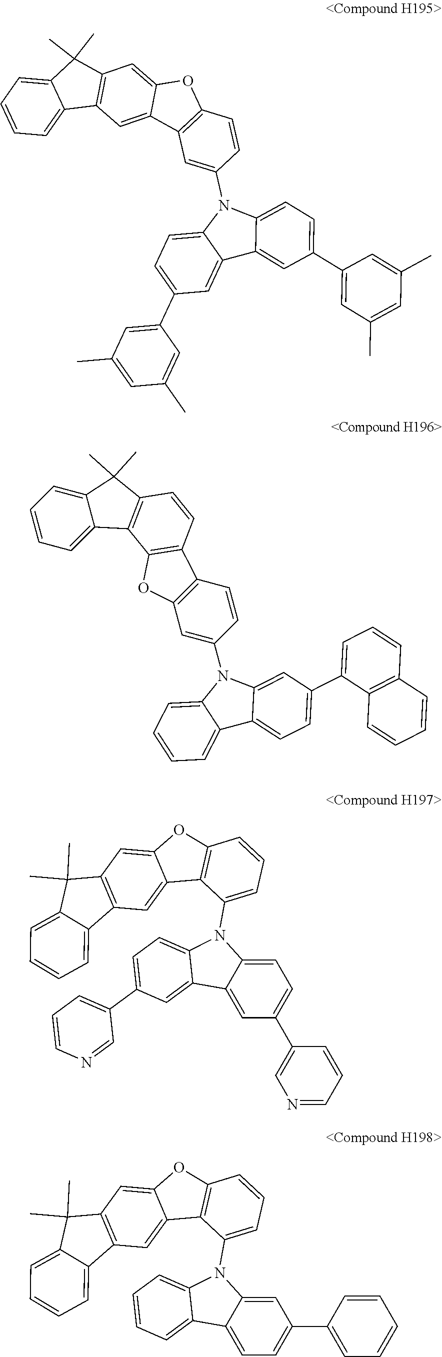

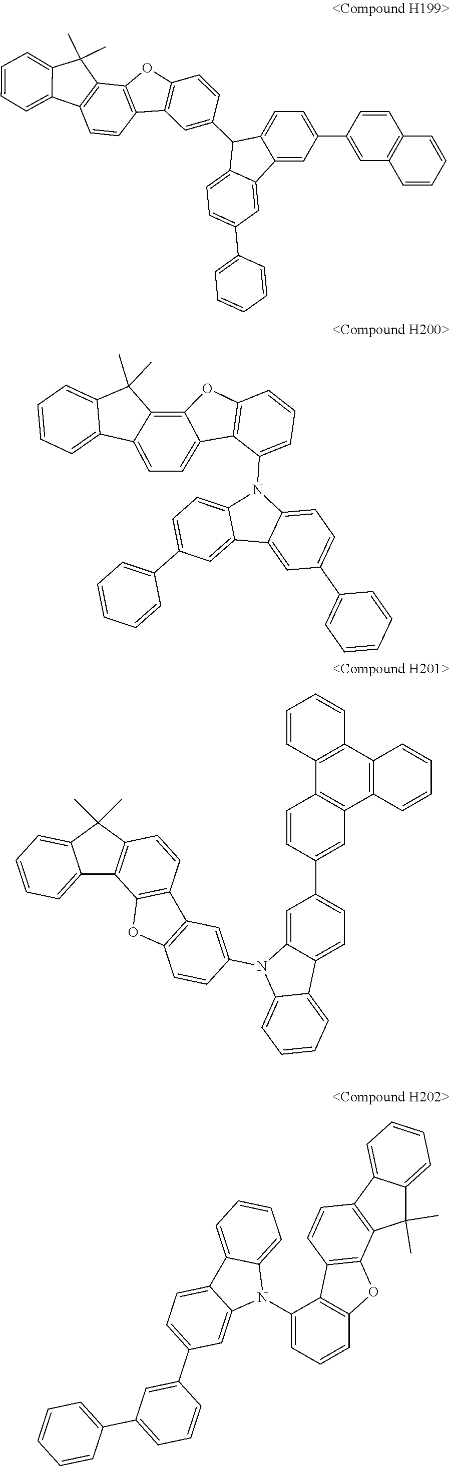 [SMILES: CC1(C)c2ccccc2-c2ccc3c(oc4ccc(C5c6ccc(-c7ccccc7)cc6-c6cc(-c7ccc8ccccc8c7)ccc65)cc43)c21 ; CC1(C)c2ccccc2-c2ccc3c(oc4cccc(-n5c6ccc(-c7ccccc7)cc6c6cc(-c7ccccc7)ccc65)c43)c21 ; CC1(C)c2ccccc2-c2c1ccc1c2oc2ccc(-n3c4ccccc4c4ccc(-c5ccc6c7ccccc7c7ccccc7c6c5)cc43)cc21 ; CC1(C)c2ccccc2-c2ccc3c(oc4cccc(-n5c6ccccc6c6ccc(-c7cccc(-c8ccccc8)c7)cc65)c43)c21]

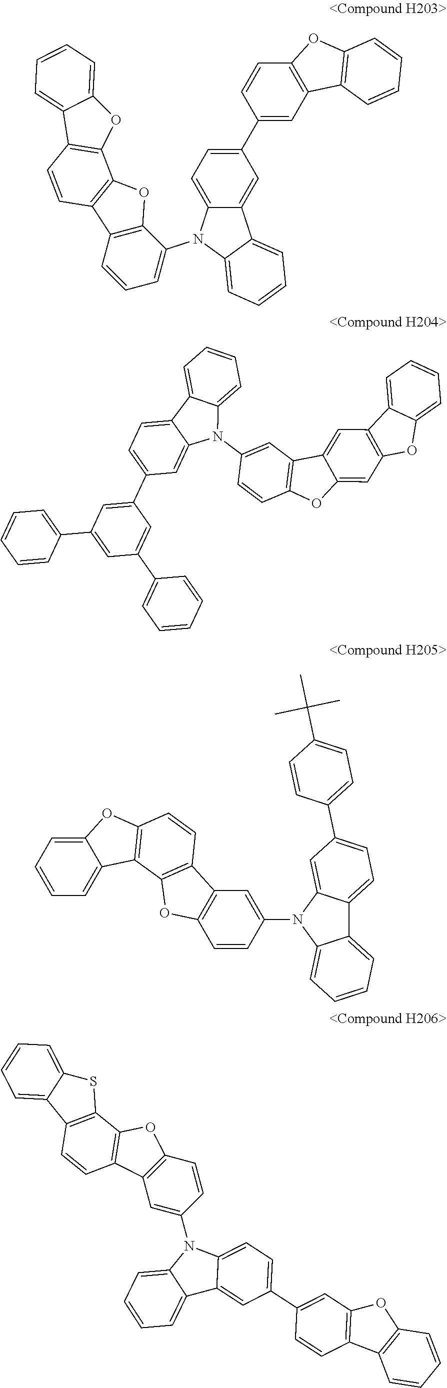 [SMILES: c1ccc2c(c1)oc1ccc(-c3ccc4c(c3)c3ccccc3n4-c3cccc4c3oc3c4ccc4c5ccccc5oc43)cc12 ; c1ccc(-c2cc(-c3ccccc3)cc(-c3ccc4c5ccccc5n(-c5ccc6oc7cc8oc9ccccc9c8cc7c6c5)c4c3)c2)cc1 ; CC(C)(C)c1ccc(-c2ccc3c4ccccc4n(-c4ccc5oc6c(ccc7oc8ccccc8c76)c5c4)c3c2)cc1 ; c1ccc2c(c1)oc1cc(-c3ccc4c(c3)c3ccccc3n4-c3ccc4oc5c(ccc6c7ccccc7sc65)c4c3)ccc12]

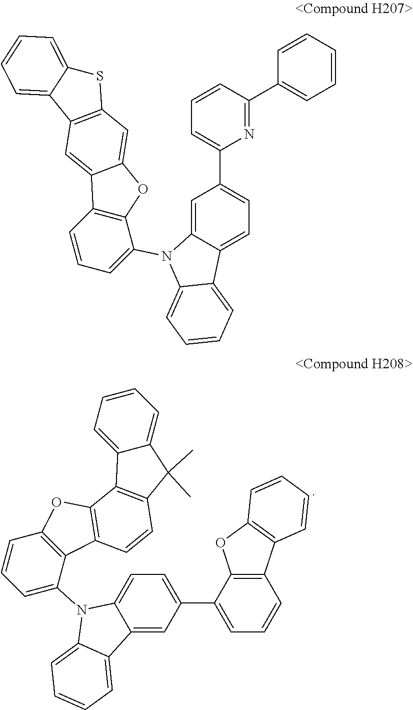 [SMILES: c1ccc(-c2cccc(-c3ccc4c5ccccc5n(-c5cccc6c5oc5cc7sc8ccccc8c7cc56)c4c3)n2)cc1 ; CC1(C)c2ccccc2-c2c1ccc1c2oc2cccc(-n3c4ccccc4c4cc(-c5cccc6c5oc5ccccc56)ccc43)c21]

11. The organic light-emitting diode of claim 1, wherein the hetero ring compound represented by Chemical Formula D is any one selected from the group consisting of compounds represented by the following Chemical Formula s E1 to E144:

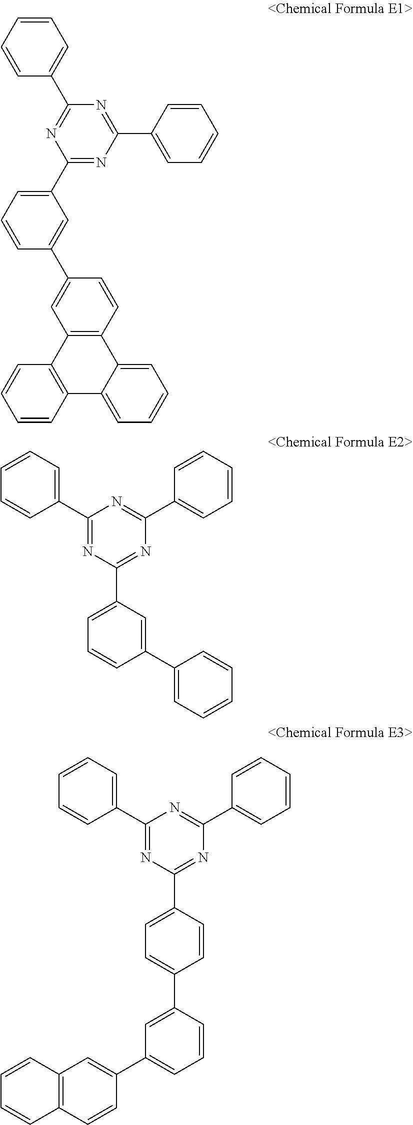

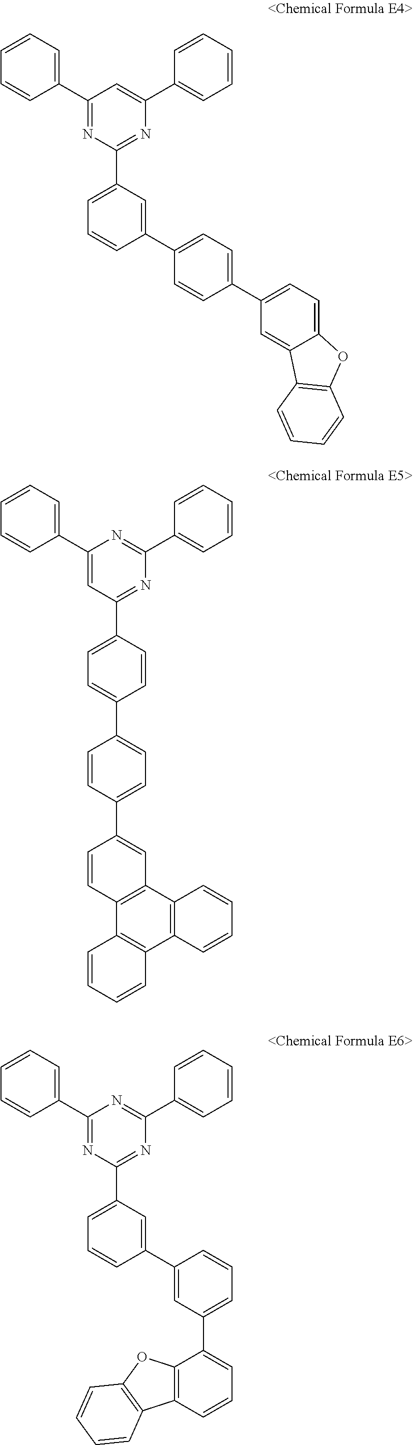 [SMILES: c1ccc(-c2cc(-c3ccccc3)nc(-c3cccc(-c4ccc(-c5ccc6oc7ccccc7c6c5)cc4)c3)n2)cc1 ; c1ccc(-c2cc(-c3ccc(-c4ccc(-c5ccc6c7ccccc7c7ccccc7c6c5)cc4)cc3)nc(-c3ccccc3)n2)cc1 ; c1ccc(-c2nc(-c3ccccc3)nc(-c3cccc(-c4cccc(-c5cccc6c5oc5ccccc56)c4)c3)n2)cc1]

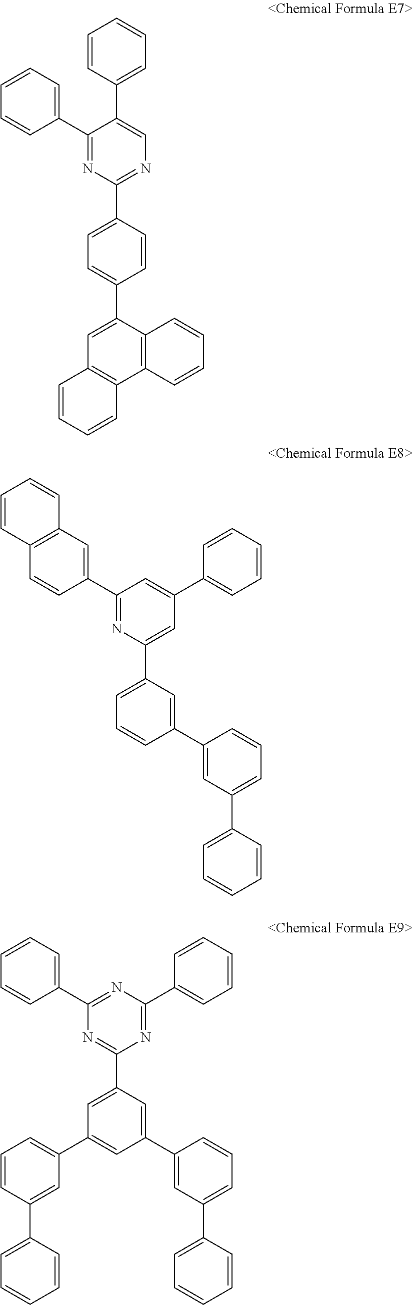 [SMILES: c1ccc(-c2cnc(-c3ccc(-c4cc5ccccc5c5ccccc45)cc3)nc2-c2ccccc2)cc1 ; c1ccc(-c2cccc(-c3cccc(-c4cc(-c5ccccc5)cc(-c5ccc6ccccc6c5)n4)c3)c2)cc1 ; c1ccc(-c2cccc(-c3cc(-c4cccc(-c5ccccc5)c4)cc(-c4nc(-c5ccccc5)nc(-c5ccccc5)n4)c3)c2)cc1]

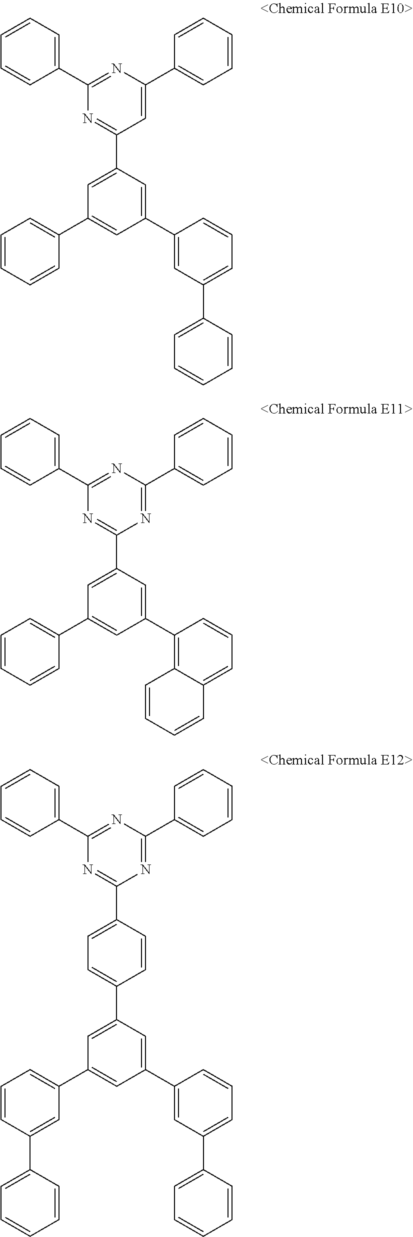

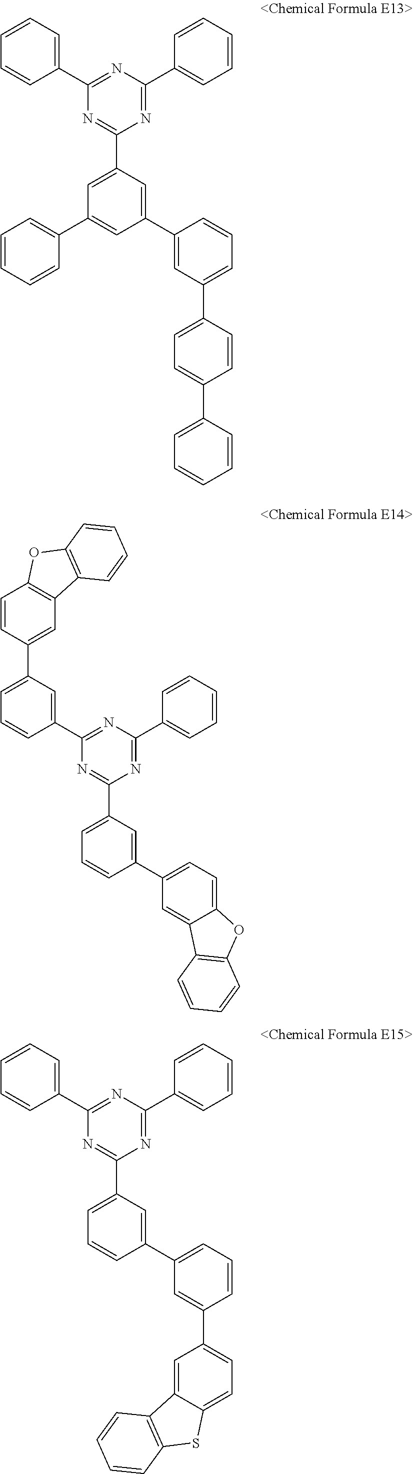

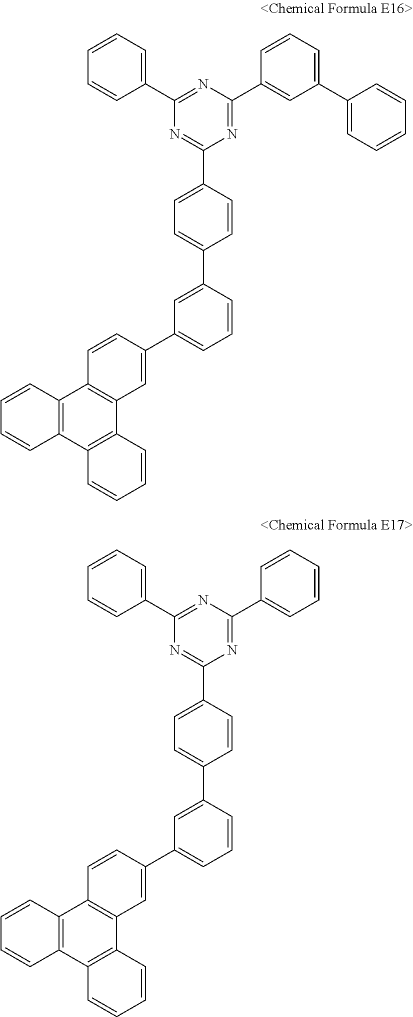 [SMILES: c1ccc(-c2cccc(-c3nc(-c4ccccc4)nc(-c4ccc(-c5cccc(-c6ccc7c8ccccc8c8ccccc8c7c6)c5)cc4)n3)c2)cc1 ; c1ccc(-c2nc(-c3ccccc3)nc(-c3ccc(-c4cccc(-c5ccc6c7ccccc7c7ccccc7c6c5)c4)cc3)n2)cc1]

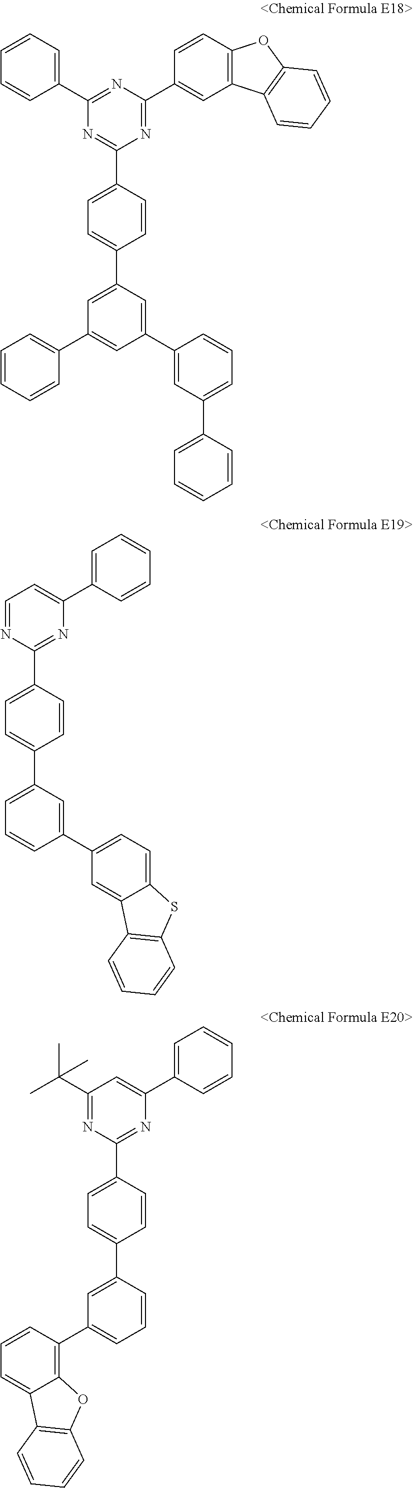 [SMILES: c1ccc(-c2cccc(-c3cc(-c4ccccc4)cc(-c4ccc(-c5nc(-c6ccccc6)nc(-c6ccc7oc8ccccc8c7c6)n5)cc4)c3)c2)cc1 ; c1ccc(-c2ccnc(-c3ccc(-c4cccc(-c5ccc6sc7ccccc7c6c5)c4)cc3)n2)cc1 ; CC(C)(C)c1cc(-c2ccccc2)nc(-c2ccc(-c3cccc(-c4cccc5c4oc4ccccc45)c3)cc2)n1]

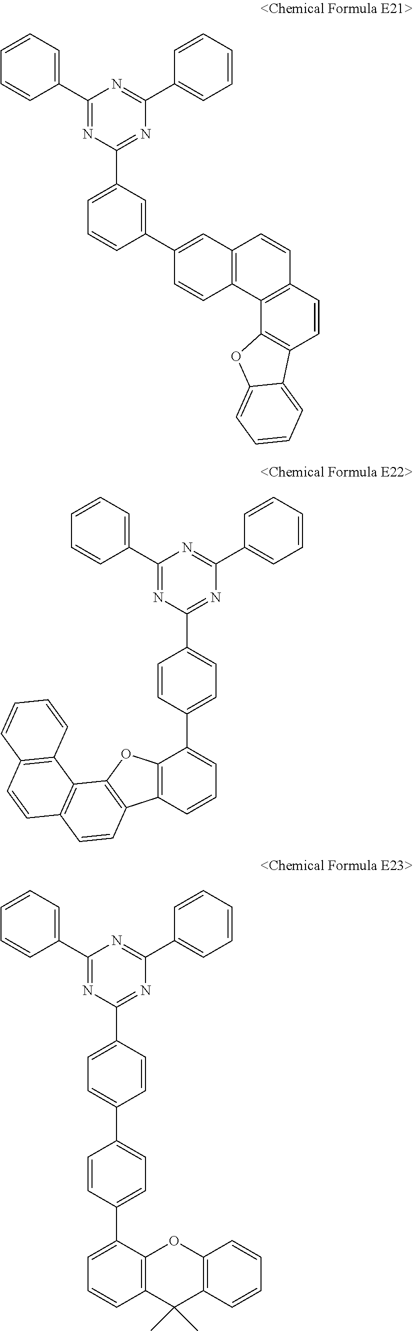 [SMILES: c1ccc(-c2nc(-c3ccccc3)nc(-c3cccc(-c4ccc5c(ccc6ccc7c8ccccc8oc7c65)c4)c3)n2)cc1 ; c1ccc(-c2nc(-c3ccccc3)nc(-c3ccc(-c4cccc5c4oc4c5ccc5ccc6ccccc6c54)cc3)n2)cc1 ; CC1(C)c2ccccc2Oc2c(-c3ccc(-c4ccc(-c5nc(-c6ccccc6)nc(-c6ccccc6)n5)cc4)cc3)cccc21]

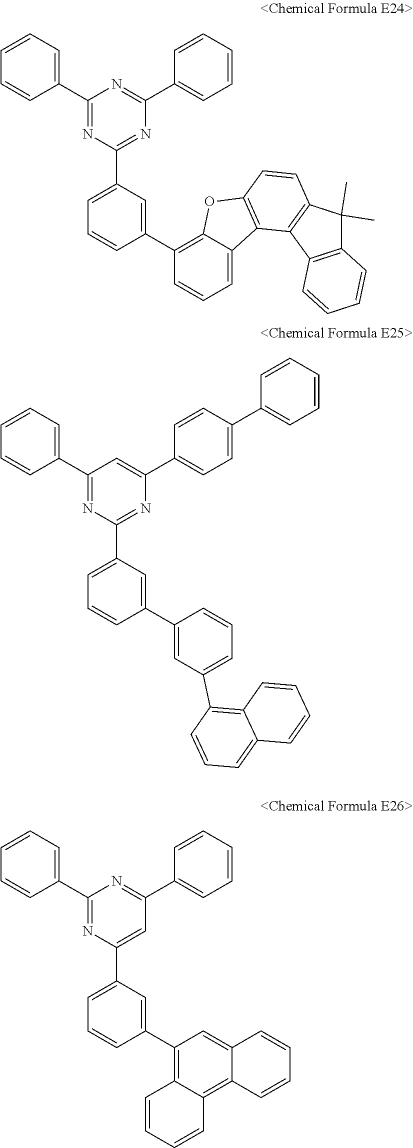 [SMILES: CC1(C)c2ccccc2-c2c1ccc1oc3c(-c4cccc(-c5nc(-c6ccccc6)nc(-c6ccccc6)n5)c4)cccc3c21 ; c1ccc(-c2ccc(-c3cc(-c4ccccc4)nc(-c4cccc(-c5cccc(-c6cccc7ccccc67)c5)c4)n3)cc2)cc1 ; c1ccc(-c2cc(-c3cccc(-c4cc5ccccc5c5ccccc45)c3)nc(-c3ccccc3)n2)cc1]

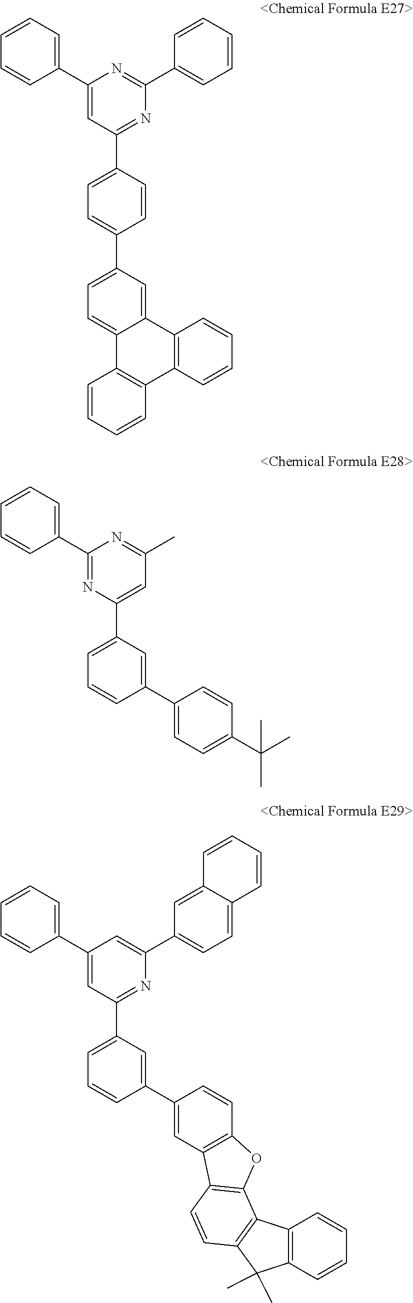 [SMILES: c1ccc(-c2cc(-c3ccc(-c4ccc5c6ccccc6c6ccccc6c5c4)cc3)nc(-c3ccccc3)n2)cc1 ; Cc1cc(-c2cccc(-c3ccc(C(C)(C)C)cc3)c2)nc(-c2ccccc2)n1 ; CC1(C)c2ccccc2-c2c1ccc1c2oc2ccc(-c3cccc(-c4cc(-c5ccccc5)cc(-c5ccc6ccccc6c5)n4)c3)cc21]

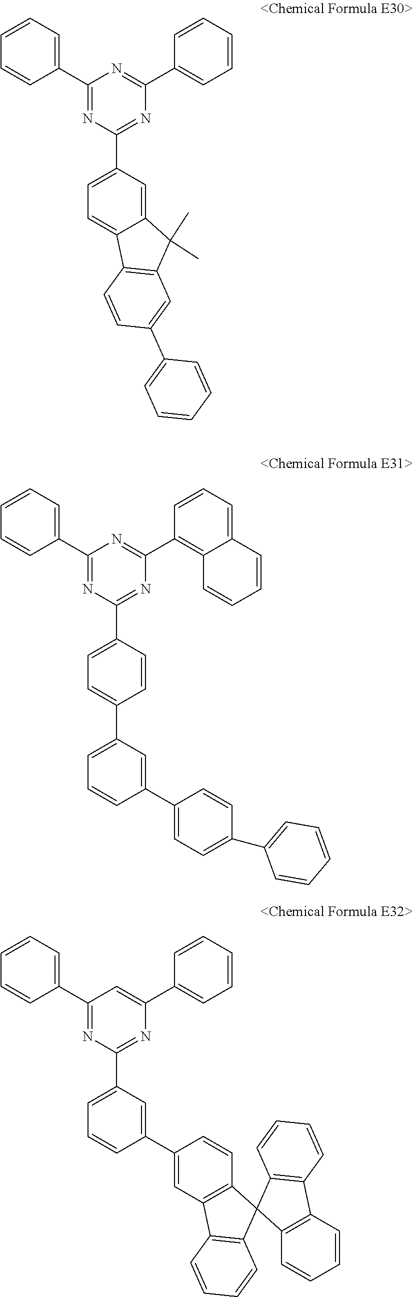 [SMILES: CC1(C)c2cc(-c3ccccc3)ccc2-c2ccc(-c3nc(-c4ccccc4)nc(-c4ccccc4)n3)cc21 ; c1ccc(-c2ccc(-c3cccc(-c4ccc(-c5nc(-c6ccccc6)nc(-c6cccc7ccccc67)n5)cc4)c3)cc2)cc1 ; c1ccc(-c2cc(-c3ccccc3)nc(-c3cccc(-c4ccc5c(c4)-c4ccccc4C54c5ccccc5-c5ccccc54)c3)n2)cc1]

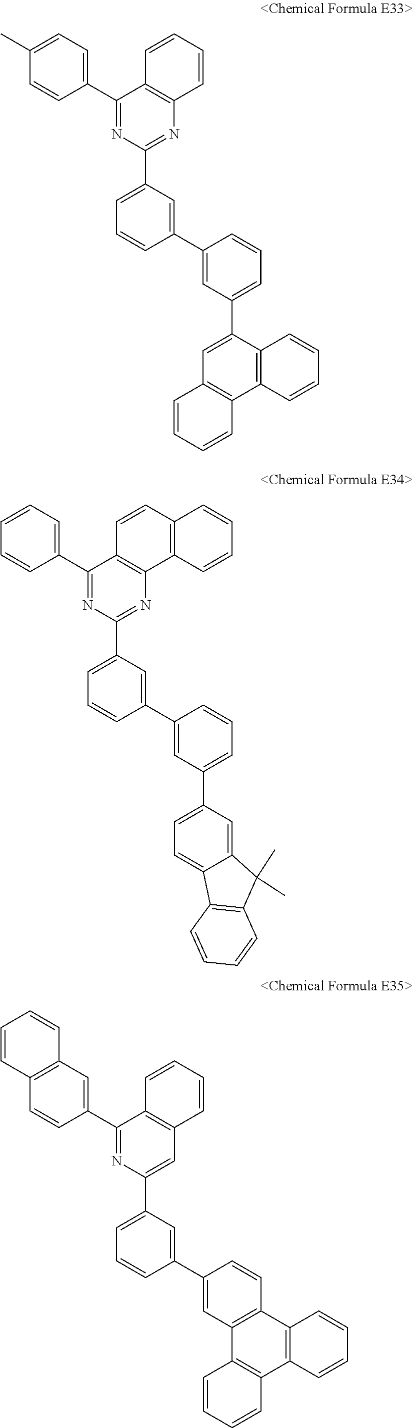 [SMILES: Cc1ccc(-c2nc(-c3cccc(-c4cccc(-c5cc6ccccc6c6ccccc56)c4)c3)nc3ccccc23)cc1 ; CC1(C)c2ccccc2-c2ccc(-c3cccc(-c4cccc(-c5nc(-c6ccccc6)c6ccc7ccccc7c6n5)c4)c3)cc21 ; c1cc(-c2ccc3c4ccccc4c4ccccc4c3c2)cc(-c2cc3ccccc3c(-c3ccc4ccccc4c3)n2)c1]

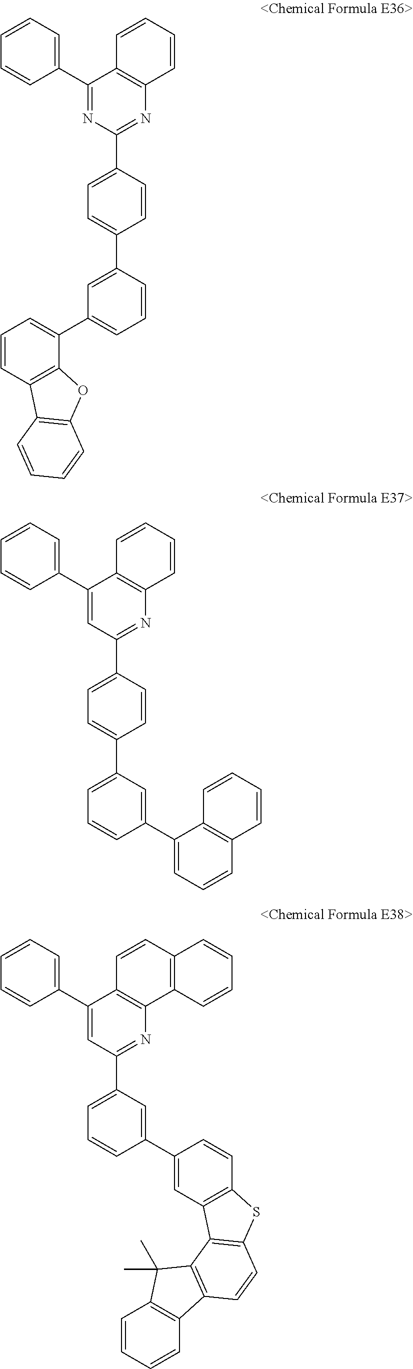 [SMILES: c1ccc(-c2nc(-c3ccc(-c4cccc(-c5cccc6c5oc5ccccc56)c4)cc3)nc3ccccc23)cc1 ; c1ccc(-c2cc(-c3ccc(-c4cccc(-c5cccc6ccccc56)c4)cc3)nc3ccccc23)cc1 ; CC1(C)c2ccccc2-c2ccc3sc4ccc(-c5cccc(-c6cc(-c7ccccc7)c7ccc8ccccc8c7n6)c5)cc4c3c21]

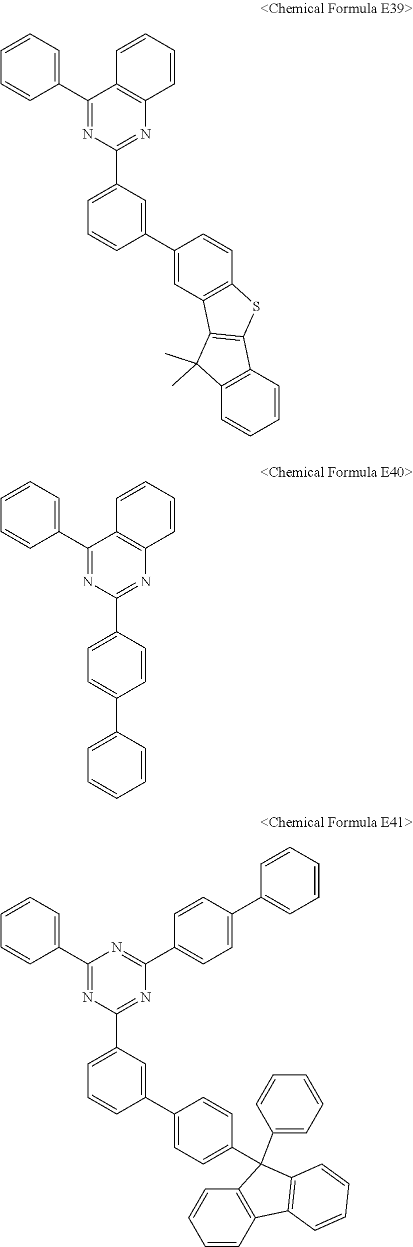 [SMILES: CC1(C)c2ccccc2-c2sc3ccc(-c4cccc(-c5nc(-c6ccccc6)c6ccccc6n5)c4)cc3c21 ; c1ccc(-c2ccc(-c3nc(-c4ccccc4)c4ccccc4n3)cc2)cc1 ; c1ccc(-c2ccc(-c3nc(-c4ccccc4)nc(-c4cccc(-c5ccc(C6(c7ccccc7)c7ccccc7-c7ccccc76)cc5)c4)n3)cc2)cc1]

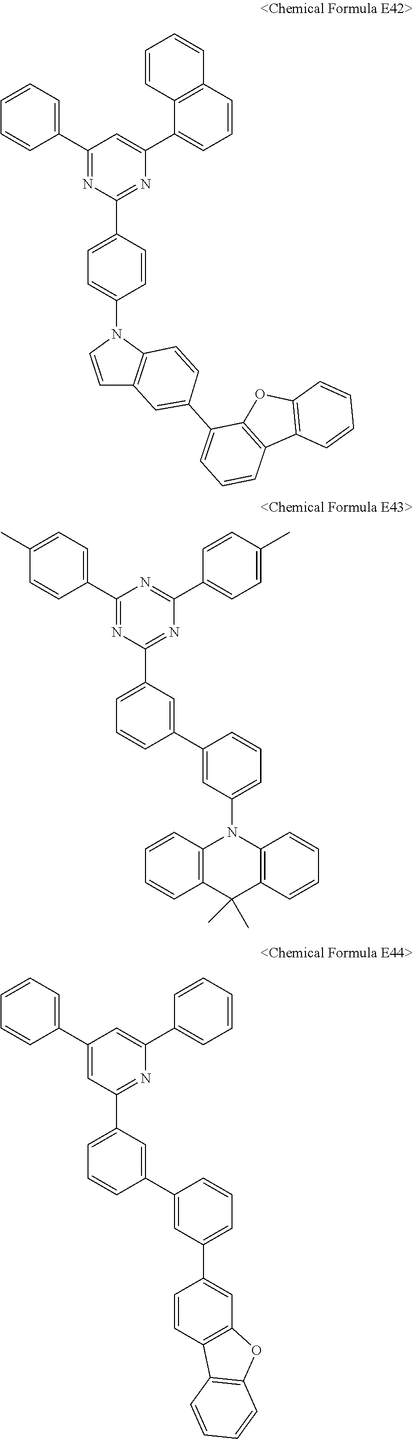 [SMILES: c1ccc(-c2cc(-c3cccc4ccccc34)nc(-c3ccc(-n4ccc5cc(-c6cccc7c6oc6ccccc67)ccc54)cc3)n2)cc1 ; Cc1ccc(-c2nc(-c3ccc(C)cc3)nc(-c3cccc(-c4cccc(N5c6ccccc6C(C)(C)c6ccccc65)c4)c3)n2)cc1 ; c1ccc(-c2cc(-c3ccccc3)nc(-c3cccc(-c4cccc(-c5ccc6c(c5)oc5ccccc56)c4)c3)c2)cc1]

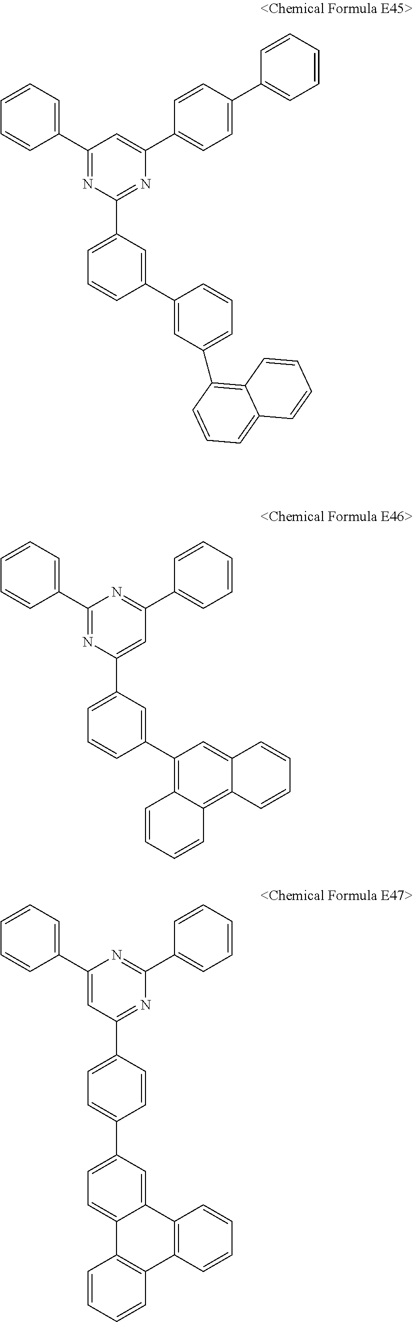 [SMILES: c1ccc(-c2ccc(-c3cc(-c4ccccc4)nc(-c4cccc(-c5cccc(-c6cccc7ccccc67)c5)c4)n3)cc2)cc1 ; c1ccc(-c2cc(-c3cccc(-c4cc5ccccc5c5ccccc45)c3)nc(-c3ccccc3)n2)cc1 ; c1ccc(-c2cc(-c3ccc(-c4ccc5c6ccccc6c6ccccc6c5c4)cc3)nc(-c3ccccc3)n2)cc1]

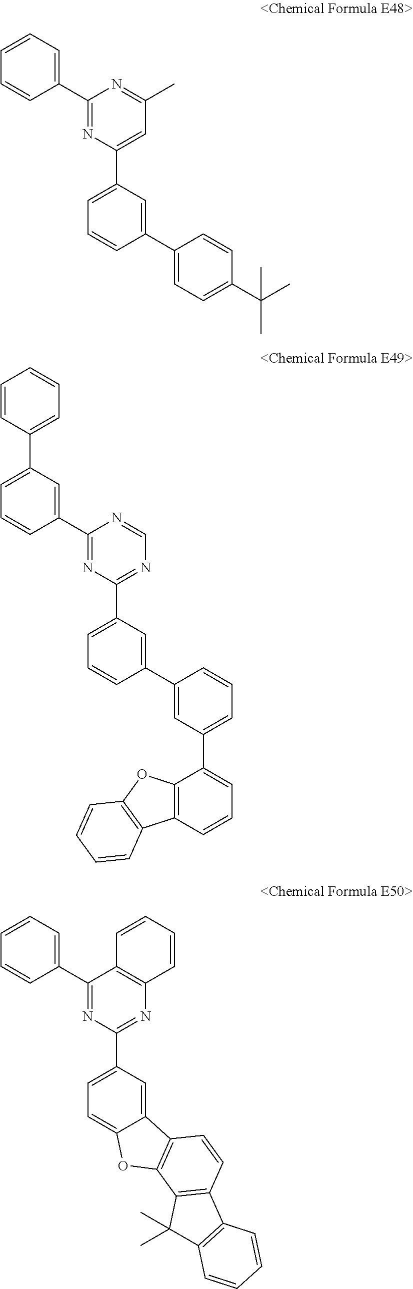 [SMILES: Cc1cc(-c2cccc(-c3ccc(C(C)(C)C)cc3)c2)nc(-c2ccccc2)n1 ; c1ccc(-c2cccc(-c3ncnc(-c4cccc(-c5cccc(-c6cccc7c6oc6ccccc67)c5)c4)n3)c2)cc1 ; CC1(C)c2ccccc2-c2ccc3c(oc4ccc(-c5nc(-c6ccccc6)c6ccccc6n5)cc43)c21]

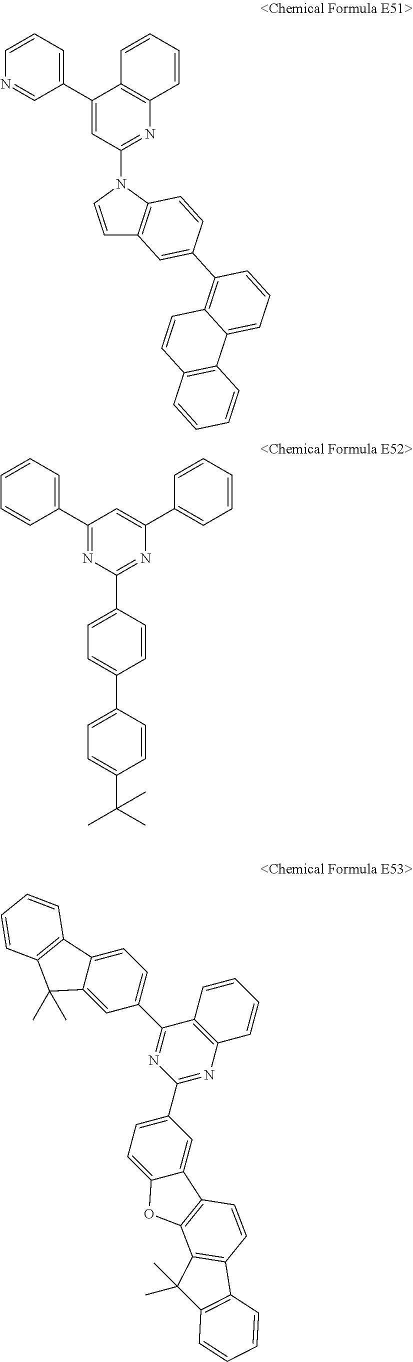

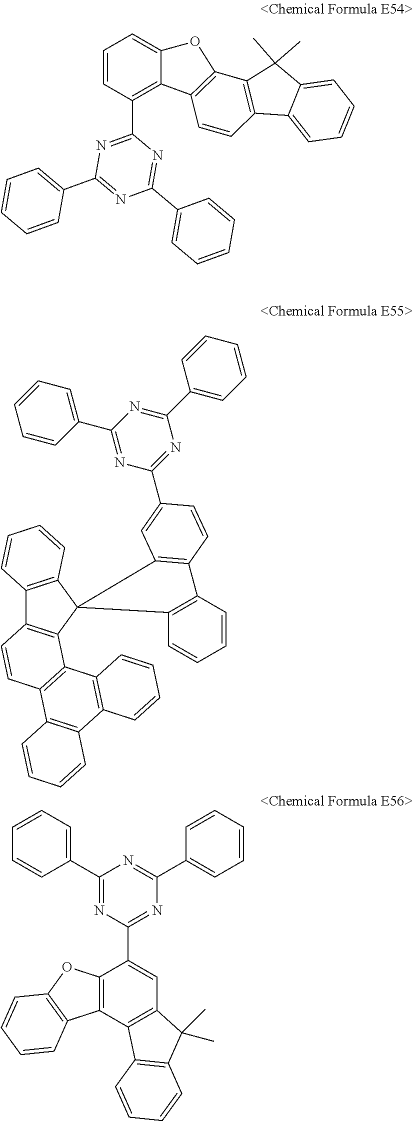

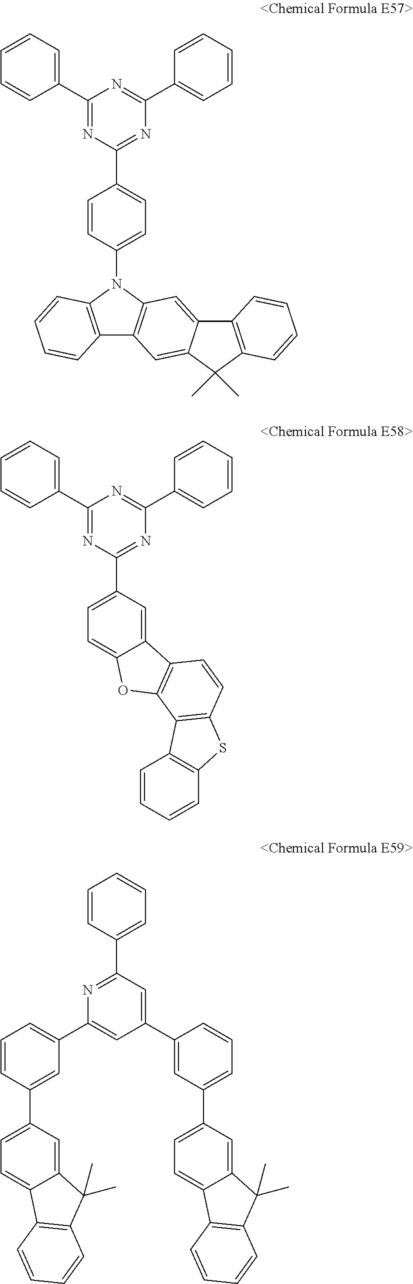

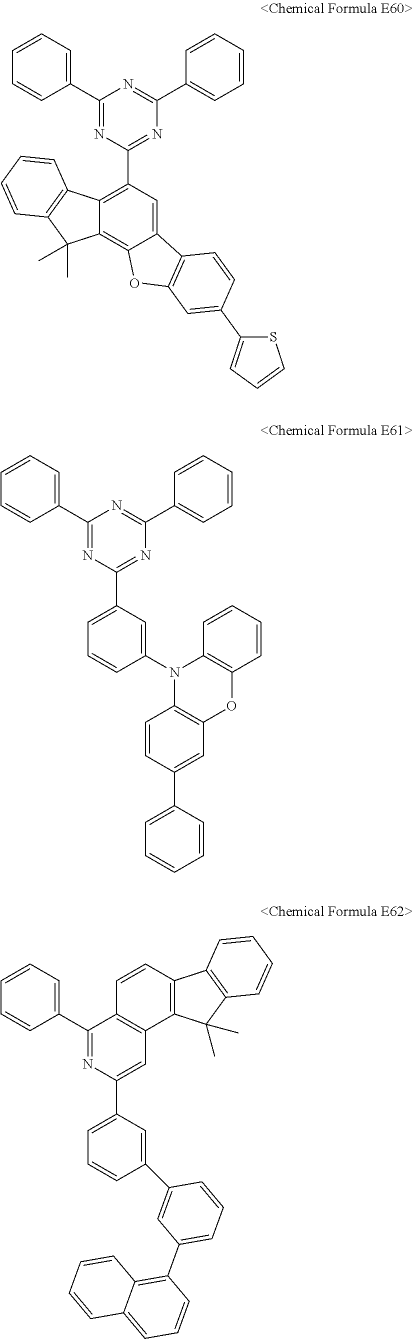 [SMILES: CC1(C)c2ccccc2-c2c(-c3nc(-c4ccccc4)nc(-c4ccccc4)n3)cc3c(oc4cc(-c5cccs5)ccc43)c21 ; c1ccc(-c2ccc3c(c2)Oc2ccccc2N3c2cccc(-c3nc(-c4ccccc4)nc(-c4ccccc4)n3)c2)cc1 ; CC1(C)c2ccccc2-c2ccc3c(-c4ccccc4)nc(-c4cccc(-c5cccc(-c6cccc7ccccc67)c5)c4)cc3c21]

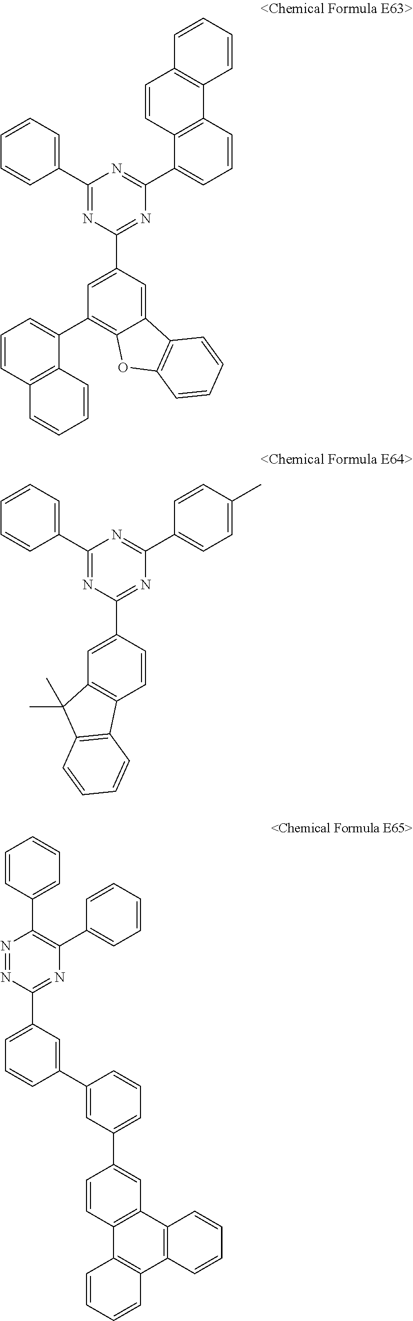 [SMILES: c1ccc(-c2nc(-c3cc(-c4cccc5ccccc45)c4oc5ccccc5c4c3)nc(-c3cccc4c3ccc3ccccc34)n2)cc1 ; Cc1ccc(-c2nc(-c3ccccc3)nc(-c3ccc4c(c3)C(C)(C)c3ccccc3-4)n2)cc1 ; c1ccc(-c2nnc(-c3cccc(-c4cccc(-c5ccc6c7ccccc7c7ccccc7c6c5)c4)c3)nc2-c2ccccc2)cc1]

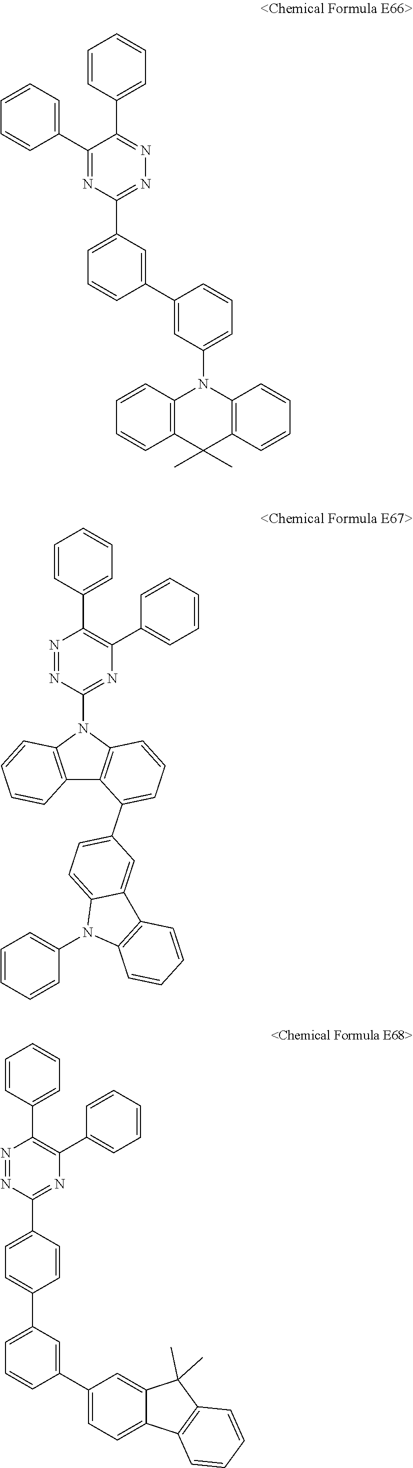

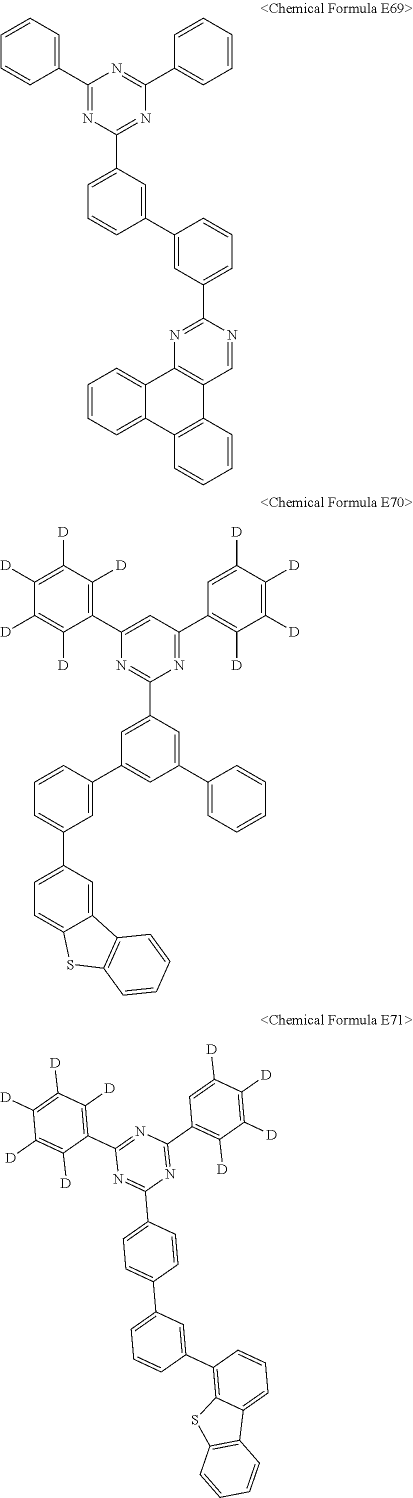 [SMILES: c1ccc(-c2nc(-c3ccccc3)nc(-c3cccc(-c4cccc(-c5ncc6c7ccccc7c7ccccc7c6n5)c4)c3)n2)cc1 ; [2H]c1cc(-c2cc(-c3c([2H])c([2H])c([2H])c([2H])c3[2H])nc(-c3cc(-c4ccccc4)cc(-c4cccc(-c5ccc6sc7ccccc7c6c5)c4)c3)n2)c([2H])c([2H])c1[2H] ; [2H]c1cc(-c2nc(-c3ccc(-c4cccc(-c5cccc6c5sc5ccccc56)c4)cc3)nc(-c3c([2H])c([2H])c([2H])c([2H])c3[2H])n2)c([2H])c([2H])c1[2H]]

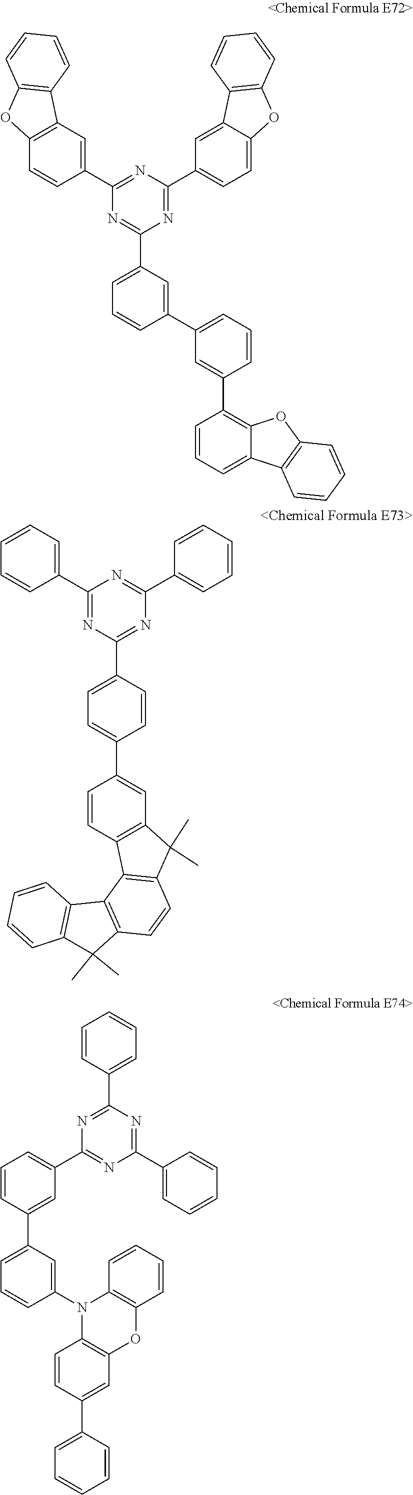

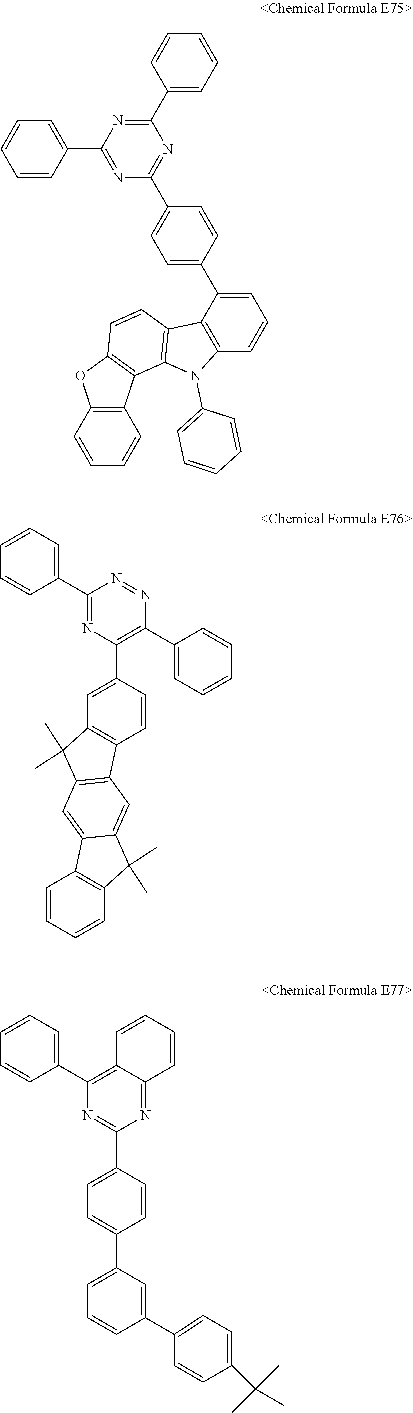 [SMILES: c1ccc(-c2nc(-c3ccccc3)nc(-c3ccc(-c4cccc5c4c4ccc6oc7ccccc7c6c4n5-c4ccccc4)cc3)n2)cc1 ; CC1(C)c2ccccc2-c2cc3c(cc21)-c1ccc(-c2nc(-c4ccccc4)nnc2-c2ccccc2)cc1C3(C)C ; CC(C)(C)c1ccc(-c2cccc(-c3ccc(-c4nc(-c5ccccc5)c5ccccc5n4)cc3)c2)cc1]

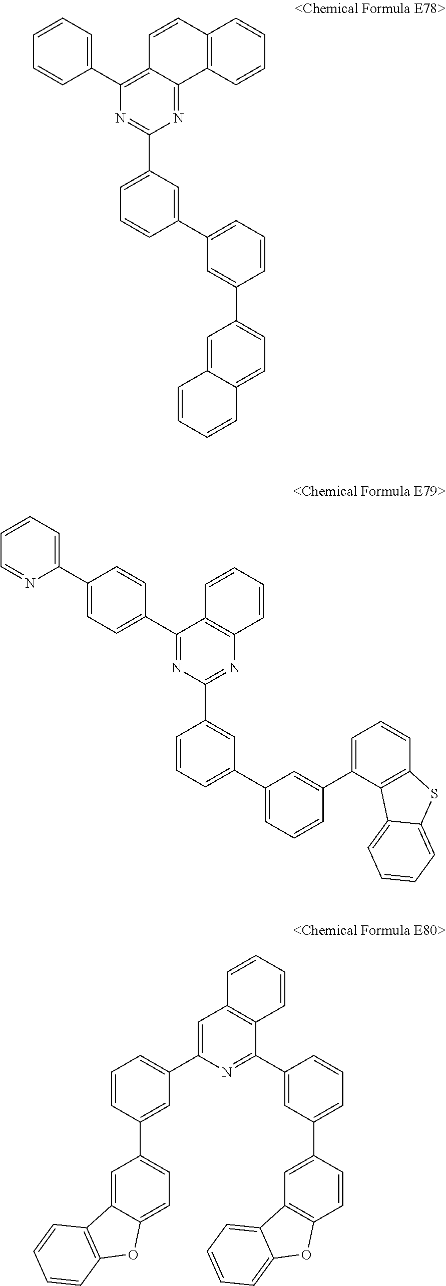 [SMILES: c1ccc(-c2nc(-c3cccc(-c4cccc(-c5ccc6ccccc6c5)c4)c3)nc3c2ccc2ccccc23)cc1 ; c1ccc(-c2ccc(-c3nc(-c4cccc(-c5cccc(-c6cccc7sc8ccccc8c67)c5)c4)nc4ccccc34)cc2)nc1 ; c1cc(-c2ccc3oc4ccccc4c3c2)cc(-c2cc3ccccc3c(-c3cccc(-c4ccc5oc6ccccc6c5c4)c3)n2)c1]

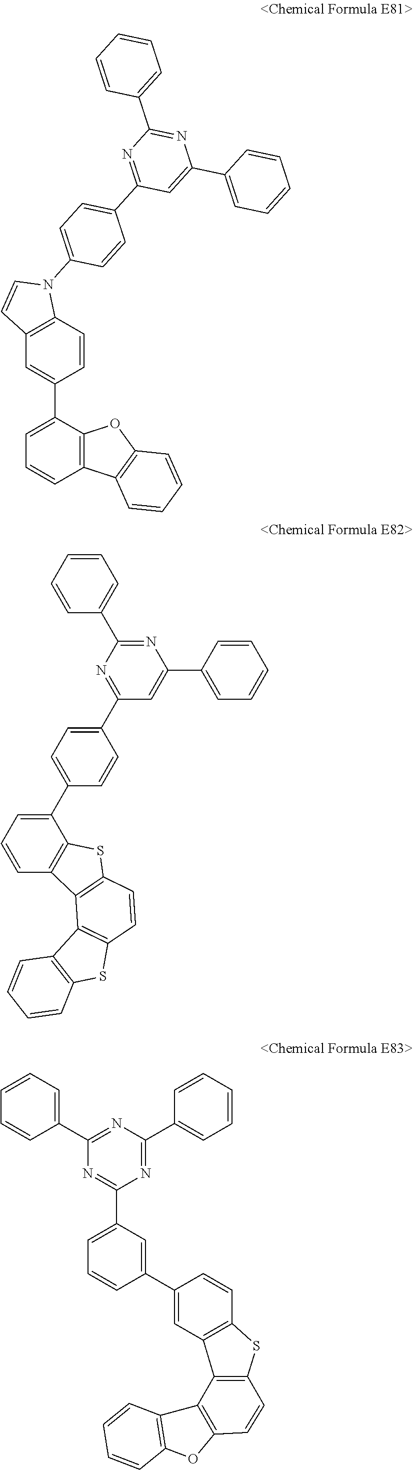 [SMILES: c1ccc(-c2cc(-c3ccc(-n4ccc5cc(-c6cccc7c6oc6ccccc67)ccc54)cc3)nc(-c3ccccc3)n2)cc1 ; c1ccc(-c2cc(-c3ccc(-c4cccc5c4sc4ccc6sc7ccccc7c6c45)cc3)nc(-c3ccccc3)n2)cc1 ; c1ccc(-c2nc(-c3ccccc3)nc(-c3cccc(-c4ccc5sc6ccc7oc8ccccc8c7c6c5c4)c3)n2)cc1]

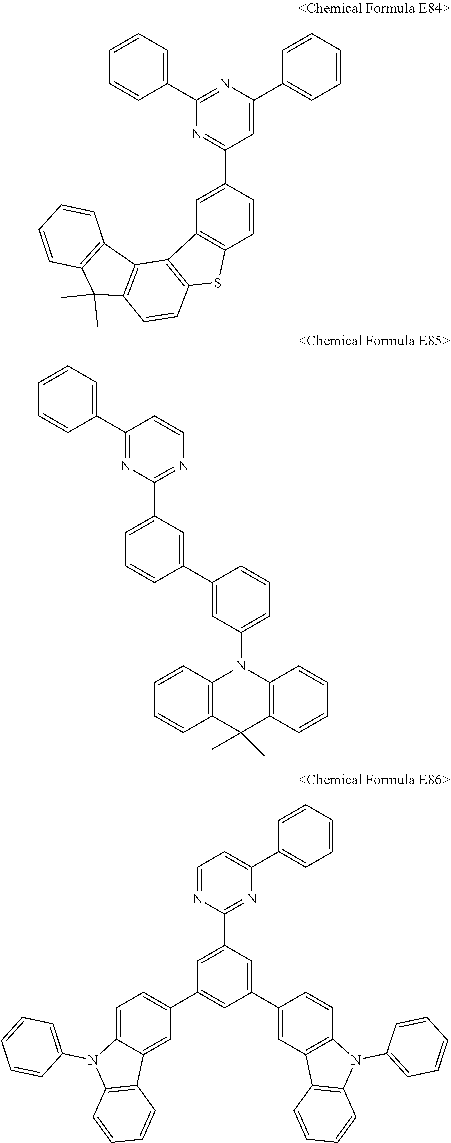 [SMILES: CC1(C)c2ccccc2-c2c1ccc1sc3ccc(-c4cc(-c5ccccc5)nc(-c5ccccc5)n4)cc3c21 ; CC1(C)c2ccccc2N(c2cccc(-c3cccc(-c4nccc(-c5ccccc5)n4)c3)c2)c2ccccc21 ; c1ccc(-c2ccnc(-c3cc(-c4ccc5c(c4)c4ccccc4n5-c4ccccc4)cc(-c4ccc5c(c4)c4ccccc4n5-c4ccccc4)c3)n2)cc1]

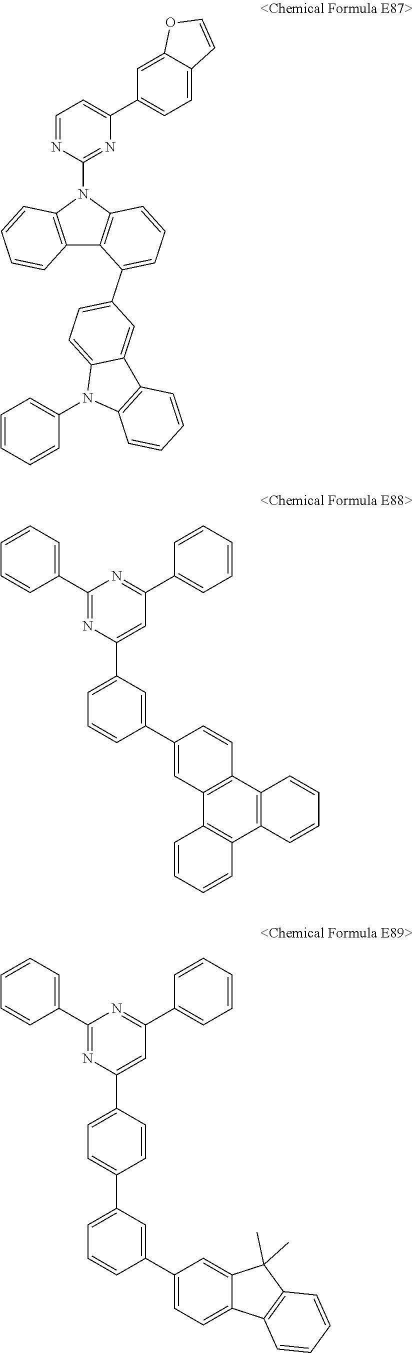 [SMILES: c1ccc(-n2c3ccccc3c3cc(-c4cccc5c4c4ccccc4n5-c4nccc(-c5ccc6ccoc6c5)n4)ccc32)cc1 ; c1ccc(-c2cc(-c3cccc(-c4ccc5c6ccccc6c6ccccc6c5c4)c3)nc(-c3ccccc3)n2)cc1 ; CC1(C)c2ccccc2-c2ccc(-c3cccc(-c4ccc(-c5cc(-c6ccccc6)nc(-c6ccccc6)n5)cc4)c3)cc21]

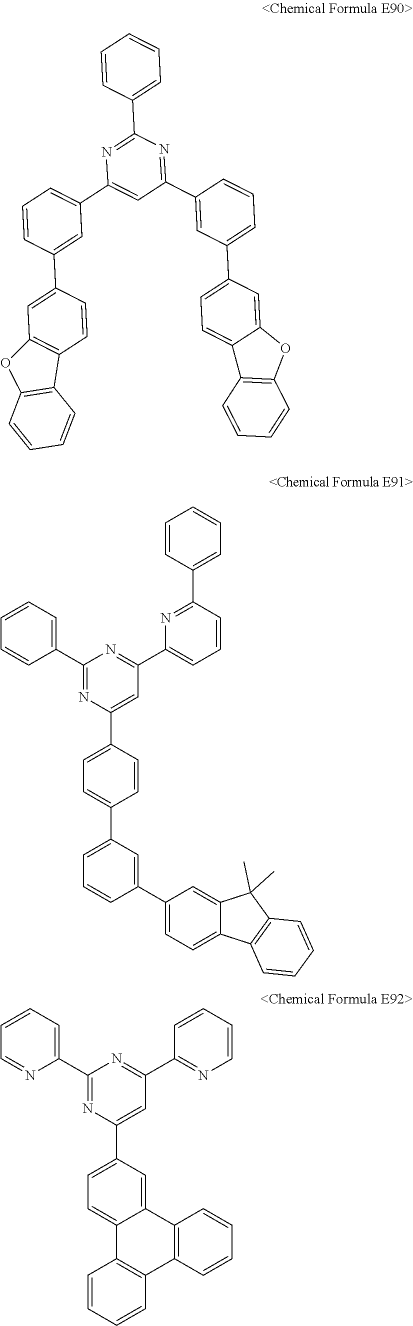 [SMILES: c1ccc(-c2nc(-c3cccc(-c4ccc5c(c4)oc4ccccc45)c3)cc(-c3cccc(-c4ccc5c(c4)oc4ccccc45)c3)n2)cc1 ; CC1(C)c2ccccc2-c2ccc(-c3cccc(-c4ccc(-c5cc(-c6cccc(-c7ccccc7)n6)nc(-c6ccccc6)n5)cc4)c3)cc21 ; c1ccc(-c2cc(-c3ccc4c5ccccc5c5ccccc5c4c3)nc(-c3ccccn3)n2)nc1]

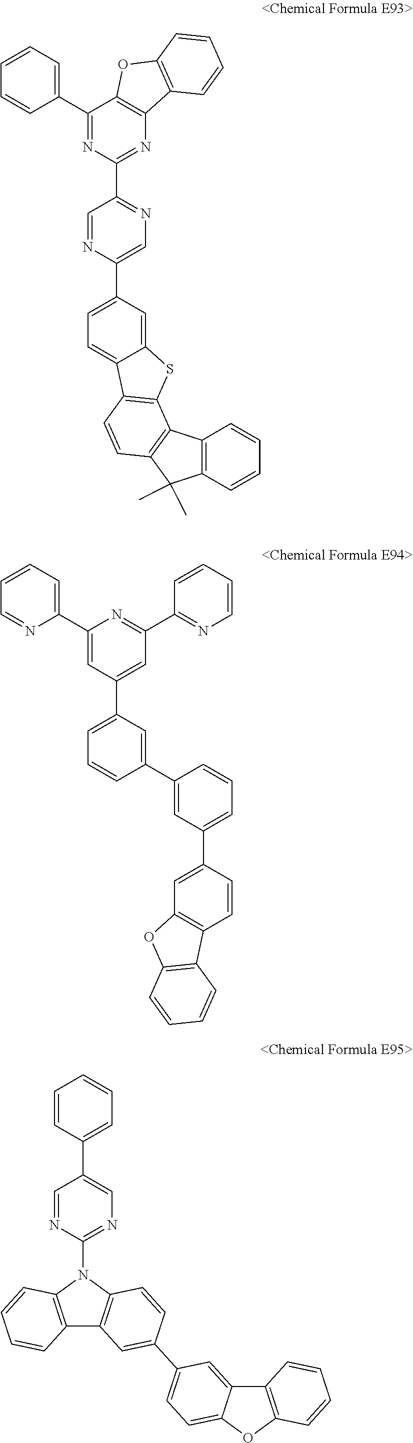 [SMILES: CC1(C)c2ccccc2-c2c1ccc1c2sc2cc(-c3cnc(-c4nc(-c5ccccc5)c5oc6ccccc6c5n4)cn3)ccc21 ; c1ccc(-c2cc(-c3cccc(-c4cccc(-c5ccc6c(c5)oc5ccccc56)c4)c3)cc(-c3ccccn3)n2)nc1 ; c1ccc(-c2cnc(-n3c4ccccc4c4cc(-c5ccc6oc7ccccc7c6c5)ccc43)nc2)cc1]

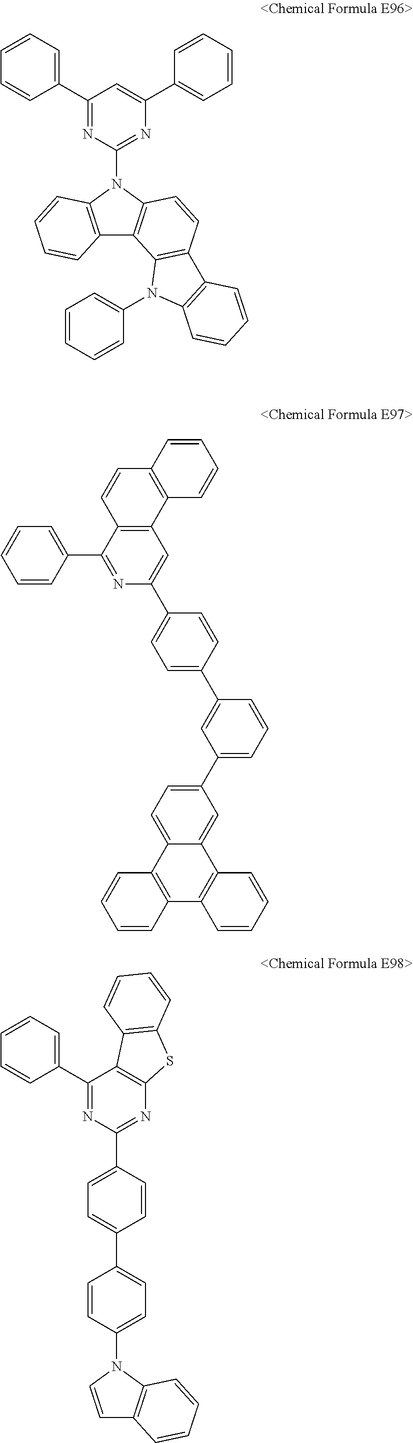

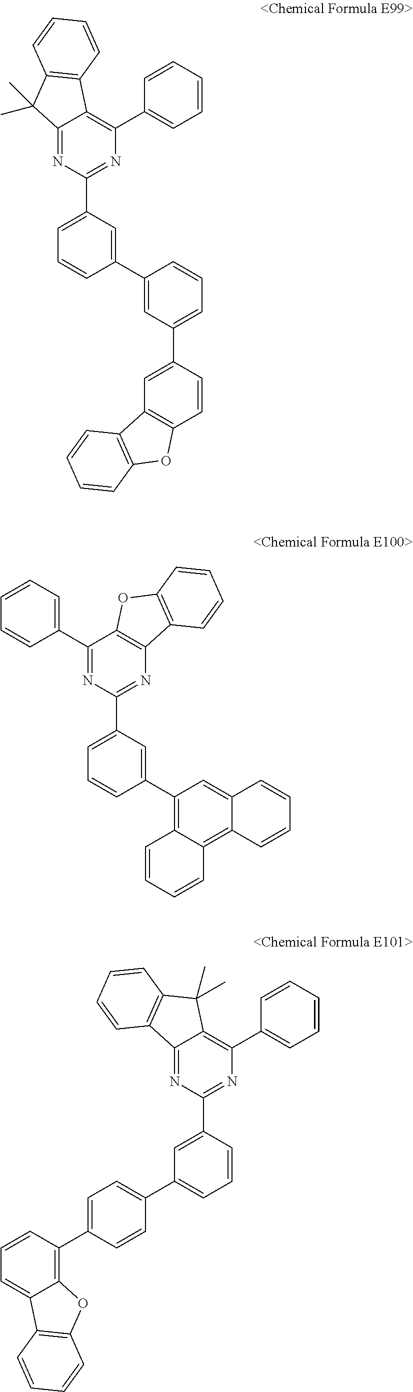 [SMILES: CC1(C)c2ccccc2-c2c(-c3ccccc3)nc(-c3cccc(-c4cccc(-c5ccc6oc7ccccc7c6c5)c4)c3)nc21 ; c1ccc(-c2nc(-c3cccc(-c4cc5ccccc5c5ccccc45)c3)nc3c2oc2ccccc23)cc1 ; CC1(C)c2ccccc2-c2nc(-c3cccc(-c4ccc(-c5cccc6c5oc5ccccc56)cc4)c3)nc(-c3ccccc3)c21]

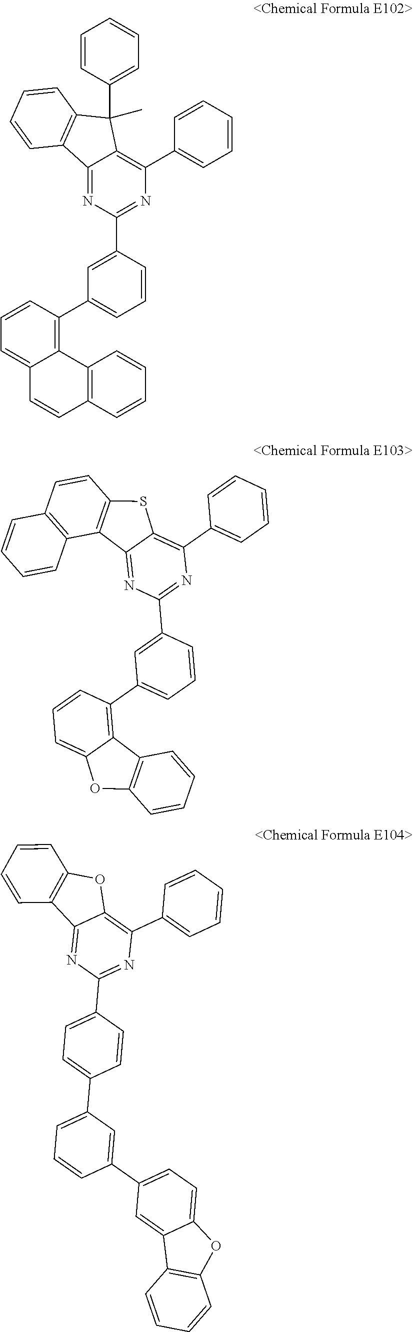 [SMILES: CC1(c2ccccc2)c2ccccc2-c2nc(-c3cccc(-c4cccc5ccc6ccccc6c45)c3)nc(-c3ccccc3)c21 ; c1ccc(-c2nc(-c3cccc(-c4cccc5oc6ccccc6c45)c3)nc3c2sc2ccc4ccccc4c23)cc1 ; c1ccc(-c2nc(-c3ccc(-c4cccc(-c5ccc6oc7ccccc7c6c5)c4)cc3)nc3c2oc2ccccc23)cc1]

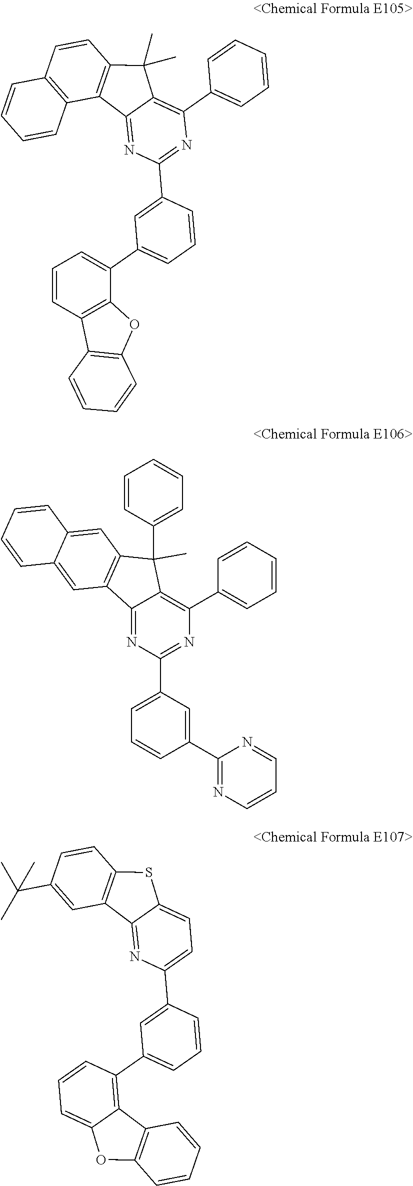 [SMILES: CC1(C)c2ccc3ccccc3c2-c2nc(-c3cccc(-c4cccc5c4oc4ccccc45)c3)nc(-c3ccccc3)c21 ; CC1(c2ccccc2)c2cc3ccccc3cc2-c2nc(-c3cccc(-c4ncccn4)c3)nc(-c3ccccc3)c21 ; CC(C)(C)c1ccc2sc3ccc(-c4cccc(-c5cccc6oc7ccccc7c56)c4)nc3c2c1]

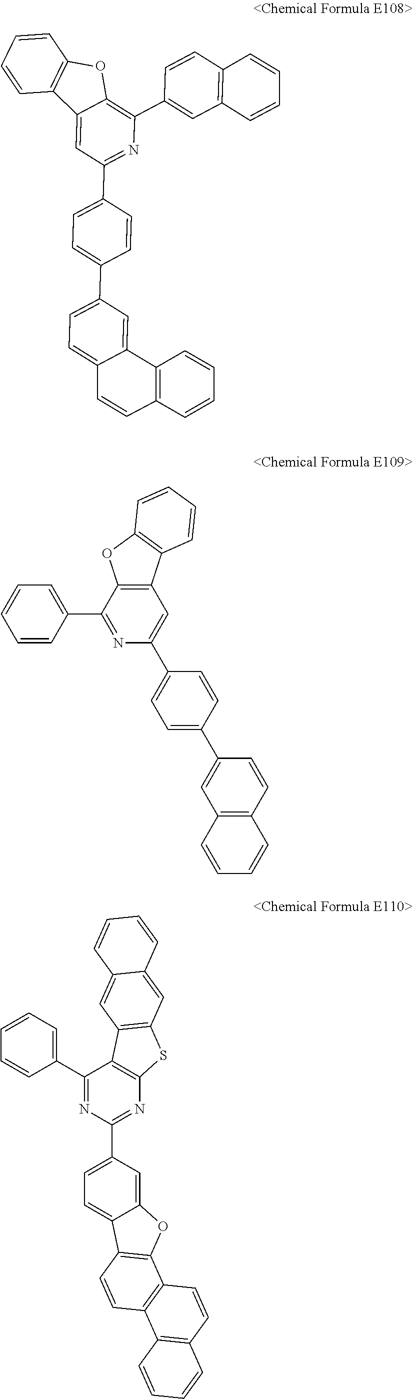 [SMILES: c1ccc2cc(-c3nc(-c4ccc(-c5ccc6ccc7ccccc7c6c5)cc4)cc4c3oc3ccccc34)ccc2c1 ; c1ccc(-c2nc(-c3ccc(-c4ccc5ccccc5c4)cc3)cc3c2oc2ccccc23)cc1 ; c1ccc(-c2nc(-c3ccc4c(c3)oc3c4ccc4c5ccccc5ccc43)nc3sc4cc5ccccc5cc4c23)cc1]

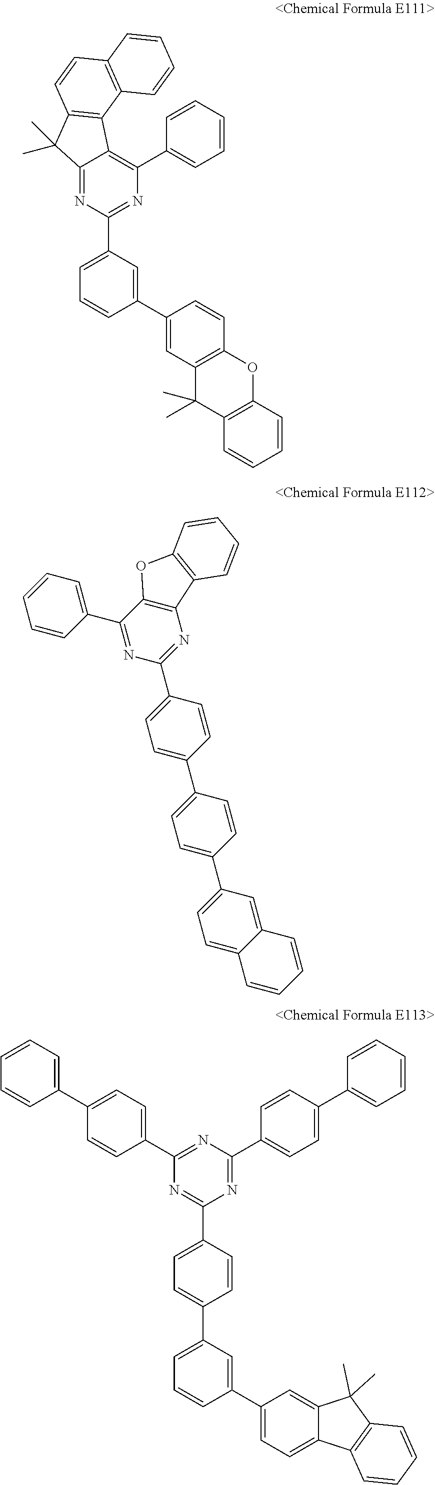

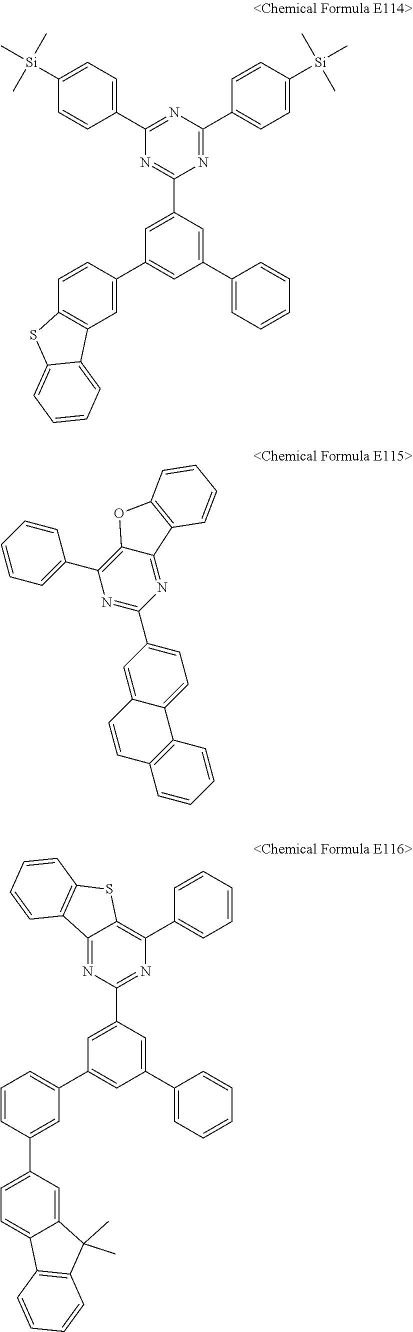

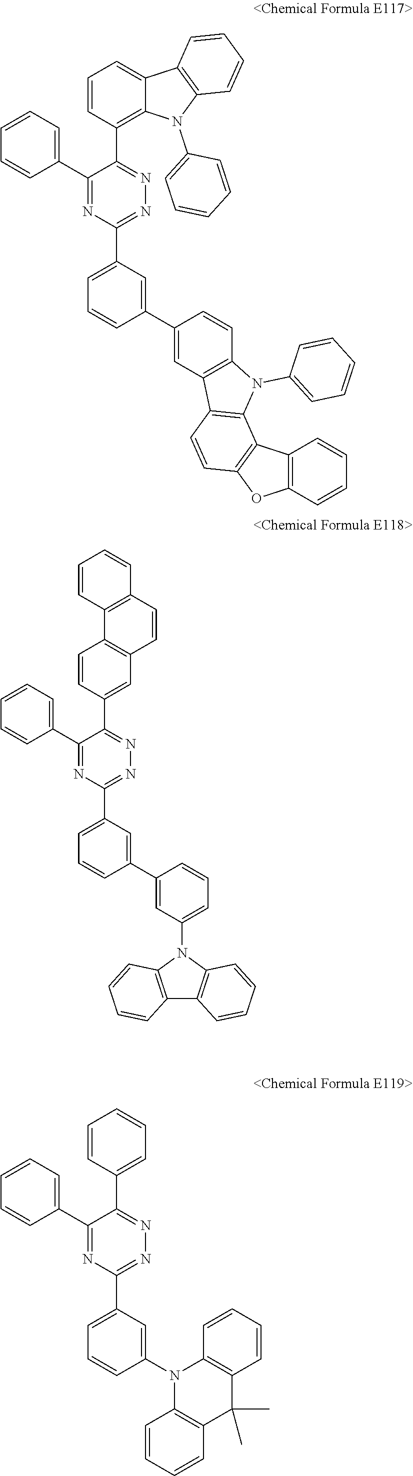

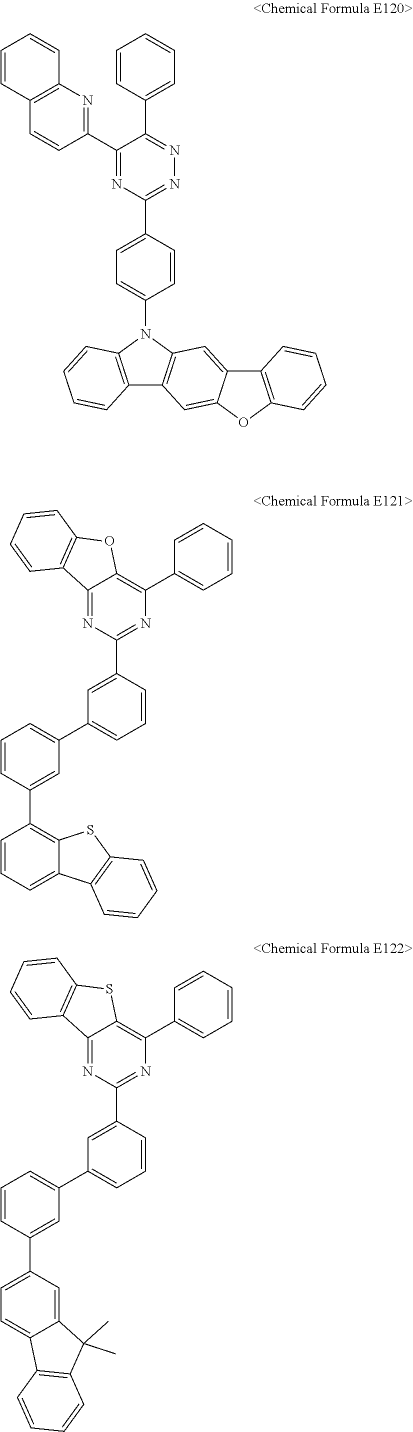

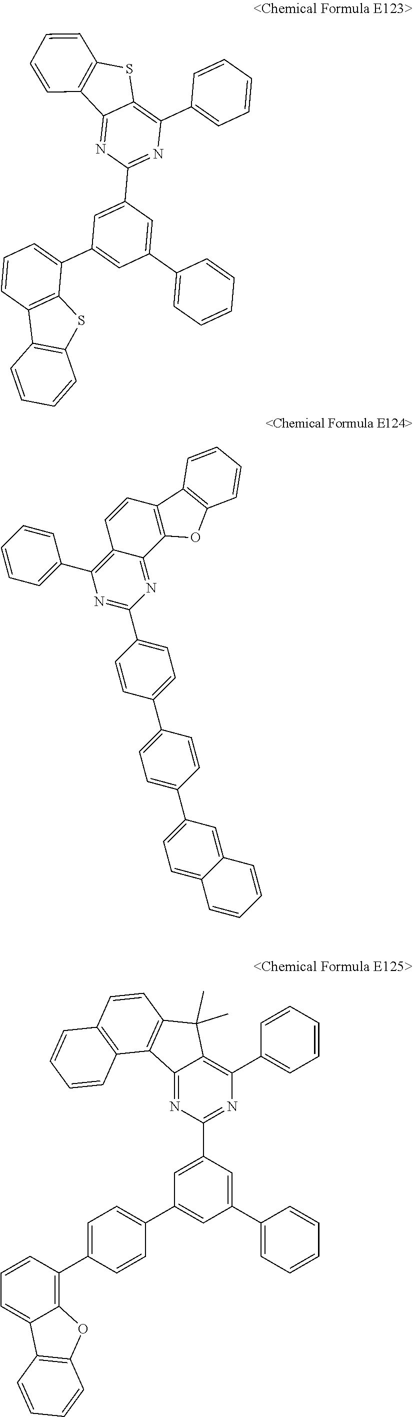

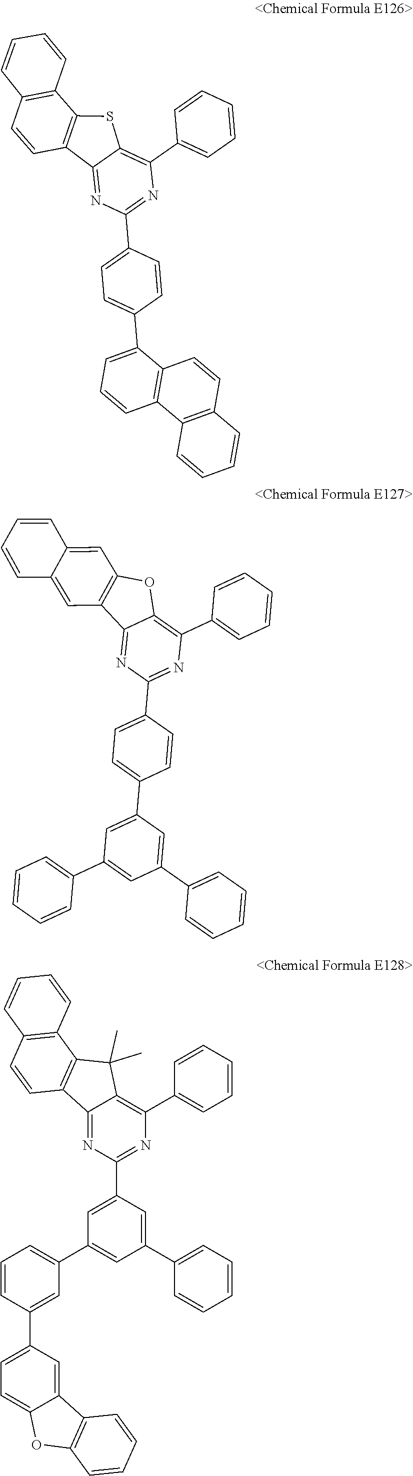

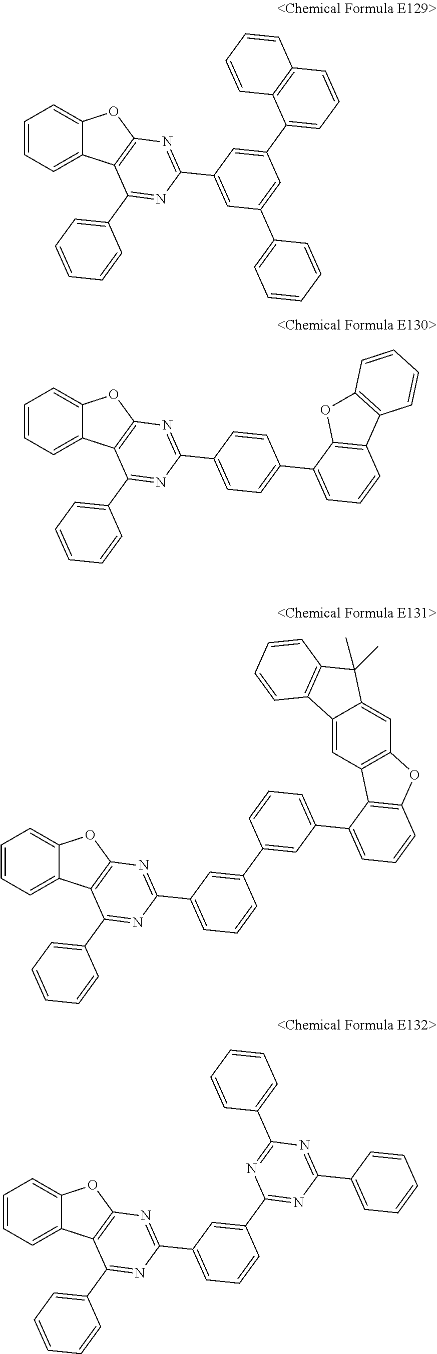 [SMILES: c1ccc(-c2cc(-c3nc(-c4ccccc4)c4c(n3)oc3ccccc34)cc(-c3cccc4ccccc34)c2)cc1 ; c1ccc(-c2nc(-c3ccc(-c4cccc5c4oc4ccccc45)cc3)nc3oc4ccccc4c23)cc1 ; CC1(C)c2ccccc2-c2cc3c(cc21)oc1cccc(-c2cccc(-c4cccc(-c5nc(-c6ccccc6)c6c(n5)oc5ccccc56)c4)c2)c13 ; c1ccc(-c2nc(-c3ccccc3)nc(-c3cccc(-c4nc(-c5ccccc5)c5c(n4)oc4ccccc45)c3)n2)cc1]

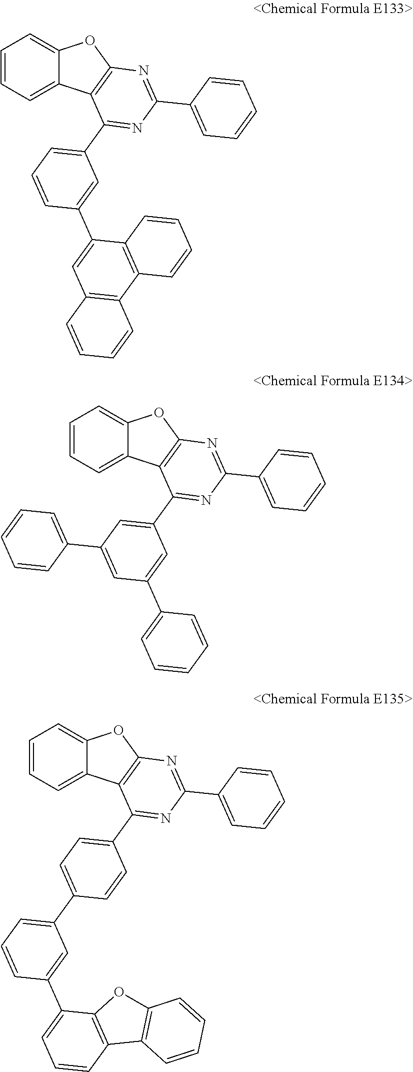 [SMILES: c1ccc(-c2nc(-c3cccc(-c4cc5ccccc5c5ccccc45)c3)c3c(n2)oc2ccccc23)cc1 ; c1ccc(-c2cc(-c3ccccc3)cc(-c3nc(-c4ccccc4)nc4oc5ccccc5c34)c2)cc1 ; c1ccc(-c2nc(-c3ccc(-c4cccc(-c5cccc6c5oc5ccccc56)c4)cc3)c3c(n2)oc2ccccc23)cc1]

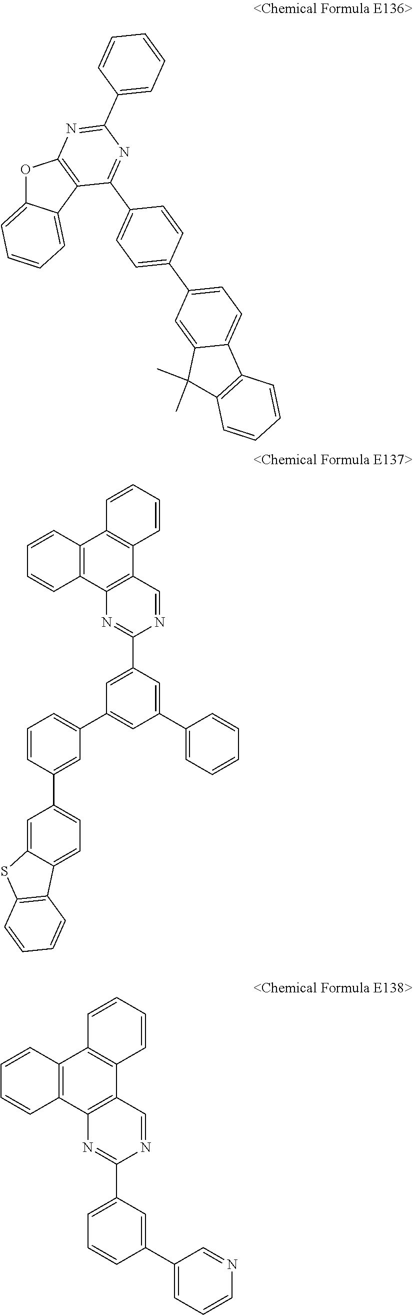 [SMILES: CC1(C)c2ccccc2-c2ccc(-c3ccc(-c4nc(-c5ccccc5)nc5oc6ccccc6c45)cc3)cc21 ; c1ccc(-c2cc(-c3cccc(-c4ccc5c(c4)sc4ccccc45)c3)cc(-c3ncc4c5ccccc5c5ccccc5c4n3)c2)cc1 ; c1cncc(-c2cccc(-c3ncc4c5ccccc5c5ccccc5c4n3)c2)c1]

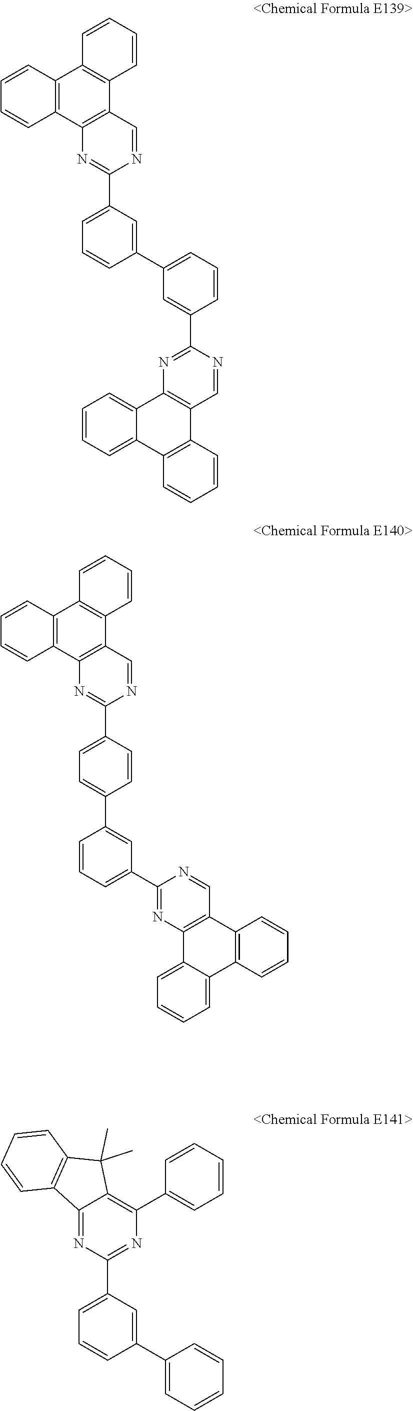 [SMILES: c1cc(-c2cccc(-c3ncc4c5ccccc5c5ccccc5c4n3)c2)cc(-c2ncc3c4ccccc4c4ccccc4c3n2)c1 ; c1cc(-c2ccc(-c3ncc4c5ccccc5c5ccccc5c4n3)cc2)cc(-c2ncc3c4ccccc4c4ccccc4c3n2)c1 ; CC1(C)c2ccccc2-c2nc(-c3cccc(-c4ccccc4)c3)nc(-c3ccccc3)c21]

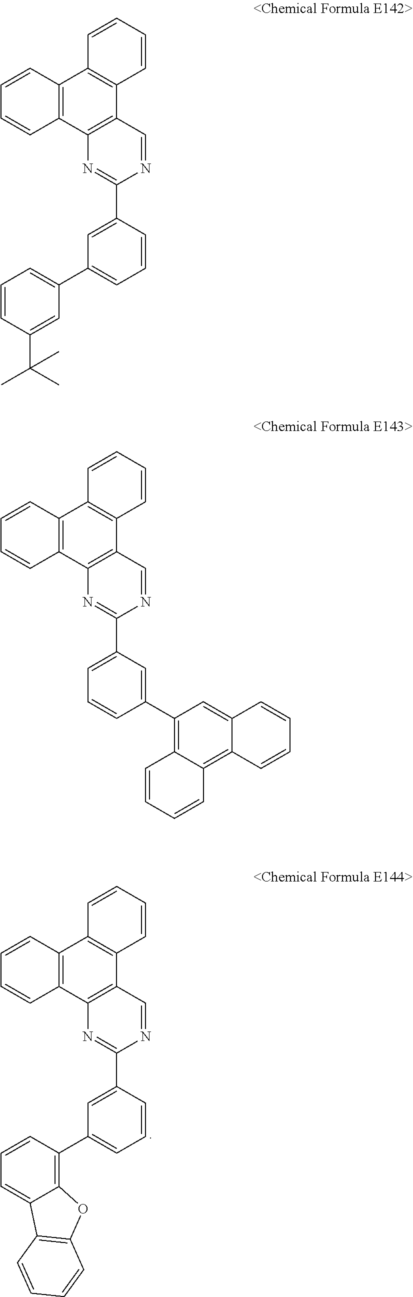 [SMILES: CC(C)(C)c1cccc(-c2cccc(-c3ncc4c5ccccc5c5ccccc5c4n3)c2)c1 ; c1cc(-c2ncc3c4ccccc4c4ccccc4c3n2)cc(-c2cc3ccccc3c3ccccc23)c1 ; c1cc(-c2ncc3c4ccccc4c4ccccc4c3n2)cc(-c2cccc3c2oc2ccccc23)c1]

12. The organic light-emitting diode of claim 1, wherein the fused ring compound represented by [Chemical Formula A] and the hetero ring compound represented by [Chemical Formula D] are each used as a host.

13. The organic light-emitting diode of claim 12, wherein the fused ring compound represented by Chemical Formula A and the hetero ring compound represented by Chemical Formula D is combined at a weight ratio of 1:9 to 9:1.

14. The organic light-emitting diode of claim 12, wherein the light-emitting layer further contains a dopant.

15. The organic light-emitting diode of claim 1, further comprising at least one selected from a hole injection layer, a hole transport layer, a functional layer capable of both hole injection and hole transport, an electron transport layer, and an electron injection layer in addition to the light-emitting layer.

16. The organic light-emitting diode of claim 15, wherein the at least one selected from among the layers is formed using a deposition process or a solution process.

17. The organic light-emitting diode of claim 1, wherein R₄ in Structural Formula 1 is a single bond connected to the linker L₁ in Chemical Formula A.

18. The organic light-emitting diode of claim 1, wherein the organic light-emitting diode is used for a device selected from among a flat display device, a flexible display device, a monochrome or grayscale flat illumination device, and a monochrome or grayscale flexible illumination device.
